(19) United States
(12) Patent Application Publication
(10) Pub. No.: US 2024/0114788 A1
(43) Pub. Date: Apr. 4, 2024

(54) LIGHT EMITTING ELEMENT AND POLYCYCLIC COMPOUND FOR THE SAME

(71) Applicant: Samsung Display Co., Ltd., Yongin-si (KR)

(72) Inventors: MUN-KI SIM, Yongin-si (KR); EUNG DO KIM, Yongin-si (KR); TAEIL KIM, Yongin-si (KR); MinJae SUNG, Yongin-si (KR); MINJUNG JUNG, Yongin-si (KR); Seonhyoung HUR, Yongin-si (KR)

(73) Assignee: Samsung Display Co., Ltd., Yongin-si (KR)

(21) Appl. No.: 18/348,650

(22) Filed: Jul. 7, 2023

(30) Foreign Application Priority Data
Aug. 24, 2022 (KR) 10-2022-0106466

(51) Int. Cl. H10K 85/60; C07F 5/02; C09K 11/06

(52) U.S. Cl. CPC H10K 85/658; C07F 5/027; C09K 11/06; H10K 50/11

(57) ABSTRACT

Embodiments provide light emitting element which includes a first electrode, a second electrode disposed on the first electrode, and an emission layer disposed between the first electrode and the second electrode, wherein the emission layer includes a polycyclic compound represented by Formula 1, which is explained in the specification:

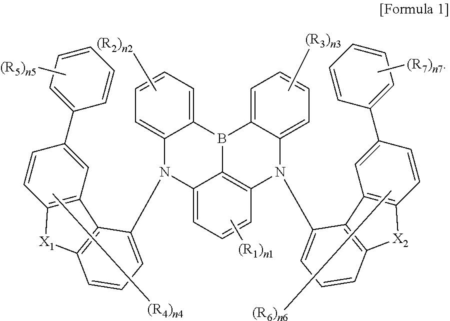

### CROSS-REFERENCE TO RELATED APPLICATION(S)

This application claims priority to and benefits of Korean Patent Application No. 10-2022-0106466 under 35 U.S.C. § 119, filed on Aug. 24, 2022, in the Korean Intellectual Property Office, the entire contents of which are incorporated herein by reference.

### BACKGROUND

### 1. Technical Field

The disclosure relates to a light emitting element including a novel polycyclic compound in an emission layer.

### 2. Description of the Related Art

Active development continues for an organic electroluminescence display device as an image display device. The organic electroluminescence display device is a so-called self-luminescent display device in which holes and electrons respectively injected from a first electrode and a second electrode recombine in an emission layer, so that a light emitting material in the emission layer emits light to achieve display.

In the application of a light emitting element to a display device, there is a demand for a low driving voltage, high emission efficiency, and a long service life, and continuous development is required on materials for a light emitting element that are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element showing high efficiency and long-life characteristics.

The disclosure also provides a polycyclic compound which is a material for a light emitting element having high emission efficiency and improved life characteristics.

An embodiment provides a light emitting element which may include a first electrode, a second electrode disposed on the first electrode, and an emission layer disposed between the first electrode and the second electrode, wherein the emission layer may include a first compound represented by Formula 1:

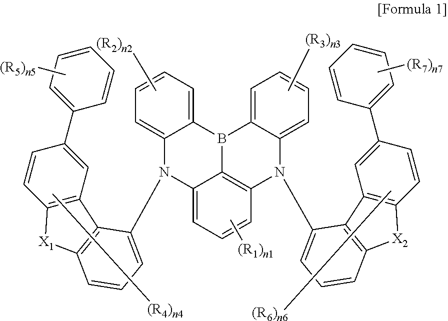

In Formula 1, X₁ and X₂ may each independently be O, S, N(R₈), or C(R₉)(R₁₀). In Formula 1, R₁ to R₇ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. In Formula 1, R₈ to R₁₀ may each independently be a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms, or R₉ and R₁₀ may be combined with each other to form a ring. In Formula 1, n1 may be an integer from 0 to 3; n2 and n3 may each independently be an integer from 0 to 4; n4 and n6 may each independently be an integer from 0 to 6; and n5 and n7 may each independently be an integer from 0 to 5.

In an embodiment, the first compound may be represented by any one of Formula 2-1 to Formula 2-5:

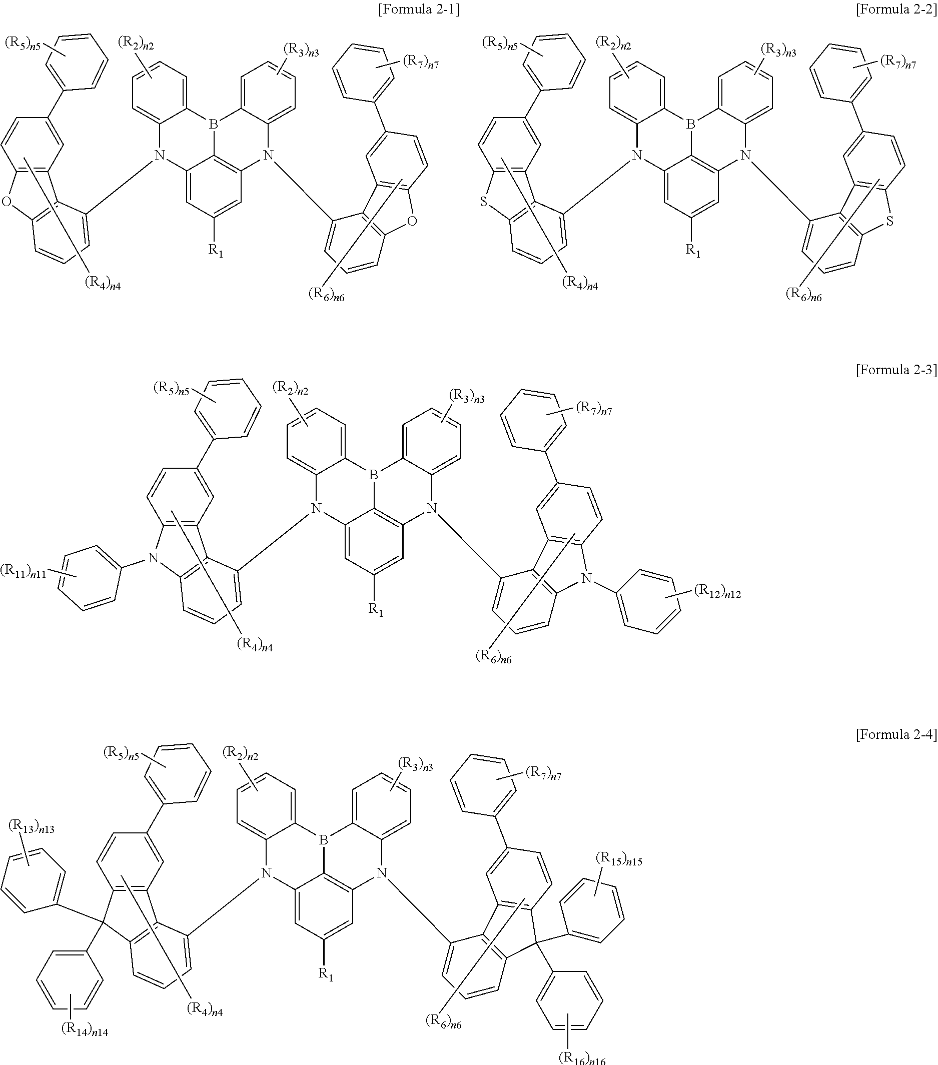

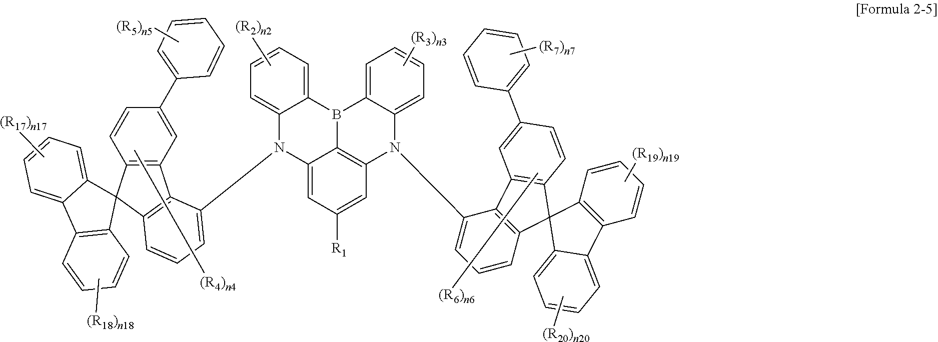

In Formula 2-3 to Formula 2-5, R₁₁ to R₂₀ may each independently be a hydrogen atom, a deuterium atom, a substituted or unsubstituted alkyl group of 1 to 20 carbon atoms, or a substituted or unsubstituted aryl group of 3 to 20 carbon atoms. In Formula 2-3 to Formula 2-5, n11 to n16 may each independently be an integer from 0 to 5; and n17 to n20 may each independently be an integer from 0 to 4. In Formula 2-1 to Formula 2-5, R₁ to R₇ and n2 to n7 are the same as defined in Formula 1.

In an embodiment, the first compound may be represented by Formula 3:

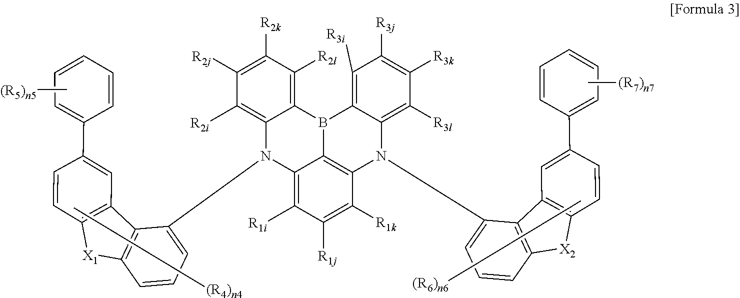

In Formula 3, at least one of R₁ᵢ, R₁ⱼ, and R₁ₖ may each independently be a substituted or unsubstituted t-butyl group, a substituted or unsubstituted dibenzofuran group, a substituted or unsubstituted carbazole group, or a substituted or unsubstituted benzofurocarbazole group; and the remainder of R₁ᵢ, R₁ⱼ, and R₁ₖ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. In Formula 3, at least one of R₂ᵢ, R₂ⱼ, R₂ₖ, R₂ₗ, R₃ᵢ, R₃ⱼ, R₃ₖ, and R₃ₗ may each independently be a substituted or unsubstituted phenyl group or a substituted or unsubstituted carbazole group; and the remainder of R₂ᵢ, R₂ⱼ, R₂ₖ, R₂ₗ, R₃ᵢ, R₃ⱼ, R₃ₗ, and R₃ₗ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. In Formula 3, X₁, X₂, R₄ to R₇, and n4 to n7 are the same as defined in Formula 1.

In an embodiment, the first compound may be represented by any one of Formula 4-1 to Formula 4-3.

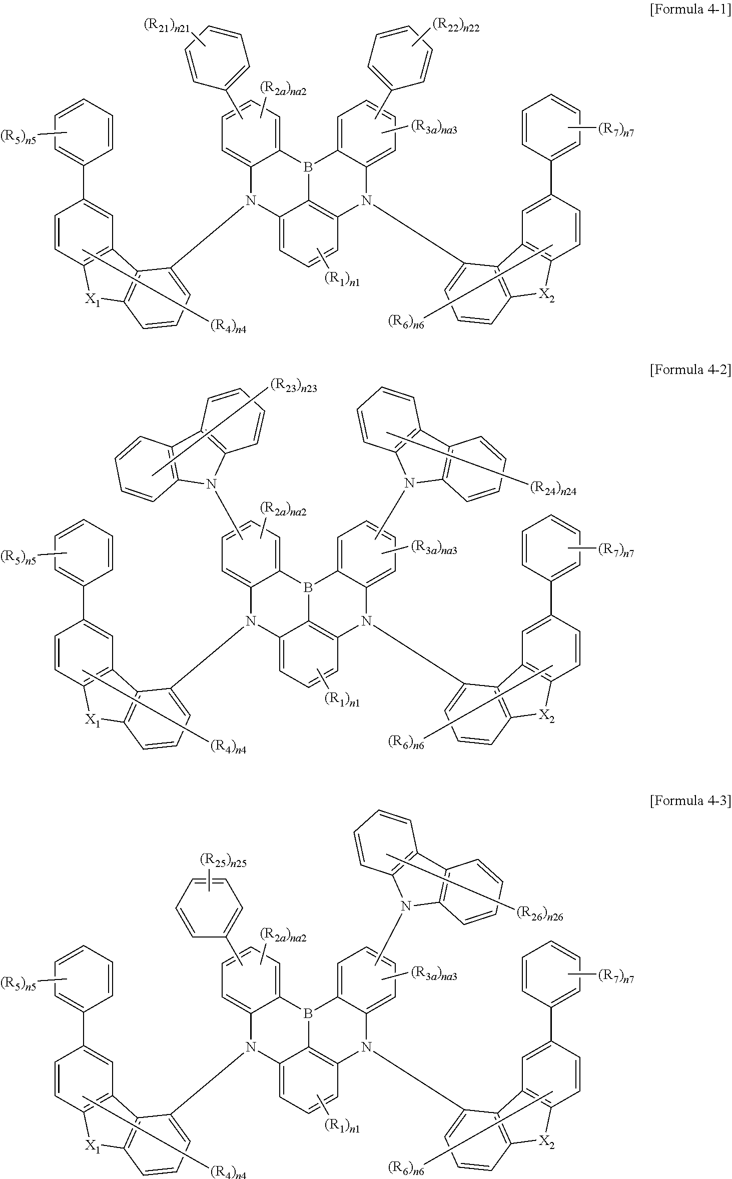

In Formula 4-1 to Formula 4-3, R₂₁ to R₂₆ may each independently be a hydrogen atom, a deuterium atom, a cyano group, a substituted or unsubstituted alkyl group of 1 to 20 carbon atoms, or a substituted or unsubstituted aryl group of 3 to 20 ring-forming carbon atoms. In Formula 4-1 to Formula 4-3, R₂ₐ and R₃ₐ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. In Formula 4-1 to Formula 4-3, n21, n22, and n25 may each independently be an integer from 0 to 5; n23, n24, and n26 may each independently be an integer from 0 to 8; and na2 and na3 may each independently be an integer from 0 to 3. In Formula 4-1 to Formula 4-3, X₁, X₂, R₁, R₄ to R₇, n1, and n4 to n7 are the same as defined in Formula 1.

In an embodiment, the first compound may be represented by any one of Formula 5-1 to Formula 5-4.

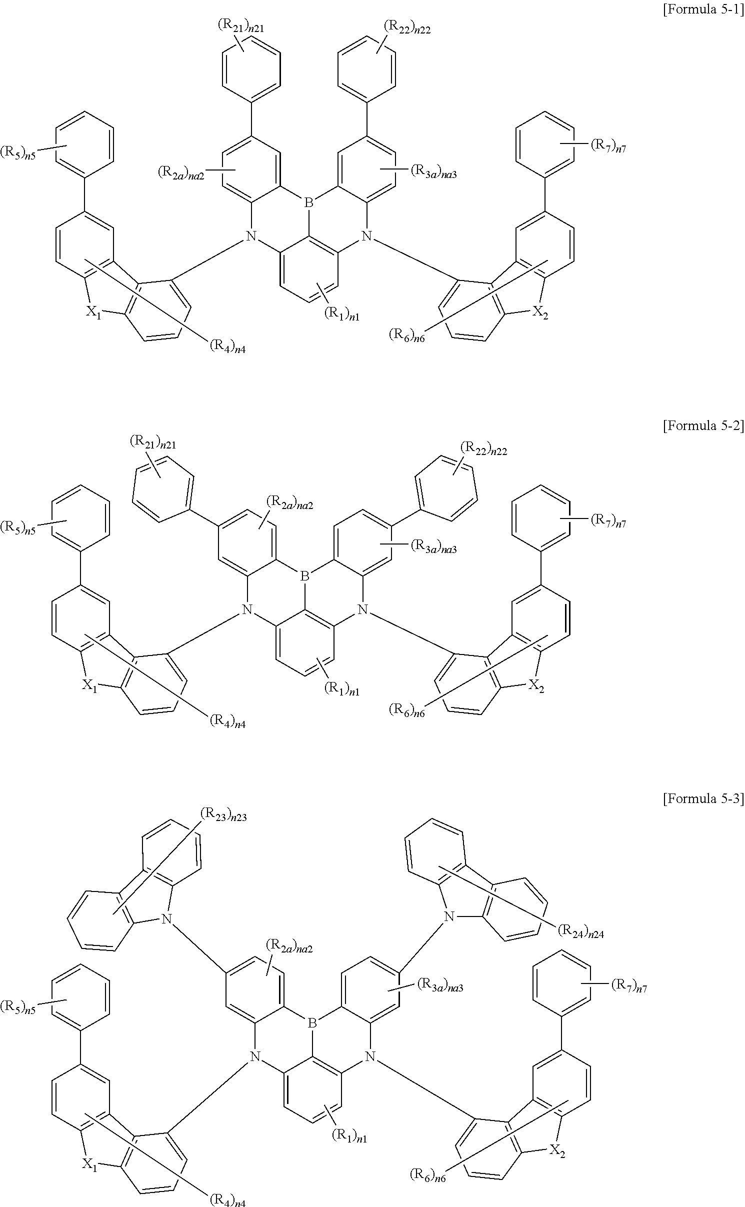

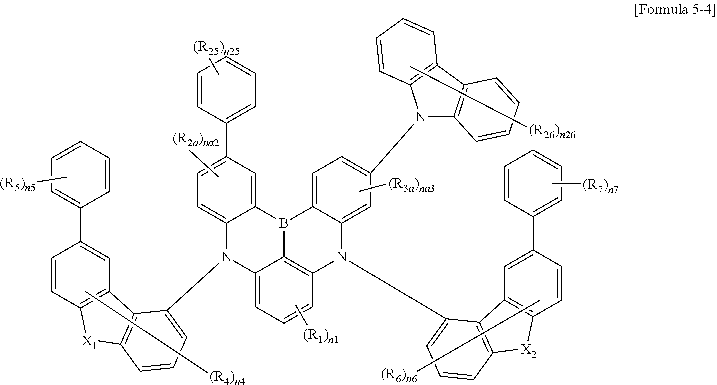

In Formula 5-1 to Formula 5-4, X₁, X₂, R₁, R₄ to R₇, n1, and n4 to n7 are the same as defined in Formula 1; and R₂₁ to R₂₆, R₂ₐ, R₃ₐ, n21 to n26, na2, and na3 are the same as defined in Formula 4-1 to Formula 4-3.

In an embodiment, R₁ may be a group represented by any one of Formula RS-1 to Formula RS-5:

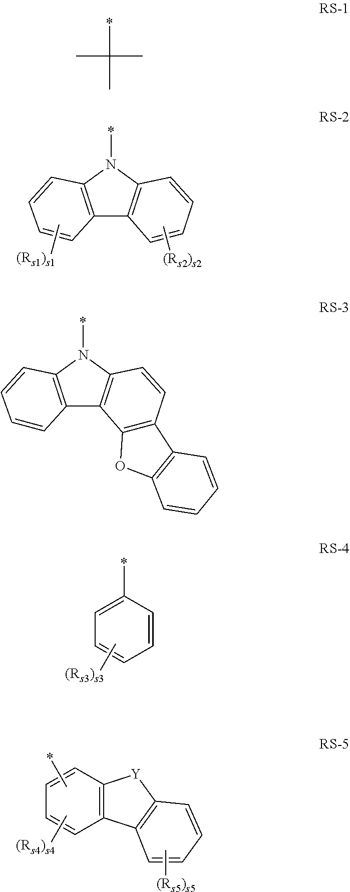

In Formula RS-5, Y may be O or N(Rₛ₆). In Formula RS-2, Formula RS-4, and Formula RS-5, Rₛ₁ to Rₛ₆ may each independently be a hydrogen atom, a deuterium atom, a cyano group, a substituted or unsubstituted alkyl group of 1 to 10 carbon atoms, or a substituted or unsubstituted aryl group of 6 to 10 ring-forming carbon atoms. In Formula RS-2, Formula RS-4, and Formula RS-5, s1, s2, and s5 may each independently be an integer from 0 to 4; s3 may be an integer from 0 to 5; and s4 may be an integer from 0 to 3.

In an embodiment, R₄ to R₇ may each independently be a hydrogen atom, a deuterium atom, a substituted or unsubstituted t-butyl group, or a substituted or unsubstituted phenyl group.

In an embodiment, the emission layer may further include at least one of a second compound represented by Formula HT and a third compound represented by Formula ET:

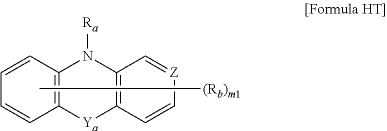

In Formula HT, Rₐ and R_{b} may each independently be a hydrogen atom, a deuterium atom, a cyano group, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring; and m1 may be an integer from 0 to 7. In Formula HT, Yₐ may be a direct linkage, C(R_{y1})(R_{y2}), or Si(R_{y3})(R_{y4}); Z may be C(R_{z}) or N; R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms; and R_{z} may be a hydrogen atom or a deuterium atom.

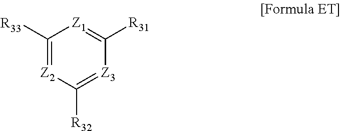

In Formula ET, Z₁ to Z₃ may each independently be N or C(R₃₄); at least one of Z₁ to Z₃ may each be N; and R₃₁ to R₃₄ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring.

In an embodiment, the emission layer may further include a fourth compound represented by Formula PS:

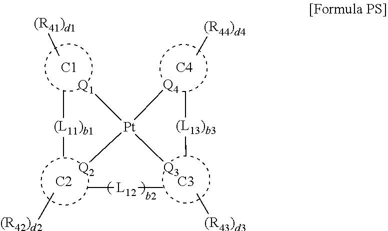

In Formula PS, Q₁ to Q₄˜ may each independently be C or N; and C1 to C4 may each independently be a substituted or unsubstituted hydrocarbon ring of 5 to 30 ring-forming carbon atoms or a substituted or unsubstituted heterocycle of 2 to 30 ring-forming carbon atoms. In Formula PS, L₁₁ to L₁₃ may each independently be a direct linkage,

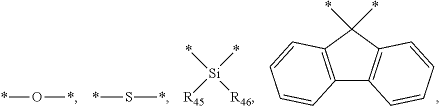

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms; b1 to b3 may each independently be 0 or 1; R₄₁ to R₄₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring; and d1 to d4 may each independently be an integer from 0 to 4.

In an embodiment, the emission layer may include the first compound, the second compound, and the third compound.

In an embodiment, the emission layer may include the first compound, the second compound, the third compound, and the fourth compound.

In an embodiment, the first compound may include at least one compound selected from Compound Group 1, which is explained below.

An embodiment provides a polycyclic compound which may be represented by Formula 1, which is explained herein.

In an embodiment, Formula 1 may be represented by any one of Formula 2-1 to Formula 2-5, which are explained herein.

In an embodiment, Formula 1 may be represented by Formula 3, which is explained herein.

In an embodiment, Formula 1 may be represented by any one of Formula 4-1 to Formula 4-3, which are explained herein.

In an embodiment, Formula 1 may be represented by any one of Formula 5-1 to Formula 5-4, which are explained herein.

In an embodiment, R₁ may be a group represented by any one of Formula RS-1 to Formula RS-5, which are explained herein.

In an embodiment, R₄ to R₇ may each independently be a hydrogen atom, a deuterium atom, a substituted or unsubstituted t-butyl group, or a substituted or unsubstituted phenyl group.

In an embodiment, the polycyclic compound represented by Formula 1 may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view showing a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a display device according to an embodiment;

FIG. 8 is a schematic cross-sectional view of a display device according to an embodiment;

FIG. 9 is a schematic cross-sectional view of a display device according to an embodiment; and

FIG. 10 is a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the substituents listed above may itself be substituted or unsubstituted. For example, a biphenyl group may be interpreted as an aryl group or it may be interpreted as a phenyl group substituted with a phenyl group.

In the specification, the term “combined with an adjacent group to form a ring” may be interpreted as a group that is combined with an adjacent group to form a substituted or unsubstituted hydrocarbon ring or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by the combination of adjacent groups may itself be combined with another ring to form a spiro structure.

In the specification, the term “adjacent group” may be interpreted as a substituent that is substituted for an atom which is directly combined with an atom substituted with a corresponding substituent, as another substituent substituted for an atom which is substituted with a corresponding substituent, or as a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For example, in 4,5-dimethylphenanthrene, two methyl groups may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., without limitation.

In the specification, an alkenyl group may be a hydrocarbon group that includes one or more carbon-carbon double bonds in the middle or at a terminus of an alkyl group having 2 or more carbon atoms. The alkenyl group may be linear or branched. The number of carbon atoms in an alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the specification, an alkynyl group may be a hydrocarbon group that includes one or more carbon-carbon triple bonds in the middle or at a terminus of an alkyl group having 2 or more carbon atoms. An alkynyl group may be linear or branched. The number of carbon atoms is not specifically limited, but may be 2 to 30, 2 to 20, or 2 to 10. Examples of an alkynyl group may include an ethynyl group, a propynyl group, etc., without limitation.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., without limitation.

In the specification, a fluorenyl group may be substituted, and two substituents may be combined with each other to form a spiro structure. Examples of substituted fluorenyl groups are as follows, but embodiments are not limited thereto.

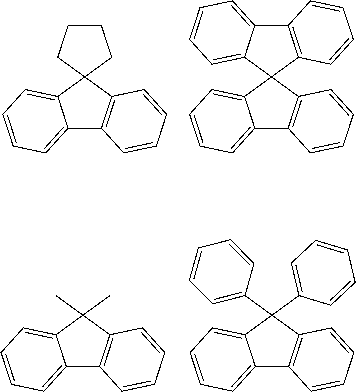

In the specification, a heterocyclic group may be any functional group or substituent derived from a ring that includes one or more of B, O, N, P, Si, or S as a heteroatom. A heterocyclic group may be an aliphatic heterocyclic group or an aromatic heterocyclic group. An aromatic heterocyclic group may be a heteroaryl group. The aliphatic heterocyclic group and the aromatic heterocyclic group may each independently be monocyclic or polycyclic.

In the specification, a heterocyclic group may include one or more of B, O, N, P, Si, or S as a heteroatom. If a heterocyclic group includes two or more heteroatoms, the two or more heteroatoms may be the same as or different from each other. A heterocyclic group may be monocyclic or polycyclic, and a heterocyclic group may be a heteroaryl group. The number of ring-forming carbon atoms in a heterocyclic group may be 2 to 30, 2 to 20, and 2 to 10.

In the specification, an aliphatic heterocyclic group may include one or more of B, O, N, P, Si, or S as a heteroatom. The number of ring-forming carbon atoms in an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the specification, a heteroaryl group may include one or more of B, O, N, P, Si, and S as a heteroatom. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 60, 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., without limitation.

In the specification, the above explanation of an aryl group may be applied to an arylene group, except that the arylene group is a divalent group. The above explanation of a heteroaryl group may be applied to a heteroarylene group, except that the heteroarylene group is a divalent group.

In the specification, a boron group may be a boron atom that is bonded to an alkyl group or an aryl group as explained above. A boron group may be an alkyl boron group or an aryl boron group. Examples of a boron group may include a dimethylboron group, a diethylboron group, a t-butylmethylboron group, a diphenylboron group, a phenylboron group, etc., without limitation.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the specification, the number of carbon atoms in a carbonyl group is not specifically limited, but may be 1 to 40, 1 to 30, or 1 to 20. For example, a carbonyl group may have one of the structures below, but is not limited thereto.

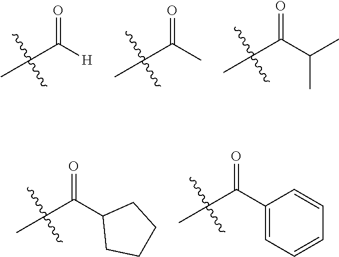

In the specification, the number of carbon atoms in a sulfinyl group or a sulfonyl group is not specifically limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may be a sulfur atom that is bonded to an alkyl group or an aryl group as explained above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the specification, an oxy group may be an oxygen atom that is bonded to an alkyl group or an aryl group as explained above. An oxy group may be an alkoxy group or an aryl oxy group. The alkoxy group may be linear, branched, or cyclic. The number of carbon atoms in an alkoxy group is not specifically limited but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc. However, embodiments are not limited thereto.

In the specification, the number of carbon atoms in an amine group is not specifically limited, but may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., without limitation.

In the specification, alkyl groups in an alkylthio group, an alkylsulfoxy group, an alkylaryl group, an alkylamino group, an alkylboron group, an alkyl silyl group, or an alkyl amine group may be the same as an example of the alkyl group as described above.

In the specification, aryl groups in an aryloxy group, an arylthio group, an arylsulfoxy group, an aryl amino group, an arylboron group, an aryl silyl group, and an aryl amine group may be the same as an example of the aryl group as described above.

In the specification, a direct linkage may be a single bond.

In the specification, the symbols

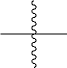

or -* each represents a bonding site to a neighboring atom.

Hereinafter, embodiments will be explained referring to the drawings.

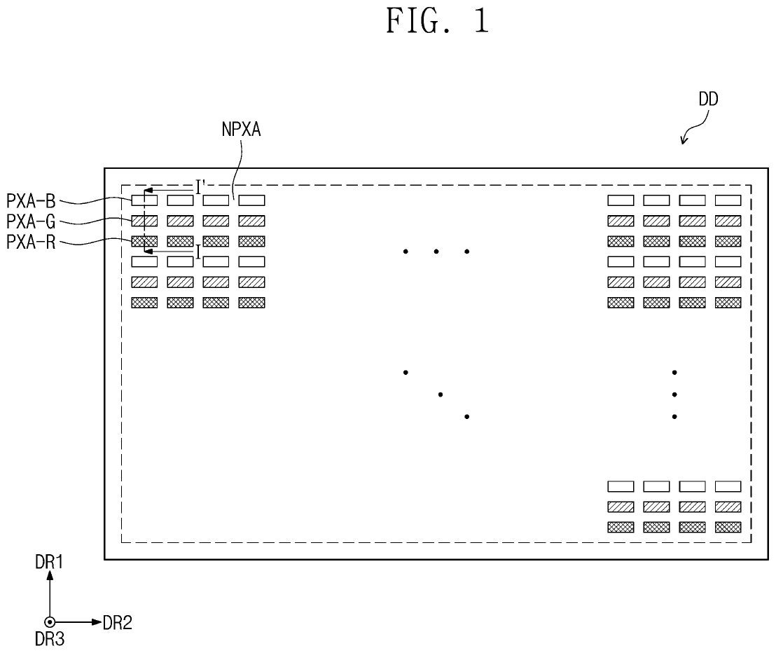

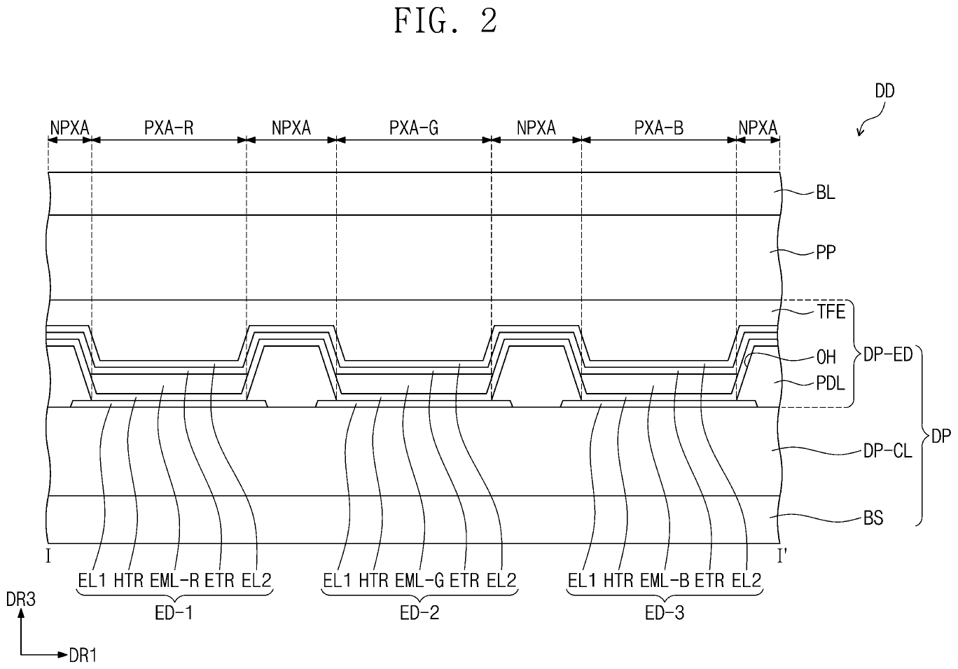

FIG. 1 is a schematic plan view of an embodiment of a display device DD. FIG. 2 is a schematic cross-sectional view of a display device DD according to an embodiment. FIG. 2 is a schematic cross-sectional view showing a part corresponding to line I-I′ of FIG. 1.

The display device DD includes a display panel DP and an optical layer PP disposed on the display panel DP. The display panel DP may include light emitting elements ED-1, ED-2, and ED-3. The display device DD may include multiples of each of the light emitting elements ED-1, ED-2, and ED-3. The optical layer PP may be disposed on the display panel DP and may control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a plugging layer (not shown). The plugging layer (not shown) may be disposed between a display element layer DP-ED and a base substrate BL. The plugging layer (not shown) may be an organic layer. The plugging layer (not shown) may include at least one of an acrylic resin, a silicone-based resin, or an epoxy-based resin.

The display panel DP may include a base layer BS, a circuit layer DP-CL provided on the base layer BS, and a display element layer DP-ED. The display element layer DP-ED may include a pixel definition layer PDL, light emitting elements ED-1, ED-2, and ED-3 disposed in the pixel definition layer PDL, and an encapsulating layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

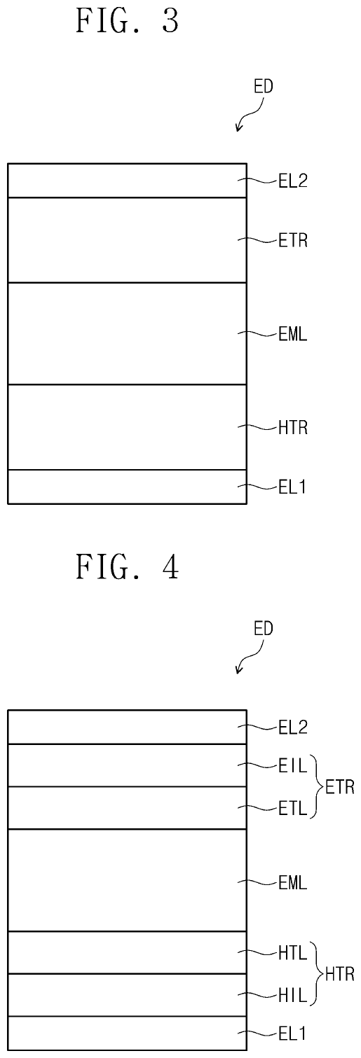

The light emitting elements ED-1, ED-2, and ED-3 may each have a structure of a light emitting element ED of an embodiment according to any of FIG. 3 to FIG. 6, which will be explained later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment where the emission layers EML-R, EML-G, and EML-B of light emitting elements ED-1, ED-2, and ED-3 are disposed in openings OH defined in a pixel definition layer PDL, and a hole transport region HTR, an electron transport region ETR, and a second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be patterned and provided in the openings OH defined in the pixel definition layer PDL. For example, in an embodiment, the hole transport region HTR, the emission layers EML-R, EML-G, and EML-B, and the electron transport region ETR of the light emitting elements ED-1, ED-2, and ED-3 may each be patterned by an ink jet printing method and provided.

An encapsulating layer TFE may cover the light emitting elements ED-1, ED-2, and ED-3. The encapsulating layer TFE may seal the display element layer DP-ED. The encapsulating layer TFE may be a thin film encapsulating layer. The encapsulating layer TFE may be formed of a single layer or formed of multiple layers. The encapsulating layer TFE may include at least one insulating layer. The encapsulating layer TFE according to an embodiment may include at least one inorganic layer (hereinafter, an encapsulating inorganic layer). In an embodiment, the encapsulating layer TFE may include at least one organic layer (hereinafter, an encapsulating organic layer) and at least one encapsulating inorganic layer.

The encapsulating inorganic layer may protect the display element layer DP-ED from moisture and/or oxygen, and the encapsulating organic layer may protect the display element layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be disposed on the second electrode EL2 and may be disposed to fill the openings OH.

Referring to FIG. 1 and FIG. 2, the display device DD may include non-luminous areas NPXA and luminous areas PXA-R, PXA-G, and PXA-B. The luminous areas PXA-R, PXA-G, and PXA-B may each be an area which emits light produced from the light emitting elements ED-1, ED-2, and ED-3, respectively. The luminous areas PXA-R, PXA-G, and PXA-B may be separated from each other in a plan view.

The luminous areas PXA-R, PXA-G, and PXA-B may each be an area separated by the pixel definition layer PDL. The non-luminous areas NPXA may be areas between neighboring luminous areas PXA-R, PXA-G, and PXA-B and may correspond to the pixel definition layer PDL. For example, in an embodiment, the luminous areas PXA-R, PXA-G, and PXA-B may each respectively correspond to a pixel. The pixel definition layer PDL may separate the light emitting elements ED-1, ED-2, and ED-3. The emission layers EML-R, EML-G, and EML-B of the light emitting elements ED-1, ED-2, and ED-3 may be disposed in the openings OH defined in the pixel definition layer PDL and separated from each other.

The luminous areas PXA-R, PXA-G, and PXA-B may be arranged into groups according to the color of light produced from the light emitting elements ED-1, ED-2, and ED-3. In the display device DD according to an embodiment shown in FIG. 1 and FIG. 2, three luminous areas PXA-R, PXA-G, and PXA-B which respectively emit red light, green light, and blue light, are illustrated. For example, the display device DD may include a red luminous area PXA-R, a green luminous area PXA-G, and a blue luminous area PXA-B, which are separated from each other.

In the display device DD according to an embodiment, the light emitting elements ED-1, ED-2, and ED-3 may emit light having different wavelength regions from each other. For example, in an embodiment, the display device DD may include a first light emitting element ED-1 that emits red light, a second light emitting element ED-2 that emits green light, and a third light emitting element ED-3 that emits blue light. For example, the red luminous area PXA-R, the green luminous area PXA-G, and the blue luminous area PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may each emit light in a same wavelength region, or at least one thereof may emit light in a wavelength region that is different from the others. For example, the first to third light emitting elements ED-1, ED-2, and ED-3 may each emit blue light.

The luminous areas PXA-R, PXA-G, and PXA-B in the display device DD according to an embodiment may be arranged in a stripe configuration. Referring to FIG. 1, the red luminous areas PXA-R, the green luminous areas PXA-G, and the blue luminous areas PXA-B may be arranged along a second directional axis DR2. In another embodiment, the red luminous area PXA-R, the green luminous area PXA-G, and the blue luminous area PXA-B may be arranged by turns along a first directional axis DR1.

In FIG. 1 and FIG. 2, the luminous areas PXA-R, PXA-G, and PXA-B are shown as all having a similar area, but embodiments are not limited thereto. The luminous areas PXA-R, PXA-G, and PXA-B may have different areas from each other according to a wavelength region of emitted light. For example, the areas of the luminous areas PXA-R, PXA-G, and PXA-B may be areas in a plan view that are defined by the first directional axis DR1 and the second directional axis DR2.

An arrangement of the luminous areas PXA-R, PXA-G, and PXA-B is not limited to the configuration shown in FIG. 1, and the order in which the red luminous areas PXA-R, the green luminous areas PXA-G, and the blue luminous areas PXA-B are arranged may be provided in various combinations according to the display quality characteristics that are required for the display device DD. For example, the luminous areas PXA-R, PXA-G, and PXA-B may be arranged in a pentile configuration (such as a PENTILE® configuration), or in a diamond configuration (such as a Diamond Pixel™ configuration).

The areas of the luminous areas PXA-R, PXA-G, and PXA-B may be different in size from each other. For example, in an embodiment, an area of the green luminous area PXA-G may be smaller than an area of the blue luminous area PXA-B, but embodiments are not limited thereto.

In the display device DD shown in FIG. 2, at least one of the first to third light emitting elements ED-1, ED-2, and ED-3 may include a polycyclic compound according to an embodiment, which will be explained later.

FIG. 3 to FIG. 6 are each a schematic cross-sectional view showing a light emitting element ED according to an embodiment. The light emitting elements ED according to embodiments may each include a first electrode EL1, a second electrode EL2 oppositely disposed to the first electrode EL1, and at least one functional layer disposed between the first electrode EL1 and the second electrode EL2. The light emitting element ED according to an embodiment may include a first compound, which will be explained later, in the at least one functional layer. In the specification, the polycyclic compound according to an embodiment may be referred to as the first compound.

The light emitting element ED may include a hole transport region HTR, an emission layer EML, an electron transport region ETR, or the like, stacked in that order, as the at least one functional layer. Referring to FIG. 3, a light emitting element ED may include a first electrode EL1, a hole transport region HTR, an emission layer EML, an electron transport region ETR, and a second electrode EL2, stacked in that order. The light emitting element ED may include a polycyclic compound according to an embodiment, which will be explained later, in the emission layer EML.

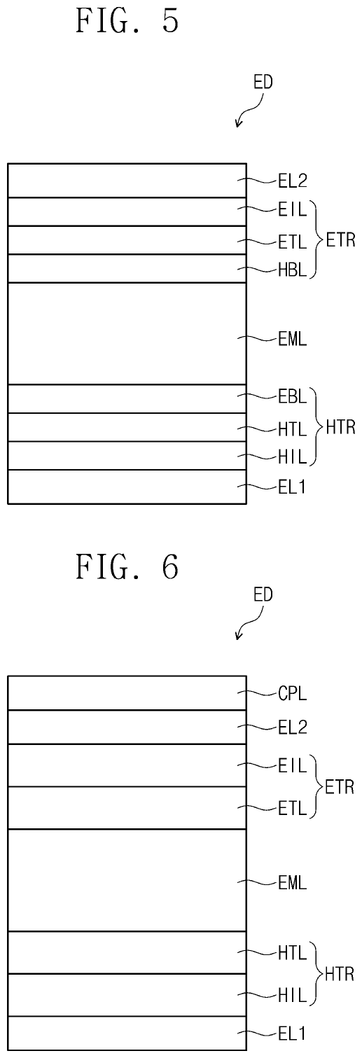

In comparison to FIG. 3, FIG. 4 shows a schematic cross-sectional view of a light emitting element ED according to an embodiment, wherein a hole transport region HTR includes a hole injection layer HIL and a hole transport layer HTL, and an electron transport region ETR includes an electron injection layer EIL and an electron transport layer ETL. In comparison to FIG. 3, FIG. 5 shows a schematic cross-sectional view of a light emitting element ED according to an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 4, FIG. 6 shows a schematic cross-sectional view of a light emitting element ED according to an embodiment that includes a capping layer CPL disposed on the second electrode EL2.

In the light emitting element ED, the first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (for example, a mixture of Ag and Mg). In another embodiment, the first electrode EL1 may have a multilayer structure including a reflective layer or a transflective layer formed of the above materials, and a transmissive conductive layer formed of ITO, IZO, ZnO, or ITZO. For example, the first electrode EL1 may have a three-layer structure of ITO/Ag/ITO. However, embodiments are not limited thereto. The first electrode EL1 may include the above-described metal materials, combinations of two or more metal materials selected from the above-described metal materials, or oxides of the above-described metal materials. A thickness of the first electrode EL1 may be in a range of about 700 Å to about 10,000 Å. For example, the thickness of the first electrode EL1 may be in a range of about 1,000 Å to about 3,000 Å.

The hole transport region HTR is provided on the first electrode EL1. The hole transport region HTR may be a layer consisting of a single material, a layer including different materials, or a structure including multiple layers including different materials.

The hole transport region HTR may include at least one of a hole injection layer HIL, a hole transport layer HTL, a buffer layer (not shown), an emission auxiliary layer (not shown), or an emission blocking layer EBL. Although not shown in the drawings, in an embodiment, the hole transport region HTR may include multiple hole transport layers.

For example, the hole transport region HTR may have a single layer structure of a hole injection layer HIL or a hole transport layer HTL, or may have a single layer structure formed of a hole injection material and a hole transport material. In an embodiment, the hole transport region HTR may have a single layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), or a hole transport layer HTL/buffer layer (not shown), are stacked in its respective stated order from the first electrode EL1, but embodiments are not limited thereto.

A thickness of the hole transport region HTR may be, for example, in a range of about 50 Å to about 15,000 Å. The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In a light emitting element ED according to an embodiment, the hole transport region HTR may include a compound represented by Formula H-1:

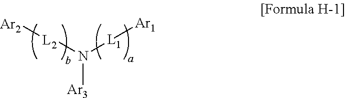

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. In Formula H-1, a and b may each independently be an integer from 0 to 10. If a or b is 2 or more, multiple L₁ groups or multiple L₂ groups may each independently be a substituted or unsubstituted arylene group of 6 to 30 ring-forming carbon atoms or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. In Formula H-1, Ar₃ may be a substituted or unsubstituted aryl group of 6 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In still other embodiments, the compound represented by Formula H-1 may be a carbazole-based compound in which at least one of Ar₁ or Ar₂ includes a substituted or unsubstituted carbazole group, or may be a fluorene-based compound in which at least one of Ar₁ or Ar₂ includes a substituted or unsubstituted fluorene group.

The compound represented by Formula H-1 may be any compound selected from Compound Group H. However, the compounds shown in Compound Group H are only examples, and the compound represented by Formula H-1 is not limited to Compound Group H:

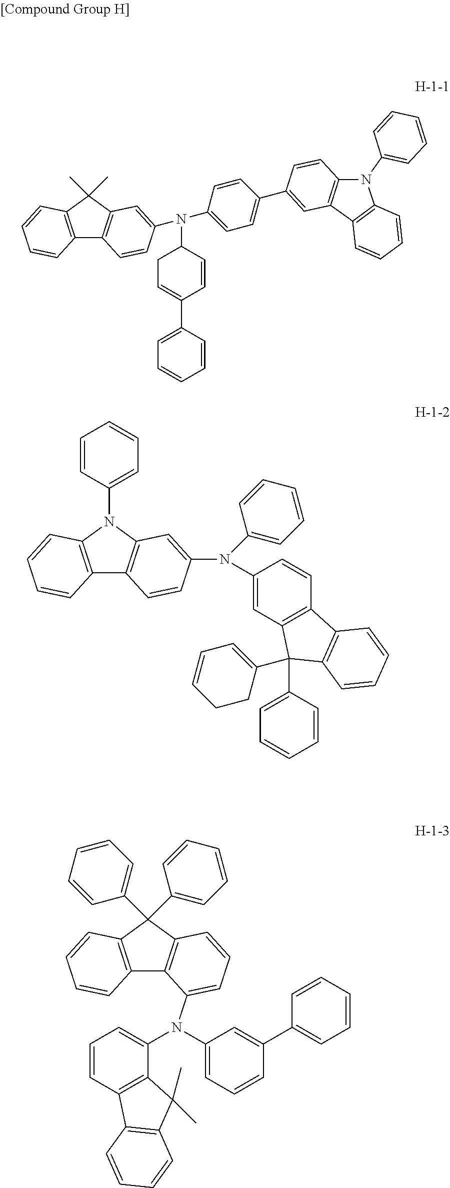 [SMILES: CC1(C)c2ccccc2-c2ccc(N(c3ccc(-c4ccc5c(c4)c4ccccc4n5-c4ccccc4)cc3)C3C=CC(c4ccccc4)=CC3)cc21 ; C1=CCCC(C2(c3ccccc3)c3ccccc3-c3ccc(N(c4ccccc4)c4ccc5c6ccccc6n(-c6ccccc6)c5c4)cc32)=C1 ; CC1(C)c2ccccc2-c2cccc(N(c3cccc(-c4ccccc4)c3)c3cccc4c3-c3ccccc3C4(c3ccccc3)c3ccccc3)c21]

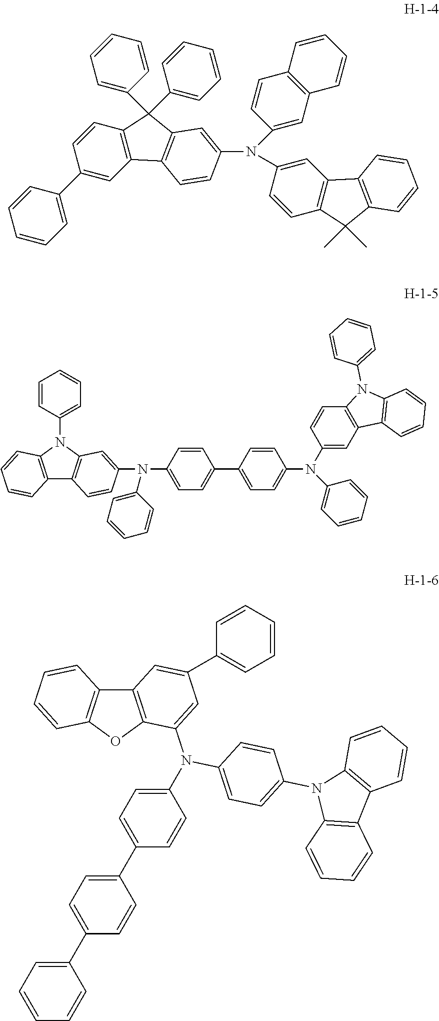 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

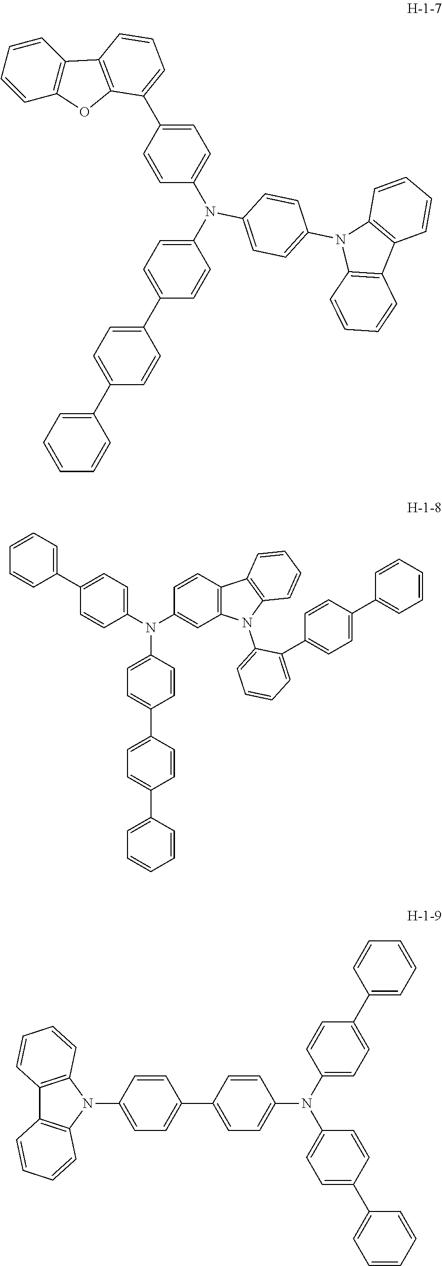 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

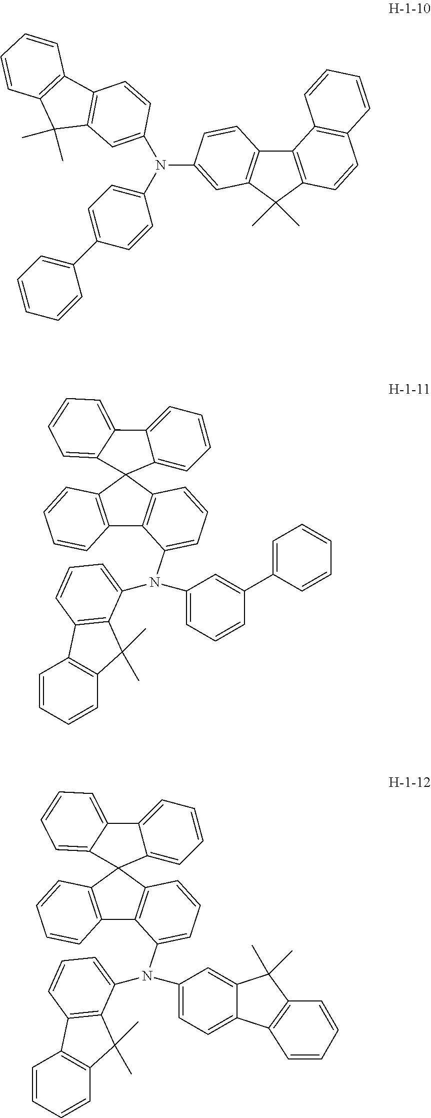 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

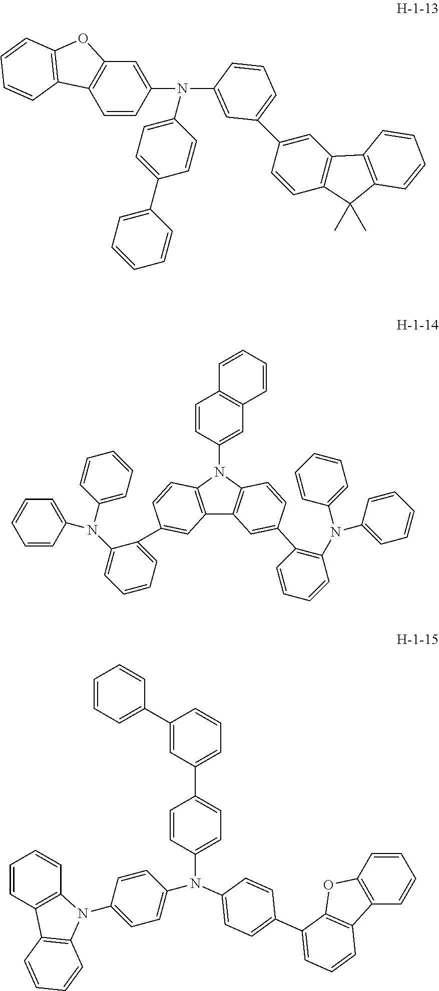 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

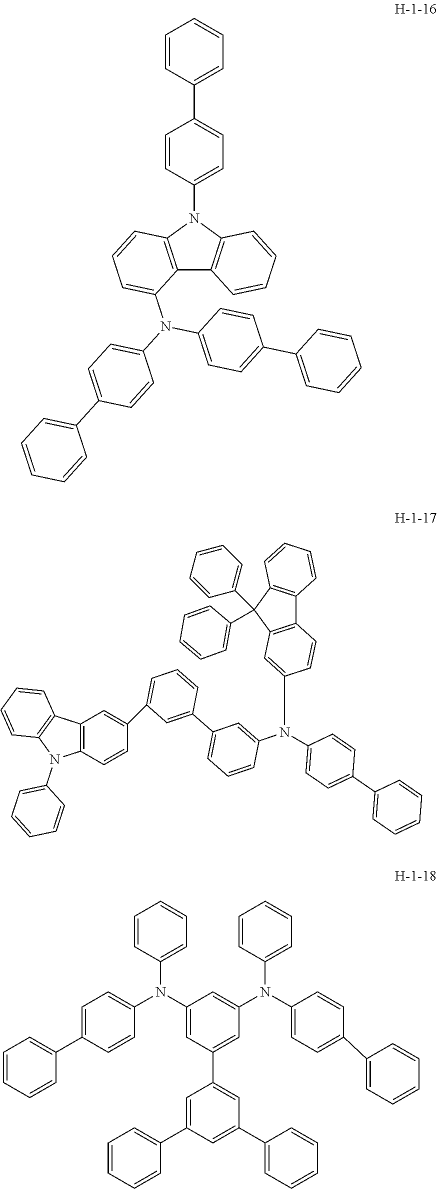 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

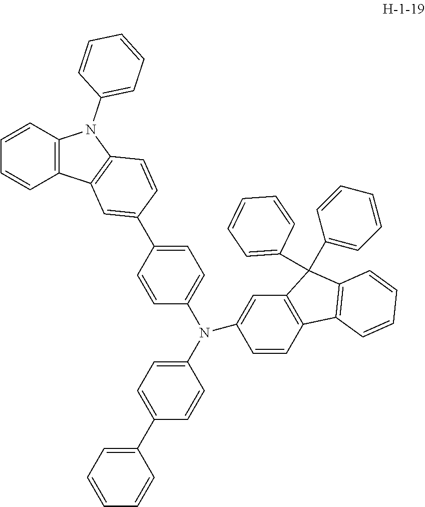 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB) (or NPD, α-NPD), triphenylamine-containing polyetherketone (TPAPEK), 4-isopropyl-4′-methyldiphenyliodonium [tetrakis(pentafluorophenyl)borate], and dipyrazino[2,3-f:2′,3′-h] quinoxaline-2,3,6,7,10,11-hexacarbonitrile (HATCN).

The hole transport region HTR may include carbazole derivatives such as N-phenylcarbazole and polyvinylcarbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), or the like.

The hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

A thickness of the hole transport region HTR may be in a range of about 100 Å to about 10,000 Å. For example, the thickness of the hole transport region HTR may be in a range of about 100 Å to about 5,000 Å. In case that the hole transport region HTR includes a hole injection layer HIL, a thickness of the hole injection layer HIL may be, for example, in a range of about 30 Å to about 1,000 Å. In case that the hole transport region HTR includes a hole transport layer HTL, a thickness of the hole transport layer HTL may be in a range of about 30 Å to about 1,000 Å. In case that the hole transport region HTR includes an electron blocking layer EBL, a thickness of the electron blocking layer EBL may be in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide compound, a quinone derivative, a metal oxide, or a cyano group-containing compound, without limitation. For example, the p-dopant may include a metal halide compound such as CuI or RbI, a quinone derivative such as tetracyanoquinodimethane (TCNQ) or 2,3,5,6-tetrafluoro-7,7,8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

As described above, the hole transport region HTR may further include at least one of a buffer layer (not shown), an emission auxiliary layer (not shown), or an electron blocking layer EBL, in addition to a hole injection layer HIL and a hole transport layer HTL. The buffer layer (not shown) may compensate for a resonance distance according to a wavelength of light emitted from an emission layer EML and may increase emission efficiency. A material that may be included in the hole transport region HTR may be used a material included in the buffer layer (not shown). The electron blocking layer EBL may block the injection of electrons from an electron transport region ETR to a hole transport region HTR. The emission auxiliary layer (not shown) may improve the charge balance of holes and electrons. If the hole transport region HTR includes an electron blocking layer EBL, the electron blocking layer EBL may include the function of an emission auxiliary layer.

The emission layer EML is provided on the hole transport region HTR. The emission layer EML may have a thickness in a range of about 100 Å to about 1,000 Å. For example, the emission layer EML may have a thickness in a range of about 100 Å to about 300 Å. The emission layer EML may be a layer consisting of a single material, a layer including different materials, or a structure including multiple layers including different materials.

In the light emitting element ED according to an embodiment, the emission layer EML may include a first compound. The first compound corresponds to the polycyclic compound according to an embodiment. The polycyclic compound may include a fused ring core that includes a boron atom (B) and two nitrogen atoms (N) as ring-forming atoms. In the polycyclic compound, the fused ring core may have a fused structure of first to third aromatic rings which are bonded to one boron atom and two nitrogen atoms. The first aromatic ring and the second aromatic ring may by symmetric to each other with respect to the boron atom in the fused ring core. The third aromatic ring may be bonded to the boron atom and to the two nitrogen atoms in the fused ring core.

The polycyclic compound may include substituents having large steric hindrance and respectively connected to the two nitrogen atoms. In an embodiment, the substituents having large steric hindrance may include a first substituent connected to a nitrogen atom among the two nitrogen atoms of the fused ring core, and a second substituent connected to the remaining nitrogen atom. In an embodiment, the first and second substituents may each independently include a dibenzofuran moiety, a dibenzothiophene moiety, a carbazole moiety, or a fluorene moiety, each independently bonded to at least one substituted or unsubstituted phenyl group.

In the specification, the numbering of the carbon atoms constituting the first and second substituents may correspond to Formula S. In Formula S, X may correspond to X₁ or X₂ of Formula 1, which will be explained later. For the convenience of explanation, in Formula S, the representation on the position of a substituent that may be connected to each benzene ring and the position connected to the fused ring core will be omitted.

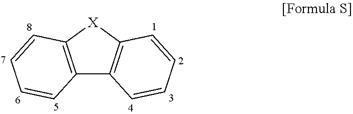

In Formula S, the number of carbon atoms starts from a benzene ring positioned at the right among two benzene rings, and the number starts from a carbon atom not related to the fusion of rings and at the nearest to X, and is given clockwise.

In the polycyclic compound, substituted or unsubstituted phenyl groups are connected to a carbon atom at position 3, first and second substituents connected to the nitrogen atoms of the fused ring at a carbon atom corresponding to position 5, and the polycyclic compound may contribute to the increase of emission efficiency and device life of the light emitting element.

The polycyclic compound according to an embodiment may be represented by Formula 1. In Formula 1, a benzene ring substituted with a substituent represented by R₂ may correspond to the first aromatic ring, a benzene ring substituted with a substituent represented by R₃ may correspond to the second aromatic ring, and a benzene ring substituted with a substituent represented by R₁ may correspond to the third aromatic ring. In Formula 1, a fused ring moiety including X₁ as a ring-forming atom may correspond to the first substituent, and a fused ring moiety including X₂ as a ring-forming atom may correspond to the second substituent.

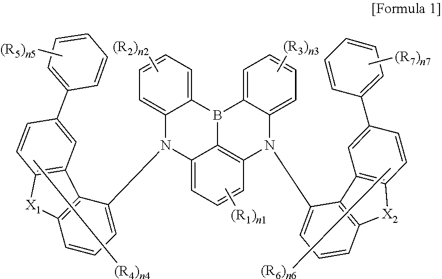

In Formula 1, X₁ and X₂ may each independently be an oxygen atom (O), a sulfur atom (S), N(R₈), or C(R₉)(R₁₀). In an embodiment, X₁ and X₂ may be the same. However, embodiments are not limited thereto, and X₁ and X₂ may be different from each other.

In Formula 1, R₁ to R₇ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. For example, R₁ to R₇ may be each independently a hydrogen atom, a deuterium atom, a substituted or unsubstituted t-butyl group, a substituted or unsubstituted phenyl group, a substituted or unsubstituted carbazole group, a substituted or unsubstituted dibenzofuran group, or a substituted or unsubstituted benzofurocarbazole group.

In an embodiment, R₁ may be a group represented by any one of Formula RS-1 to Formula RS-5. For example, if the polycyclic compound represented by Formula 1 includes multiple R₁ substituents, at least one R₁ may each independently be represented by any one of Formula RS-1 to Formula RS-5, and the remainder thereof may each be a hydrogen atom.

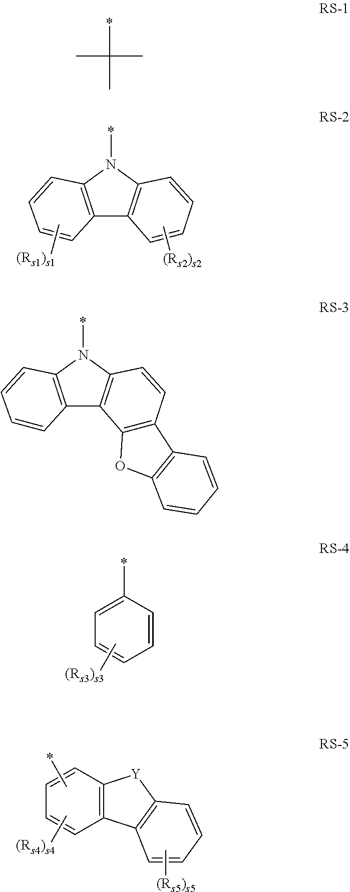

In Formula RS-5, Y may be O or N(Rₛ₆). For example, RS-5 may be a substituted or unsubstituted dibenzofuran group or a substituted or unsubstituted carbazole group.

In Formula RS-2, Formula RS-4, and Formula RS-5, Rₛ₁ to Rₛ₆ may each independently be a hydrogen atom, a deuterium atom, a cyano group, a substituted or unsubstituted alkyl group of 1 to 10 carbon atoms, or a substituted or unsubstituted aryl group of 6 to 10 ring-forming carbon atoms. For example, Rₛ₁ to Rₛ₆ may each independently be a hydrogen atom, a deuterium atom, a cyano group, a substituted or unsubstituted t-butyl group, or a substituted or unsubstituted phenyl group.

In Formula RS-2, Formula RS-4, and Formula RS-5, s1, s2, and s5 may each independently be an integer from 0 to 4; s3 may be an integer from 0 to 5; and s4 may be an integer from 0 to 3. For example, if s1 to s5 are each 2 or more, multiple groups of each of Rₛ₁, Rₛ₂, Rₛ₃, Rₛ₄, and Rₛ₅ may be the same, or at least one thereof may be different from the remainder. For example, if s1 to s5 are each 0, the polycyclic compound may not be substituted with Rₛ₁, Rₛ₂, Rₛ₃, Rₛ₄, and Rₛ₅. A case where s1, s2, and s5 are each 0, may be the same as a case where s1, s2, and s5 are each 4, and Rₛ₁ groups, Rₛ₂ groups, and Rₛ₃ groups are all hydrogen atoms. A case where s3 is 0 may be the same as a case where s3 is 5, and Rₛ₃ groups are all hydrogen atoms. A case where s4 is 0 may be the same as a case where s4 is 3, and Rₛ₄ groups are all hydrogen atoms.

In an embodiment, R₂ and R₃ may each independently be a hydrogen atom, a deuterium atom, a substituted or unsubstituted phenyl group, or a substituted or unsubstituted carbazole group. In an embodiment, R₄ to R₇ may each independently be a hydrogen atom, a deuterium atom, a substituted or unsubstituted t-butyl group, or a substituted or unsubstituted phenyl group. However, embodiments are not limited thereto.

In Formula 1, R₈ to R₁₀ may each independently be a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms, or R₉ and R₁₀ may be combined with each other to form a ring. In an embodiment, R₈ to R₁₀ may each independently be a substituted or unsubstituted phenyl group. In another embodiment, R₉ and R₁₀ may be combined with each other to form a ring. For example, if X₁ and X₂ are each independently N(R₈), R₈ may be a substituted or unsubstituted phenyl group. As another example, if X₁ and X₂ are each independently C(R₉)(R₁₀), R₉ and R₁₀ may each independently be a substituted or unsubstituted phenyl group, or R₉ and R₁₀ may be combined with each other to form a hydrocarbon ring, and a ring thus formed may form a spiro structure.

In Formula 1, n1 may be an integer from 0 to 3; n2 and n3 may each independently be an integer from 0 to 4; n4 and n6 may each independently be an integer from 0 to 6; and n5 and n7 may each independently be an integer from 0 to 5.

For example, if n1 to n7 are each 2 or more, multiple groups of each of R₁, R₂, R₃, R₄, R₅, R₆, and R₇ may be all the same, or at least one thereof may be different from the remainder. For example, if n1 to n7 are each 0, the polycyclic compound may not be substituted with R₁, R₂, R₃, R₄, R₅, R₆, and R₇. A case where n1 is 0 may be the same as a case where n1 is 4 and R₁ groups are all hydrogen atoms. A case where n2 and n3 are each 0 may be the same as a case where n2 and n3 are each 4 and R₂ groups and R₃ groups are all hydrogen atoms. A case where n4 and n6 are each 0 may be the same as a case where n4 and n6 are each 6 and R₄ groups and R₆ groups are all hydrogen atoms. A case where n5 and n7 are each 0 may be the same as a case where n5 and n7 are each 5 and R₅ groups and R₇ groups are all hydrogen atoms.

In an embodiment, the first compound represented by Formula 1 may be represented by any one of Formula 2-1 to Formula 2-5. Formula 2-1 to Formula 2-5 are each an embodiment in which the first substituent and the second substituent connected to the fused ring core are defined and a bonding position of R₁ is specified. Formula 2-1 is an embodiment in which the first and second substituents are each a dibenzofuran moiety including a substituted or unsubstituted phenyl group that is bonded at carbon position 3. Formula 2-2 is an embodiment in which the first and second substituents are each a dibenzothiophene moiety including a substituted or unsubstituted phenyl group that is bonded at carbon position 3. Formula 2-3 is an embodiment in which the first and second substituents are each a carbazole moiety including a substituted or unsubstituted phenyl group that is bonded at carbon position 3. Formula 2-4 and Formula 2-5 are each an embodiment in which the first and second substituents are each a fluorene moiety including a substituted or unsubstituted phenyl group that is bonded at carbon position 3. Formula 2-1 to Formula 2-5 are each an embodiment where R₁ is bonded at a para position to the boron atom of the fused ring core.

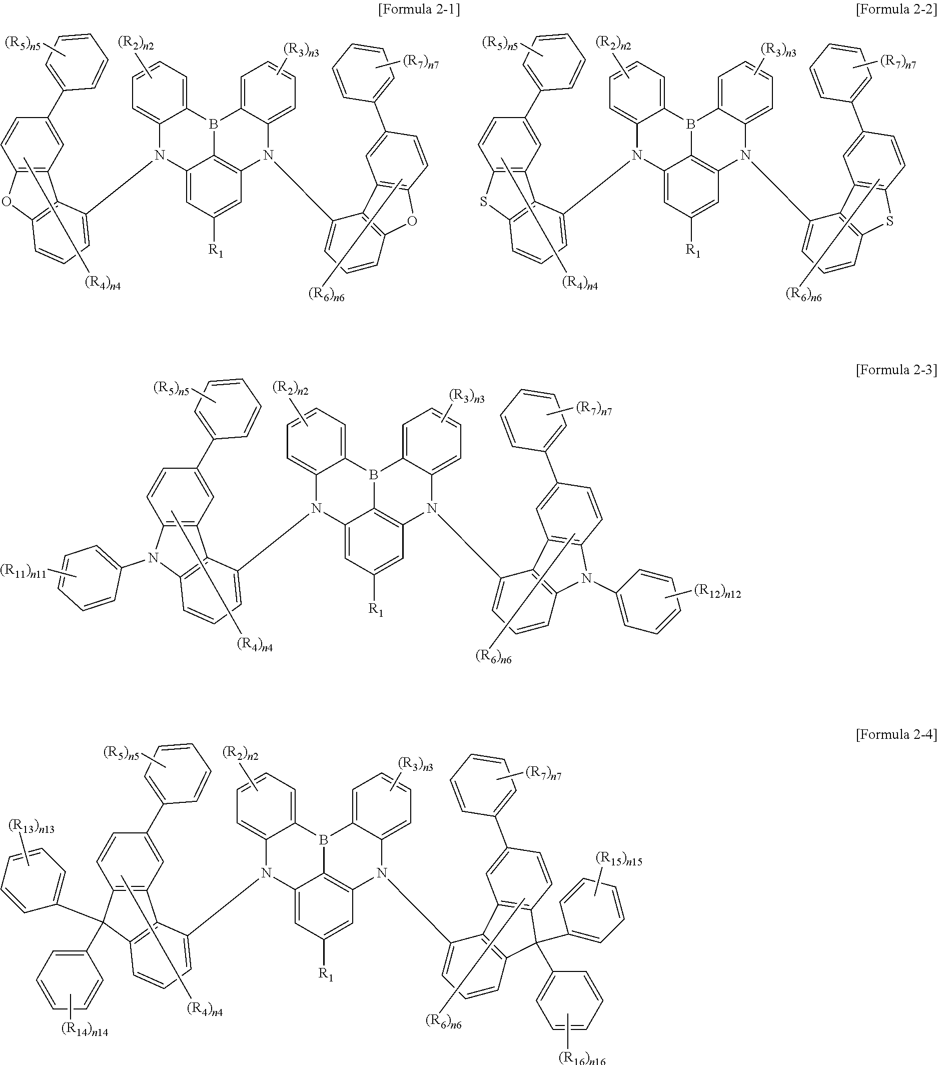

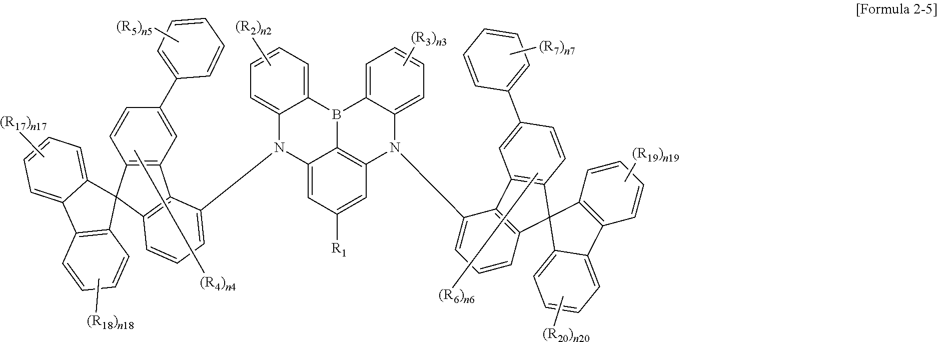

In Formula 2-3 to Formula 2-5, R₁₁ to R₂₀ may each independently be a hydrogen atom, a deuterium atom, a substituted or unsubstituted alkyl group of 1 to 20 carbon atoms, or a substituted or unsubstituted aryl group of 3 to 20 ring-forming carbon atoms. For example, R₁₁ to R₂₀ may each be a hydrogen atom. However, embodiments are not limited thereto.

In Formula 2-3 to Formula 2-5, n11 to n16 may each independently be an integer from 0 to 5; and n17 to n20 may each independently be an integer from 0 to 4. For example, if n11 to n16 are each 2 or more, multiple groups of each of R₁₁, R₁₂, R₁₃, R₁₄, R₁₅, and R₁₆ may all be the same, or at least one thereof may be different from the remainder. For example, if n11 to n16 are each 0, the polycyclic compound may not be substituted with R₁₁, R₁₂, R₁₃, R₁₄, R₁₅, and R₁₆. A case where n11 to n16 are each 0 may be the same as a case where n11 to n16 are each 5 and groups of R₁₁ to R₁₆ are all hydrogen atoms. If n17 to n20 are each 2 or more multiple groups of each of R₁₇, R₁₈, R₁₉, and R₂₀ may all be the same, or at least one thereof may be different from the remainder. For example, if n17 to n20 are each 0, the polycyclic compound may not be substituted with R₁₇, R₁₈, R₁₉, and R₂₀. A case where n17 to n20 are each 0 may be the same as a case where n17 to n20 are each 4 and groups of R₁₇ to R₂₀ are all hydrogen atoms.

In Formula 2-1 to Formula 2-5, R₁ to R₇ and n2 to n7 are the same as defined in Formula 1.

In an embodiment, the first compound represented by Formula 1 may be represented by Formula 3. Formula 3 is an embodiment of Formula 1 in which the substituents represented by R₁ to R₃ are further defined. In Formula 3, X₁, X₂, R₄ to R₇, and n4 to n7 are the same as defined in Formula 1.

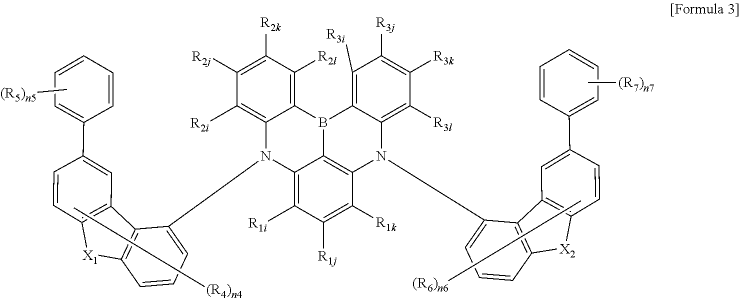

In Formula 3, at least one of R₁ᵢ, R₁ⱼ, and R₁ₖ may each independently be a substituted or unsubstituted t-butyl group, a substituted or unsubstituted dibenzofuran group, a substituted or unsubstituted carbazole group, or a substituted or unsubstituted benzofurocarbazole group; and the remainder of R₁ᵢ, R₁ⱼ, and R₁ₖ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. For example, R₁ⱼ may be a substituted or unsubstituted t-butyl group, a substituted or unsubstituted dibenzofuran group, a substituted or unsubstituted carbazole group, or a substituted or unsubstituted benzofurocarbazole group, and R₁ᵢ and R₁ₖ may each be a hydrogen atom.

In Formula 3, at least one of R₂ᵢ, R₂ⱼ, R₂ₖ, R₂ₗ, R₃ᵢ, R₃ⱼ, R₃ₖ, and R₃ₗ may each independently be a substituted or unsubstituted phenyl group or a substituted or unsubstituted carbazole group; and the remainder of R₂ᵢ, R₂ⱼ, R₂ₖ, R₂ₗ, R₃ᵢ, R₃ⱼ, R₃ₖ, and R₃ₗ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. For example, at least one of R₂ᵢ, R₂ⱼ, R₂ₖ, and R₂ₗ and at least one of R₃ᵢ, R₃ⱼ, R₃ₖ, and R₃ₗ may each independently be a substituted or unsubstituted phenyl group or a substituted or unsubstituted carbazole group, and the remainder of R₂ᵢ, R₂ⱼ, R₂ₖ, R₂ₗ, R₃ᵢ, R₃ⱼ, R₃ₖ, and R₃ₗ may each be a hydrogen atom.

In an embodiment, the first compound represented by Formula 1 may be represented by any one of Formula 4-1 to Formula 4-3. Formula 4-1 to Formula 4-3 are each an embodiment in which the substituents represented by R₂ and R₃ that are respectively bonded to the first and second aromatic rings are further defined. Formula 4-1 is an embodiment in which a substituted or unsubstituted phenyl group is bonded to each of the first and second aromatic rings. Formula 4-2 is an embodiment in which a substituted or unsubstituted carbazole group is bonded to each of the first and second aromatic rings. Formula 4-3 is an embodiment in which a substituted or unsubstituted phenyl group is bonded to the first aromatic ring, and a substituted or unsubstituted carbazole group is bonded to the second aromatic ring. In Formula 4-1 to Formula 4-3, X₁, X₂, R₁, R₄ to R₇, n1 and n4 to n7 are the same as defined in Formula 1.

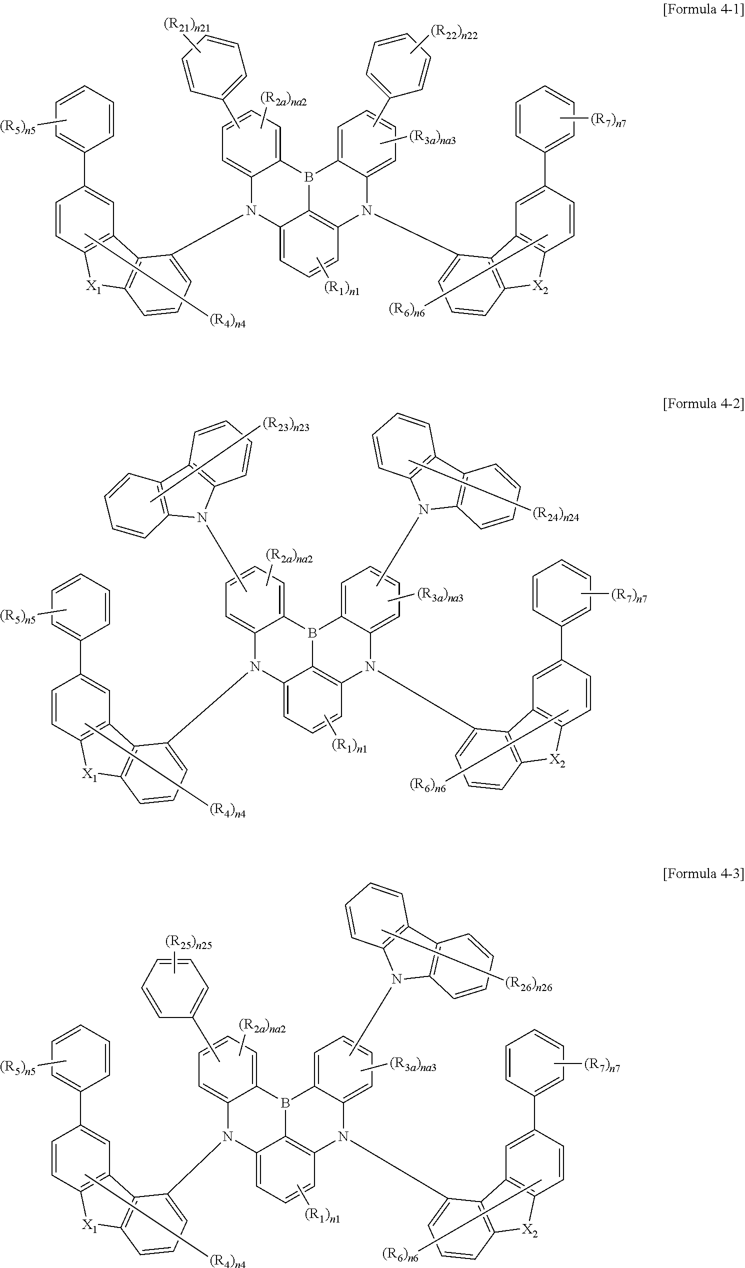

In Formula 4-1 to Formula 4-3, R₂₁ to R₂₆ may each independently be a hydrogen atom, a deuterium atom, a cyano group, a substituted or unsubstituted alkyl group of 1 to 20 carbon atoms, or a substituted or unsubstituted aryl group of 3 to 20 ring-forming carbon atoms. For example, R₂₁ to R₂₆ may each independently be a hydrogen atom, a deuterium atom, a cyano group, or a substituted or unsubstituted t-butyl group.

In Formula 4-1 to Formula 4-3, R₂ₐ and R₃ₐ may each independently be a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms. For example, R₂ₐ and R₃ₐ may each be a hydrogen atom.

In Formula 4-1 to Formula 4-3, n21, n22, and n25 may each independently be an integer from 0 to 5; n23, n24, and n26 may each independently be an integer from 0 to 8, and na2 and na3 may each independently be an integer of 0 from 3.

If n21 to n26 are each 2 or more, multiple groups of each of R₂₁, R₂₂, R₂₃, R₂₄, R₂₅, and R₂₆ may be all the same, or at least one thereof may be different from the remainder. For example, if n21 to n26 are each 0, the polycyclic compound may not be substituted with R₂₁, R₂₂, R₂₃, R₂₄, R₂₅, and R₂₆. A case where n21, n22, and n25 are each 0 may be the same as a case where n21, n22, and n25 are each 5 and groups of R₂₁, R₂₂, and R₂₅ are all hydrogen atoms. A case where n23, n24, and n26 are each 0 may be the same as a case where n23, n24, and n26 are each 8 and groups of R₂₃, R₂₄, and R₂₆ are all hydrogen atoms. If na2 and na3 are each 2 or more, multiple groups of each of R₂ₐ and R₃ₐ may be all the same, or at least one thereof may be different from the remainder. For example, if na2 and na3 are each 0, the polycyclic compound may not be substituted with R₂ₐ and R₃ₐ. A case where na2 and na3 are each 0 may be the same as a case where na2 and na3 are each 3 and groups of R₂ₐ and R₃ₐ are all hydrogen atoms.

In an embodiment, the first compound represented by Formula 1 may be represented by any one of Formula 5-1 to Formula 5-4. Formula 5-1 to Formula 5-4 are each an embodiment of the first compound as represented by Formula 4-1 to Formula 4-3, in which the bonding positions of the substituted or unsubstituted phenyl group and the substituted or unsubstituted carbazole group bonded to the first and second aromatic rings are further defined. Formula 5-1 is an embodiment in which the substituted or unsubstituted phenyl groups are bonded to the first and second aromatic rings at a meta position to the boron atom of the fused ring core. Formula 5-2 is an embodiment in which the substituted or unsubstituted phenyl groups are bonded to the first and second aromatic rings at a para position to the boron atom of the fused ring core. Formula 5-3 is an embodiment in which the substituted or unsubstituted carbazole groups are bonded to the first and second aromatic rings at a para position to the boron atom of the fused ring core. Formula 5-4 is an embodiment in which the substituted or unsubstituted phenyl group is bonded to the first aromatic ring at a meta position to the boron atom of the fused ring core, and the substituted or unsubstituted carbazole group is bonded to the second aromatic ring at a para position to the boron atom of the fused ring core.

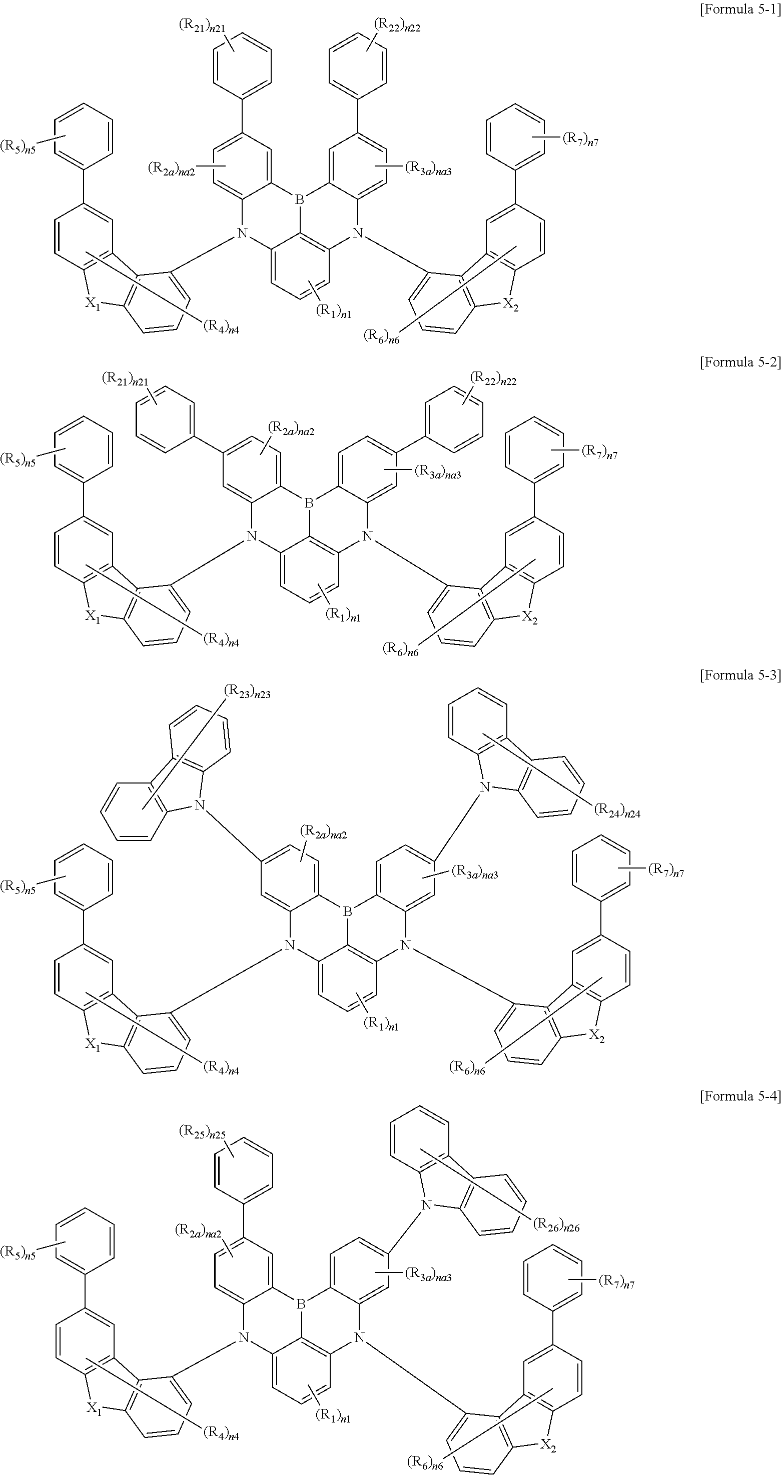

In Formula 5-1 to Formula 5-4, X₁, X₂, R₁, R₄ to R₇, n1, and n4 to n7 are the same as defined in Formula 1. In Formula 5-1 to Formula 5-4, R₂₁ to R₂₆, R₂ₐ, R₃ₐ, n21 to n26, na2, and na3 are the same as defined in Formula 4-1 to Formula 4-3.

In an embodiment, the polycyclic compound may be selected from Compound Group 1. In an embodiment, in the light emitting element ED, the first compound may include at least one compound selected from Compound Group 1. In Compound Group 1, D represents a deuterium atom.

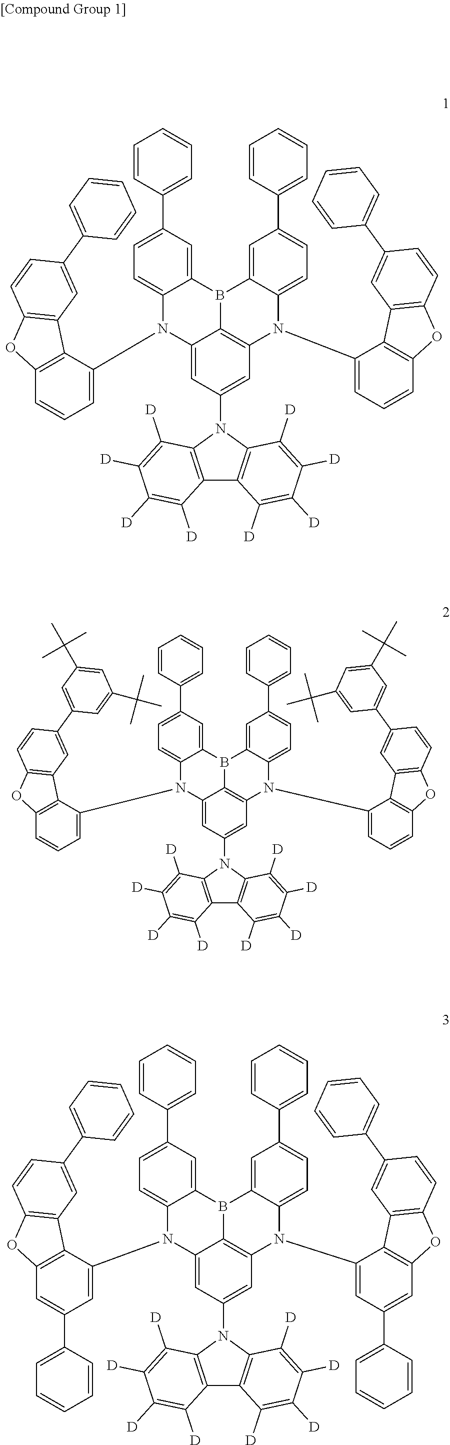

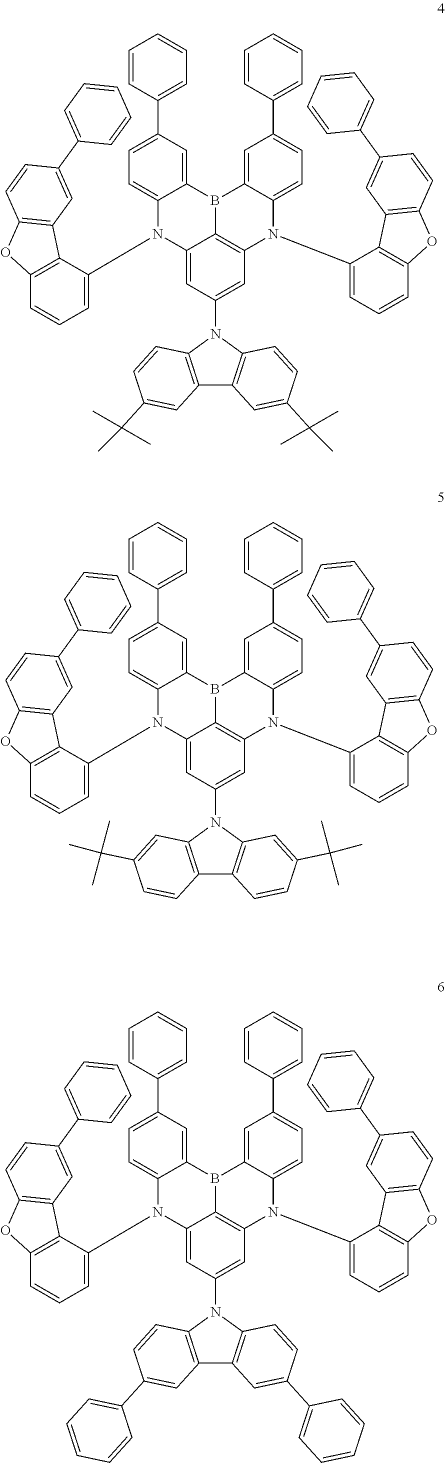 [SMILES: CC(C)(C)c1ccc2c(c1)c1cc(C(C)(C)C)ccc1n2-c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1ccc2c3ccc(C(C)(C)C)cc3n(-c3cc4c5c(c3)N(c3cccc6oc7ccc(-c8ccccc8)cc7c36)c3ccc(-c6ccccc6)cc3B5c3cc(-c5ccccc5)ccc3N4c3cccc4oc5ccc(-c6ccccc6)cc5c34)c2c1 ; c1ccc(-c2ccc3c(c2)B2c4cc(-c5ccccc5)ccc4N(c4cccc5oc6ccc(-c7ccccc7)cc6c45)c4cc(-n5c6ccc(-c7ccccc7)cc6c6cc(-c7ccccc7)ccc65)cc(c42)N3c2cccc3oc4ccc(-c5ccccc5)cc4c23)cc1]

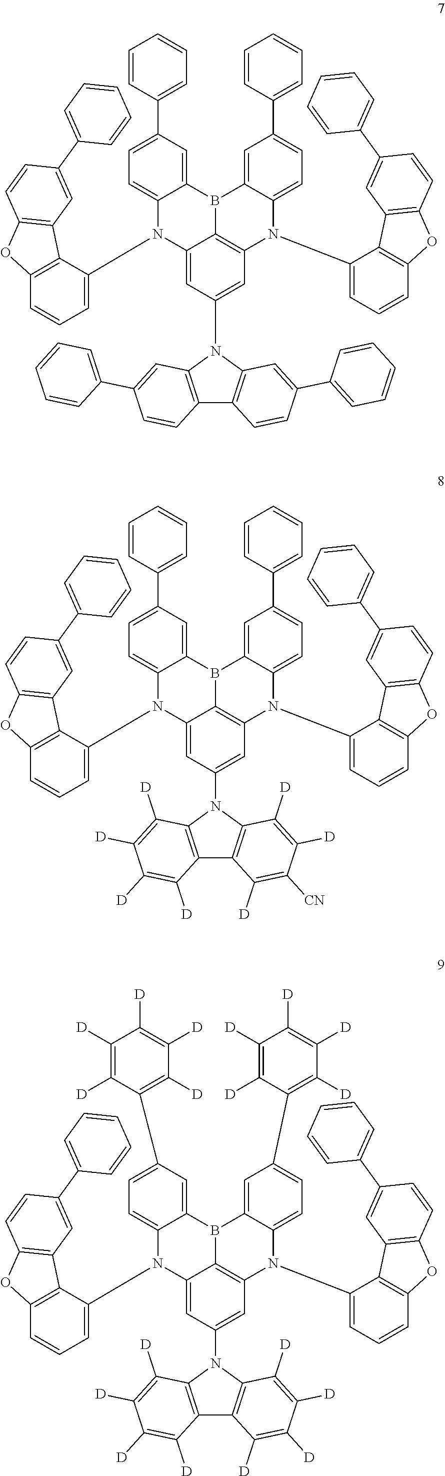

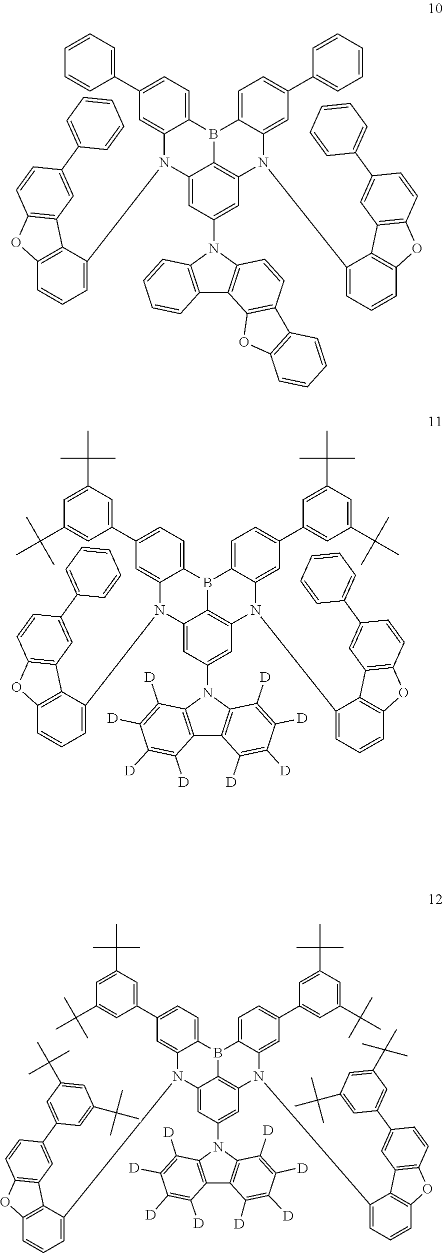

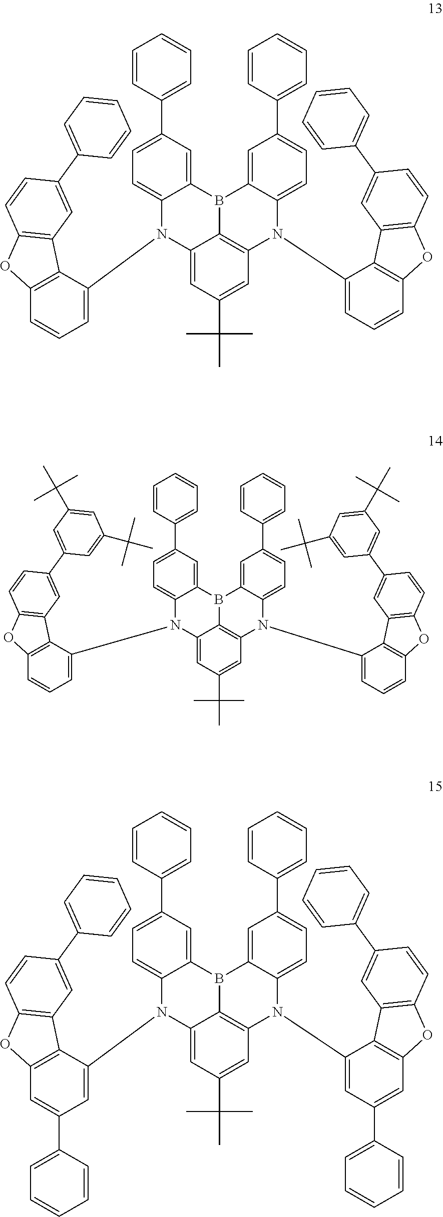 [SMILES: CC(C)(C)c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1cc(-c2ccc3oc4cccc(N5c6ccc(-c7ccccc7)cc6B6c7cc(-c8ccccc8)ccc7N(c7cccc8oc9ccc(-c%10cc(C(C)(C)C)cc(C(C)(C)C)c%10)cc9c78)c7cc(C(C)(C)C)cc5c76)c4c3c2)cc(C(C)(C)C)c1 ; CC(C)(C)c1cc2c3c(c1)N(c1cc(-c4ccccc4)cc4oc5ccc(-c6ccccc6)cc5c14)c1ccc(-c4ccccc4)cc1B3c1cc(-c3ccccc3)ccc1N2c1cc(-c2ccccc2)cc2oc3ccc(-c4ccccc4)cc3c12]

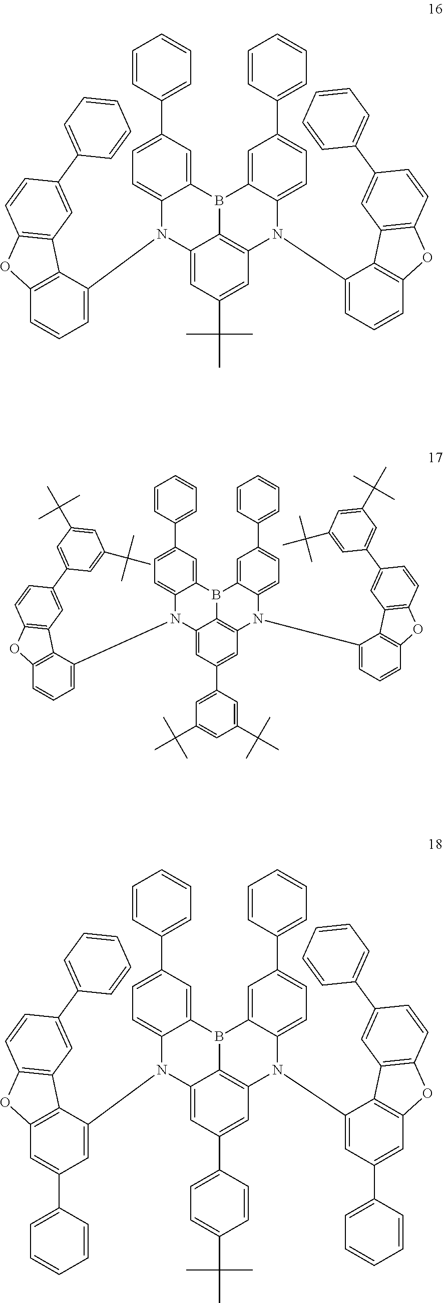 [SMILES: CC(C)(C)c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1cc(-c2cc3c4c(c2)N(c2cccc5oc6ccc(-c7cc(C(C)(C)C)cc(C(C)(C)C)c7)cc6c25)c2ccc(-c5ccccc5)cc2B4c2cc(-c4ccccc4)ccc2N3c2cccc3oc4ccc(-c5cc(C(C)(C)C)cc(C(C)(C)C)c5)cc4c23)cc(C(C)(C)C)c1 ; CC(C)(C)c1ccc(-c2cc3c4c(c2)N(c2cc(-c5ccccc5)cc5oc6ccc(-c7ccccc7)cc6c25)c2ccc(-c5ccccc5)cc2B4c2cc(-c4ccccc4)ccc2N3c2cc(-c3ccccc3)cc3oc4ccc(-c5ccccc5)cc4c23)cc1]

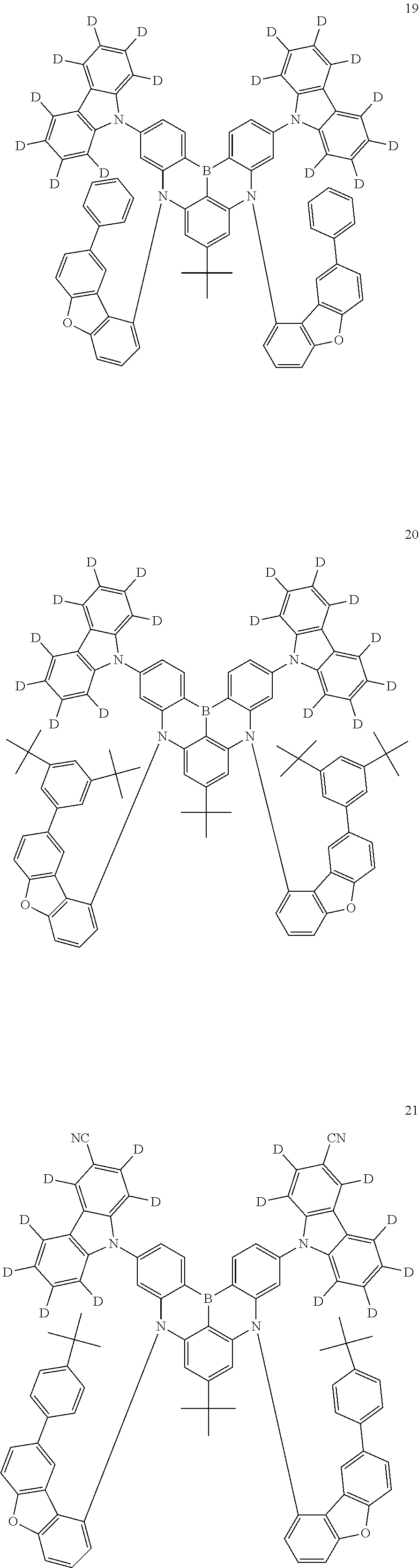

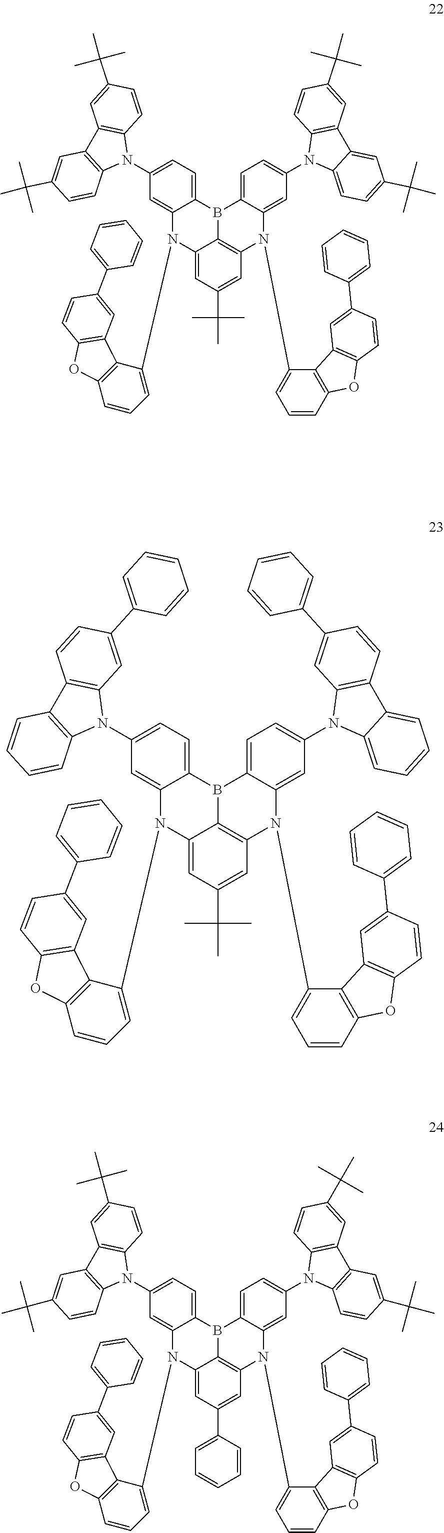

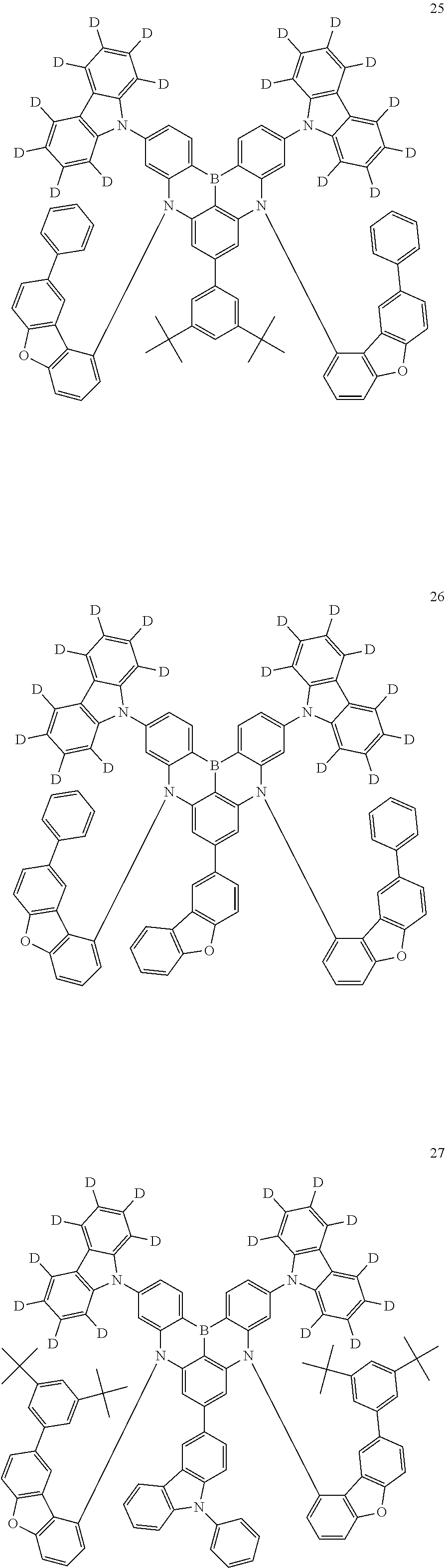

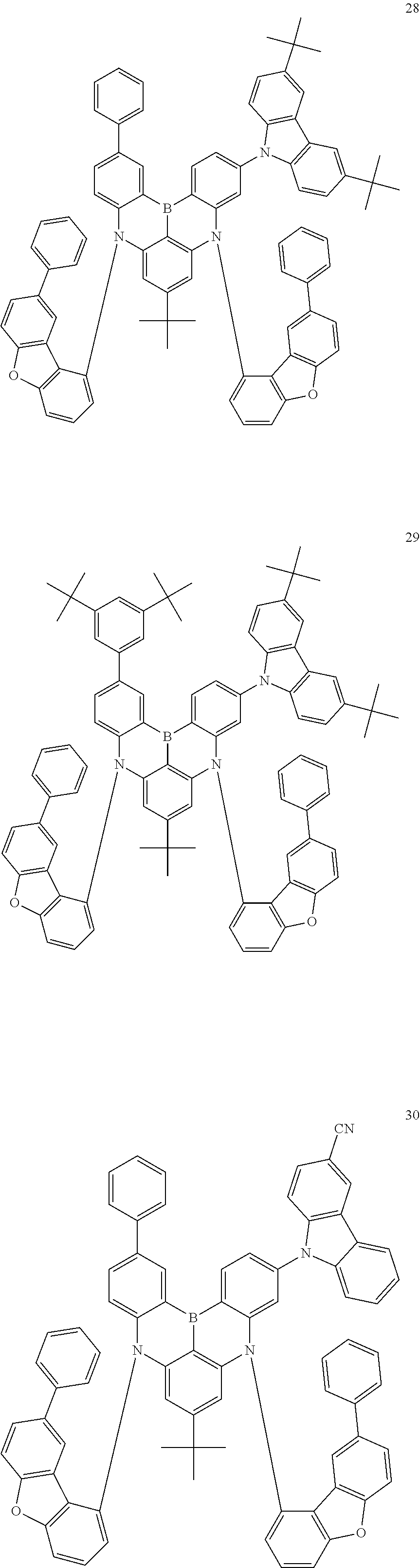 [SMILES: CC(C)(C)c1cc2c3c(c1)N(c1cccc4oc5ccc(-c6ccccc6)cc5c14)c1cc(-n4c5ccc(C(C)(C)C)cc5c5cc(C(C)(C)C)ccc54)ccc1B3c1cc(-c3ccccc3)ccc1N2c1cccc2oc3ccc(-c4ccccc4)cc3c12 ; CC(C)(C)c1cc(-c2ccc3c(c2)B2c4ccc(-n5c6ccc(C(C)(C)C)cc6c6cc(C(C)(C)C)ccc65)cc4N(c4cccc5oc6ccc(-c7ccccc7)cc6c45)c4cc(C(C)(C)C)cc(c42)N3c2cccc3oc4ccc(-c5ccccc5)cc4c23)cc(C(C)(C)C)c1 ; CC(C)(C)c1cc2c3c(c1)N(c1cccc4oc5ccc(-c6ccccc6)cc5c14)c1cc(-n4c5ccccc5c5cc(C#N)ccc54)ccc1B3c1cc(-c3ccccc3)ccc1N2c1cccc2oc3ccc(-c4ccccc4)cc3c12]

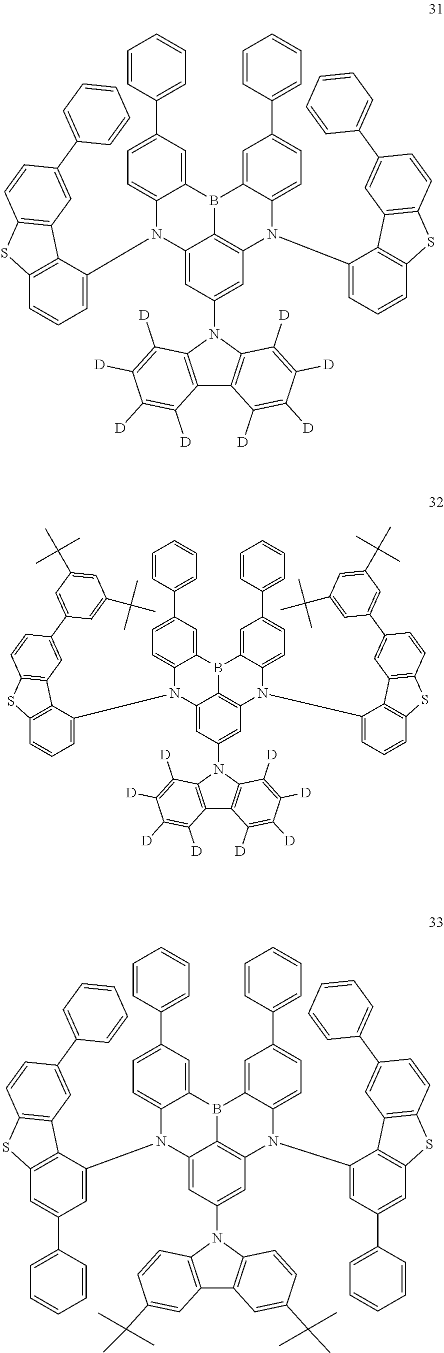

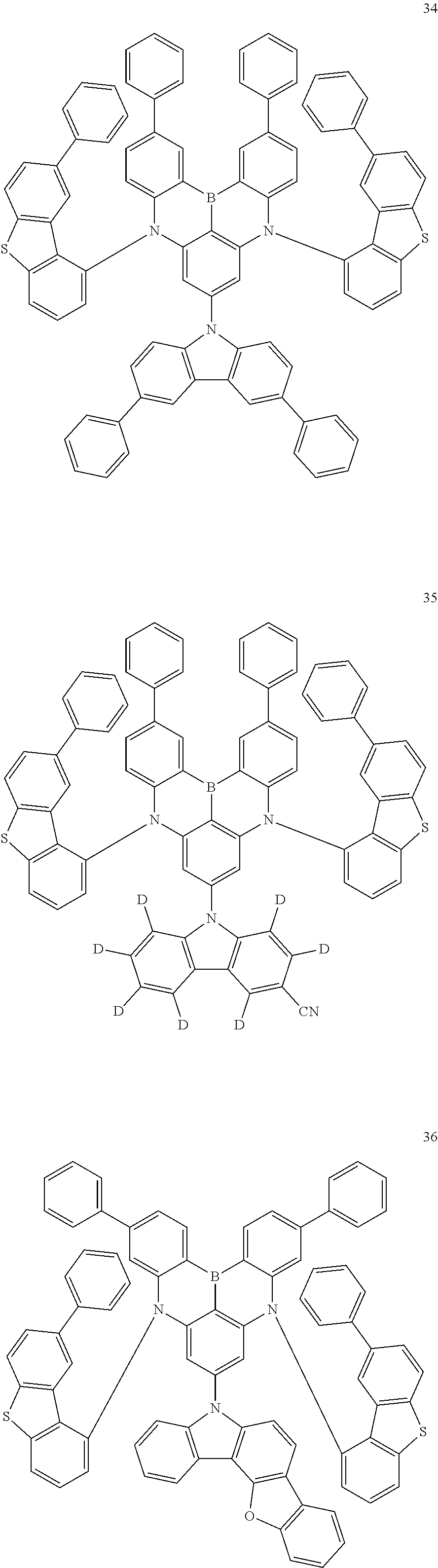

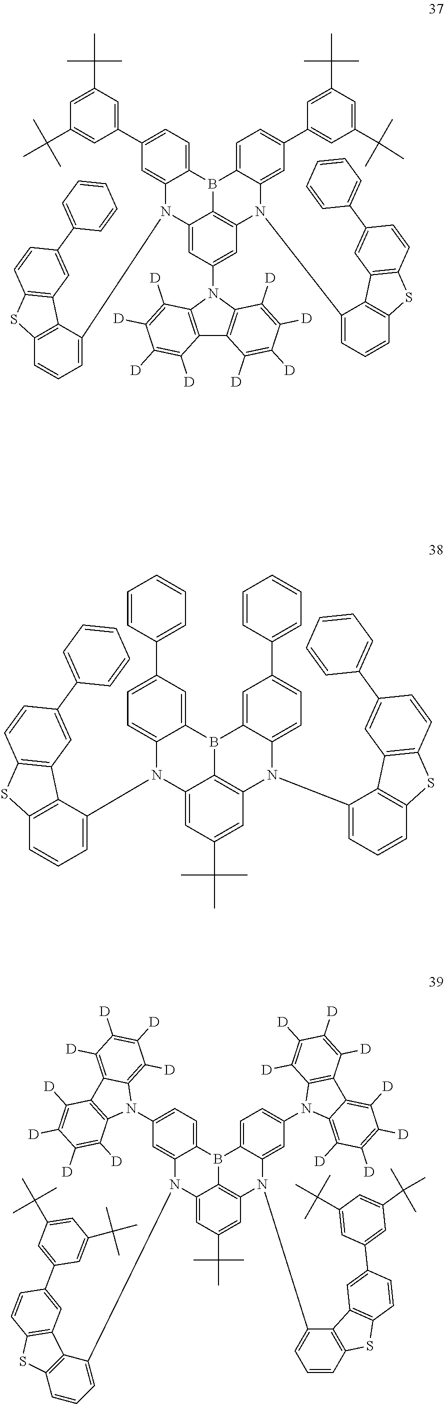

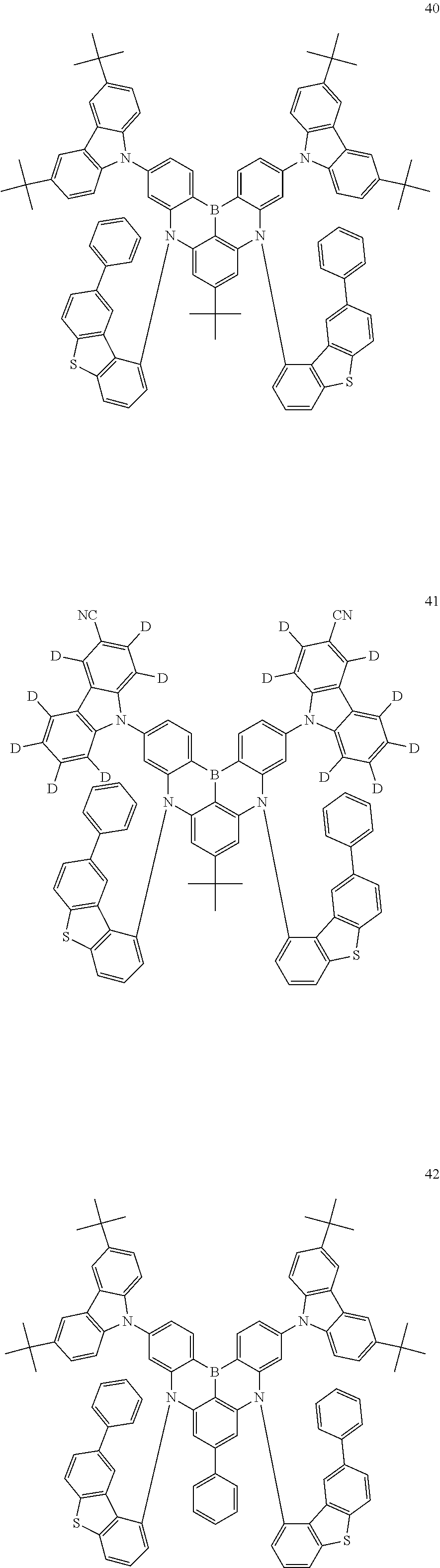

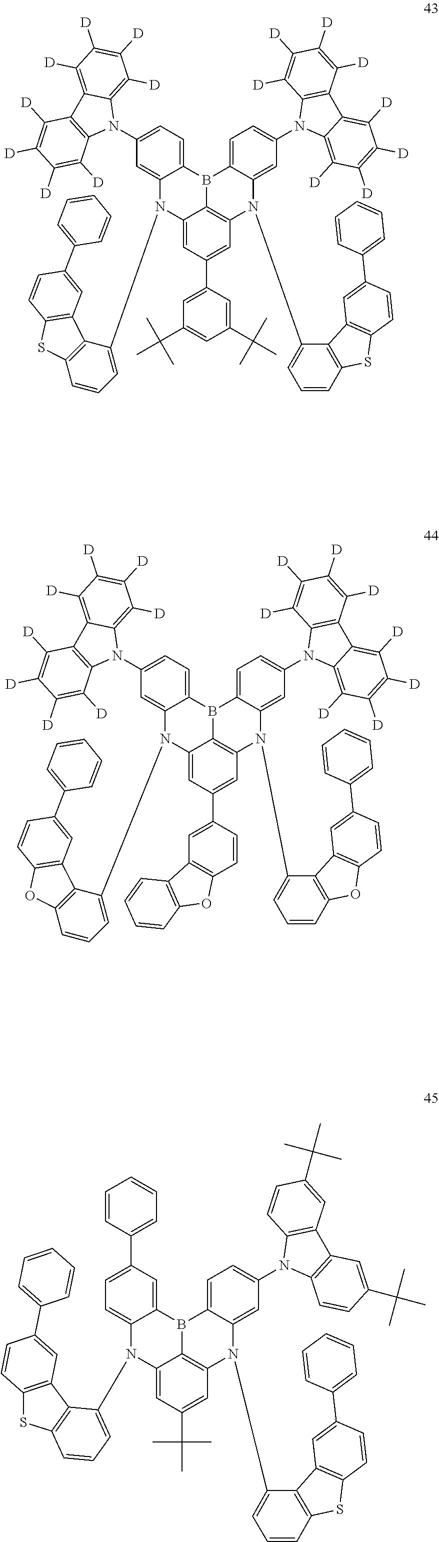

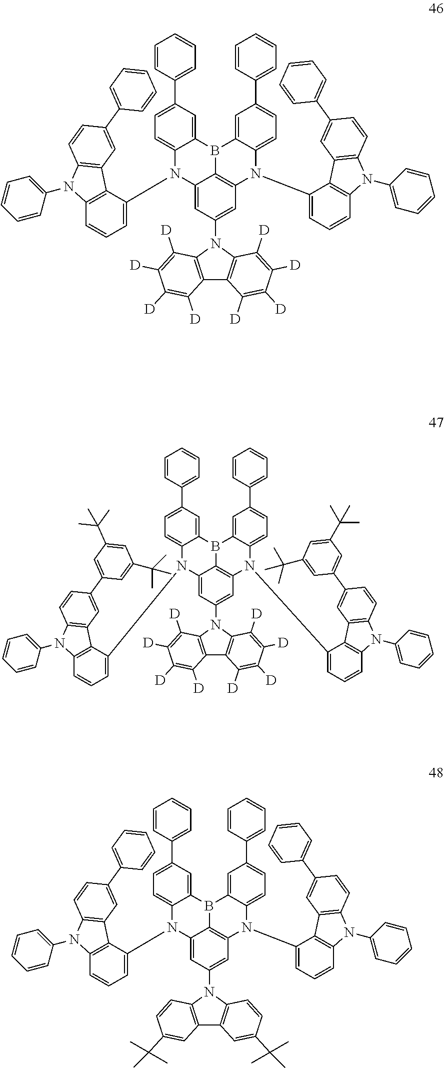

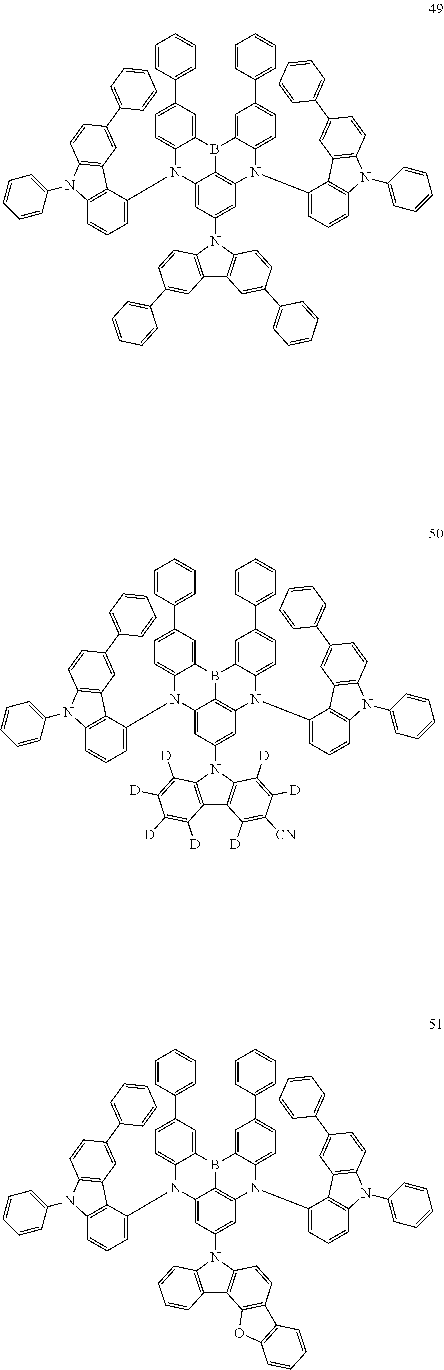

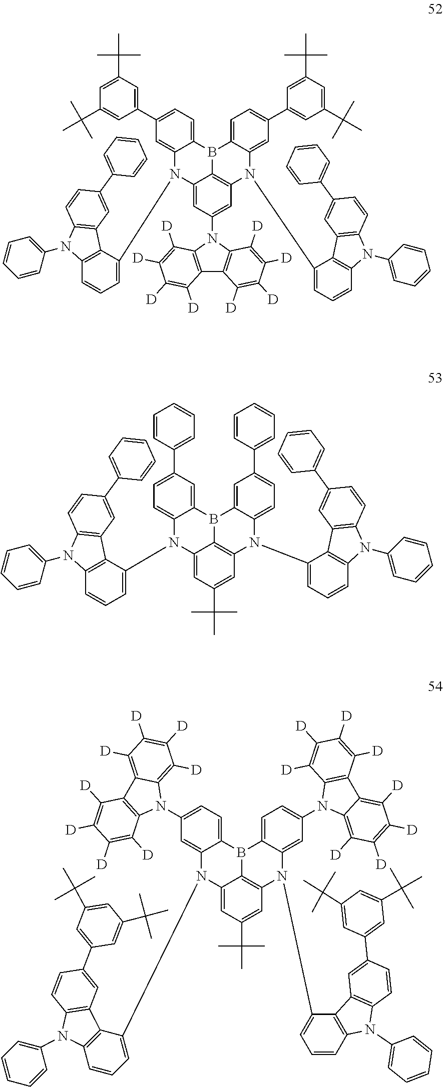

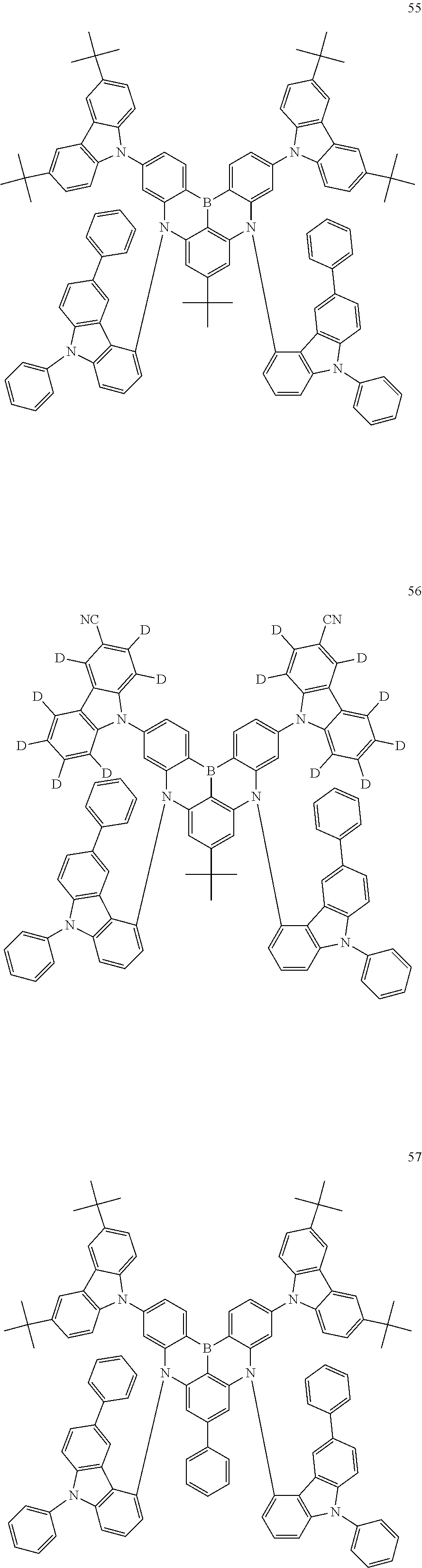

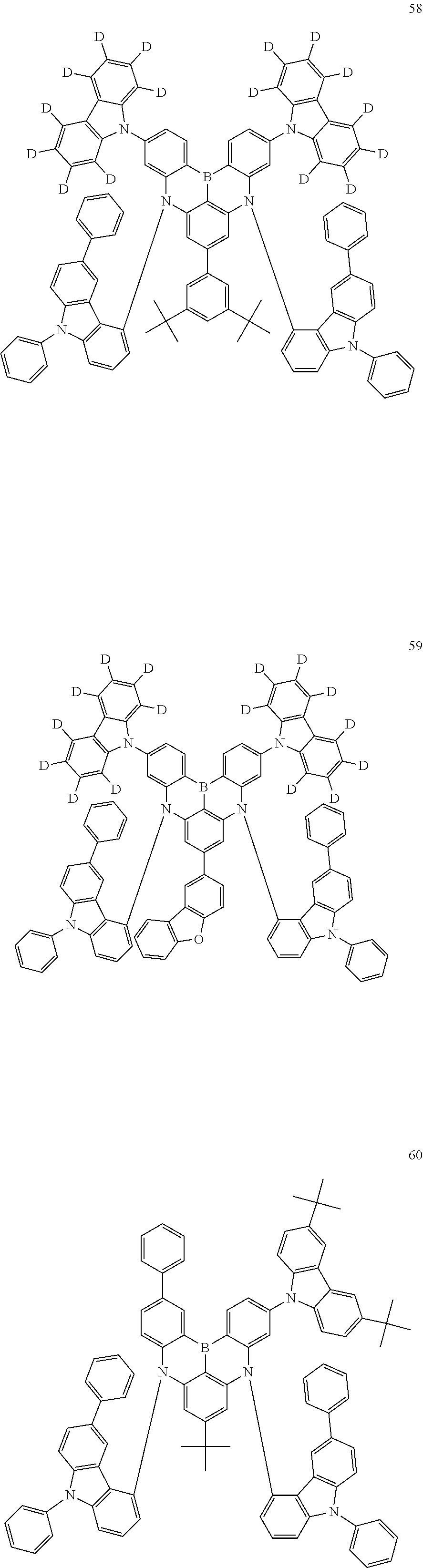

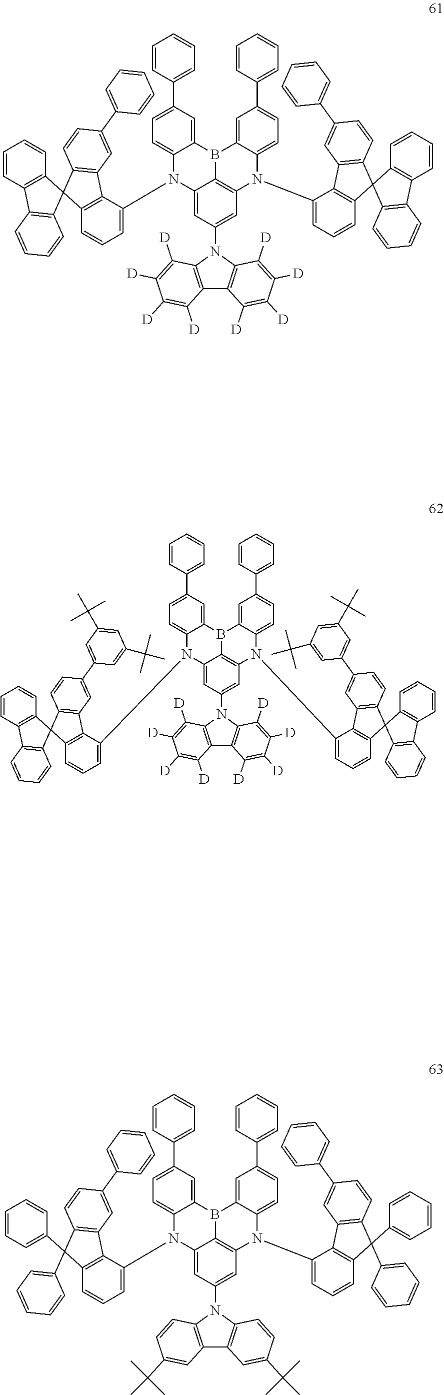

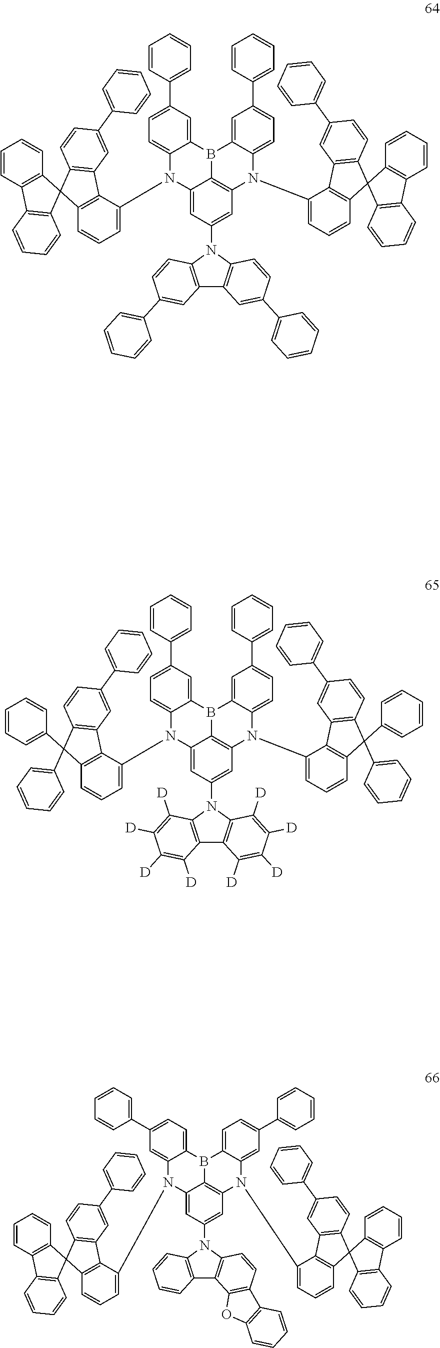

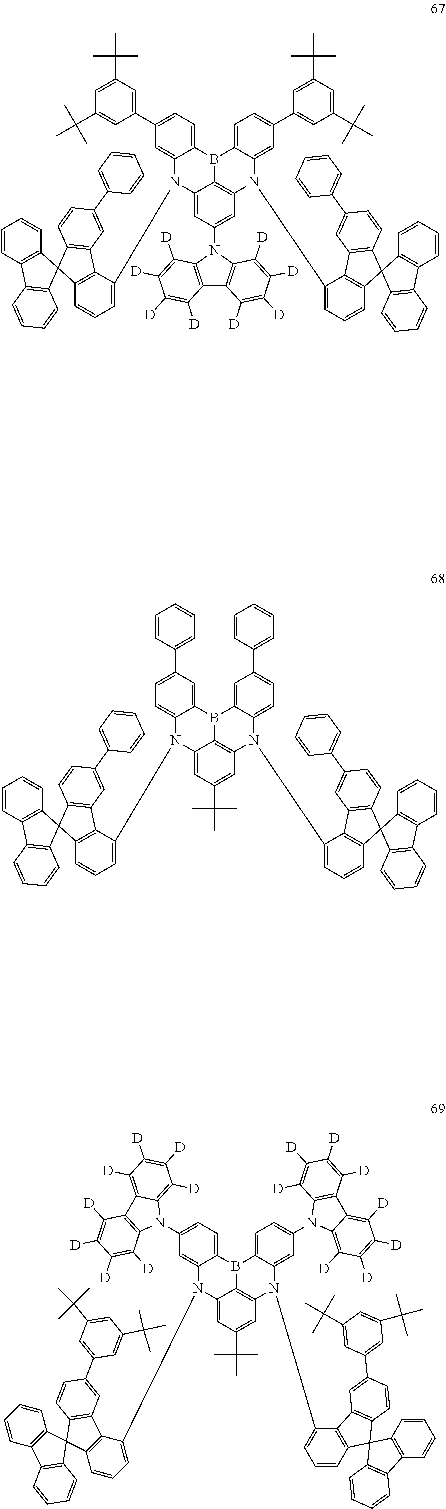

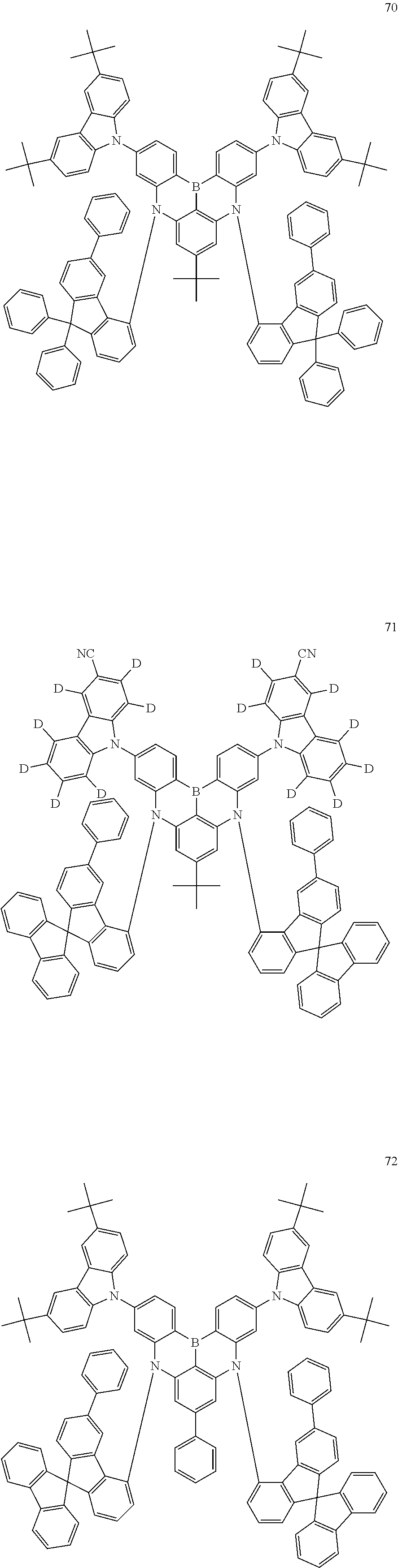

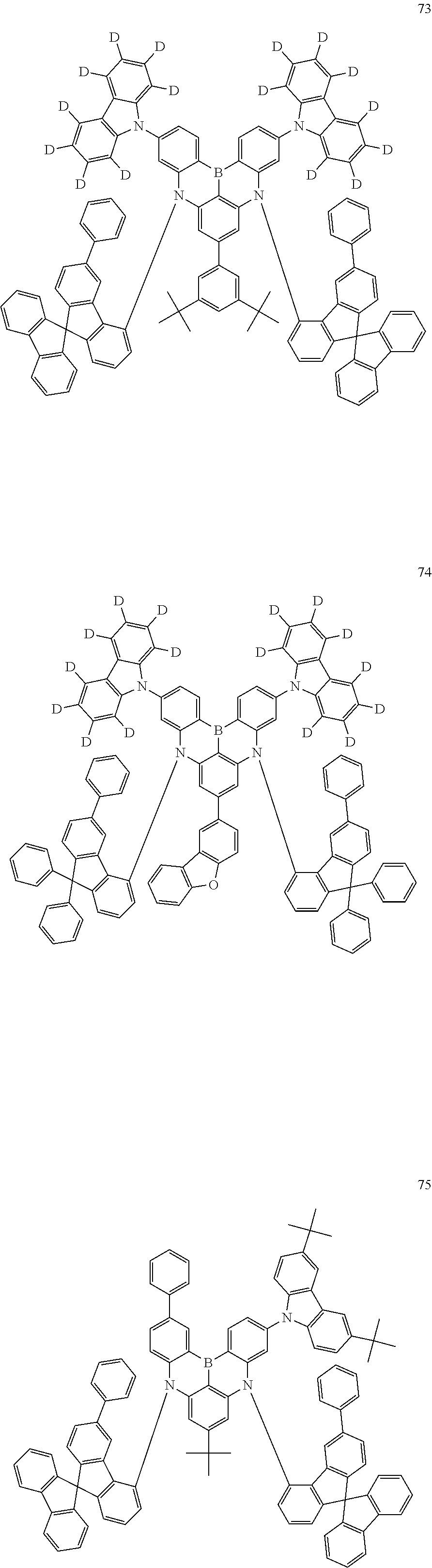

The polycyclic compound represented by Formula 1 has a structure in which the first and second substituents are each connected to a nitrogen atom of the fused ring core at a specific position, and when used as a material for a light emitting element, high emission efficiency and long service life could be achieved.

The first and second substituents of the polycyclic compound may each have large steric hindrance effects. For example, first and second substituents may each independently include a dibenzofuran moiety, a dibenzothiphene moiety, a carbazole moiety, or a fluorene moiety, and a substituted or unsubstituted phenyl group may be connected to each of the first and second substituents at carbon position 3. The first and second substituents may be connected to a nitrogen atom of the fused ring core at carbon position 5. The polycyclic compound, including the first and second substituents having such large steric hindrance effects, may protect the p-orbital of the boron atom, and may control intermolecular distance to effectively control intermolecular interaction such as Dexter energy transfer.

For example, the polycyclic compound includes a fused ring core including a boron atom and two nitrogen atoms, and substituents connected to the fused ring core and having large steric hindrance, thereby showing increased stability properties of the polycyclic compound. Accordingly, the polycyclic compound may contribute to the improvement of emission efficiency and service life of a light emitting element.

The emission layer EML may include the polycyclic compound according to an embodiment. The emission layer EML may include the polycyclic compound as a dopant material. The polycyclic compound may be a thermally activated delayed fluorescence (TADF) material. The polycyclic compound of an embodiment may be used as a thermally activated delayed fluorescence (TADF) dopant. For example, in the light emitting element ED according to an embodiment, the emission layer EML may include at least one polycyclic compound selected from Compound Group 1 as a thermally activated delayed fluorescence dopant. However, the use of the polycyclic compound is not limited thereto.

The polycyclic compound of an embodiment may be a light emitting material having central emission wavelength in a range of about 430 nm to about 490 nm. For example, the polycyclic compound may emit blue light. For example, the polycyclic compound represented by Formula 1 may be a blue thermally activated delayed fluorescence (TADF) dopant. However, embodiments are not limited thereto.

In an embodiment, the emission layer EML may further include compounds, in addition to the above-described first compound. For example, in an embodiment, the emission layer EML may include the polycyclic compound represented by Formula 1, i.e., the first compound, and may further include at least one of a second compound, a third compound, and a fourth compound. In an embodiment, the emission layer EML may include the first compound, and may further include at least one of the second compound, the third compound, and the fourth compound.

In an embodiment, the emission layer EML may include a second compound represented by Formula HT. In an embodiment, the second compound represented by Formula HT may be used as a hole transport host material of the emission layer EML.

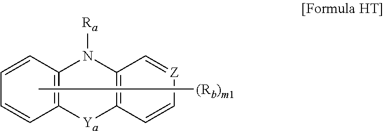

In Formula HT, m1 may be an integer from 0 to 7. If m1 is 2 or more, multiple R_{b} groups may be the same, or at least one thereof may be different. In Formula HT, Rₐ and R_{b} may each independently be a hydrogen atom, a deuterium atom, a cyano group, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring. For example, Rₐ may be a substituted or unsubstituted phenyl group, a substituted pyrimidine group, an unsubstituted dibenzofuran group, a substituted carbazole group, or an unsubstituted fluorenyl group. For example, R_{b} may be a hydrogen atom, a deuterium atom, a cyano group, a substituted or unsubstituted phenyl group, a substituted or unsubstituted carbazole group, or a substituted fluorenyl group. In an embodiment, two adjacent R_{b} groups may be combined with each other to form a substituted or unsubstituted heterocycle.

In Formula HT, Yₐ may be a direct linkage, C(R_{y1})(R_{y2}), or Si(R_{y3})(R_{y4}). For example, in Formula HT, two benzene rings that are connected to the nitrogen atom of Formula HT may be connected to each other via a direct linkage,

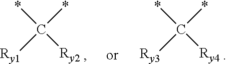

For example, if Yₐ is a direct linkage, the second compound represented by Formula HT may include a carbazole moiety. In Formula HT, R_{y1} to R_{y4} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms. For example, R_{y1} to R_{y4} may each independently be a methyl group or a phenyl group.

In Formula HT, Z may be C(R_{z}) or a nitrogen atom (N). For example, if Yₐ is a direct linkage, and Z is C(R_{z}), the second compound represented by Formula HT may include a carbazole moiety. For example, if Yₐ is a direct linkage, and Z is a nitrogen atom, the second compound represented by Formula HT may include a pyridoindole moiety. In Formula HT, R_{z} may be a hydrogen atom or a deuterium atom.

In an embodiment, the second compound represented by Formula HT may be selected from Compound Group 2. In an embodiment, in the light emitting element ED, the second compound may include at least one compound selected from Compound Group 2. In Compound Group 2, D represents a deuterium atom, and Ph represents a substituted or unsubstituted phenyl group.

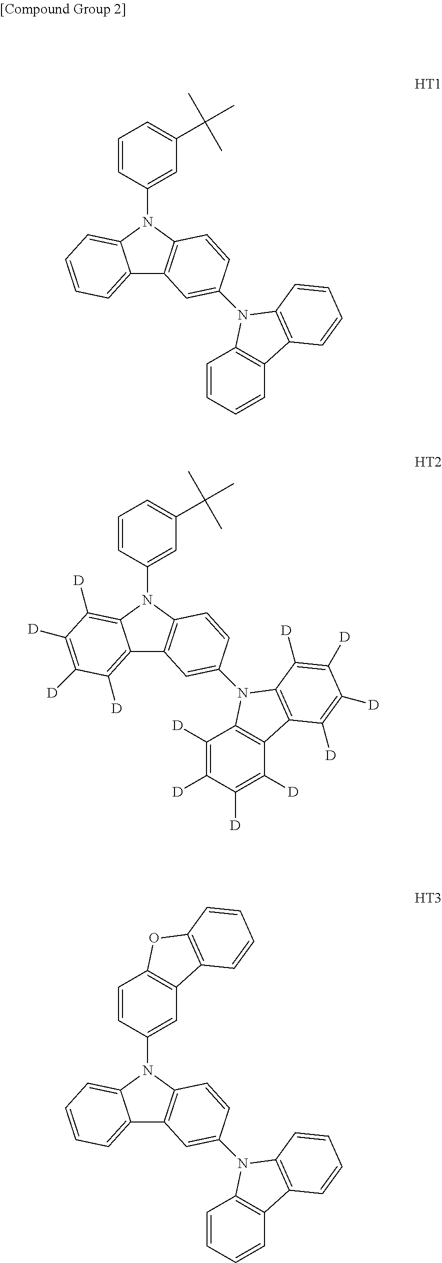 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

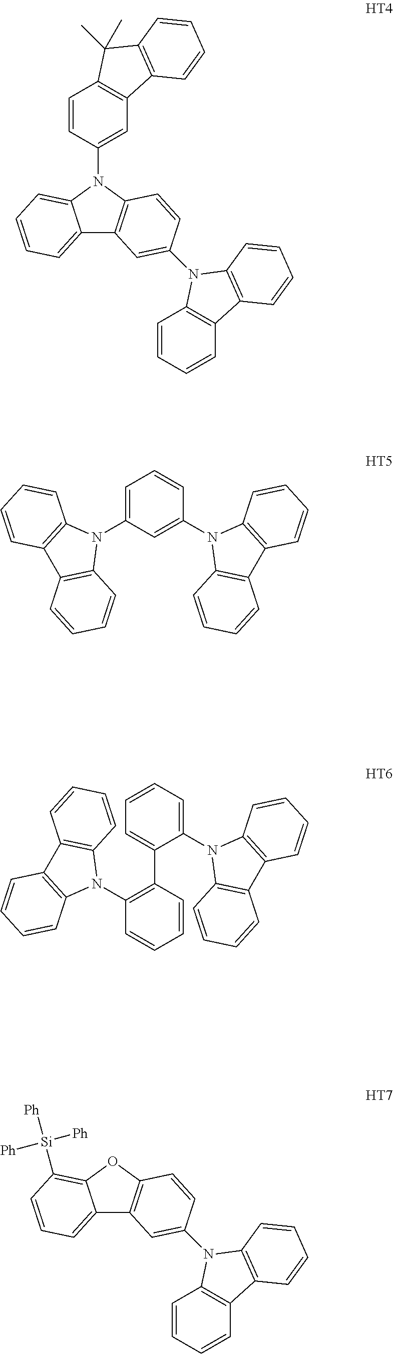 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

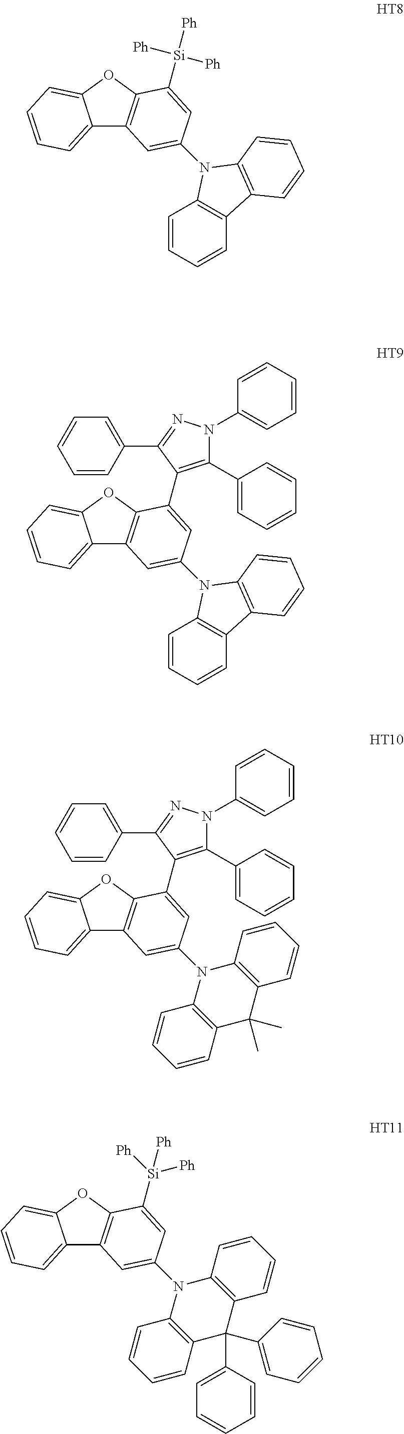 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

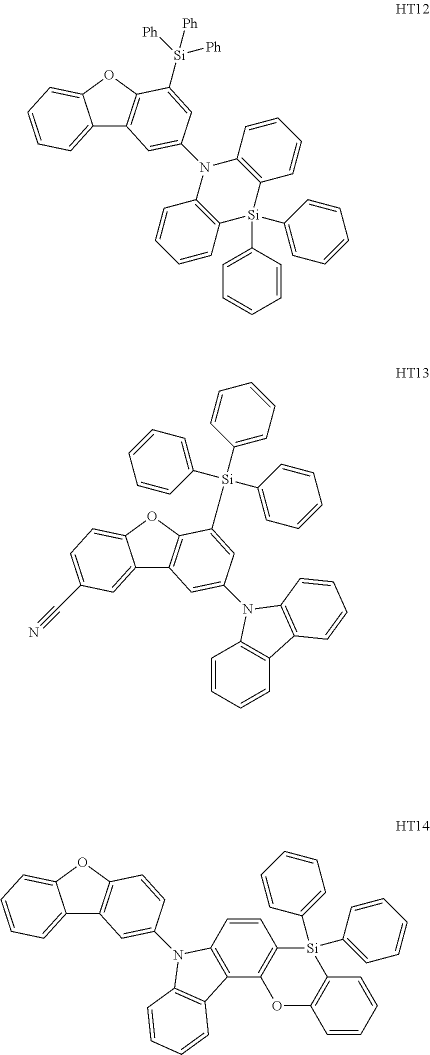 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

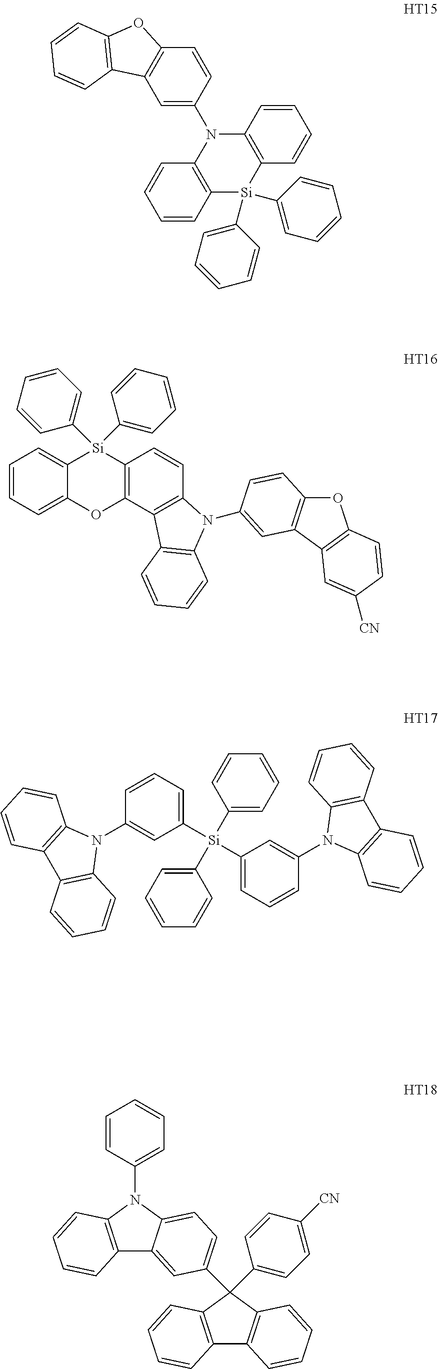 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

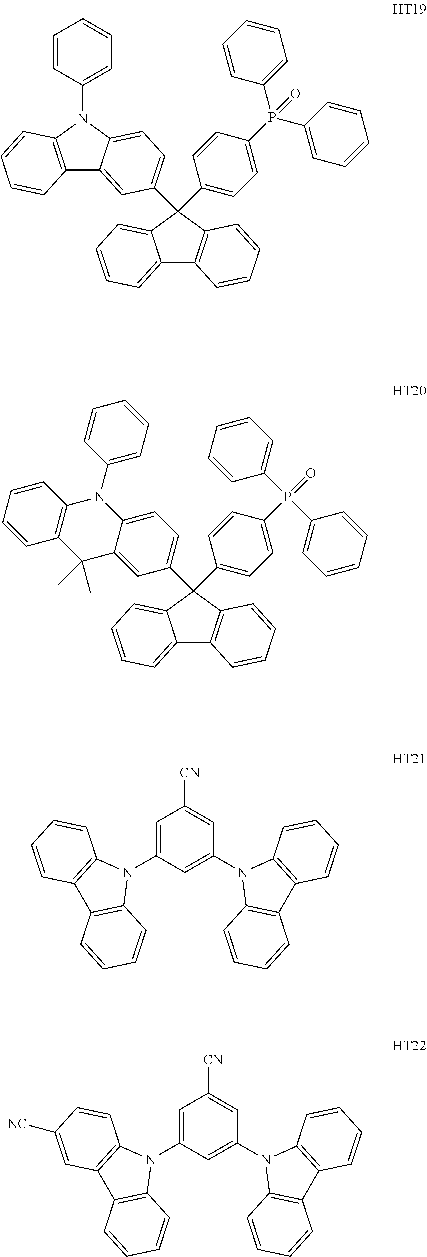 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

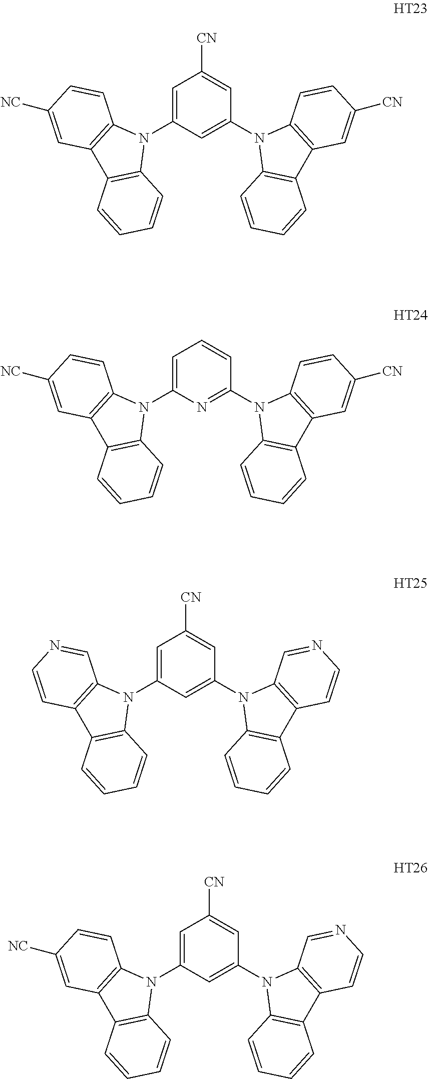 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

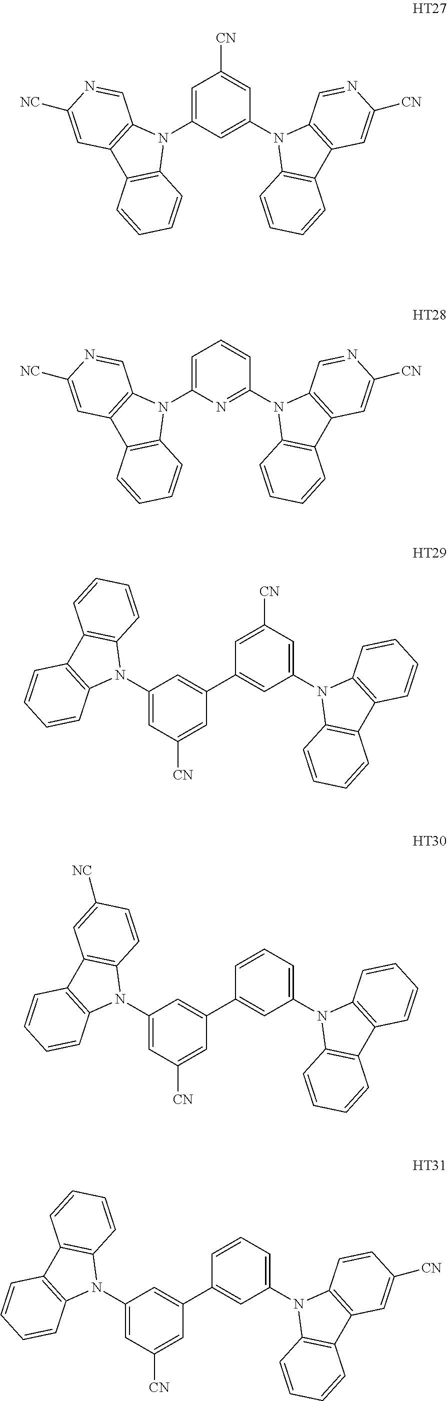 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

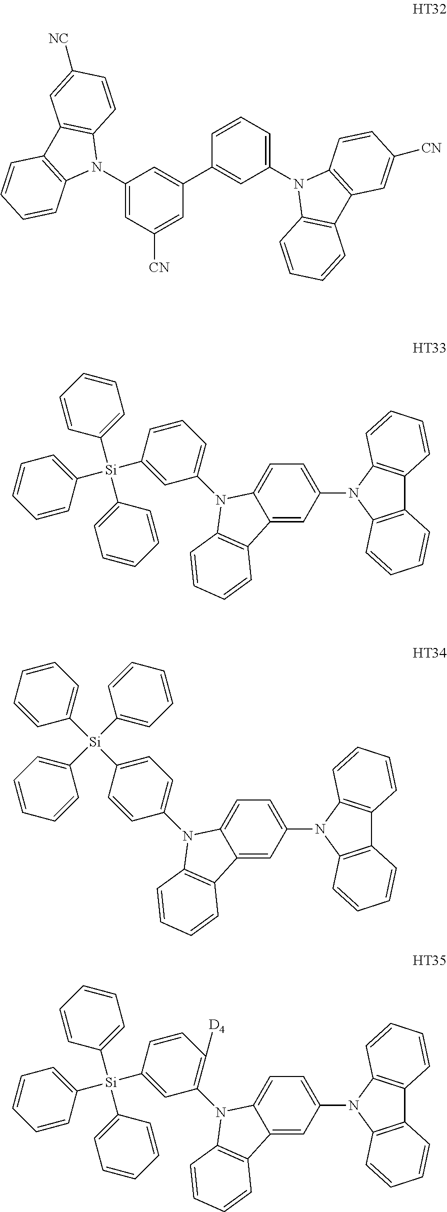

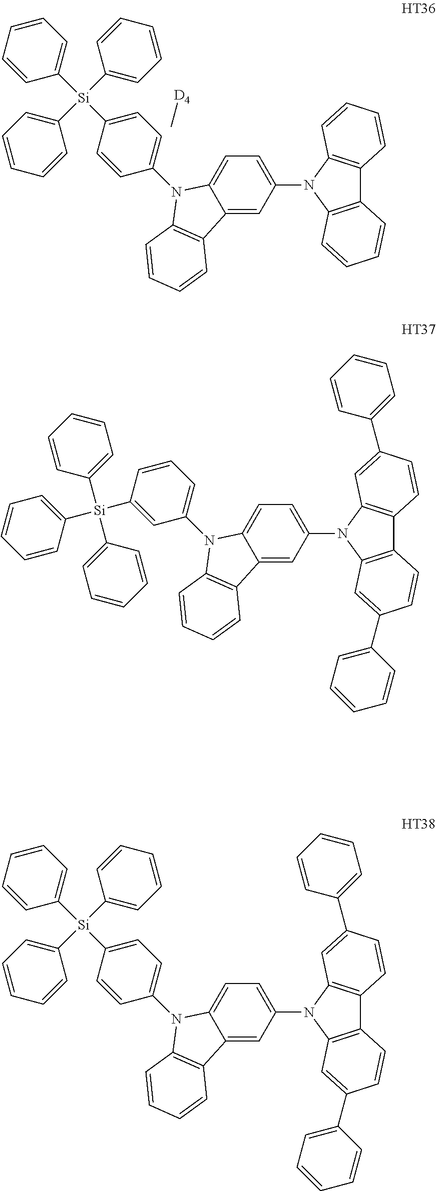

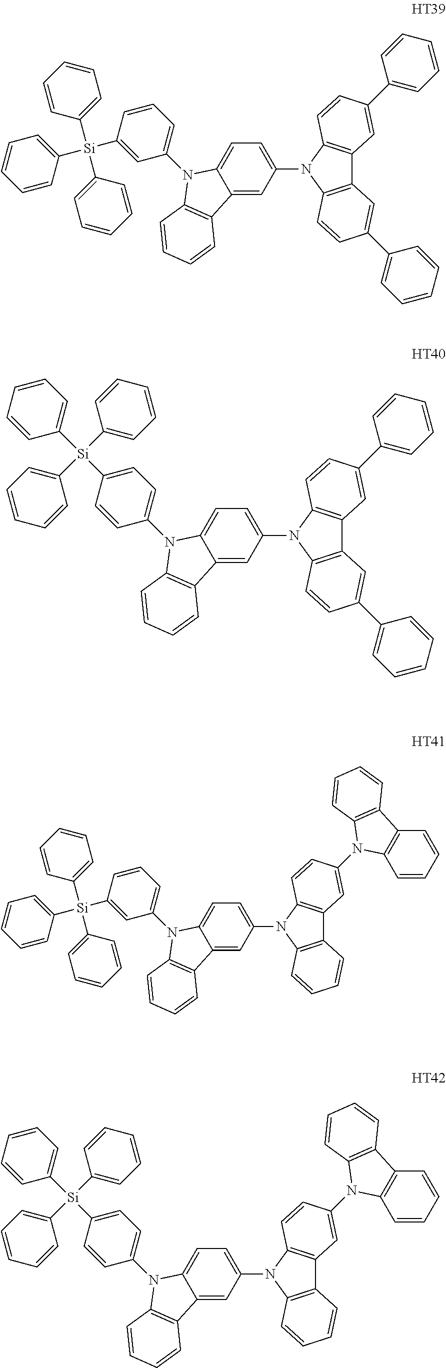 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

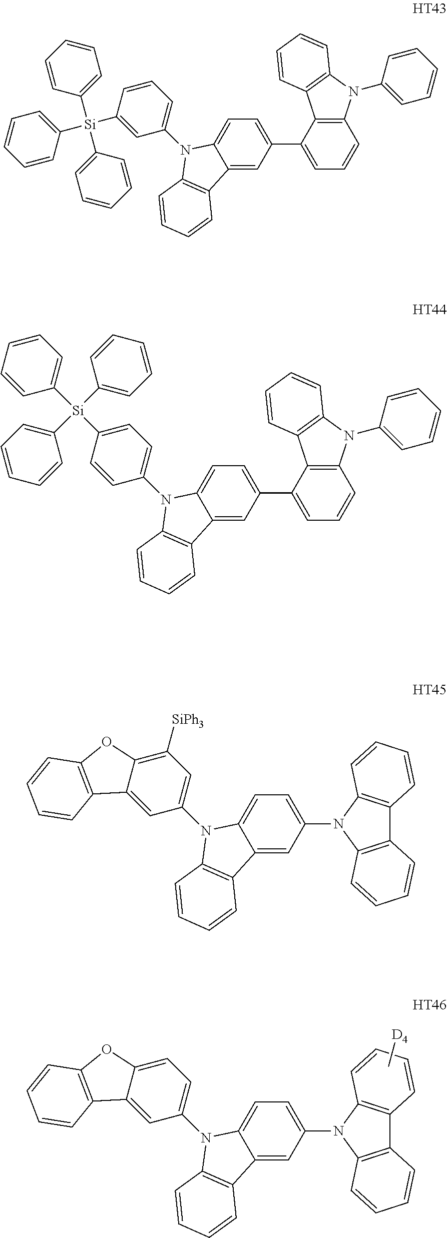

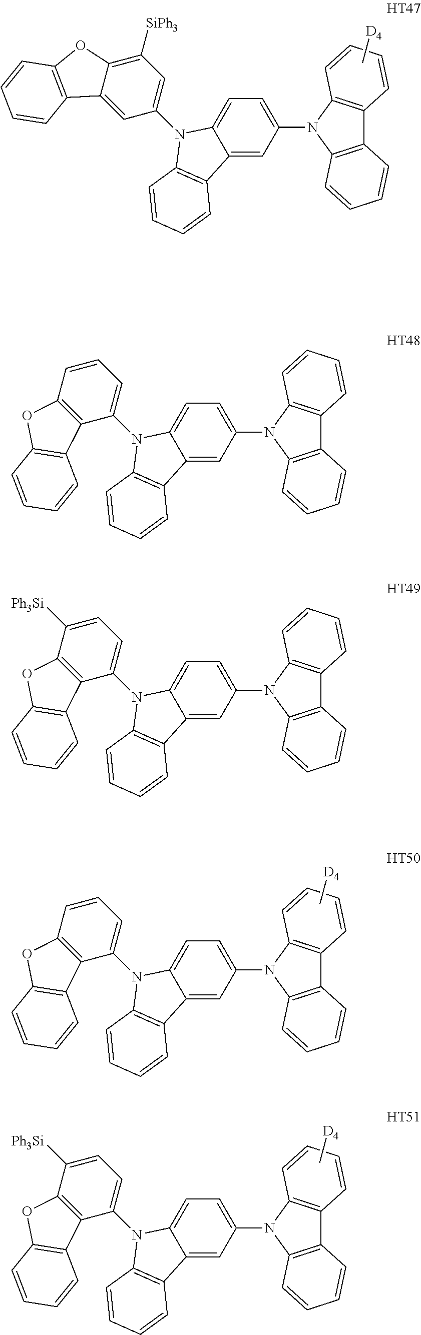

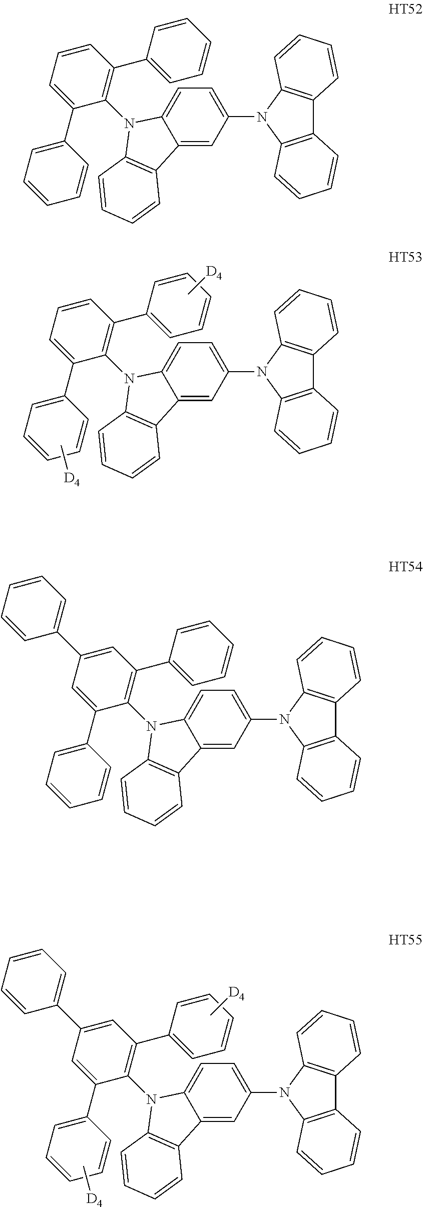

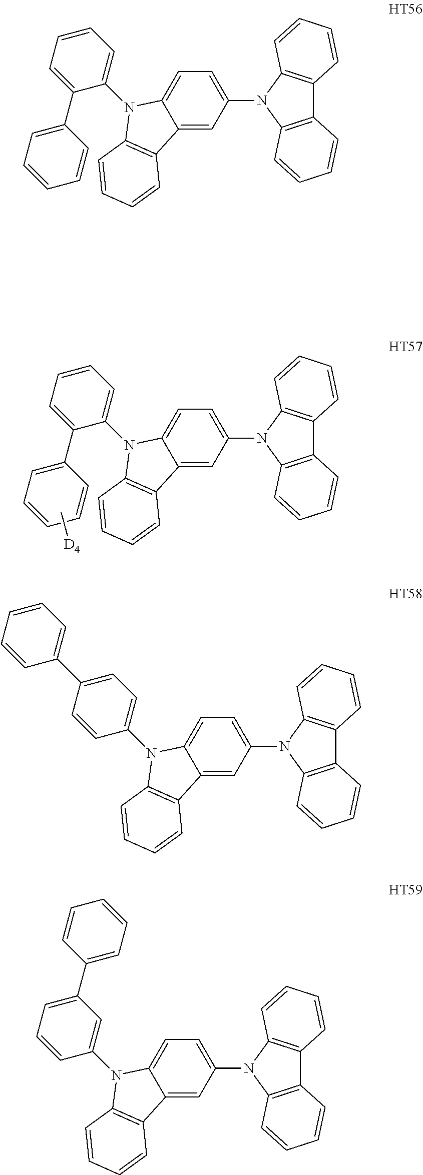

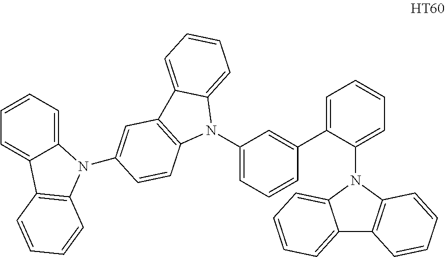 [SMILES: c1cc(-c2ccccc2-n2c3ccccc3c3ccccc32)cc(-n2c3ccccc3c3cc(-n4c5ccccc5c5ccccc54)ccc32)c1]

In an embodiment, the emission layer EML may include a third compound represented by Formula ET. In an embodiment, the third compound represented by Formula ET may be used as an electron transport host material of the emission layer EML.

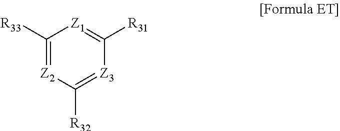

In Formula ET, Z₁ to Z₃ may each independently be N or C(R₃₄); and at least one of Z₁ to Z₃ may each be N. For example, Z₁ to Z₃ may all be N. As another example, any two of Z₁ to Z₃ may each be N, and the remainder of Z₁ to Z₃ may be C(R₃₄). As yet another example, any one of Z₁ to Z₃ may be N, and the remainder of Z₁ to Z₃ may each independently be C(R₃₄).

In Formula ET, R₃₁ to R₃₄ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring. For example, R₃₁ to R₃₄ may each independently be a substituted or unsubstituted phenyl group or a substituted or unsubstituted carbazole group. However, embodiments are not limited thereto.

In an embodiment, the third compound represented by Formula ET may be selected from Compound Group 3. In an embodiment, in the light emitting element ED, the third compound may include at least one compound selected from Compound Group 3. In Compound Group 3, D represents a deuterium atom.

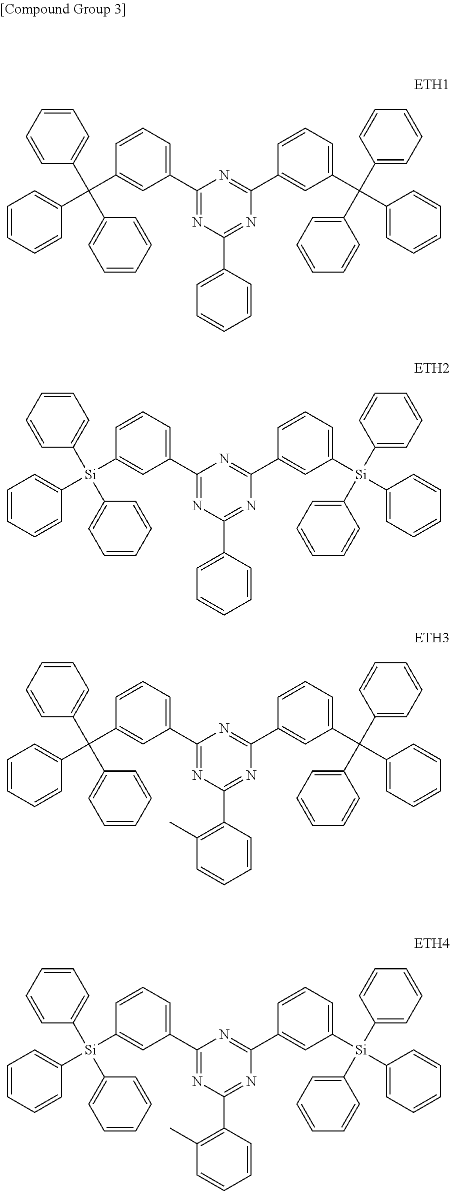 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

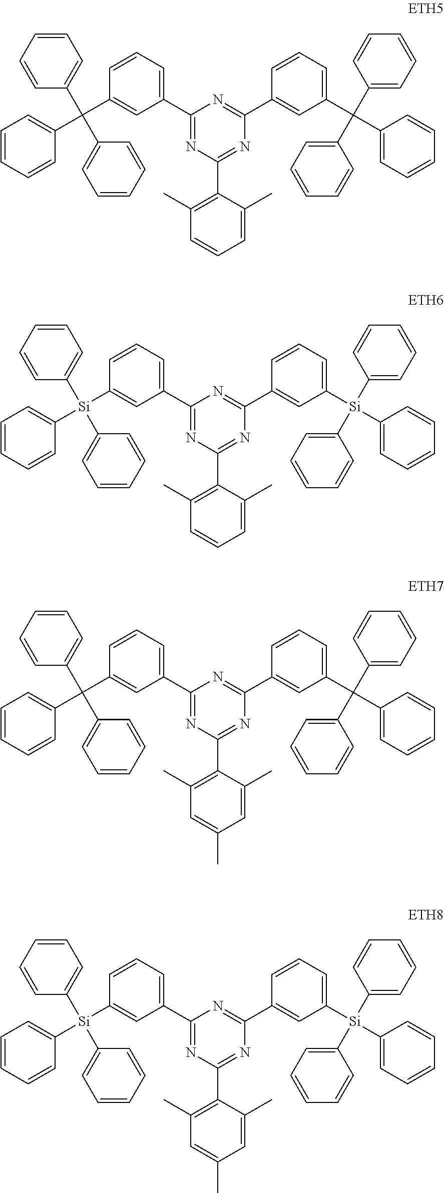 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

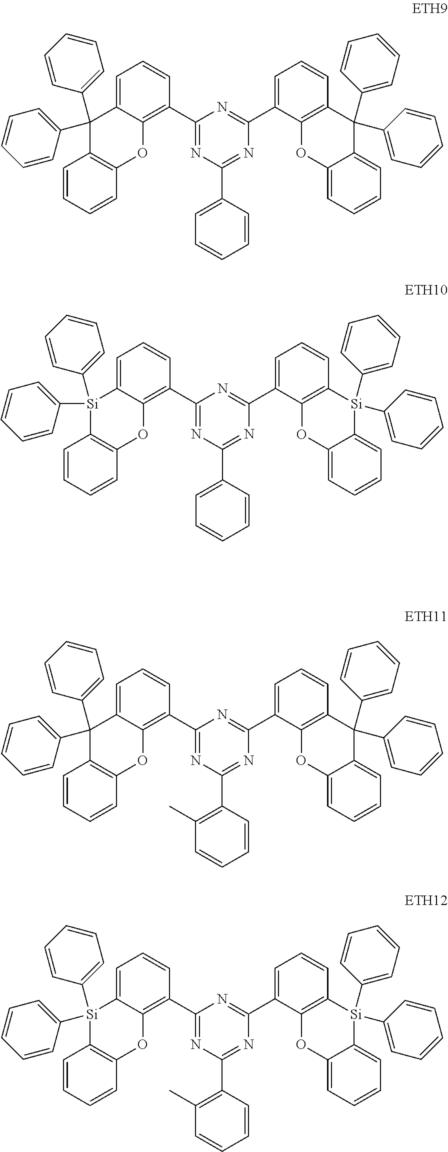 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

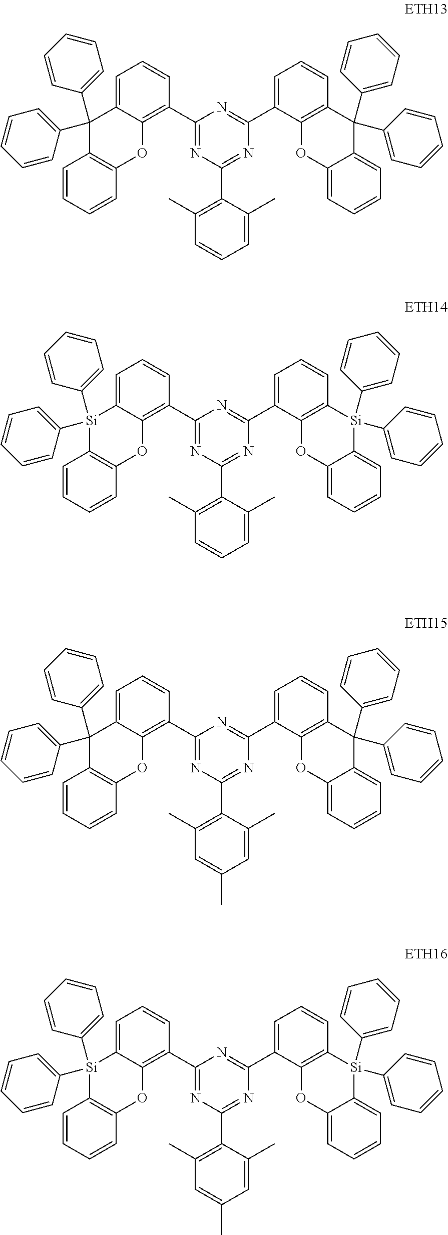 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

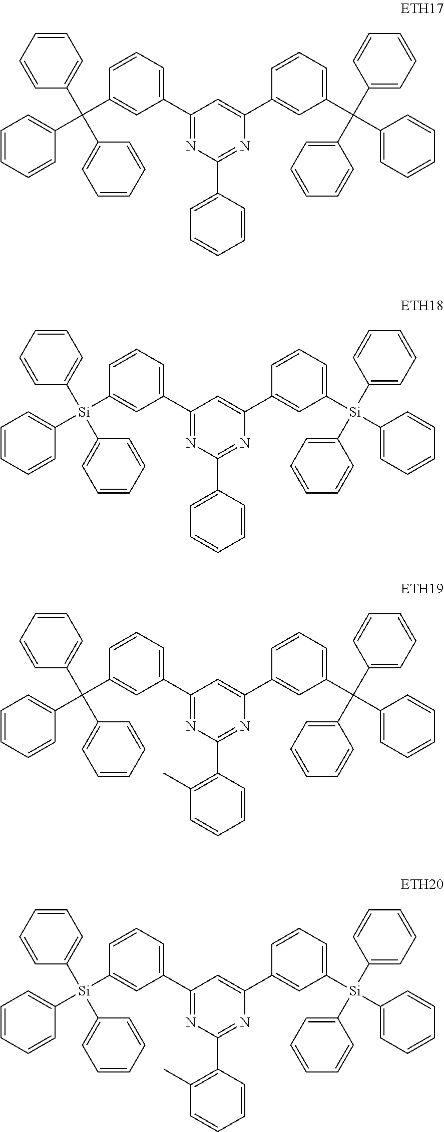 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

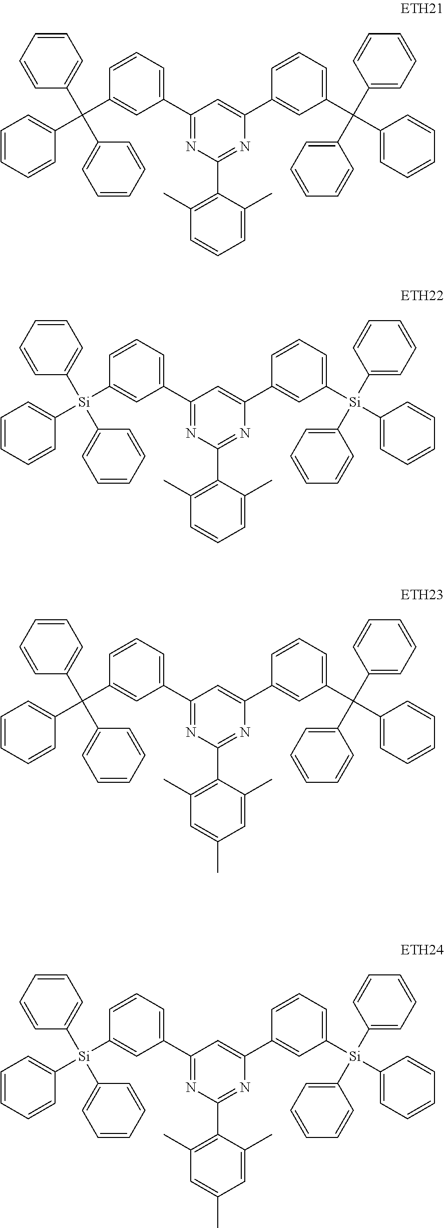 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

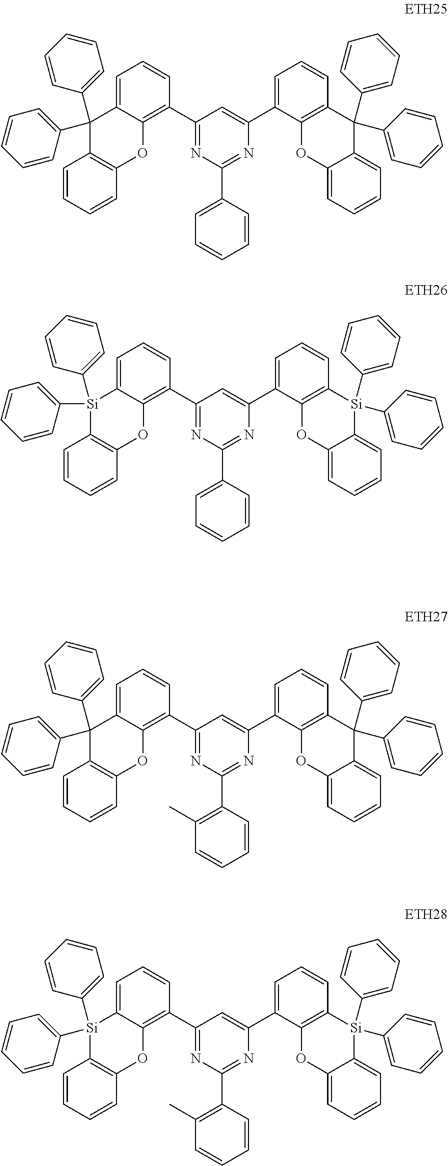 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

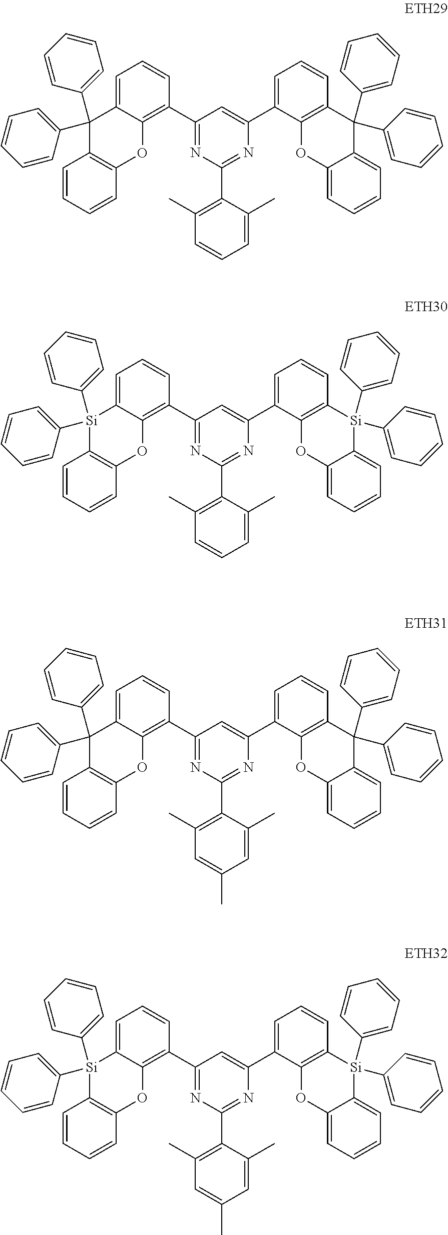 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

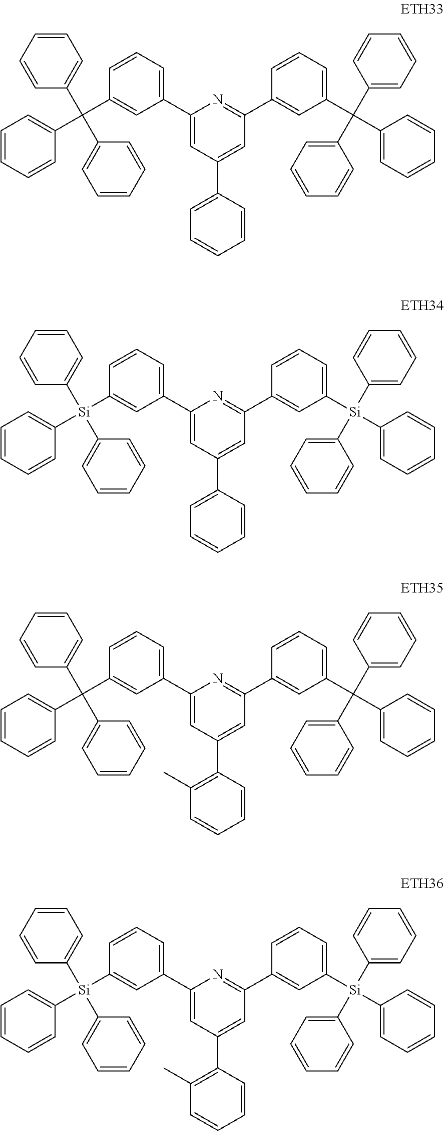 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

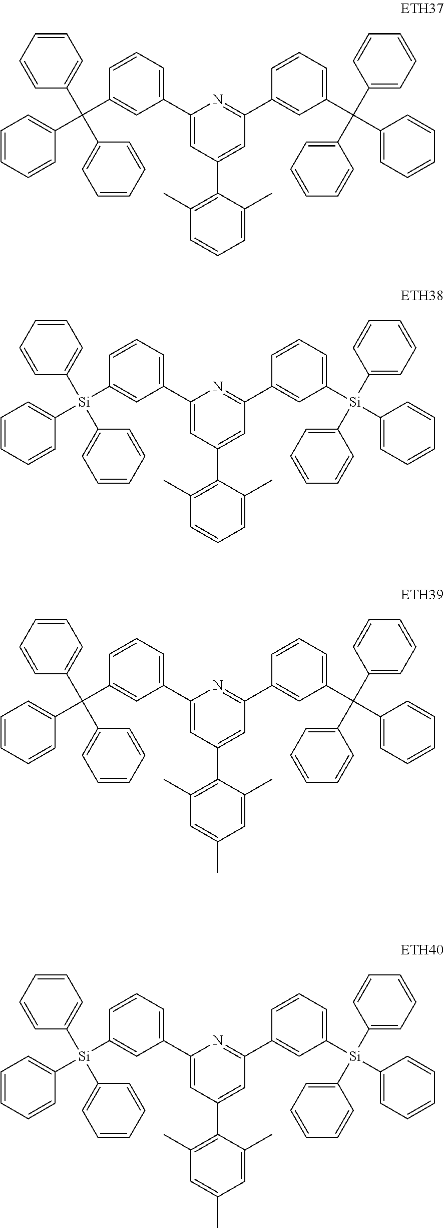 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

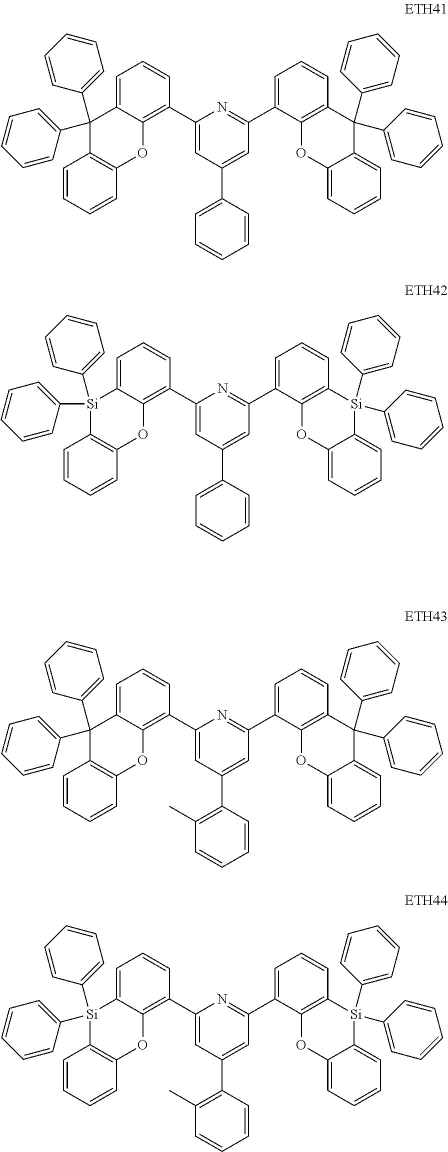 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

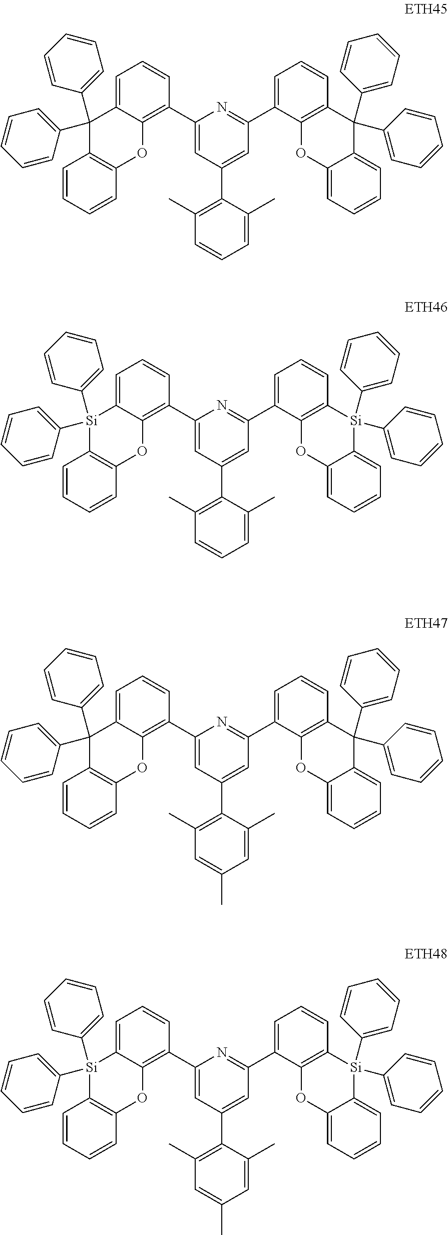 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

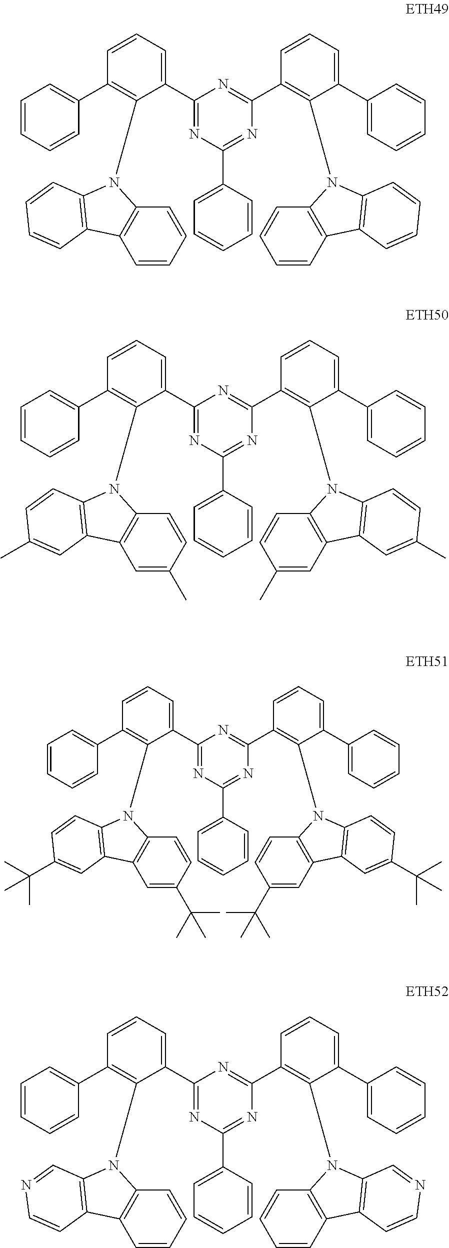

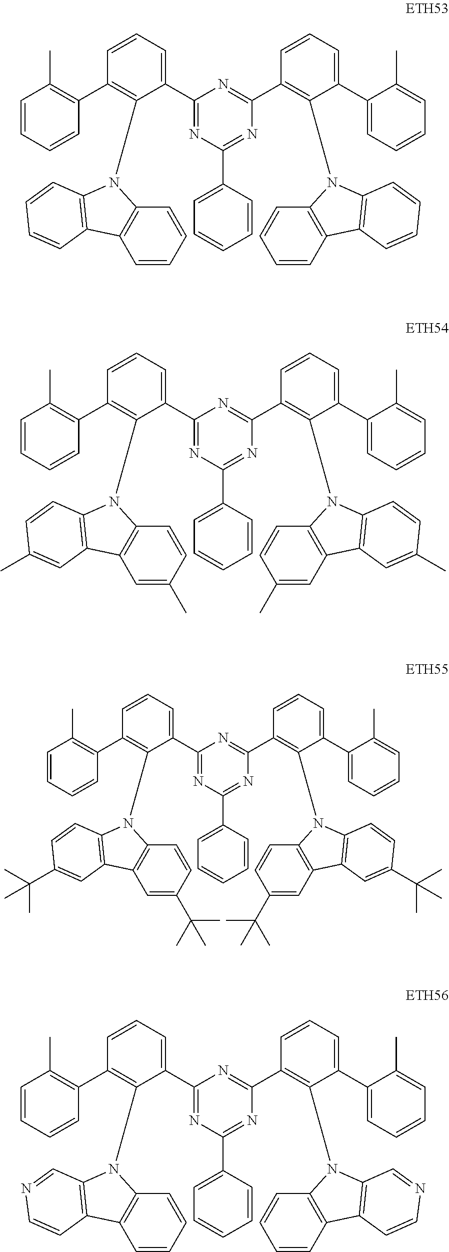

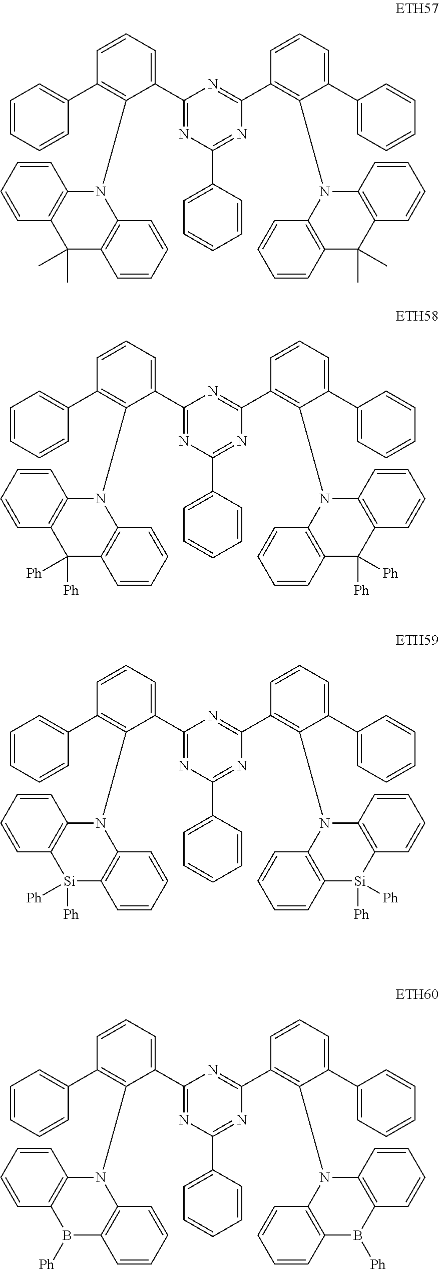

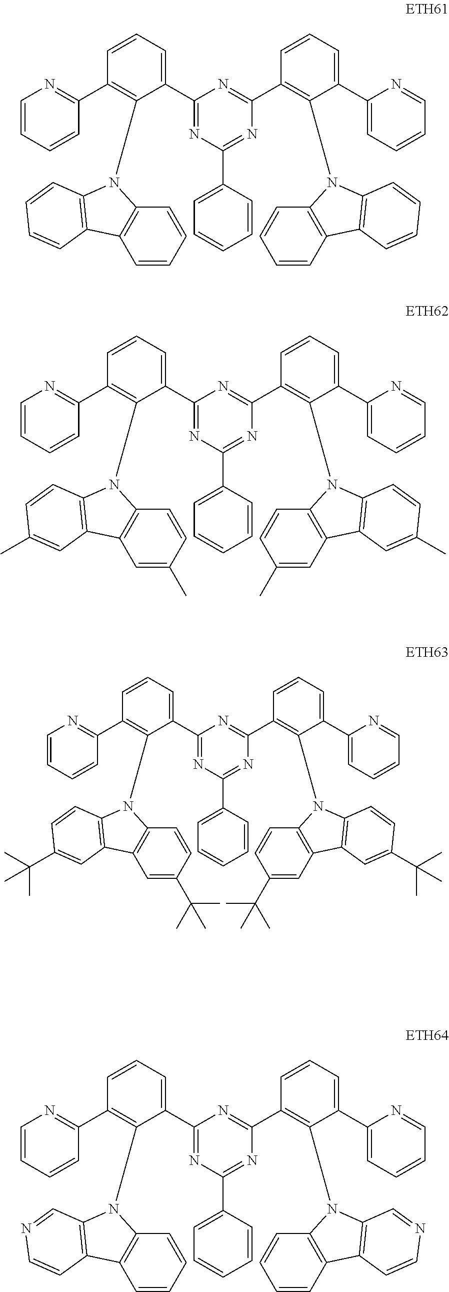

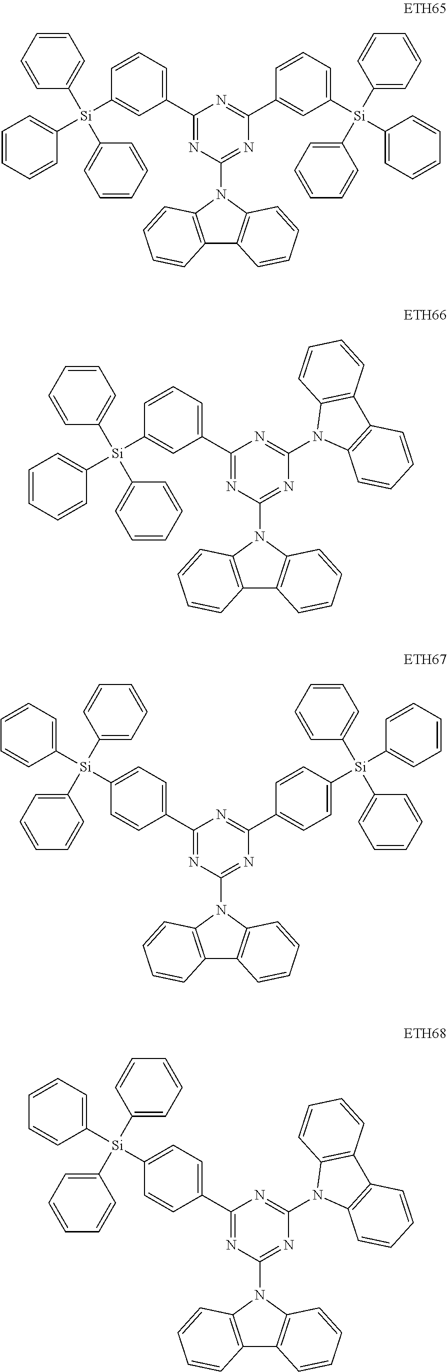 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

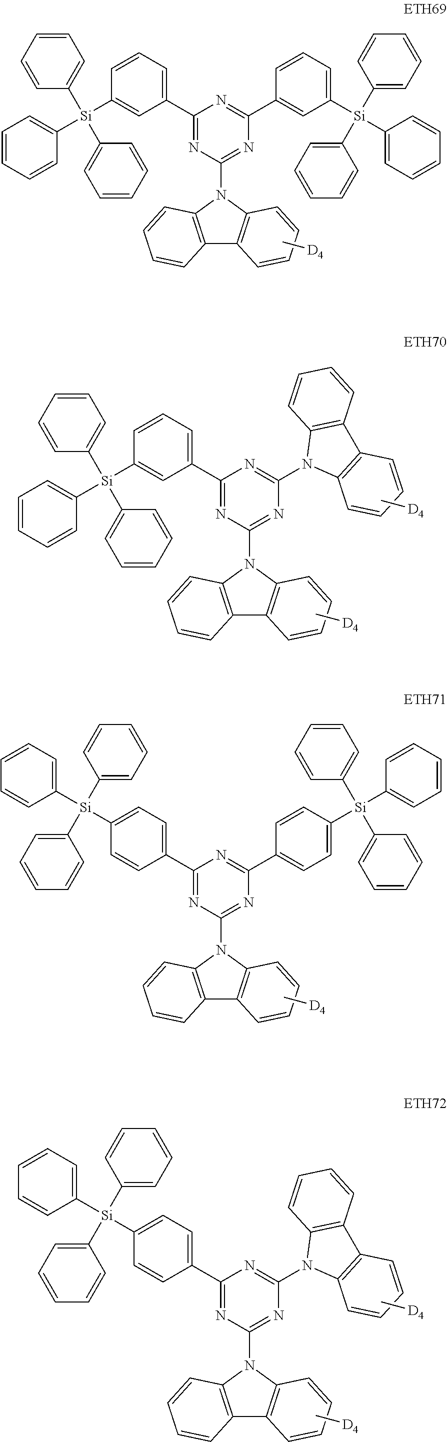

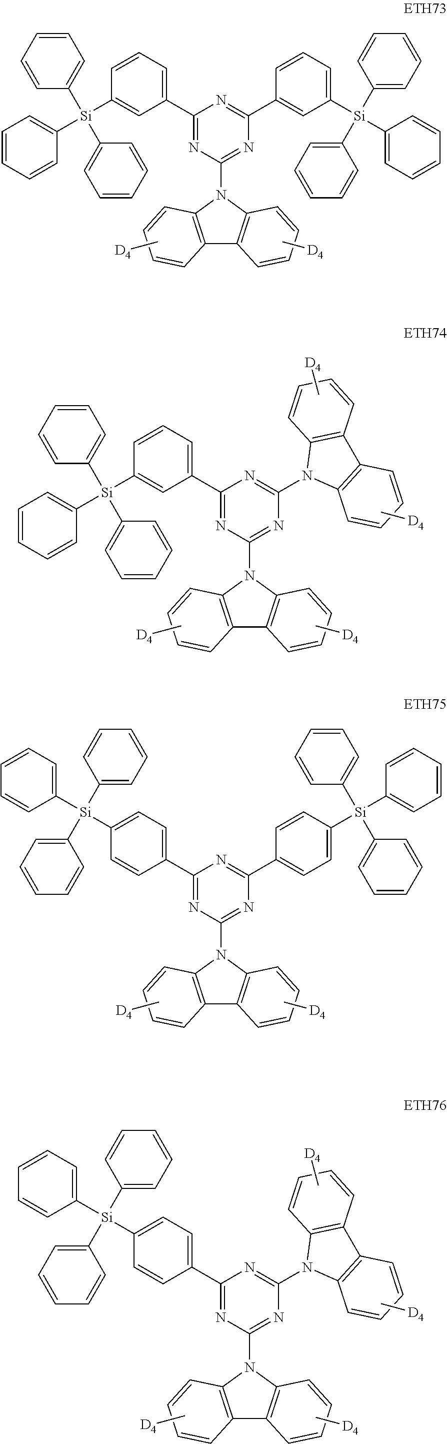

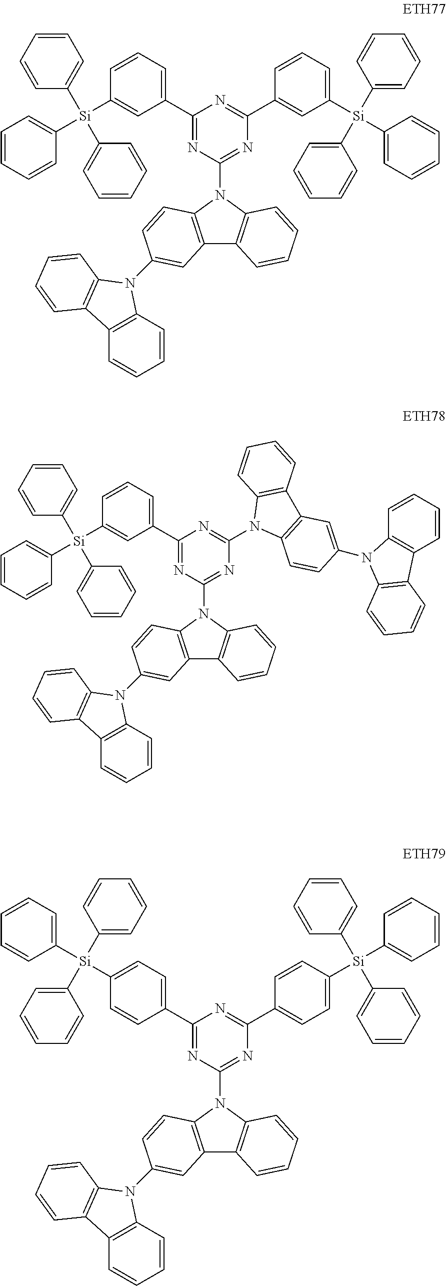 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

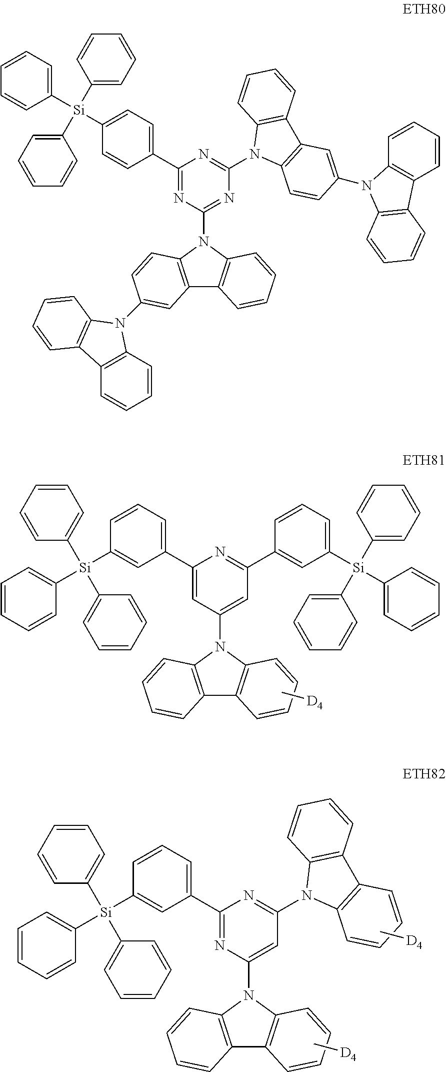

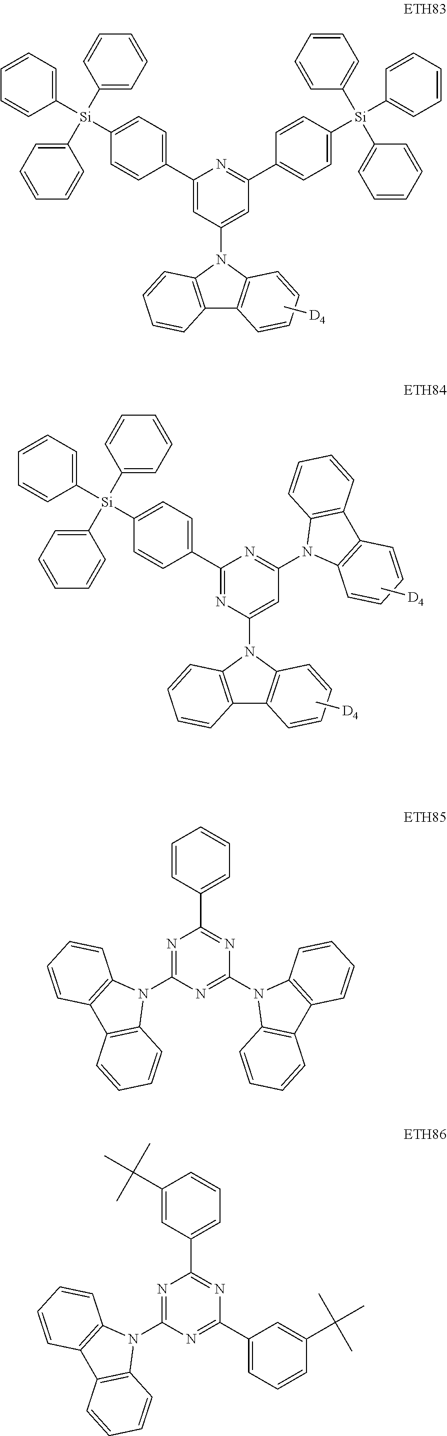

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transport host and an electron transport host may correspond to a difference between a lowest unoccupied molecular orbital (LUMO) energy level of the electron transport host and a highest occupied molecular orbital (HOMO) energy level of the hole transport host.

For example, an absolute value of a triplet energy level (T1) of the exciplex formed by a hole transport host and an electron transport host may be in a range of about 2.4 eV to about 3.0 eV. A triplet energy of the exciplex may be a value that is smaller than an energy gap of each host material. The exciplex may have a triplet energy equal to or less than about 3.0 eV, which is an energy gap between the hole transport host and the electron transport host.

In an embodiment, the emission layer EML may include a fourth compound represented by Formula PS. In an embodiment, the fourth compound represented by Formula PS may be used as a phosphorescence sensitizer of an emission layer EML. Since the emission layer EML includes the fourth compound together with the first compound, energy may transfer from the fourth compound to the first compound to emit light.

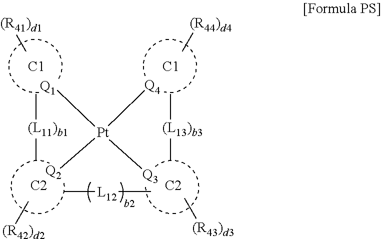

In Formula PS, Q₁ to Q₄ may each independently be C or N.

In Formula PS, L₁₁ to L₁₃ may each independently be a direct linkage,

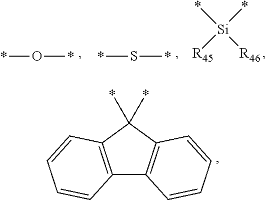

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, -* represents a bonding site to one of C1 to C4.

In Formula PS, b1 to b3 may each independently be 0 or 1. If b1 is 0, C1 and C2 may not be directly connected to each other. If b2 is 0, C2 and C3 may not be directly connected to each other. If b3 is 0, C3 and C4 may not be directly connected to each other.

In Formula PS, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or may be combined with an adjacent group to form a ring. For example, R₄₁ to R₄₆ may each independently be a substituted or unsubstituted methyl group or a substituted or unsubstituted t-butyl group.

In Formula PS, d1 to d4 may each independently be an integer from 0 to 4. If d1 is 2 or more, multiple R₄₁ groups may be the same, or at least one thereof may be different from the remainder. If d2 is 2 or more, multiple R₄₂ groups may be the same, or at least one thereof may be different from the remainder. If d3 is 2 or more, multiple R₄₃ groups may be the same, or at least one thereof may be different from the remainder. If d4 is 2 or more, multiple R₄₄ groups may be the same, or at least one thereof may be different from the remainder. For example, if d1 to d4 are each 0, the fourth compound may not be substituted with R₄₁ to R₄₄. A case where d1 to d4 are each 4 and R₄₁ to R₄₄ are all hydrogen atoms may be the same as a case where d1 to d4 are each 0.

In Formula PS, C1 to C4 may each independently be a substituted or unsubstituted hydrocarbon ring of 5 to 30 ring-forming carbon atoms or a substituted or unsubstituted heterocycle of 2 to 30 ring-forming carbon atoms.

In an embodiment, C1 to C4 may each independently be a substituted or unsubstituted hydrocarbon ring or a substituted or unsubstituted heterocycle represented by any one of Formula C-1 to Formula C-4:

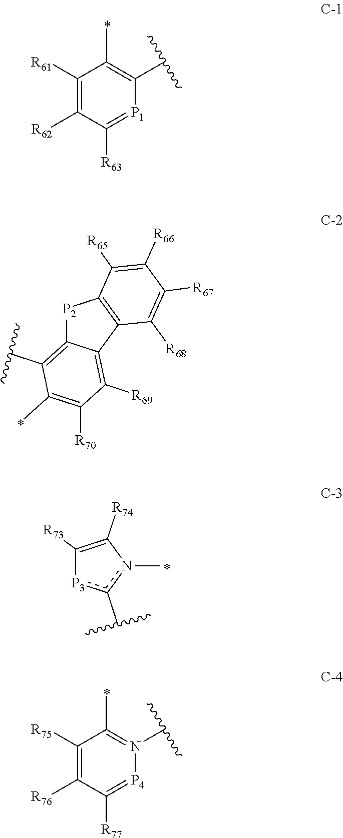

In Formula C-1 to Formula C-4, P₁ may be C—* or C(R₆₄), P₂ may be N—* or N(R₇₁), P₃ may be N—* or N(R₇₂), and P₄ may be C—* or C(R₇₈). In Formula C-1 to Formula C-4, R₆₁ to R₇₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula C-1 to Formula C-4,

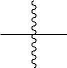

represents a bonding site to a central metal atom of Pt, and -* represents a bonding site to an adjacent ring group (C1 to C4) or to a linker (L₁₁ to L₁₃).

In an embodiment, the fourth compound may be selected from Compound Group 4. In an embodiment, in the light emitting element ED, the fourth compound may include at least one compound selected from Compound Group 4:

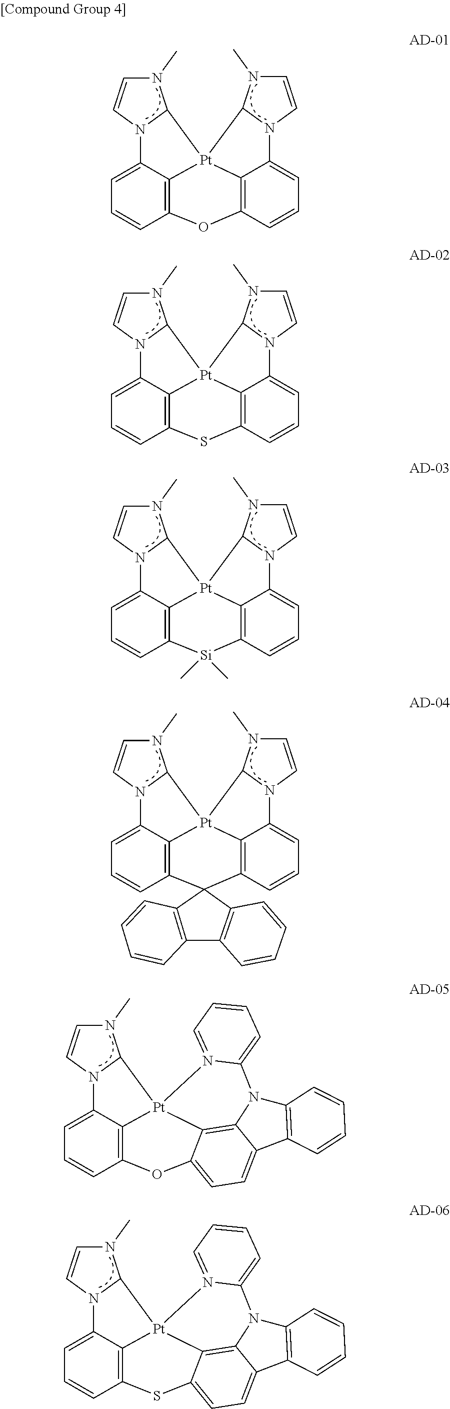

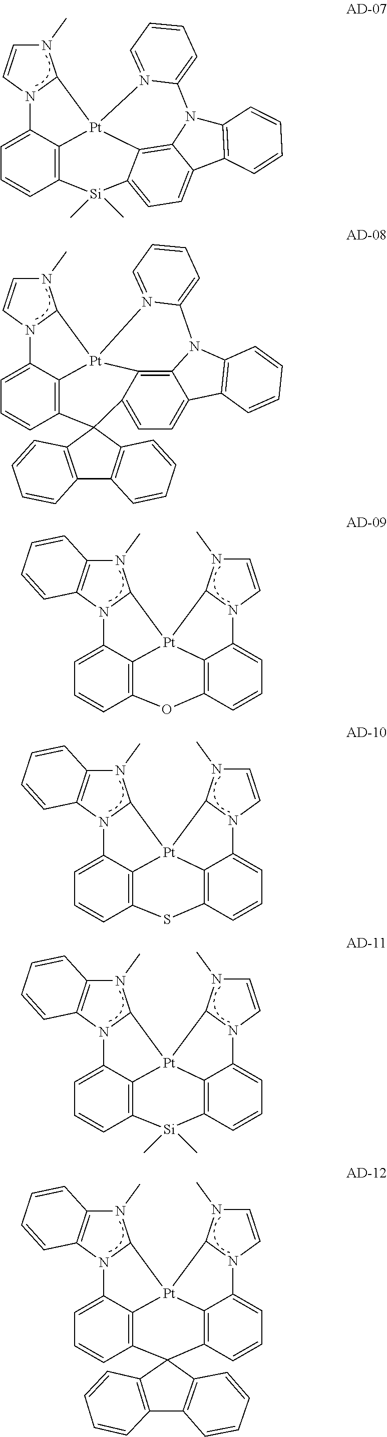

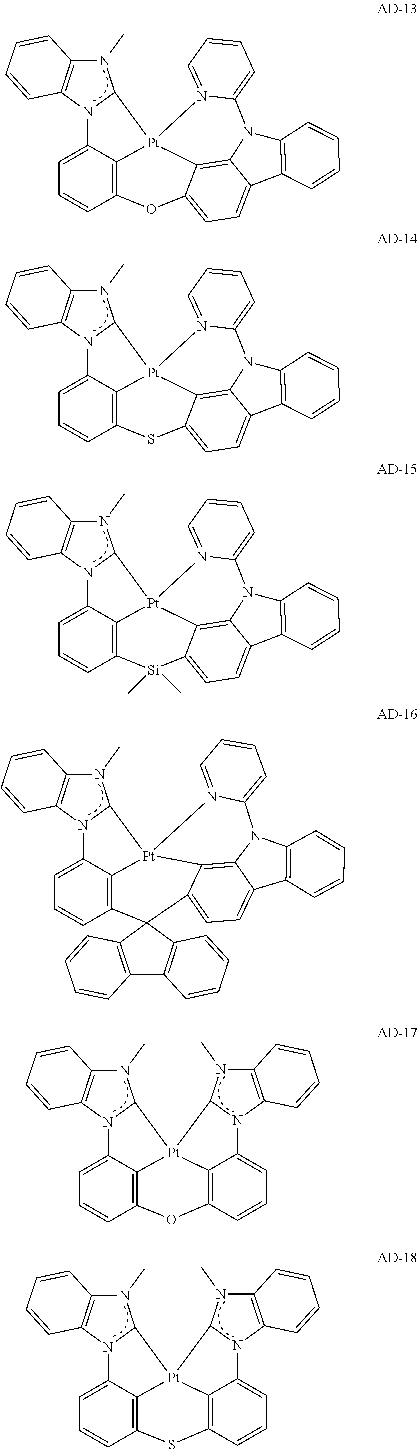

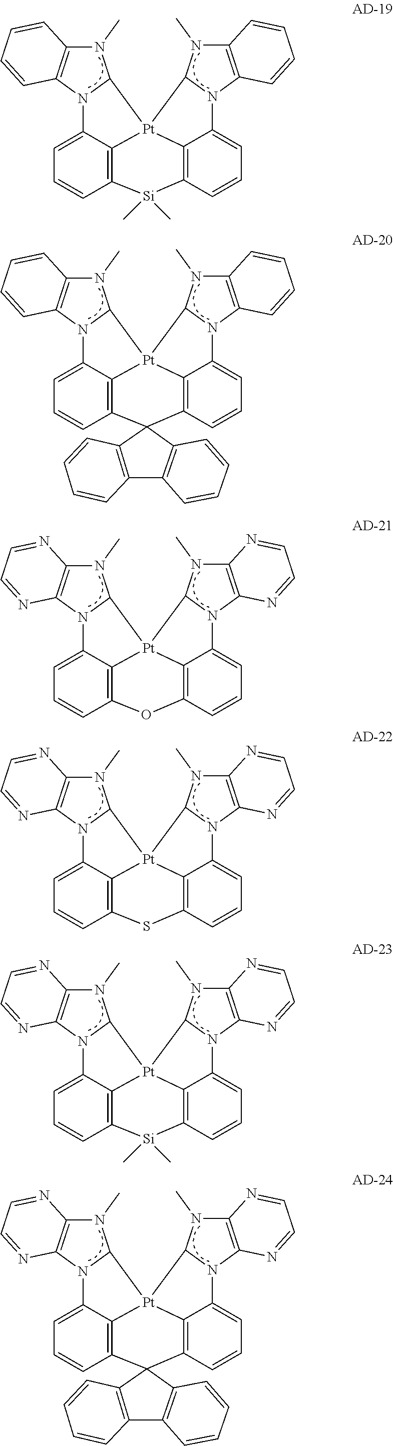

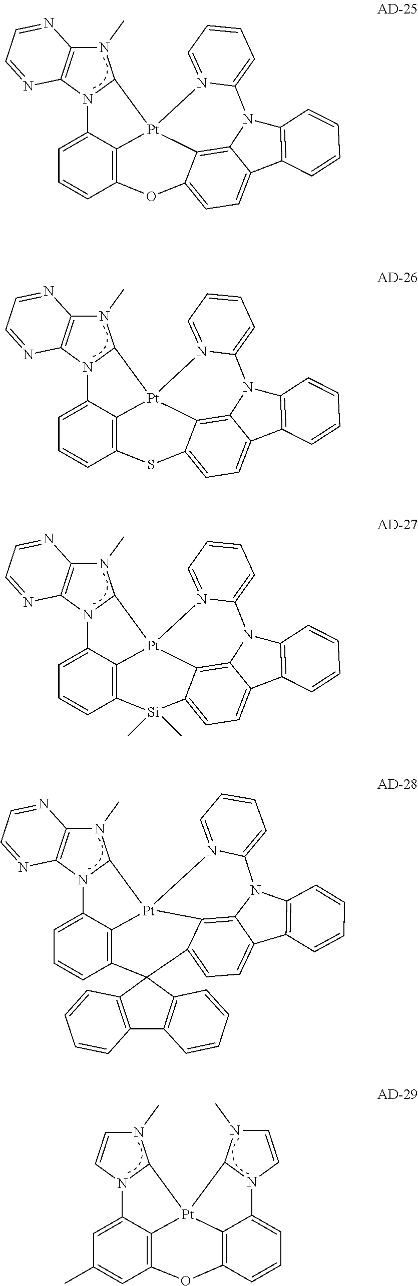

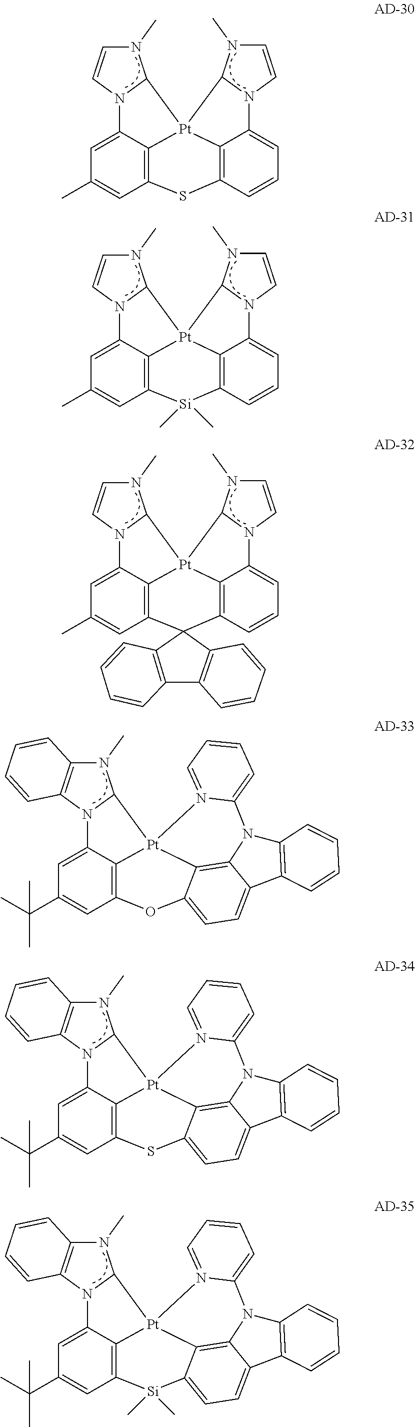

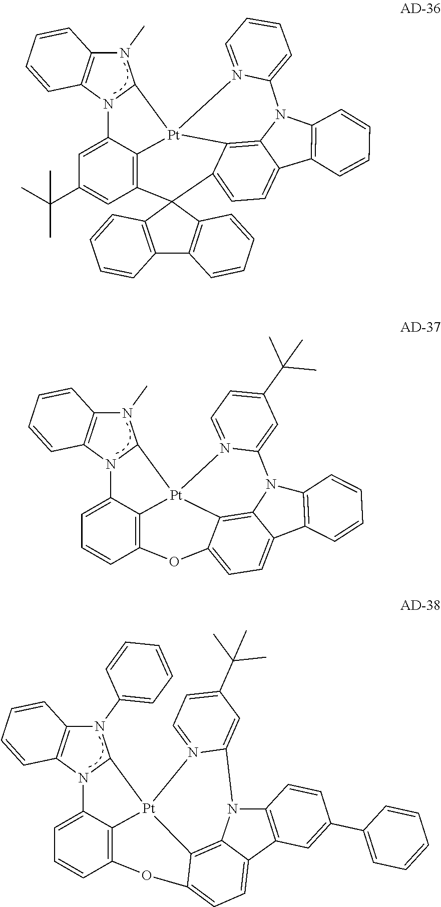

In an embodiment, the emission layer EML may include the first compound, which is a polycyclic compound according to an embodiment, and at least one of the second compound and the third compound. For example, the emission layer EML may include the first compound, the second compound, and the third compound. In the emission layer EML, the second compound and the third compound may form an exciplex, and energy transfer from the exciplex to the first compound may occur to emit light.

In another embodiment, the emission layer EML may include the first compound and at least one of the second compound, the third compound, and the fourth compound. For example, the emission layer EML may include the first compound, the second compound, the third compound, and the fourth compound. In the emission layer EML, the second compound and the third compound may form an exciplex, and energy transfer from the exciplex to the fourth compound and the first compound may occur to emit light. The fourth compound may be referred to as a sensitizer. The fourth compound may emit phosphorescence, or may transfer energy to the first compound as an auxiliary dopant. However, the suggested functions of the compounds are only examples, and embodiments are not limited thereto.

The light emitting element ED according to an embodiment may include all of the first compound, the second compound, the third compound, and the fourth compound, and the emission layer EML may include the combination of two host materials and two dopant materials. In the light emitting element ED, the emission layer EML may include the second compound and the third compound, which are two different hosts, the first compound may emit delayed fluorescence, and the fourth compound may include an organometallic complex, and the light emitting element ED may thus show excellent emission efficiency properties.

In an embodiment, the light emitting element ED may include multiple emission layers. The emission layers may be provided as a stack of emission layers to emit white light. The light emitting element including multiple emission layers may be a light emitting element having a tandem structure. If the light emitting element ED includes multiple emission layers, at least one emission layer EML may include the first compound represented by Formula 1. If the light emitting element ED includes multiple emission layers, at least one emission layer EML may include all of the first compound, the second compound, the third compound, and the fourth compound as described above.

In an embodiment, the emission layer EML may further include emission layer materials of the related art, in addition to the first to fourth compounds. In the light emitting element ED, the emission layer EML may include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting element ED according to embodiments as shown in each of FIG. 3 to FIG. 6, the emission layer EML may include a compound represented by Formula E-1. The compound represented by Formula E-1 may be used as a fluorescence host material.

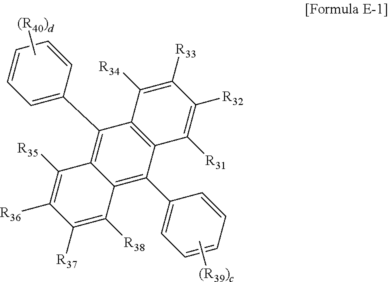

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, in Formula E-1, R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any compound selected from Compound E1 to Compound E19:

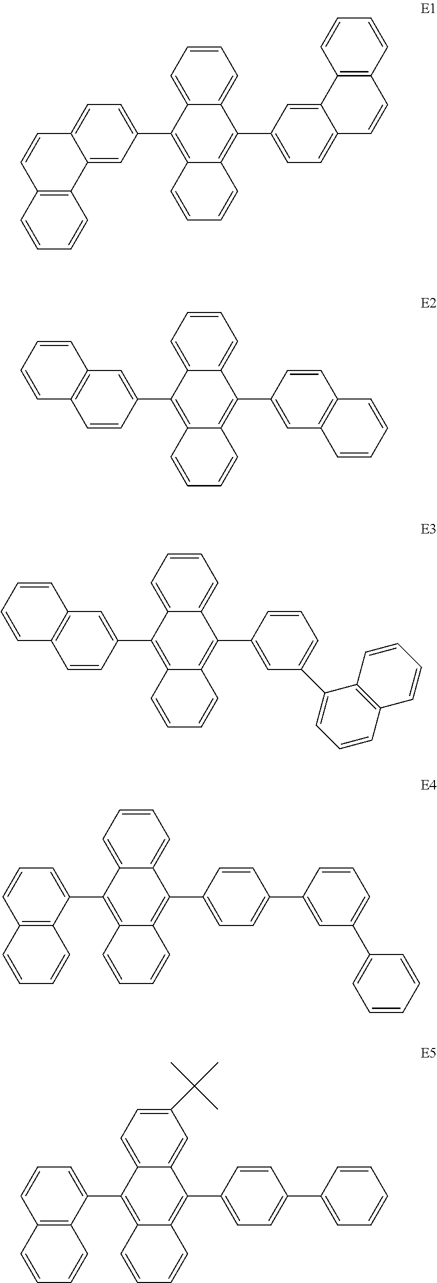

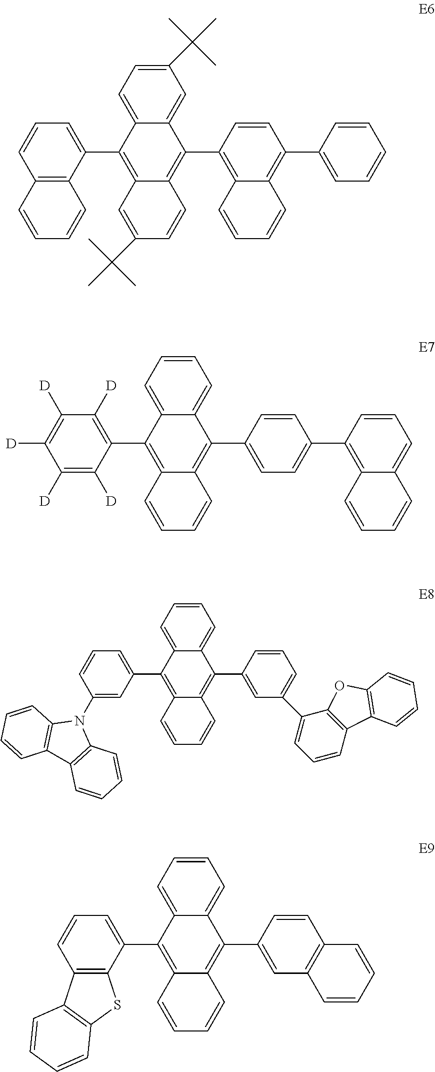

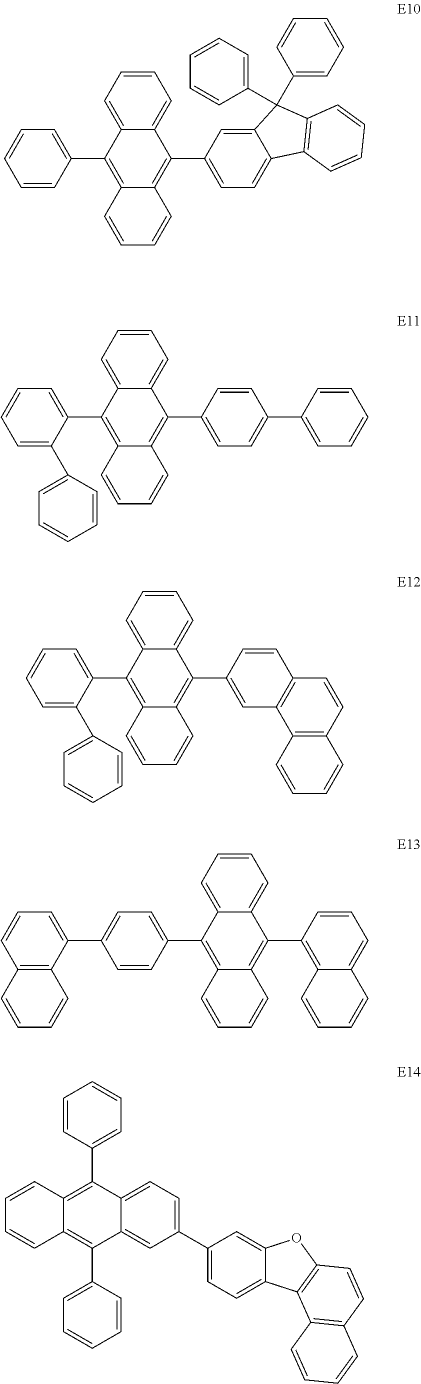

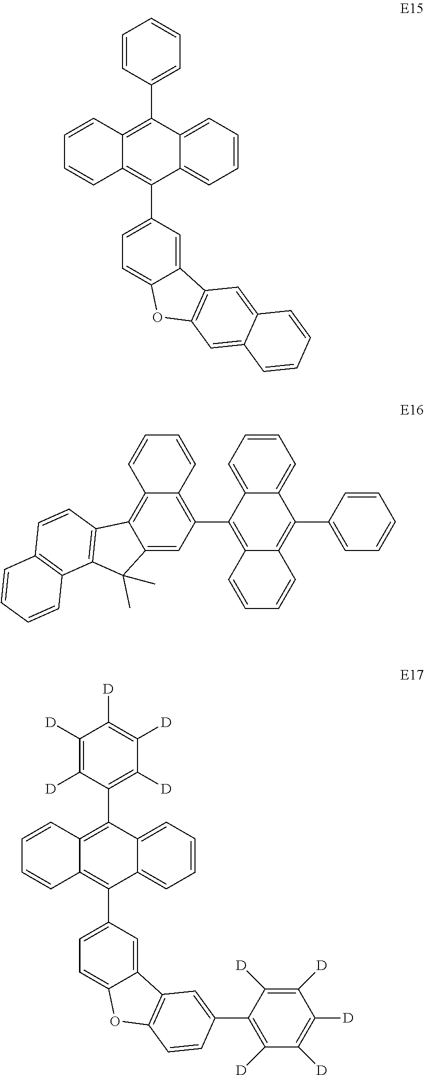

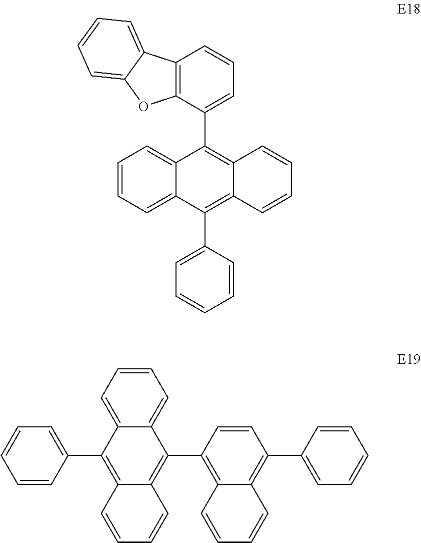

In an embodiment, the emission layer EML may include a compound represented by Formula E-2a or Formula E-2b. The compound represented by Formula E-2a or Formula E-2b may be used as a phosphorescence host material.

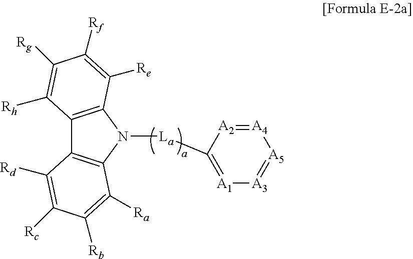

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ groups may each independently be a substituted or unsubstituted arylene group of 6 to 30 ring-forming carbon atoms or a substituted or unsubstituted heteroarylene group of 2 to 30 ring-forming carbon atoms.

In Formula E-2a, A₁ to A₅ may each independently be N or C(Rᵢ). In Formula E-2a, Rₐ to R₁ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. For example, Rₐ to R₁ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

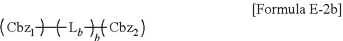

In Formula E-2b, Cbz1 and Cbz2 may each independently be an unsubstituted carbazole group, or a carbazole group substituted with an aryl group of 6 to 30 ring-forming carbon atoms. In Formula E-2b, Le may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple Le groups may each independently be a substituted or unsubstituted arylene group of 6 to 30 ring-forming carbon atoms or a substituted or unsubstituted heteroarylene group of 2 to 30 ring-forming carbon atoms.

The compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

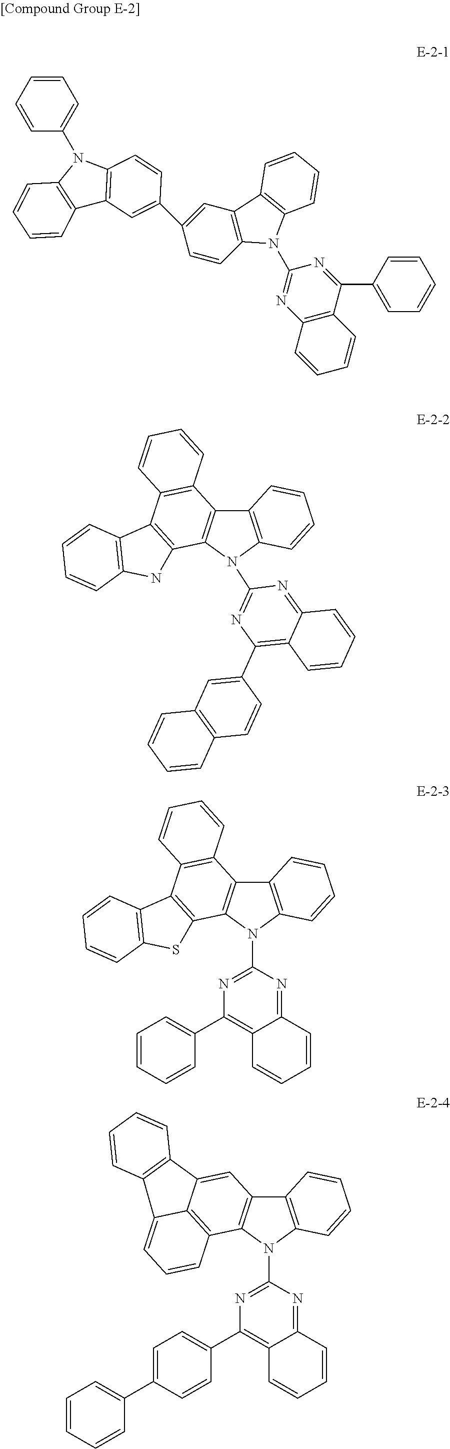

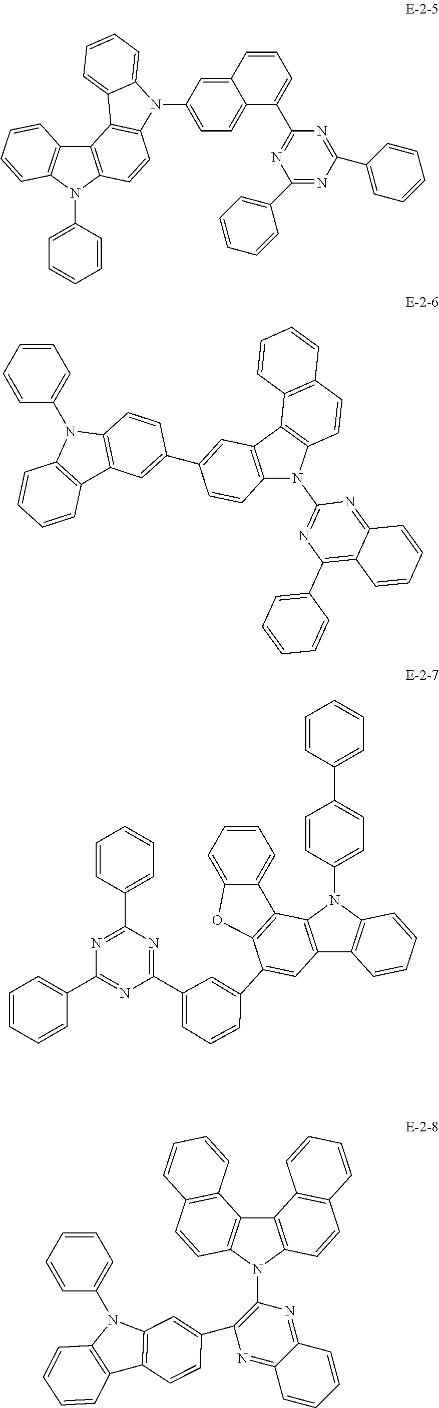 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

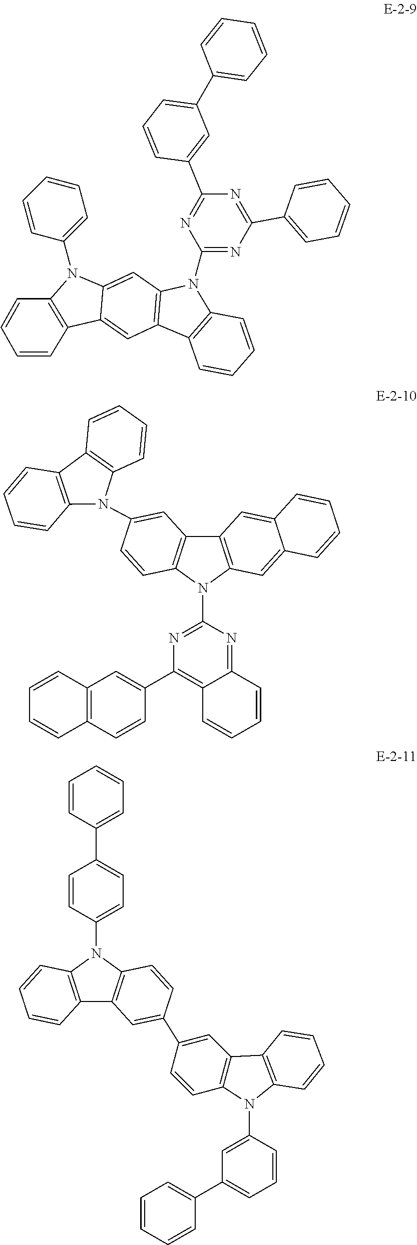

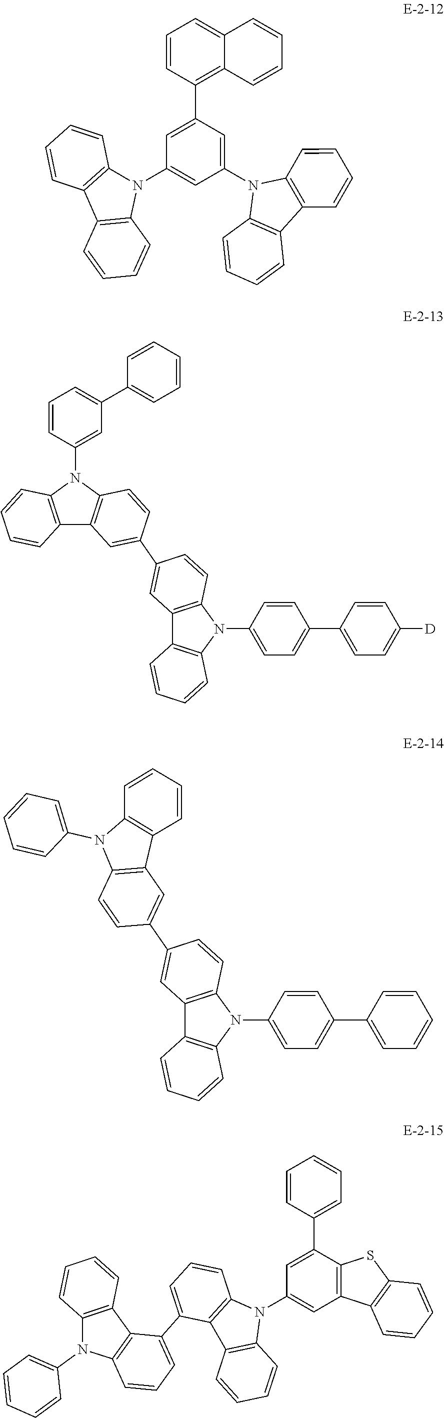 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

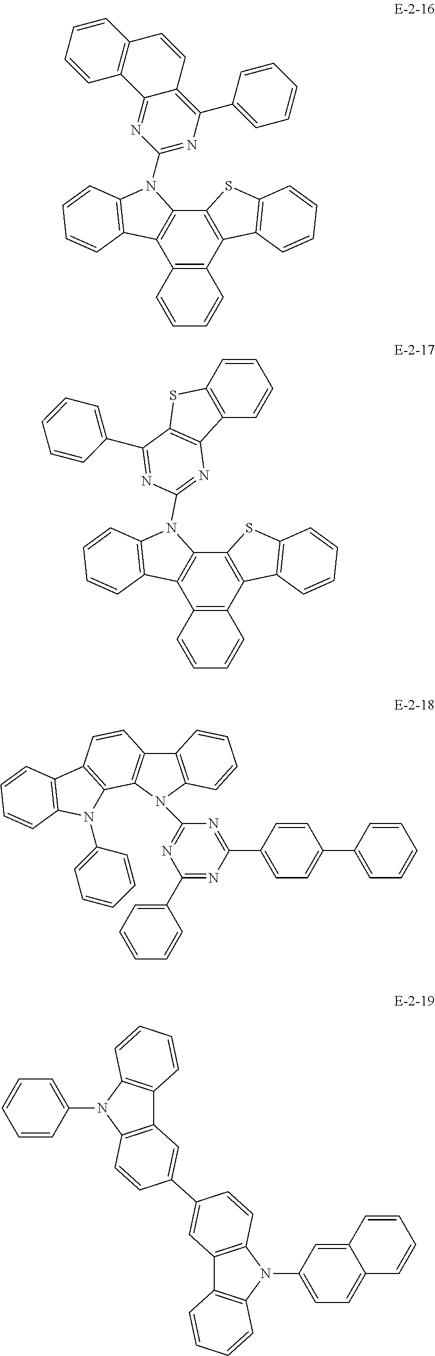

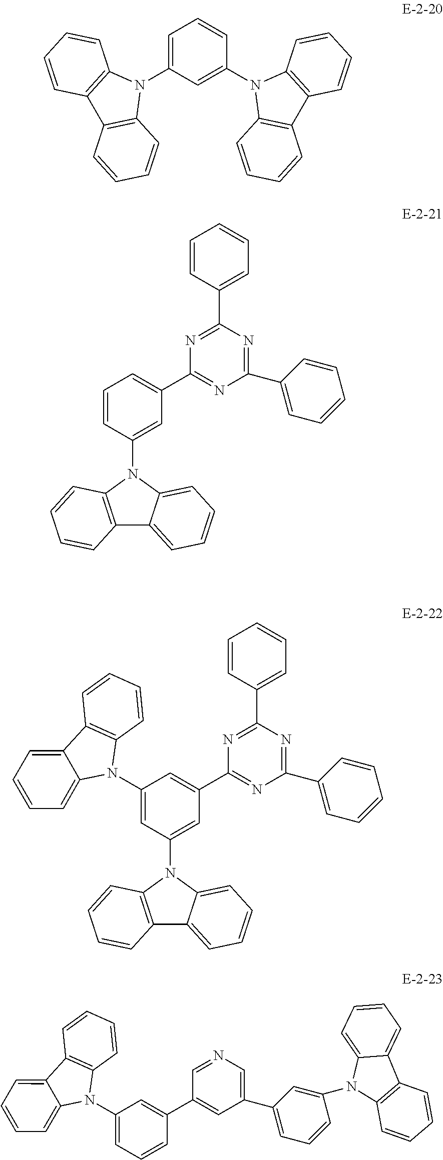 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

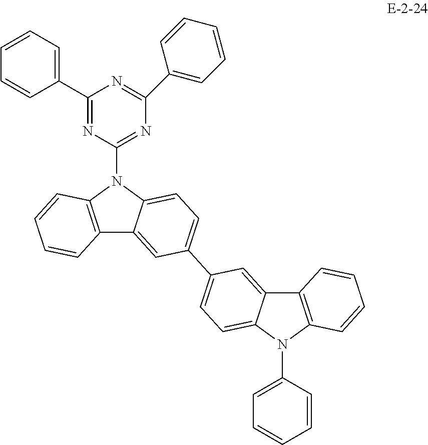 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The emission layer EML may include a compound represented by Formula M-a. The compound represented by Formula M-a may be used as a phosphorescence dopant material. In an embodiment, the compound represented by Formula M-a may be used as an auxiliary dopant material.

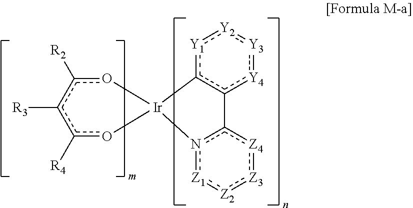

In Formula M-a, Yi to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, m may be 0 or 1, and n may be 2 or 3. In Formula M-a, if m is 0, n may be 3, and if m is 1, nmaybe 2.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25.

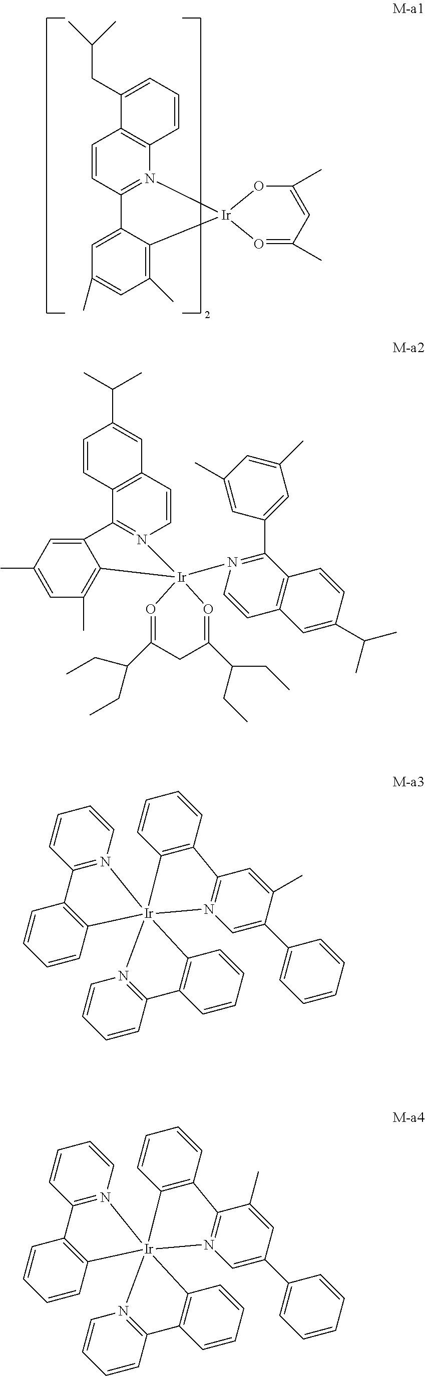

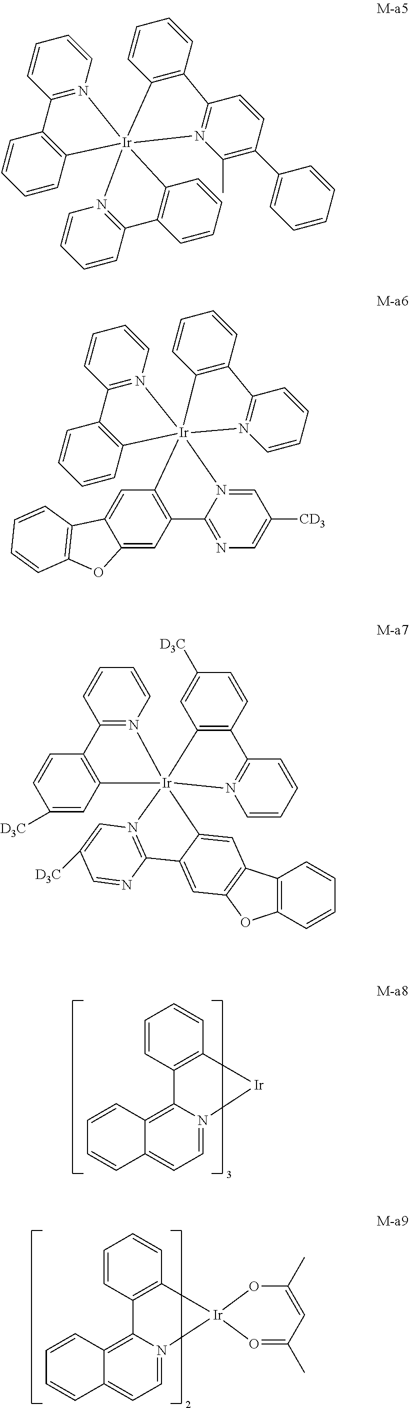

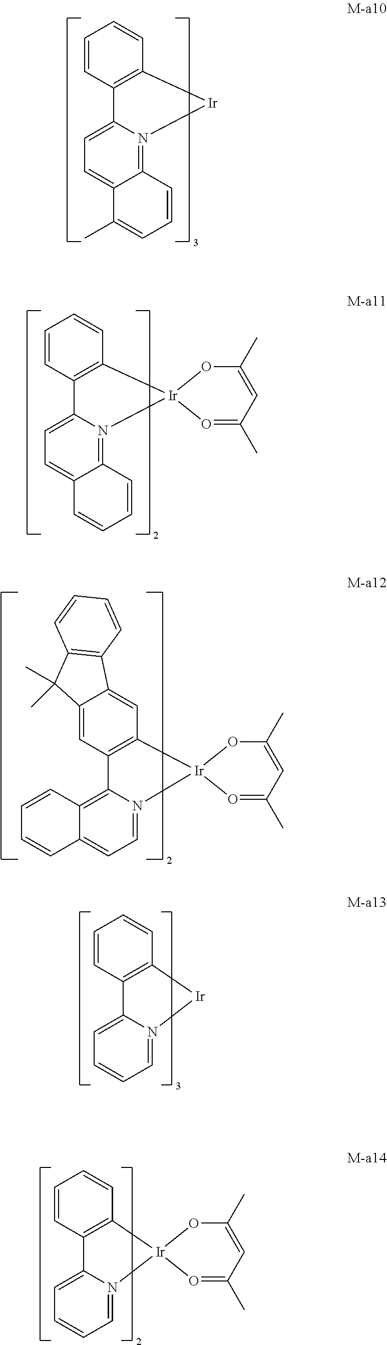

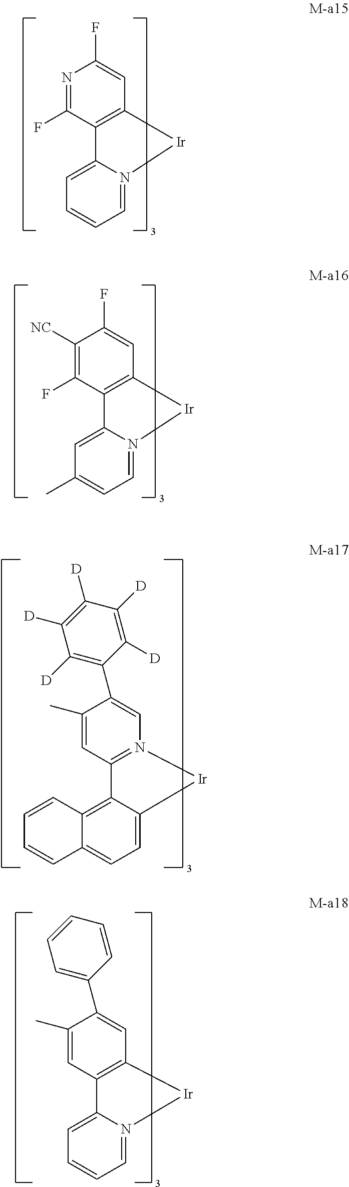

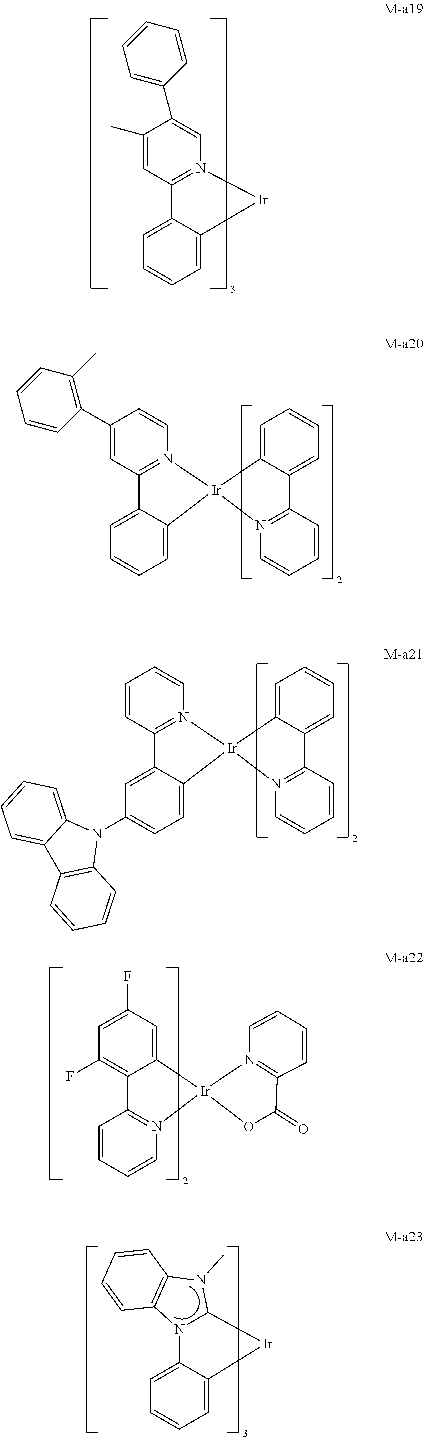

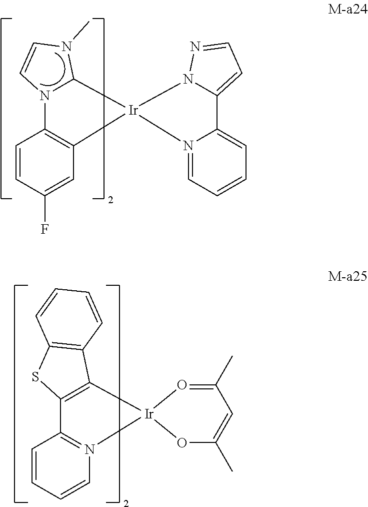

Compound M-a1 and Compound M-a2 may be used as red dopant materials, and Compound M-a3 to Compound M-a7 may be used as green dopant materials.

The emission layer EML may include a compound represented by any one of Formula F-a to Formula F-c. The compound represented by one of Formula F-a to Formula F-c may be used as a fluorescence dopant material.

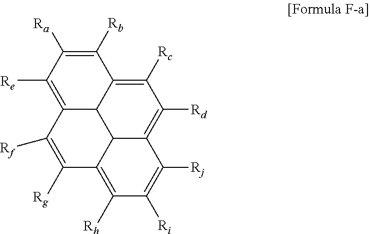

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by *—NAr₁Ar₂, Ar₁ and Ar₂ may each independently be a substituted or unsubstituted aryl group of 6 to 30 ring-forming carbon atoms or a substituted or unsubstituted heteroaryl group of 2 to 30 ring-forming carbon atoms. For example, at least one of Ar₁ and Ar₂ may be a heteroaryl group including O or S as a ring-forming atom.

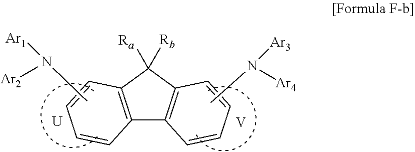

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula F-b, Ar₁ to Ar₄ may each independently be a substituted or unsubstituted aryl group of 6 to 30 ring-forming carbon atoms or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms or a substituted or unsubstituted heterocycle of 2 to 30 ring-forming carbon atoms.

In Formula F-b, the number of rings represented by U and V may each independently be 0 or 1. For example, in Formula F-b, if the number of U or V is 1, a fused ring may be present at the part designated by U or V, and if the number of U or V is 0, a fused ring may not be present at the part designated by U or V. If the number of U is 0 and the number of V is 1, or if the number of U is 1 and the number of V is 0, a fused ring having a fluorene core of Formula F-b may be a cyclic compound having four rings. If the number of U and V are each 0, a fused ring having a fluorene core of Formula F-b may be a cyclic compound having three rings. If the number of U and V are each 1, a fused ring having a fluorene core of Formula F-b may be a cyclic compound having five rings.

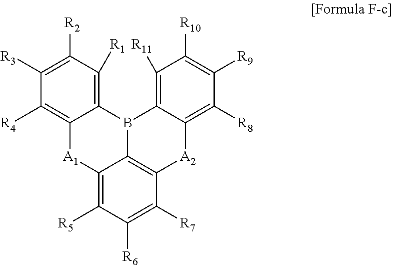

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-c, A₁ and A₂ may each independently be combined with the substituents of an adjacent ring to form a fused ring. For example, if A₁ and A₂ are each independently N(Rₘ), A₁ may be combined with R₄ or R₅ to form a ring. For example, A₂ may be combined with R₇ or R₈ to form a ring.

In an embodiment, the emission layer EML may include, as a dopant material of the related art, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino)pyrene), etc.

The emission layer EML may further include a phosphorescence dopant material of the related art. For example, the phosphorescence dopant may be a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, embodiments are not limited thereto.

In an embodiment, the emission layer EML may include a quantum dot. The quantum dot may be a Group II-VI compound, a Group III-VI compound, a Group I-III-VI compound, a Group III-V compound, a Group III-II-V compound, a Group IV-VI compound, a Group IV element, a Group IV compound, or any combination thereof.

The Group II-VI compound may include: a binary compound selected from the group consisting of CdSe, CdTe, CdS, ZnS, ZnSe, ZnTe, ZnO, HgS, HgSe, HgTe, MgSe, MgS, and any mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture thereof; a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and any mixture thereof; or any combination thereof.

The Group III-VI compound may include: a binary compound such as In₂S₃, and In₂Se₃; a ternary compound such as InGaS₃, and InGaSe₃; or any combination thereof.

The Group I-III-VI compound may include: a ternary compound selected from the group consisting of AgInS, AgInS₂, CuInS, CuInS₂, AgGaS₂, CuGaS₂, CuGaO₂, AgGaO₂, AgAlO₂ and any mixture thereof; a quaternary compound such as AgInGaS₂, and CuInGaS₂; or any combination thereof.

The Group III-V compound may be include: a binary compound selected from the group consisting of GaN, GaP, GaAs, GaSb, AlN, AlP, AlAs, AlSb, InN, InP, InAs, InSb, and any mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture thereof; or any combination thereof. In an embodiment, the Group III-V compound may further include a Group II metal. For example, InZnP, etc. may be selected as a Group III-II-V compound.

The Group IV-VI compound may include: a binary compound selected from the group consisting of SnS, SnSe, SnTe, PbS, PbSe, PbTe, and any mixture thereof; a ternary compound selected from the group consisting of SnSeS, SnSeTe, SnSTe, PbSeS, PbSeTe, PbSTe, SnPbS, SnPbSe, SnPbTe, and any mixture thereof; a quaternary compound selected from the group consisting of SnPbSSe, SnPbSeTe, SnPbSTe, and any mixture thereof; or any combination thereof. The Group IV element may be Si, Ge, or any mixture thereof. The Group IV compound may include a binary compound selected from the group consisting of SiC, SiGe, and any mixture thereof.

A binary compound, a ternary compound, or a quaternary compound may be present in a particle at uniform concentration or may be present in a particle at a partially different concentration distribution. In an embodiment, a quantum dot may have a core/shell structure in which a quantum dot surrounds another quantum dot. A quantum dot having a core/shell structure may have a concentration gradient at an interface between the core and the shell, in which the concentration of a material that is present in the shell decreases toward the core.

In embodiments, the quantum dot may have the above-described core/shell structure including a core including a nanocrystal and a shell surrounding the core. The shell of the quantum dot may serve as a protection layer for preventing the chemical deformation of the core to maintain semiconductor properties and/or may serve as a charging layer for imparting the quantum dot with electrophoretic properties. The shell may be a single layer or a multilayer. Examples of a shell of a quantum dot may include a metal oxide, a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, a ternary compound such as MgAl₂O₄, CoFe₂O₄, NiFe₂O₄ and CoMn₂O₄; or any combination thereof. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Within these ranges, color purity or color reproducibility may be improved. Light emitted through a quantum dot may be emitted in all directions, so that a wide viewing angle may be improved.

The shape of a quantum dot may be any form that is used in the related art. For example, a quantum dot may have a spherical shape, a pyramidal shape, a multi-arm shape, or a cubic shape, or the quantum dot may be in the form of a nanoparticle, a nanotube, a nanowire, a nanofiber, a nanoplate, etc.

A quantum dot may control the color of light emitted according to a particle size thereof, and accordingly, the quantum dot may have various emission colors, such as blue, red, or green.

In the light emitting element ED according to an embodiment as shown in each of FIG. 3 to FIG. 6, the electron transport region ETR is provided on the emission layer EML. The electron transport region ETR may include at least one of an electron blocking layer HBL, an electron transport layer ETL or an electron injection layer EIL. However, embodiments are not limited thereto.

The electron transport region ETR may be a layer consisting of a single material, a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In another embodiment, the electron transport region ETR may have a single layer structure including different materials, or may have a structure in which an electron transport layer ETL/electron injection layer EIL, a hole blocking layer HBL/electron transport layer ETL/electron injection layer EIL, or an electron transport layer ETL/buffer layer (not shown)/electron injection layer EIL are stacked in its respective stated order from an emission layer EML, but embodiments are not limited thereto. A thickness of the electron transport region ETR may be, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-1:

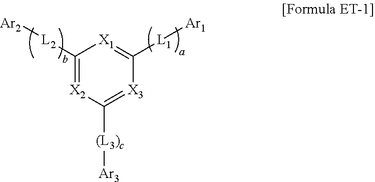

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-1, Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are each 2 or more, multiple groups of each of L₁ to L₃ may each independently be a substituted or unsubstituted arylene group of 6 to 30 ring-forming carbon atoms or a substituted or unsubstituted heteroarylene group of 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide (TSPO1), and mixtures thereof, without limitation.

In an embodiment, the electron transport region ETR may include at least one compound selected from Compounds ET1 to ET36:

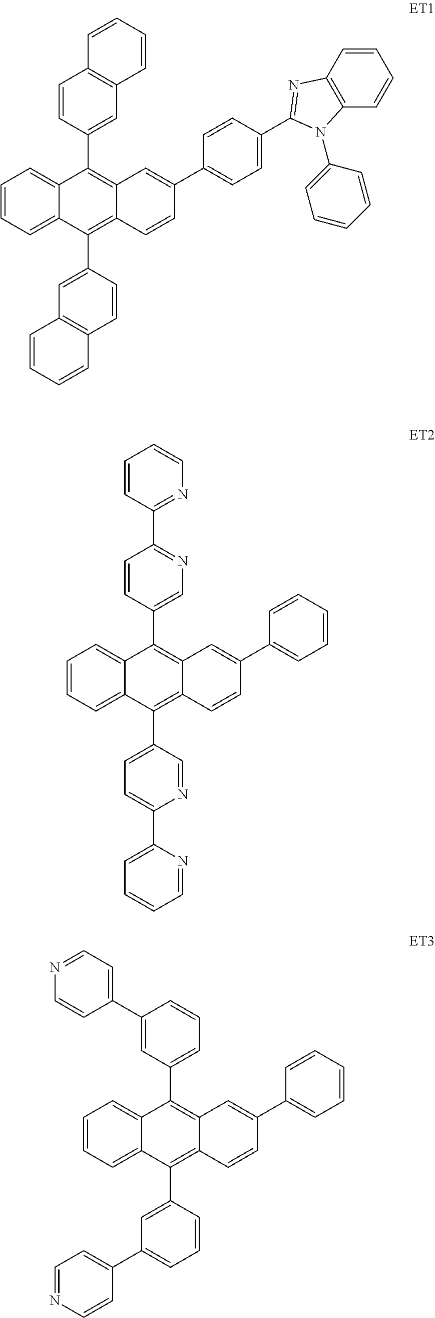 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

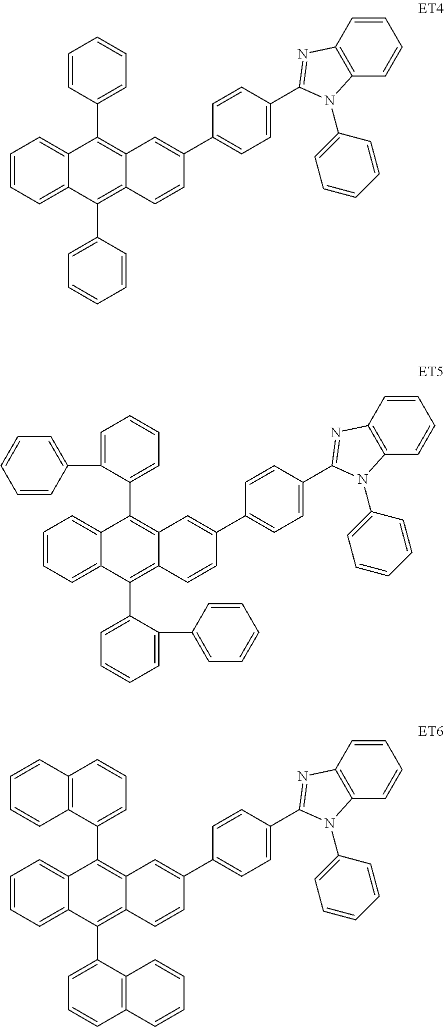 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

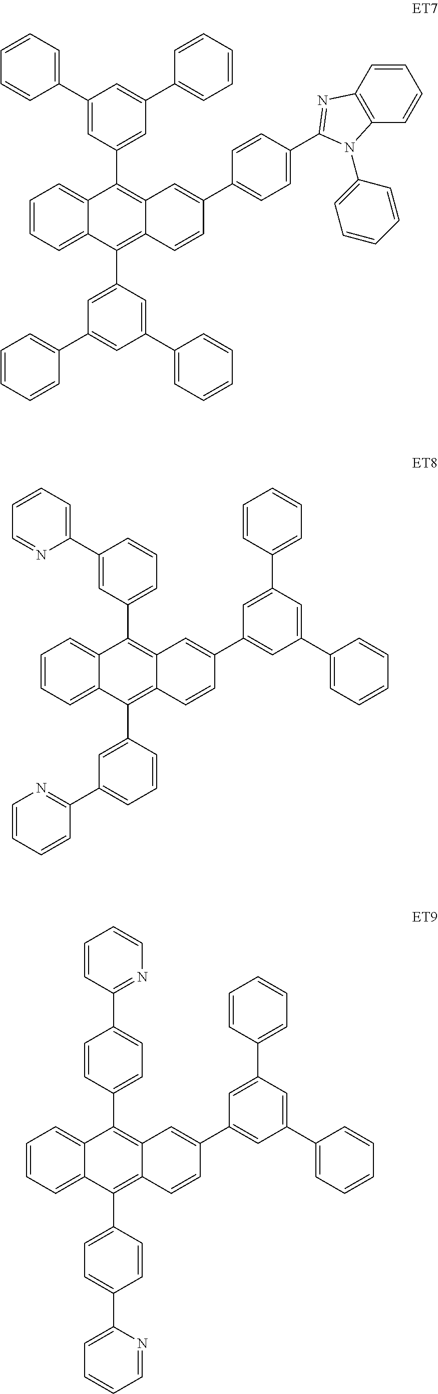 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

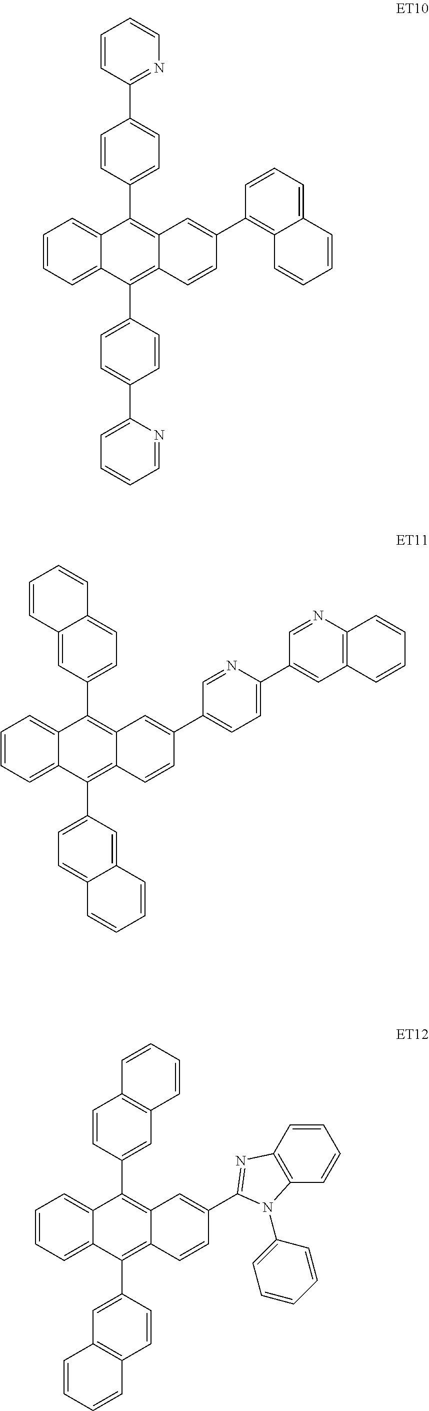 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

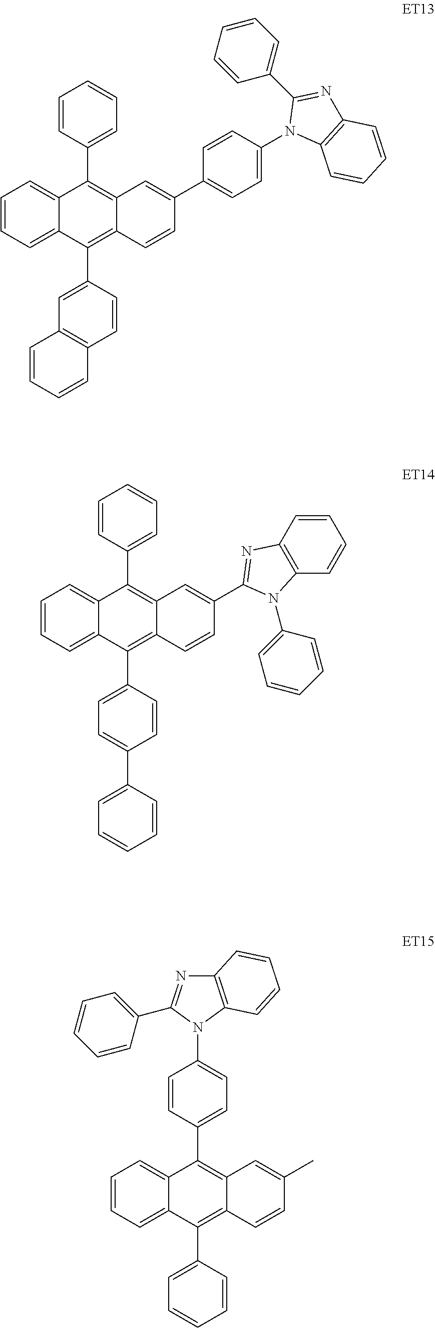 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

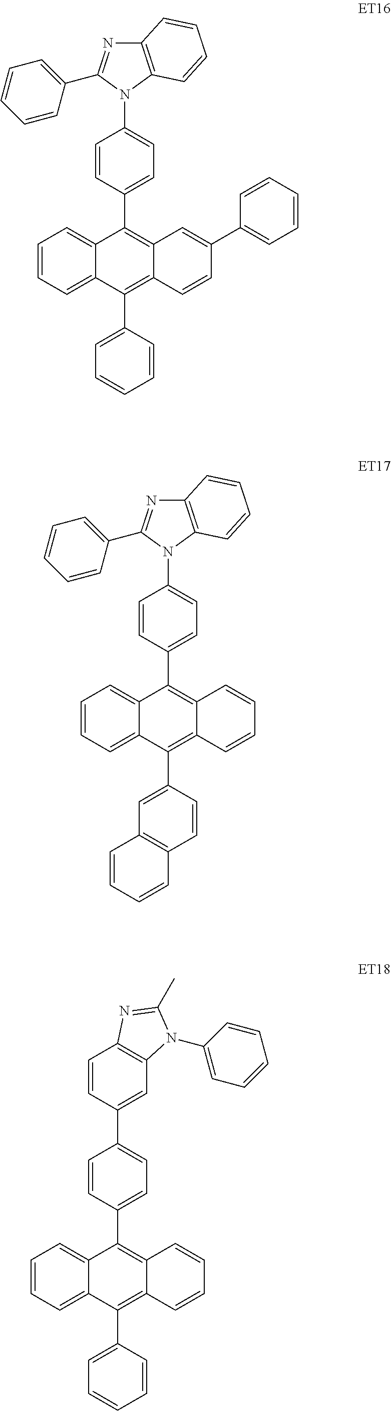 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

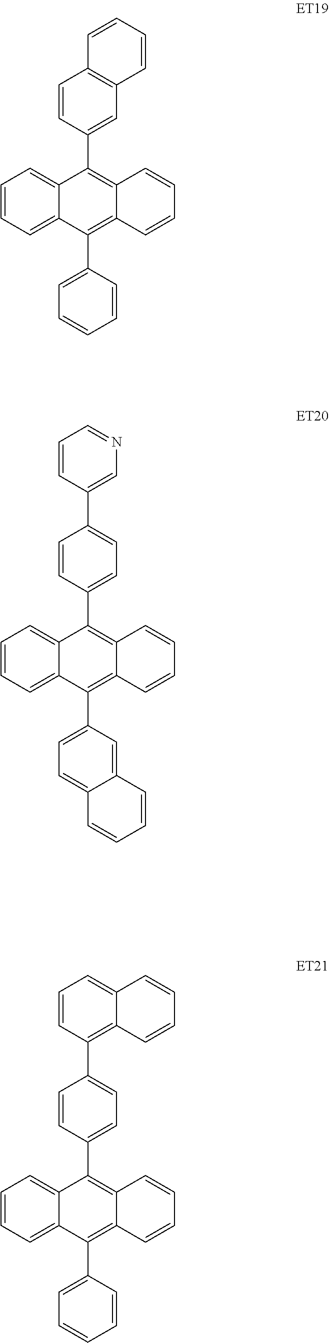

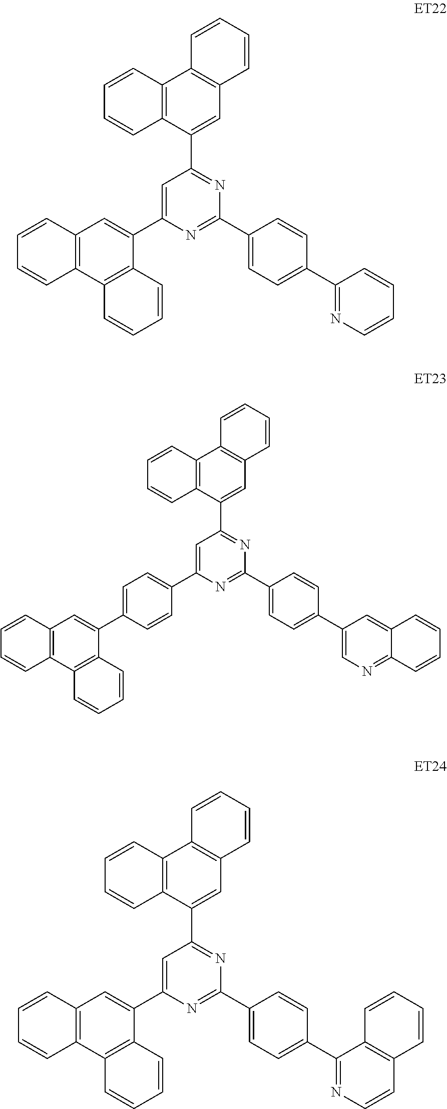 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

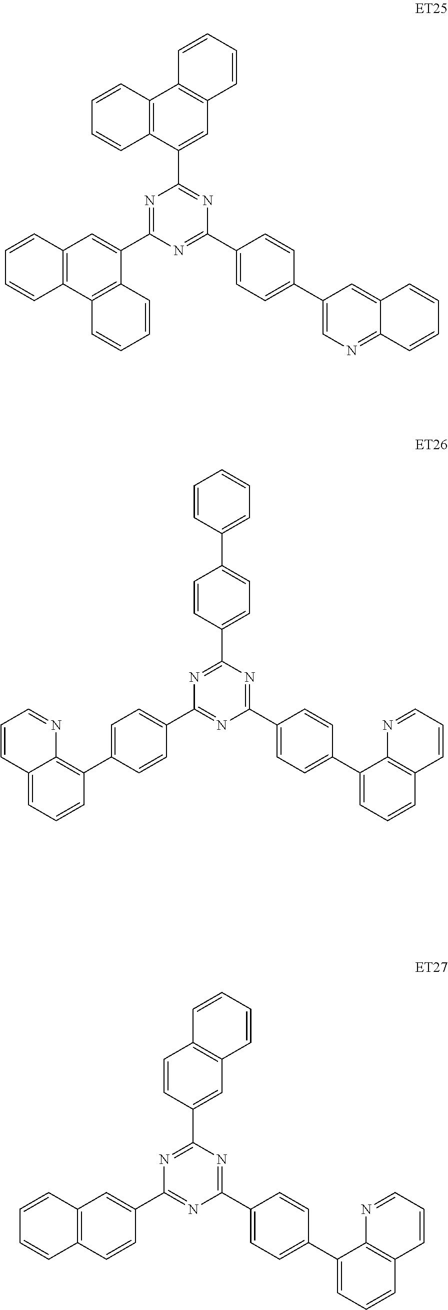 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

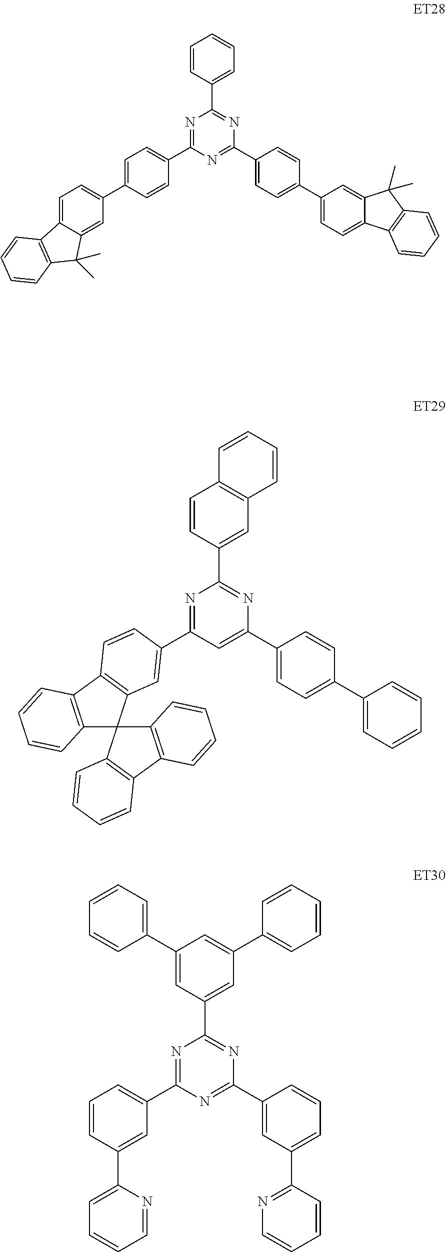 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

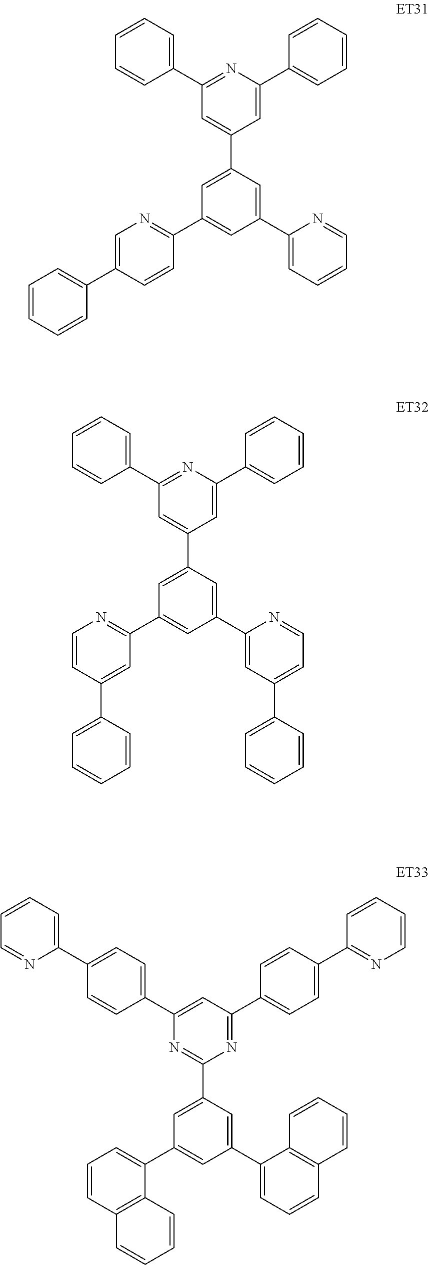 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

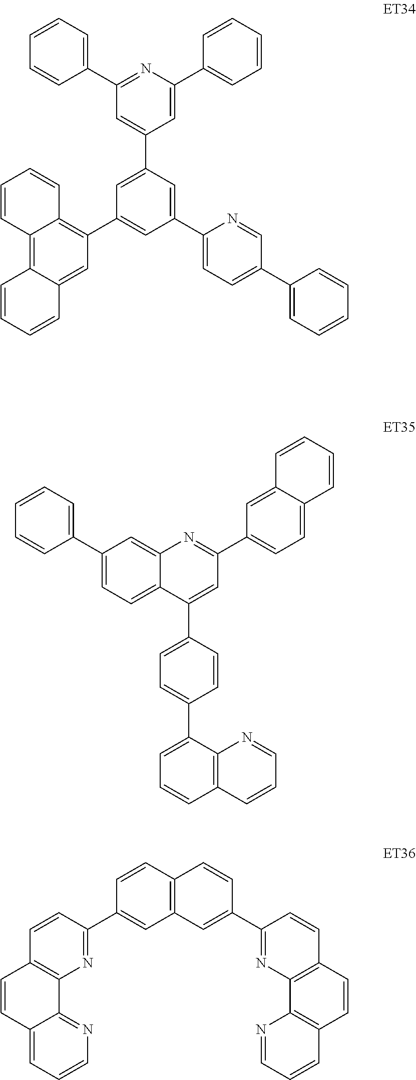 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI and KI; a lanthanide metal such as Yb; or a co-deposited material of a metal halide and a lanthanide metal. For example, the electron transport region ETR may include KI:Yb, RbI:Yb, LiF:Yb, etc., as a co-deposited material. The electron transport region ETR may include a metal oxide such as Li₂O and BaO, or 8-hydroxy-lithium quinolate (Liq). However, embodiments are not limited thereto. The electron transport region ETR also may be formed of a mixture material of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, embodiments are not limited thereto.

The electron transport region ETR may include the above-described compounds of the electron transport region in at least one of an electron injection layer EIL, an electron transport layer ETL, or a hole blocking layer HBL.

If the electron transport region ETR includes an electron transport layer ETL, a thickness of the electron transport layer ETL may be in a range of about 100 Å to about 1,000 Å. For example, the thickness of the electron transport layer ETL may be in a range of about 150 Å to about 500 Å. If the thickness of the electron transport layer ETL satisfies any of the above-described ranges, satisfactory electron transport properties may be obtained without a substantial increase of driving voltage. If the electron transport region ETR includes an electron injection layer EIL, a thickness of the electron injection layer EIL may be in a range of about 1 Å to about 100 Å. For example, the thickness of the electron injection layer EIL may be in a range of about 3 Å to about 90 Å. If the thickness of the electron injection layer EIL satisfies the any of above-described ranges, satisfactory electron injection properties may be obtained without a substantial increase of driving voltage.

The second electrode EL2 is provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL1 is a cathode, the second electrode EL2 may be an anode. The second electrode may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, Yb, W, a compound thereof, or a mixture thereof (for example, AgMg, AgYb, or MgYb). In another embodiment, the second electrode EL2 may have a multilayered structure including a reflective layer or a transflective layer formed of the above-described metal materials and a transparent conductive layer formed of ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected to an auxiliary electrode. If the second electrode EL2 is electrically connected to an auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNx, SiOy, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., or may include an epoxy resin, or an acrylate such as methacrylate. In an embodiment, a capping layer CPL may include at least one of Compounds P1 to P5, but embodiments are not limited thereto.

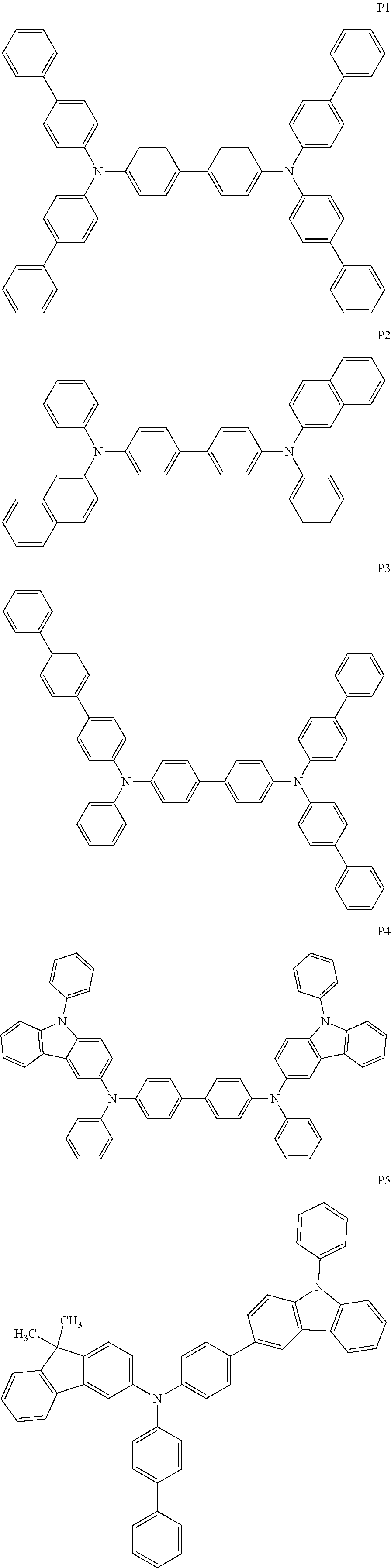 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, a refractive index of the capping layer CPL may be equal to or greater than about 1.6, with respect to light in a wavelength range of about 550 nm to about 660 nm.

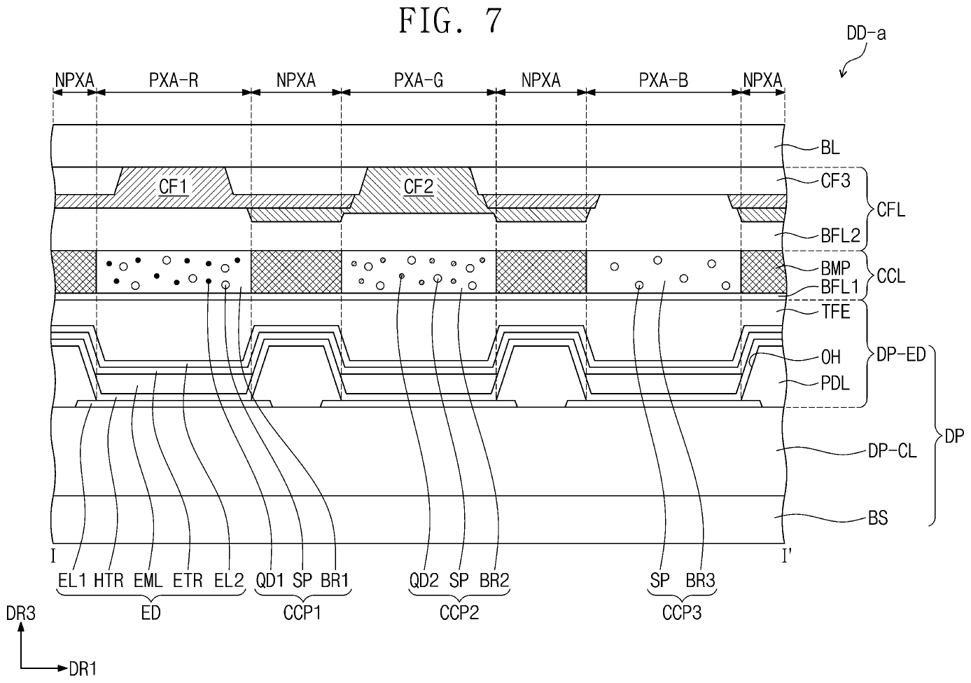

FIG. 7 to FIG. 10 are each a schematic cross-sectional view of a display device according to embodiments. In the explanation on the display devices according to embodiments in reference to FIG. 7 to FIG. 10, the features which have been described above with respect to FIG. 1 to FIG. 6 will not be explained again, and the differing features will be explained.

Referring to FIG. 7, a display device DD-a according to an embodiment may include a display panel DP including a display element layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 7 may be the same as a structure of a light emitting element according to one of FIG. 3 to FIG. 6 as described herein.

In the display device DD-a, the emission layer EML of the light emitting element ED may include the polycyclic compound as described herein.

Referring to FIG. 7, the emission layer EML may be disposed in an opening OH defined in a pixel definition layer PDL. For example, the emission layer EML, which is divided by the pixel definition layer PDL and correspondingly provided to each of the luminous areas PXA-R, PXA-G, and PXA-B, may each emit light in a same wavelength region. In the display device DD-a, the emission layer EML may emit blue light. Although not shown in the drawings, in an embodiment, the emission layer EML may be provided as a common layer for all of the luminous areas PXA-R, PXA-G, and PXA-B.

The light controlling layer CCL may be disposed on the display panel DP. The light controlling layer CCL may include a light converter. The light converter may be a quantum dot or a phosphor. The light converter may convert the wavelength of a provided light and may emit the resulting light. For example, the light controlling layer CCL may be a layer including a quantum dot or a layer including a phosphor.

The light controlling layer CCL may include light controlling parts CCP1, CCP2, and CCP3. The light controlling parts CCP1, CCP2, and CCP3 may be separated from one another.

Referring to FIG. 7, a partition pattern BMP may be disposed between the separated light controlling parts CCP1, CCP2, and CCP3, but embodiments are not limited thereto. In FIG. 7, is it shown that the partition pattern BMP does not overlap the light controlling parts CCP1, CCP2, and CCP3, but at least a portion of the edges of the light controlling parts CCP1, CCP2, and CCP3 may overlap the partition pattern BMP.

The light controlling layer CCL may include a first light controlling part CCP1 including a first quantum dot QD1 that converts first color light provided from the light emitting element ED into second color light, a second light controlling part CCP2 including a second quantum dot QD2 that converts first color light into third color light, and a third light controlling part CCP3 that transmits the first color light.

In an embodiment, the first light controlling part CCP1 may provide red light, which may be the second color light, and the second light controlling part CCP2 may provide green light, which may be the third color light. The third color controlling part CCP3 may transmit and provide blue light, which may be the first color light provided from the light emitting element ED. For example, the first quantum dot QD1 may be a red quantum dot, and the second quantum dot QD2 may be a green quantum dot. The quantum dots QD1 and QD2 may each be a quantum dot as described herein.

The light controlling layer CCL may further include a scatterer SP. The first light controlling part CCP1 may include the first quantum dot QD1 and a scatterer SP, the second light controlling part CCP2 may include the second quantum dot QD2 and a scatterer SP, and the third light controlling part CCP3 may not include a quantum dot but may include a scatterer SP.

The scatterer SP may be an inorganic particle. For example, the scatterer SP may include at least one of TiO₂, ZnO, Al₂O₃, SiO₂, and hollow silica. The scatterer SP may include any one of TiO₂, ZnO, Al₂O₃, SiO₂, and hollow silica, or the scatterer SP may be a mixture of two or more materials selected from TiO₂, ZnO, Al₂O₃, SiO₂, and hollow silica.

The first light controlling part CCP1, the second light controlling part CCP2, and the third light controlling part CCP3 may each include base resins BR1, BR2, and BR3 in which the quantum dots QD1 and QD2 and the scatterer SP are dispersed. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer SP dispersed in the third base resin BR3.

The base resins BR1, BR2, and BR3 are each a medium in which the quantum dots QD1 and QD2 and the scatterer SP are dispersed, and may be composed of various resin compositions which may be generally referred to as a binder. For example, the base resins BR1, BR2, and BR3 may be acrylic resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light controlling layer CCL may include a barrier layer BFL1. The barrier layer BFL1 may block the penetration of moisture and/or oxygen (hereinafter, will be referred to as “humidity/oxygen”). The barrier layer BFL1 may be disposed on the light controlling parts CCP1, CCP2, and CCP3 to block the light controlling parts CCP1, CCP2, and CCP3 from exposure to humidity/oxygen. The barrier layer BFL1 may cover the light controlling parts CCP1, CCP2, and CCP3. A barrier layer BFL2 may be provided between the light controlling parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. The barrier layers BFL1 and BFL2 may each independently further include an organic layer. The barrier layers BFL1 and BFL2 may each independently be formed of a single layer or of multiple layers.

In the display device DD-a, the color filter layer CFL may be disposed on the light controlling layer CCL. In an embodiment, the color filter layer CFL may be directly disposed on the light controlling layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or dye. The first filter CF1 may include a red pigment or dye, the second filter CF2 may include a green pigment or dye, and the third filter CF3 may include a blue pigment or dye. However, embodiments are not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may be provided in one body, without distinction.

The first to third filters CF1, CF2, and CF3 may be disposed to respectively correspond to the red luminous area PXA-R, the green luminous area PXA-G, and the blue luminous area PXA-B.

Although not shown in the drawings, the color filter layer CFL may include a light blocking part (not shown). The color filter layer CFL may include the light blocking part (not shown) disposed so as to overlap the boundaries of the neighboring filters CF1, CF2, and CF3. The light blocking part (not shown) may be a black matrix. The light blocking part (not shown) may include an organic light blocking material or an inorganic light blocking material that includes a black pigment or black dye. The light blocking part (not shown) may separate the boundaries between adjacent filters CF1, CF2, and CF3. In an embodiment, the light blocking part (not shown) may be formed of a blue filter.

A base substrate BL may be disposed on the color filter layer CFL. The base substrate BL may provide a base surface on which the color filter layer CFL, the light controlling layer CCL, etc. are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

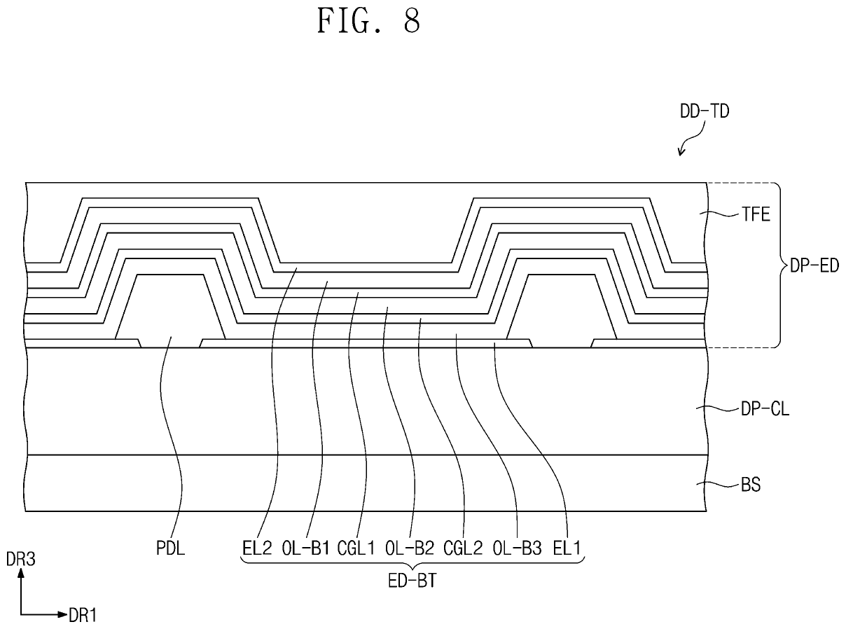

FIG. 8 is a schematic cross-sectional view showing a portion of a display device according to an embodiment that corresponds to a portion of the display panel DP of FIG. 7. In a display device DD-TD according to an embodiment, the light emitting element ED-BT may include light emitting structures OL-B1, OL-B2, and OL-B3. The light emitting element ED-BT may include a first electrode EL1 and an oppositely disposed second electrode EL2, and the light emitting structures OL-B1, OL-B2, and OL-B3 stacked in a thickness direction between the first electrode EL1 and the second electrode EL2. At least one of the light emitting structures OL-B1, OL-B2, and OL-B3 may include the above-explained polycyclic compound according to embodiments. The light emitting structures OL-B1, OL-B2, and OL-B3 may each include an emission layer EML (FIG. 7), and a hole transport region HTR and an electron transport region ETR disposed with the emission layer EML (FIG. 7) therebetween.

For example, the light emitting element ED-BT included in the display device DD-TD may be a light emitting element having a tandem structure and including multiple emission layers.

In an embodiment shown in FIG. 8, light emitted from the light emitting structures OL-B1, OL-B2, and OL-B3 may each be blue light. However, embodiments are not limited thereto, and the wavelength regions of the light emitted from the light emitting structures OL-B1, OL-B2, and OL-B3 may be different from each other. For example, the light emitting element ED-BT, which includes the light emitting structures OL-B1, OL-B2, and OL-B3 that emit light having different wavelength regions from each other, may emit white light.

Charge generating layers CGL1 and CGL2 may each be disposed between neighboring light emitting structures OL-B1, OL-B2, and OL-B3. Charge generating layers CGL1 and CGL2 may each independently include a p-type charge generating layer and/or an n-type charge generating layer.

In an embodiment, at least one of the light emitting structures OL-B1, OL-B2, and OL-B3 included in the display device DD-TD may include the polycyclic compound according to an embodiment. For example, at least one of the emission layers in the light emitting element ED-BT may each independently include the polycyclic compound.

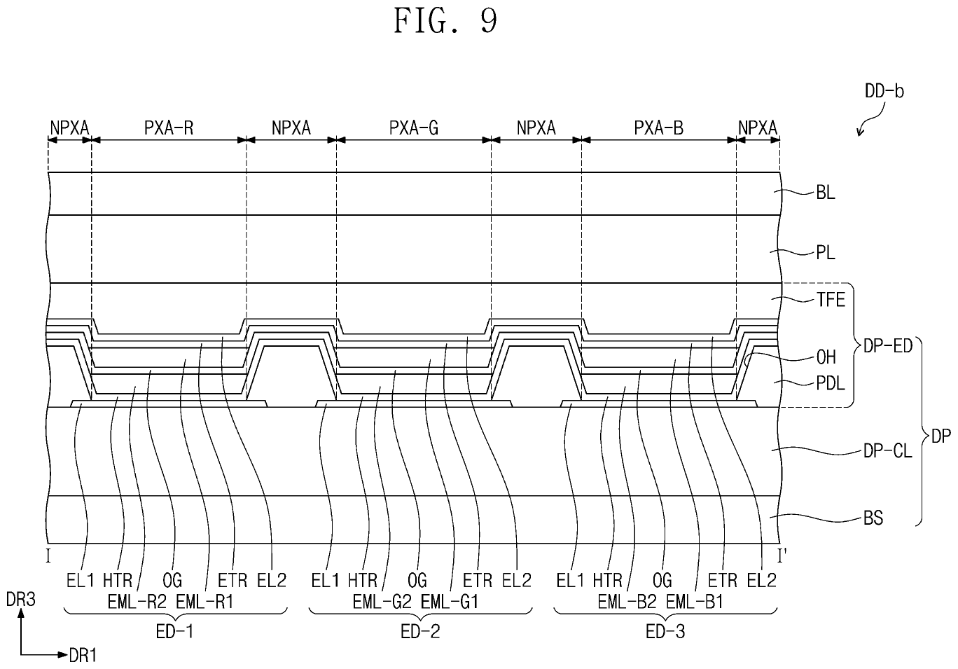

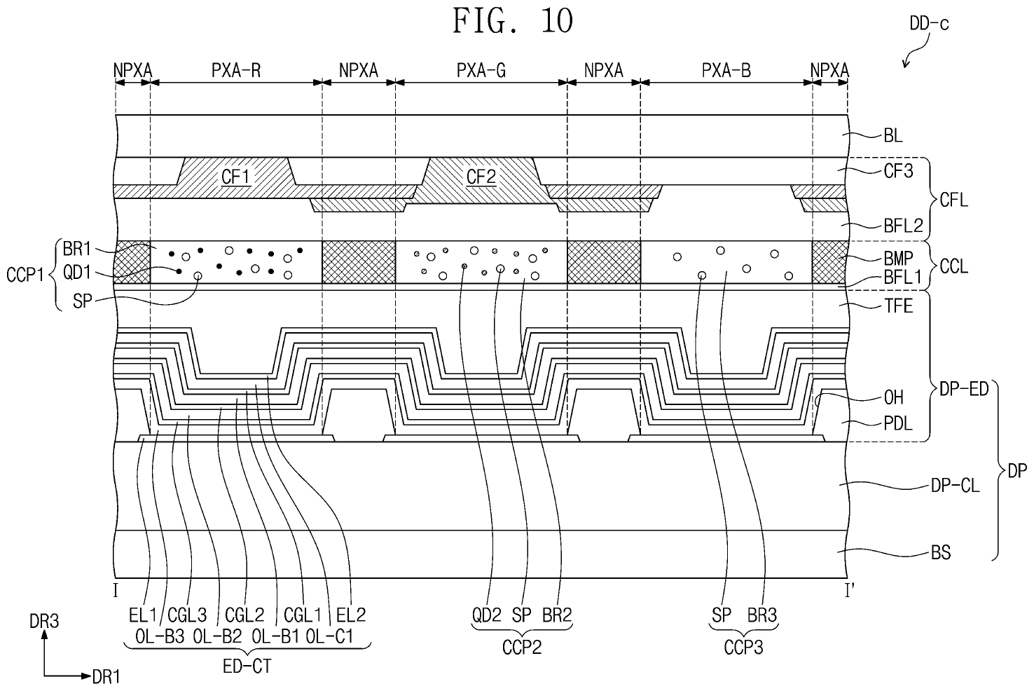

Referring to FIG. 9, a display device DD-b according to an embodiment may include light emitting elements ED-1, ED-2, and ED-3, which may each include two emission layers that are stacked. In comparison to the display device DD shown in FIG. 2, the embodiment shown in FIG. 9 is different at least in that the first to third light emitting elements ED-1, ED-2, and ED-3 each include two emission layers that are stacked in a thickness direction. In the first to third light emitting elements ED-1, ED-2, and ED-3, the two emission layers may emit light in a same wavelength region.

The first light emitting element ED-1 may include a first red emission layer EML-R₁ and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may be a single layer or a multilayer. The emission auxiliary part OG may include a charge generating layer. For example, the emission auxiliary part OG may include an electron transport region, a charge generating layer, and a hole transport region, which may be stacked in that order. The emission auxiliary part OG may be provided as a common layer for all of the first to third light emitting elements ED-1, ED-2, and ED-3. However, embodiments are not limited thereto, and the emission auxiliary part OG may be patterned and provided in the openings OH defined in the pixel definition layer PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on a display element layer DP-ED. The optical auxiliary layer PL may include a polarization layer. The optical auxiliary layer PL may be disposed on a display panel DP and may control light reflected at the display panel DP from an external light. Although not shown in the drawings, in an embodiment, the optical auxiliary layer PL may be omitted from the display device DD-b.

At least one emission layer included in the display device DD-b shown in FIG. 9 may include the polycyclic compound as described herein. For example, in an embodiment, at least one of the first blue emission layer EML-B1 or the second blue emission layer EML-B2 may include the polycyclic compound.

In contrast to FIG. 8 and FIG. 9, FIG. 10 shows a display device DD-c that is different at least in that it includes four light emitting structures OL-B1, OL-B2, OL-B3, and OL-C1. A light emitting element ED-CT may include a first electrode EL1 and an oppositely disposed second electrode EL2, and first to fourth light emitting structures OL-B1, OL-B2, OL-B3, and OL-C1 that are stacked in a thickness direction between the first electrode EL1 and the second electrode EL2. Charge generating layers CGL1, CGL2, and CGL3 may each be disposed between adjacent light emitting structures among the first to fourth light emitting structures OL-B1, OL-B2, OL-B3 and OL-C1. Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelengths from each other.

The charge generating layers CGL1, CGL2, and CGL3 which are disposed between neighboring light emitting structures OL-B1, OL-B2, OL-B3, and OL-C1 may each independently include a p-type charge generating layer and/or an n-type charge generating layer.

In the display device DD-c, at least one of the light emitting structures OL-B1, OL-B2, OL-B3, and OL-C1 may each independently include the polycyclic compound as described herein. For example, in an embodiment, at least one of the light emitting structures OL-B1, OL-B2, OL-B3 may include the polycyclic compound.

The light emitting element ED according to an embodiment may include the polycyclic compound according to an embodiment in at least one functional layer disposed between the first electrode EL1 and the second electrode EL2, thereby providing excellent emission efficiency and improved service life characteristics. For example, the emission layer EML of the light emitting element ED may include the polycyclic compound, and the light emitting element ED may show high efficiency and long-life characteristics simultaneously.

Hereinafter, a polycyclic compound according to an embodiment and a light emitting element according to an embodiment will be explained in detail with reference to the Examples and the Comparative Examples. The Examples below are only provided as illustrations to assist in understanding the disclosure, and the scope thereof is not limited thereto.

### Examples

1. Synthesis of Polycyclic Compounds

A synthesis method of the polycyclic compound according to an embodiment will be explained in detail by illustrating the synthesis methods of Compounds 1, 20, 26, 48, 51 and 68. The synthesis methods of the polycyclic compounds explained hereinafter are provided as examples, and the synthesis methods of the polycyclic compound are not limited to the Examples below.

(1) Synthesis of Compound 1

Compound 1 according to an embodiment may be synthesized, for example, by Reaction 1 below.

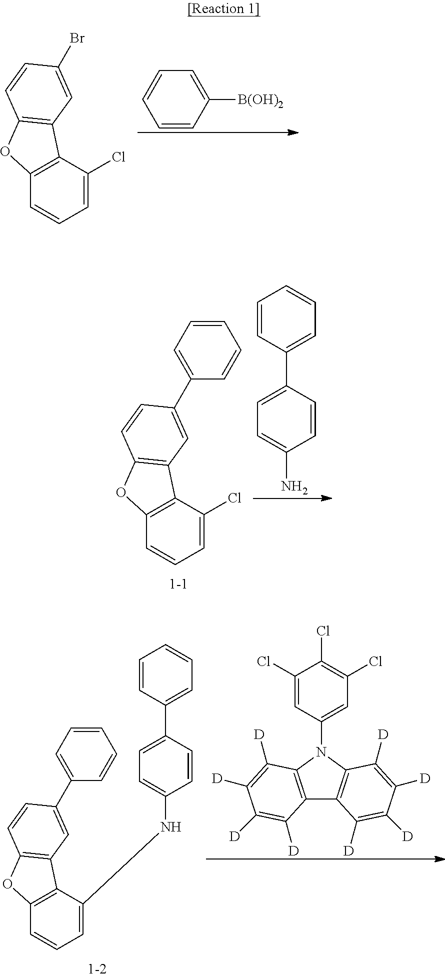

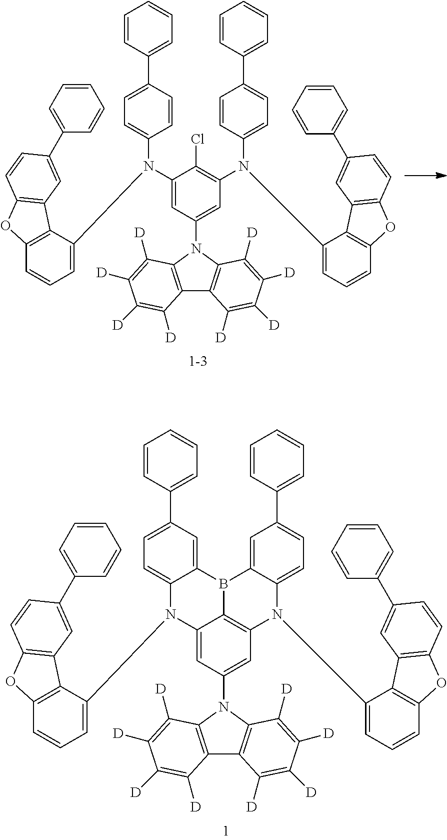 [SMILES: [2H]c1c([2H])c([2H])c2c(c1[2H])c1c([2H])c([2H])c([2H])c([2H])c1n2-c1cc(N(c2ccc(-c3ccccc3)cc2)c2cccc3oc4ccc(-c5ccccc5)cc4c23)c(Cl)c(N(c2ccc(-c3ccccc3)cc2)c2cccc3oc4ccc(-c5ccccc5)cc4c23)c1 ; [2H]c1c([2H])c([2H])c2c(c1[2H])c1c([2H])c([2H])c([2H])c([2H])c1n2-c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12]

1) Synthesis of Intermediate 1-1

8-Bromo-1-chlorodibenzo[b,d]furan (1 eq), phenylboronic acid (1 eq), Pd(PPh₃)₄ (0.05 eq), and K₂CO₃ (3 eq) were dissolved in a mixture solution of water and THF in a ratio of 2:1, and stirred at about 80 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using methylene chloride (hereinafter, MC) and n-hexane, Intermediate 1-1 was obtained (yield: 71%).

2) Synthesis of Intermediate 1-2

Intermediate 1-1 (1 eq), [1,1′-biphenyl]-4-amine (1.2 eq), tris(dibenzylideneacetone)dipalladium(0) (0.05 eq), tri-tert-butylphosphine (0.1 eq), and sodium tert-butoxide (3 eq) were dissolved in toluene, and stirred at about 90 degrees centigrade for about 6 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 1-2 was obtained (yield: 68%).

3) Synthesis of Intermediate 1-3

9-(3,4,5-Trichlorophenyl)-9H-carbazole-1,2,3,4,5,6,7,8-d8 (1 eq), Intermediate 1-2 (2.1 eq), tris(dibenzylideneacetone)dipalladium(0) (0.05 eq), tri-tert-butylphosphine (0.1 eq), and sodium tert-butoxide (3 eq) were dissolved in toluene, and stirred at about 100 degrees centigrade for about 6 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 1-3 was obtained (yield: 47%)

4) Synthesis of Compound 1

Intermediate 1-3 (1 eq) was dissolved in t-butylbenzene and cooled to about minus 78 degrees centigrade under a nitrogen atmosphere. After slowly injecting t-BuLi (2 eq), the temperature was raised to room temperature, followed by stirring for about 30 minutes, raising the temperature to 90 degrees centigrade and stirring for 1 hour. After cooling the temperature of a reactor to about minus 78 degrees centigrade, BBr₃ (2 eq) was slowly injected. After finishing dropwise addition, the temperature was raised to room temperature, followed by stirring for about 2 hours. After cooling to about 0 degrees centigrade, triethylamine (3 eq) was injected, and the temperature was raised to about 120 degrees centigrade, followed by stirring for about 6 hours. After cooling, triethylamine was slowly dropped to a flask containing the reaction solution to quench the reaction, and silica filtration and concentration were performed. The solid content thus obtained was purified by column chromatography to obtain Compound 1 (yield: 24%).

(2) Synthesis of Compound 20

Compound 20 according to an embodiment may be synthesized, for example, by Reaction 2 below.

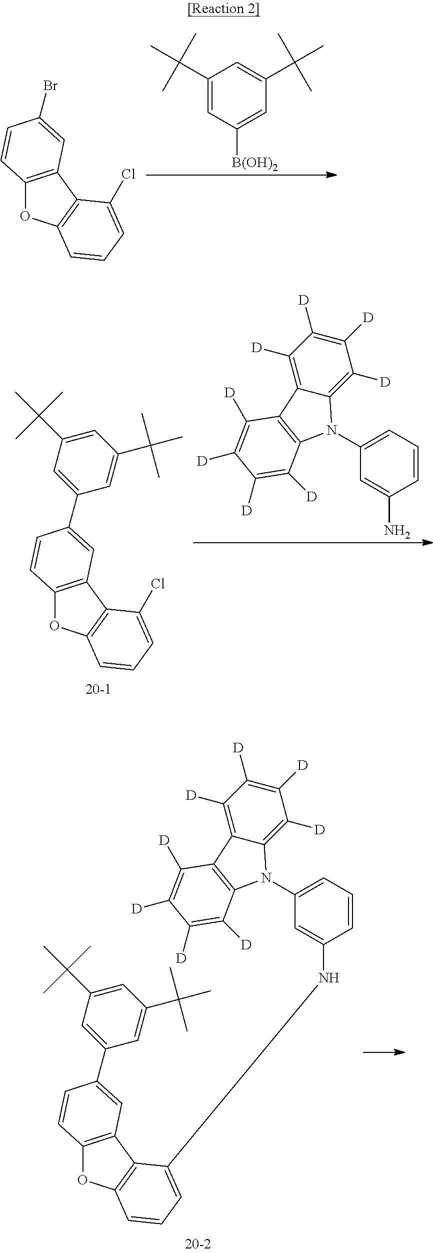

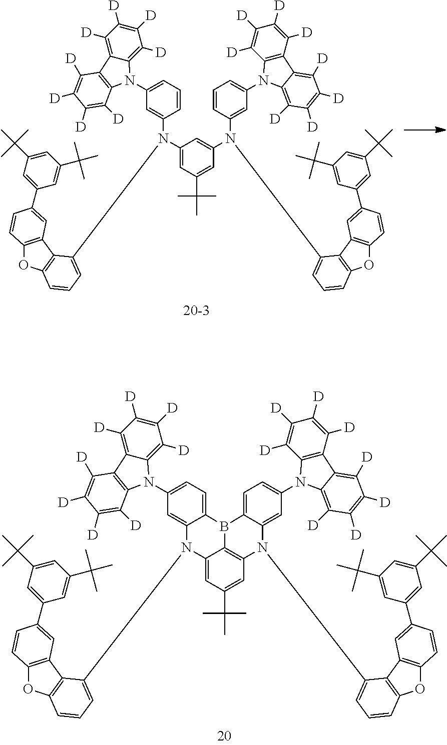

1) Synthesis of Intermediate 20-1

8-Bromo-1-chlorodibenzo[b,d]furan (1 eq), (3,5-di-tert-butylphenyl)boronic acid (1 eq), Pd(PPh₃)₄ (0.05 eq), and K₂CO₃ (3 eq) were dissolved in a mixture solution of water and THF in a ratio of 2:1, and stirred at about 80 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 20-1 was obtained (yield: 65%).

2) Synthesis of Intermediate 20-2

Intermediate 20-1 (1 eq), 3-(9H-carbazol-9-yl-d8)aniline (1.2 eq), tris(dibenzylideneacetone)dipalladium(0) (0.05 eq), tri-tert-butylphosphine (0.1 eq), and sodium tert-butoxide (3 eq) were dissolved in toluene, and stirred at about 90 degrees centigrade for about 6 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 20-2 was obtained (yield: 72%).

3) Synthesis of Intermediate 20-3

1,3-Dibromo-5-(tert-butyl)benzene (1 eq), Intermediate 20-2 (2.1 eq), tris(dibenzylideneacetone)dipalladium(0) (0.05 eq), tri-tert-butylphosphine (0.1 eq), and sodium tert-butoxide (3 eq) were dissolved in toluene, and stirred at about 100 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 20-3 was obtained (yield: 69%)

4) Synthesis of Compound 20

Intermediate 20-3 (1 eq) was dissolved in o-dichlorobenzene and cooled to about 0 degrees centigrade, and under a nitrogen atmosphere, BBr₃ (3 eq) was slowly injected. After finishing dropwise addition, the temperature was raised to about 180 degrees centigrade, followed by stirring for about 24 hours. After cooling, triethylamine was slowly dropped to a flask containing the reaction solution to quench the reaction, and ethyl alcohol was added to the reaction solution to precipitate. Filtration was performed, and the solid content thus obtained was purified by column chromatography using MC and n-hexane and recrystallized using toluene and acetone to obtain Compound 20 (yield: 6%).

(3) Synthesis of Compound 26

Compound 26 according to an embodiment may be synthesized, for example, by Reaction 3 below.

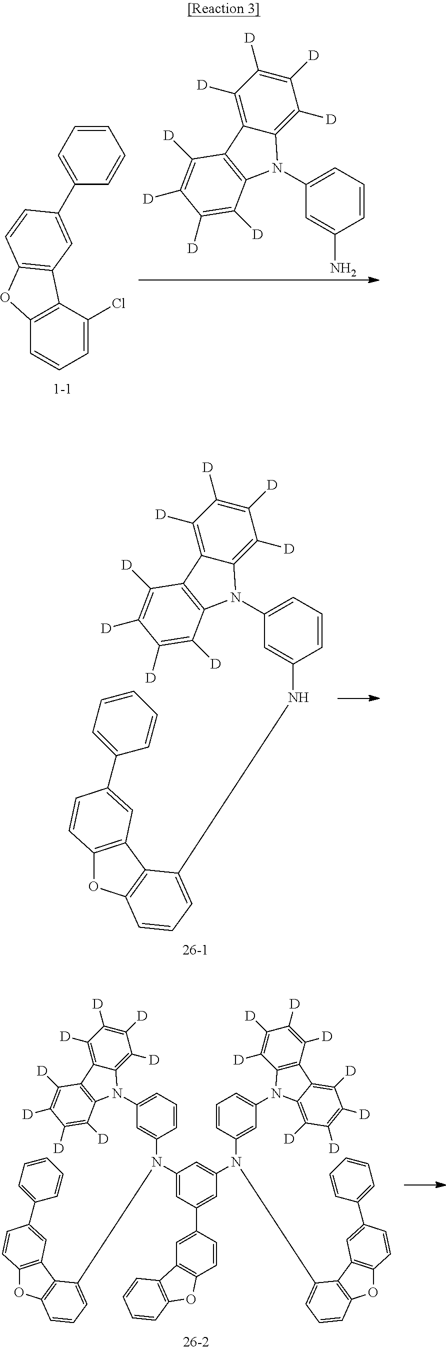 [SMILES: Clc1cccc2oc3ccc(-c4ccccc4)cc3c12 ; [2H]c1c([2H])c([2H])c2c(c1[2H])c1c([2H])c([2H])c([2H])c([2H])c1n2-c1cccc(N)c1 ; [2H]c1c([2H])c([2H])c2c(c1[2H])c1c([2H])c([2H])c([2H])c([2H])c1n2-c1cccc(Nc2cccc3oc4ccc(-c5ccccc5)cc4c23)c1 ; [2H]c1c([2H])c([2H])c2c(c1[2H])c1c([2H])c([2H])c([2H])c([2H])c1n2-c1cccc(N(c2cc(-c3ccc4oc5ccccc5c4c3)cc(N(c3cccc(-n4c5c([2H])c([2H])c([2H])c([2H])c5c5c([2H])c([2H])c([2H])c([2H])c54)c3)c3cccc4oc5ccc(-c6ccccc6)cc5c34)c2)c2cccc3oc4ccc(-c5ccccc5)cc4c23)c1]

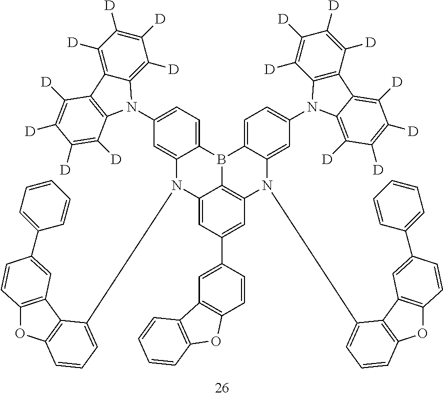 [SMILES: [2H]c1c([2H])c([2H])c2c(c1[2H])c1c([2H])c([2H])c([2H])c([2H])c1n2-c1ccc2c(c1)N(c1cccc3oc4ccc(-c5ccccc5)cc4c13)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1cccc2oc3ccc(-c4ccccc4)cc3c12]

1) Synthesis of Intermediate 26-1

Intermediate 1-1 (1 eq), 3-(9H-carbazol-9-yl-d8)aniline (1.2 eq), tris(dibenzylideneacetone)dipalladium(0) (0.05 eq), tri-tert-butylphosphine (0.1 eq), and sodium tert-butoxide (3 eq) were dissolved in toluene, and stirred at about 90 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 26-1 was obtained (yield: 73%).

2) Synthesis of Intermediate 26-2

2-(3,5-Dichlorophenyl)dibenzo[b,d]furan (1 eq), Intermediate 26-1 (2.3 eq), tris(dibenzylideneacetone)dipalladium(0) (0.1 eq), tri-tert-butylphosphine (0.2 eq), and sodium tert-butoxide (3 eq) were dissolved in o-xylene, and stirred at about 140 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 26-2 was obtained (yield: 77%)

3) Synthesis of Compound 26

Intermediate 26-2 (1 eq) was dissolved in o-dichlorobenzene and cooled to about 0 degrees centigrade, and under a nitrogen atmosphere, BBr₃ (3 eq) was slowly injected. After finishing dropwise addition, the temperature was raised to about 180 degrees centigrade, followed by stirring for about 24 hours. After cooling, triethylamine was slowly dropped to a flask containing the reaction solution to quench the reaction, and ethyl alcohol was added to the reaction solution to precipitate. Filtration was performed, and the solid content thus obtained was purified by column chromatography using MC and n-hexane and recrystallized using toluene and acetone to obtain Compound 26 (yield: 5%).

(4) Synthesis of Compound 48

Compound 48 according to an embodiment may be synthesized, for example, by Reaction 4 below.

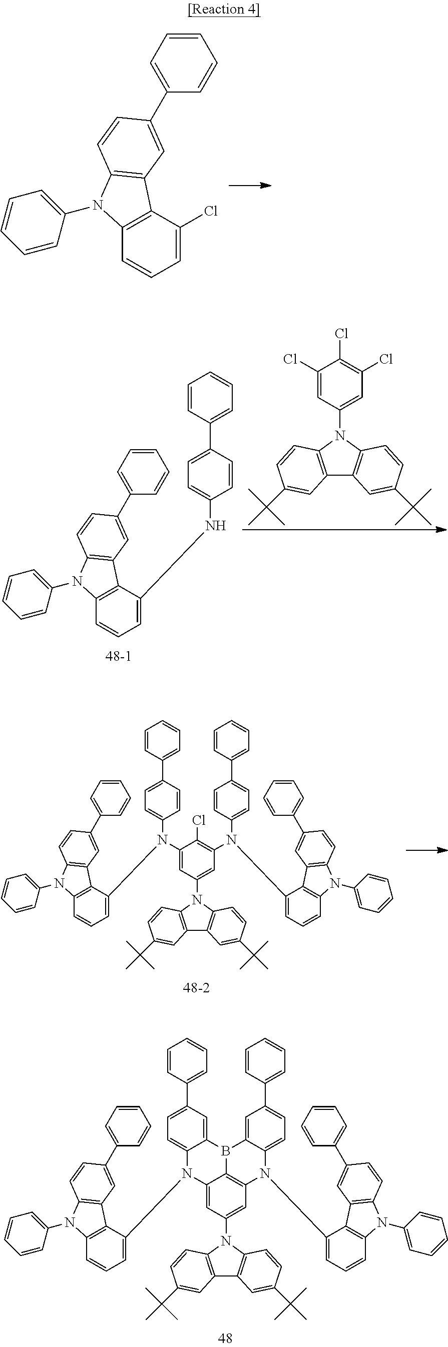

1) Synthesis of Intermediate 48-1

5-Chloro-3,9-diphenyl-9H-carbazole (1 eq), [1,1′-biphenyl]-4-amine (1.4 eq), tris(dibenzylideneacetone)dipalladium(0) (0.05 eq), tri-tert-butylphosphine (0.1 eq), and sodium tert-butoxide (3 eq) were dissolved in toluene, and stirred at about 90 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 48-1 was obtained (yield: 60%).

2) Synthesis of Intermediate 48-2

9-(3,4,5-Trichlorophenyl)-9H-carbazole-1,2,3,4,5,6,7,8-d8 (1 eq), Intermediate 48-1 (2.2 eq), tris(dibenzylideneacetone)dipalladium(0) (0.05 eq), tri-tert-butylphosphine (0.1 eq), and sodium tert-butoxide (3 eq) were dissolved in toluene, and stirred at about 100 degrees centigrade for about 6 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 48-2 was obtained (yield: 41%)

3) Synthesis of Compound 48

Intermediate 48-2 (1 eq) was dissolved in t-butylbenzene and cooled to about minus 78 degrees centigrade under a nitrogen atmosphere. After slowly injecting t-BuLi (2 eq), the temperature was raised to room temperature, followed by stirring for about 30 minutes, and the temperature was raised to about 90 degrees centigrade, followed by stirring for about 1 hour. After cooling the temperature of a reactor to about minus 78 degrees centigrade, BBr₃ (2 eq) was slowly injected. After finishing dropwise addition, the temperature was raised to room temperature, followed by stirring for about 2 hours. After cooling to about 0 degrees centigrade, triethylamine (3 eq) was injected, and the temperature was raised to about 120 degrees centigrade, followed by stirring for about 6 hours. After cooling, triethylamine was slowly dropped to a flask containing the reaction solution to quench the reaction, and silica filtration and concentration were performed. The solid content thus obtained was purified by column chromatography to obtain Compound 48 (yield: 15%).

(5) Synthesis of Compound 51

Compound 51 according to an embodiment may be synthesized, for example, by Reaction 5 below.

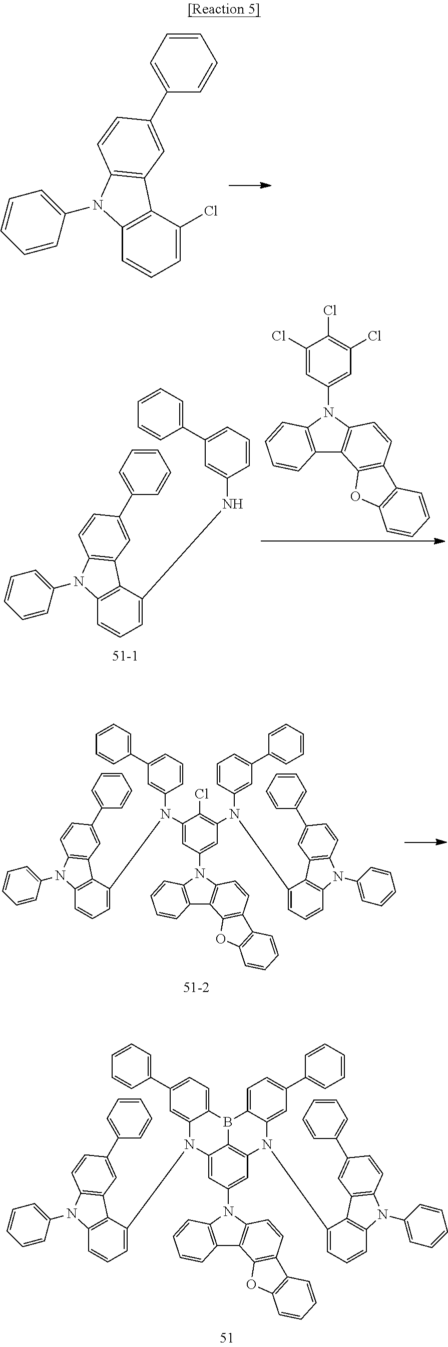

1) Synthesis of Intermediate 51-1

5-Chloro-3,9-diphenyl-9H-carbazole (1 eq), [1,1′-biphenyl]-3-amine (1.4 eq), tris(dibenzylideneacetone)dipalladium(0) (0.05 eq), tri-tert-butylphosphine (0.1 eq), and sodium tert-butoxide (3 eq) were dissolved in toluene, and stirred at about 90 degrees centigrade for about 12 hours. After cooling, the was washed with ethyl acetate and water three times, and an organic layer obtained by layer separation was dried over MgSO₄, and dried under a reduced pressure. Through purification by column chromatography using MC and n-hexane, Intermediate 51-1 was obtained (yield: 63%).

2) Synthesis of Intermediate 51-2

9-(3,4,5-Trichlorophenyl)-9H-carbazole-1,2,3,4,5,6,7,8-d8 (1 eq), Intermediate 51-1 (2.2 eq), tris(dibenzylideneacetone)dipalladium(0) (0.05 eq), tri-tert-butylphosphine (0.1 eq), and sodium tert-butoxide (3 eq) were dissolved in toluene, and stirred at about 100 degrees centigrade for about 6 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 51-2 was obtained (yield: 39%)

3) Synthesis of Compound 51

Intermediate 51-2 (1 eq) was dissolved in t-butylbenzene and cooled to about minus 78 degrees centigrade under a nitrogen atmosphere. After slowly injecting t-BuLi (2 eq), the temperature was raised to room temperature, followed by stirring for about 30 minutes, and the temperature was raised to about 90 degrees centigrade, followed by stirring for about 1 hour. After cooling the temperature of a reactor to about minus 78 degrees centigrade, BBr₃ (2 eq) was slowly injected. After finishing dropwise addition, the temperature was raised to room temperature, followed by stirring for about 2 hours. After cooling to about 0 degrees centigrade, triethylamine (3 eq) was injected, and the temperature was raised to about 120 degrees centigrade, followed by stirring for about 6 hours. After cooling, triethylamine was slowly dropped to a flask containing the reaction solution to quench the reaction, and silica filtration and concentration were performed. The solid content thus obtained was purified by column chromatography to obtain Compound 51 (yield: 20%).

(6) Synthesis of Compound 68

Compound 68 according to an embodiment may be synthesized, for example, by Reaction 6 below.

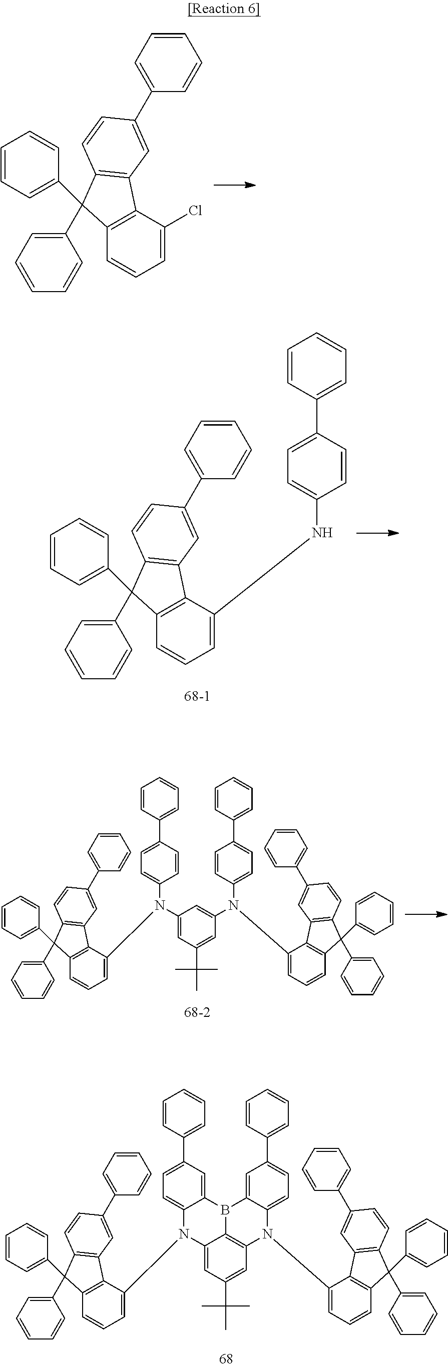 [SMILES: Clc1cccc2c1-c1cc(-c3ccccc3)ccc1C2(c1ccccc1)c1ccccc1 ; c1ccc(-c2ccc(Nc3cccc4c3-c3cc(-c5ccccc5)ccc3C4(c3ccccc3)c3ccccc3)cc2)cc1 ; CC(C)(C)c1cc(N(c2ccc(-c3ccccc3)cc2)c2cccc3c2-c2cc(-c4ccccc4)ccc2C3(c2ccccc2)c2ccccc2)cc(N(c2ccc(-c3ccccc3)cc2)c2cccc3c2-c2cc(-c4ccccc4)ccc2C3(c2ccccc2)c2ccccc2)c1 ; CC(C)(C)c1cc2c3c(c1)N(c1cccc4c1-c1cc(-c5ccccc5)ccc1C4(c1ccccc1)c1ccccc1)c1ccc(-c4ccccc4)cc1B3c1cc(-c3ccccc3)ccc1N2c1cccc2c1-c1cc(-c3ccccc3)ccc1C2(c1ccccc1)c1ccccc1]

1) Synthesis of Intermediate 68-1

5-Chloro-3,9,9-triphenyl-9H-fluorene (1 eq), [1,1′-biphenyl]-4-amine (1.3 eq), tris(dibenzylideneacetone)dipalladium(0) (0.05 eq), tri-tert-butylphosphine (0.1 eq), and sodium tert-butoxide (3 eq) were dissolved in toluene, and stirred at about 90 degrees centigrade for about 6 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 68-1 was obtained (yield: 57%).

2) Synthesis of Intermediate 68-2

1,3-Dibromo-5-(tert-butyl)benzene (1 eq), Intermediate 68-1 (2.1 eq), tris(dibenzylideneacetone)dipalladium(0) (0.05 eq), tri-tert-butylphosphine (0.1 eq), and sodium tert-butoxide (3 eq) were dissolved in toluene, and stirred at about 100 degrees centigrade for about 12 hours. After cooling, the resulting mixture was washed with ethyl acetate and water three times, and an organic layer obtained by layer separation was dried over MgSO₄, and dried under a reduced pressure. Through purification by column chromatography using MC and n-hexane, Intermediate 68-2 was obtained (yield: 55%)

3) Synthesis of Compound 68

Intermediate 68-2 (1 eq) was dissolved in o-dichlorobenzene and cooled to about 0 degrees centigrade, and under a nitrogen atmosphere, BBr₃ (3 eq) was slowly injected. After finishing dropwise addition, the temperature was raised to about 180 degrees centigrade, followed by stirring for about 24 hours. After cooling, triethylamine was slowly dropped to a flask containing the reaction solution to quench the reaction, and ethyl alcohol was added to the reaction solution to precipitate. Filtration was performed, and the solid content thus obtained was purified by column chromatography using MC and n-hexane and recrystallized using toluene and acetone to obtain Compound 68 (yield: 4%).

2. Example Compounds and Comparative Compounds

The Example Compounds and Comparative Compounds used for the manufacture of the light emitting elements of the Examples and Comparative Examples are shown below.

[Example Compounds]

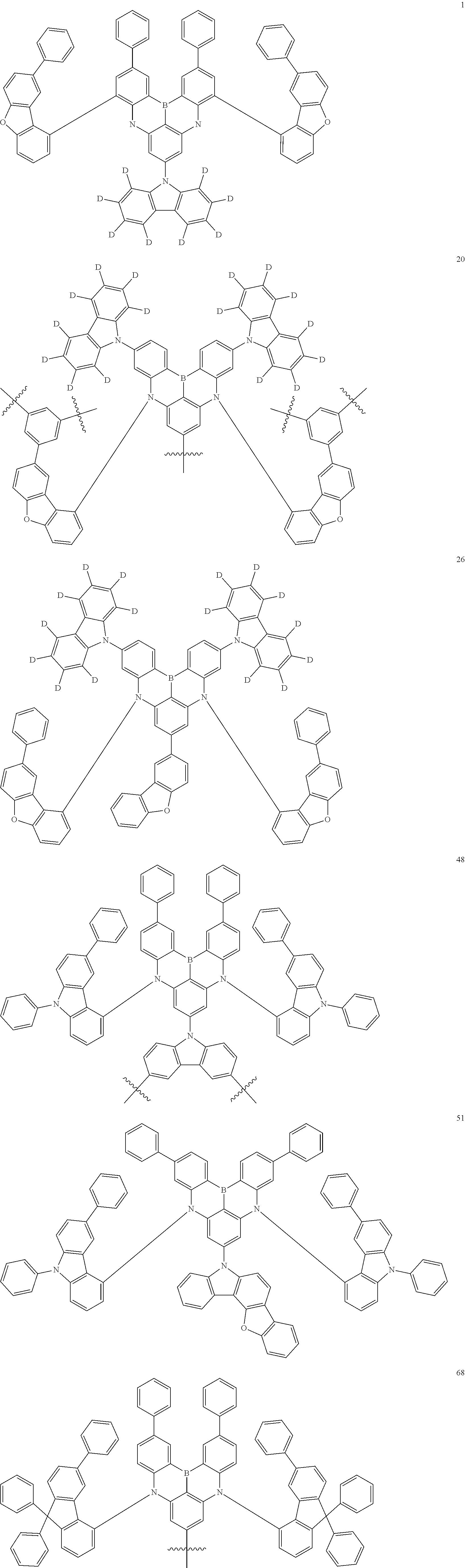

[Comparative Compounds]

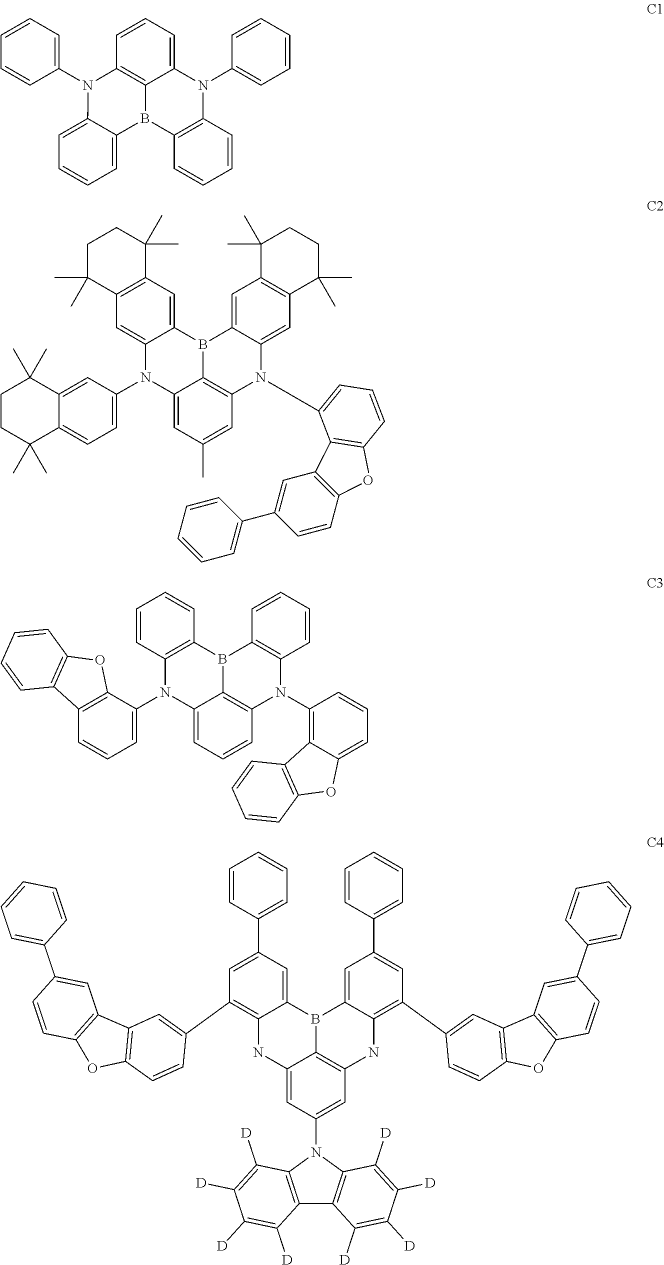

3. Manufacture and Evaluation of Light Emitting Element 1

(1) Manufacture of Light Emitting Element 1

A light emitting element 1 including the polycyclic compound of an embodiment or a Comparative Compound in an emission layer was manufactured by a method below. The light emitting elements of Examples 1-1 to 1-10 were manufactured using Compounds 1, 20, 26, 48, 51 and 68 as the dopant materials of an emission layer. The light emitting elements of Comparative Examples 1-1 to 1-7 were manufactured using Comparative Compound C1 to Comparative Compound C4 as the dopant materials of an emission layer.

As a first electrode, a glass substrate (a product of Corning Co.) on which an ITO electrode of 15 Ω/cm² (about 1,200 Å) was formed, was cut into a size of 50 mm×50 mm×0.7 mm, and washed using ultrasonic waves using isopropyl alcohol and pure water for about 5 minutes each, and cleansed by irradiating ultraviolet for about 30 minutes and exposing to ozone. The glass substrate was installed on a vacuum deposition apparatus.

On the ITO glass substrate, NPD was vacuum deposited to form a hole injection layer with a thickness of about 300 Å. On the hole injection layer, a hole transport layer material was vacuum deposited to a thickness of about 200 Å to form a hole transport layer. H-1-1 was used as the hole transport layer material. On the hole transport layer, CzSi was deposited to form an emission auxiliary layer with a thickness of about 100 Å.

On the emission auxiliary layer, a host mixture, a phosphorescence sensitizer, and a dopant of an Example Compound or a Comparative Compound were co-deposited in a weight ratio of about 85:14:1 to form an emission layer with a thickness of about 200 Å. The host mixture was provided by mixing a first host (HT60) and a second host (EHT66) in a weight ratio of about 5:5, as shown in Table 2 below. The phosphorescence sensitizer used AD-37 or AD-38, as shown in Table 2.

On the emission layer, TSPO1 was deposited to form a hole blocking layer with a thickness of about 200 Å, and on the hole blocking layer, TPBI was deposited to form an electron transport layer with a thickness of about 300 Å. On the electron transport layer, LiF was deposited to form an electron injection layer with a thickness of about 10 Å, and on the electron injection layer, Al was deposited to form a second electrode with a thickness of about 3,000 Å, to form a light emitting element 1.

The compounds used for the manufacture of the light emitting element 1 are as follows.

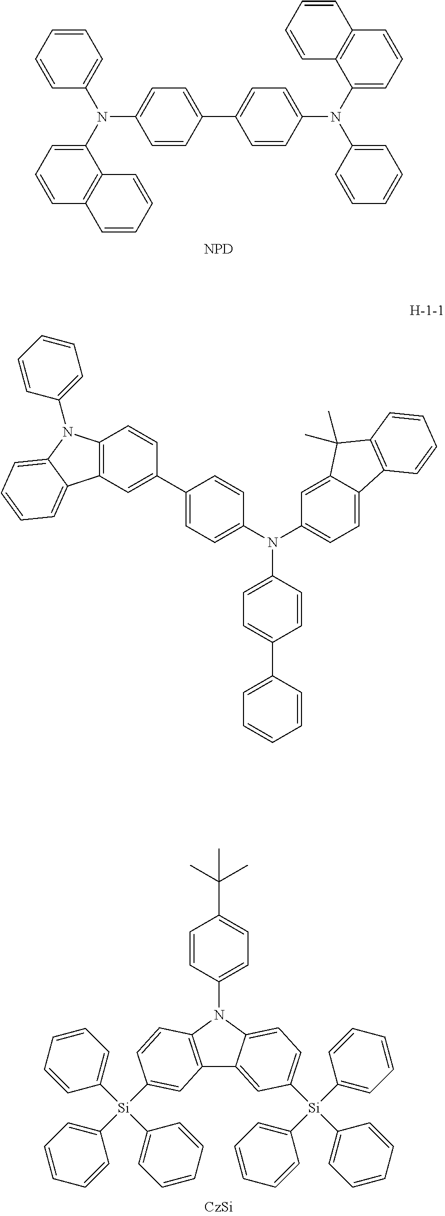

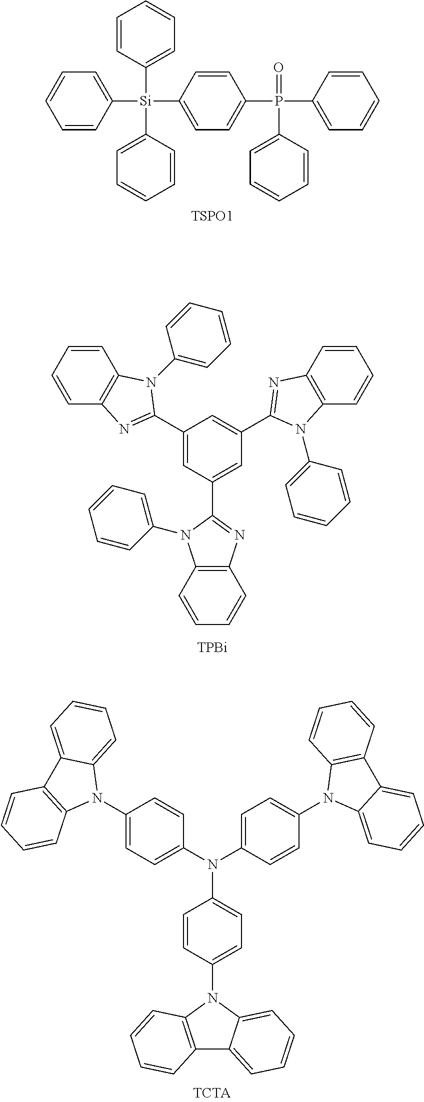

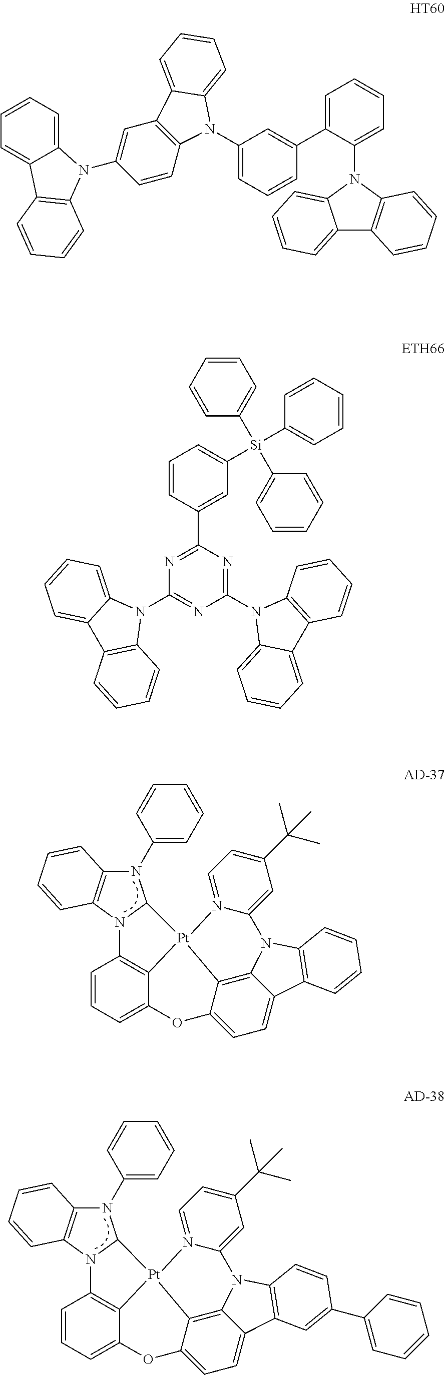

(2) Evaluation of Light Emitting Element 1

In Table 1, the driving voltage (V), emission efficiency (cd/A), emission wavelength (nm) and element lifetime were measured and shown for the light emitting elements of Examples 1-1 to 1-10, and Comparative Examples 1-1 to 1-7. The driving voltage (V), emission efficiency (cd/A), and emission wavelength (nm) of the light emitting elements were measured at a luminance of about 1,000 cd/m² using Keithley MU 236 and a luminance meter PR650. The lifetime (T95) was obtained by measuring a time consumed to reach about 95% luminance in contrast to an initial luminance.

TABLE 1

| | | | | Driving | | Emission | |
|---|---|---|---|---|---|---|---|
| | Host | Phosphorescence | Dopant | voltage | Efficiency | wavelength | Lifetime |
| | (HT:ET = 5:5) | sensitizer | compound | (V) | (cd/A) | (nm) | ratio (T₉₅) |
| Example 1-1 | HT60/EHT66 | AD-37 | Example | 4.4 | 27.4 | 458 | 6.1 |
| | | | Compound 1 | | | | |
| Example 1-2 | HT60/EHT66 | AD-37 | Example | 4.5 | 25.1 | 461 | 5.4 |
| | | | Compound 20 | | | | |
| Example 1-3 | HT60/EHT66 | AD-37 | Example | 4.4 | 26.5 | 461 | 5.7 |
| | | | Compound 26 | | | | |
| Example 1-4 | HT60/EHT66 | AD-37 | Example | 4.4 | 27.0 | 459 | 5.6 |
| | | | Compound 48 | | | | |
| Example 1-5 | HT60/EHT66 | AD-37 | Example | 4.5 | 26.1 | 460 | 5.9 |
| | | | Compound 51 | | | | |
| Example 1-6 | HT60/EHT66 | AD-38 | Example | 4.3 | 26.5 | 461 | 6.1 |
| | | | Compound 68 | | | | |
| Example 1-7 | HT60/EHT66 | AD-38 | Example | 4.3 | 26.4 | 460 | 5.6 |
| | | | Compound 1 | | | | |
| Example 1-8 | HT60/EHT66 | AD-38 | Example | 4.4 | 26.0 | 462 | 6.7 |
| | | | Compound 20 | | | | |
| Example 1-9 | HT60/EHT66 | AD-38 | Example | 4.5 | 26.7 | 460 | 6.1 |
| | | | Compound 48 | | | | |
| Example 1-10 | HT60/EHT66 | AD-38 | Example | 4.4 | 25.8 | 462 | 6.3 |
| | | | Compound 51 | | | | |
| Comparative | HT60/EHT66 | AD-38 | Comparative | 5.6 | 15.3 | 465 | 1.0 |
| Example 1-1 | | | Compound C1 | | | | |
| Comparative | HT60/EHT66 | AD-37 | Comparative | 5.3 | 17.8 | 464 | 2.5 |
| Example 1-2 | | | Compound C2 | | | | |
| Comparative | HT60/EHT66 | AD-38 | Comparative | 5.4 | 17.1 | 464 | 3.1 |
| Example 1-3 | | | Compound C2 | | | | |
| Comparative | HT60/EHT66 | AD-37 | Comparative | 5.8 | 14.3 | 457 | 0.9 |
| Example 1-4 | | | Compound C3 | | | | |
| Comparative | HT60/EHT66 | AD-37 | Comparative | 5.2 | 18.6 | 460 | 3.6 |
| Example 1-6 | | | Compound C4 | | | | |
| Comparative | HT60/EHT66 | AD-38 | Comparative | 5.3 | 19.7 | 461 | 3.9 |
| Example 1-7 | | | Compound C4 | | | | |

Referring to the results of Table 1, it could be confirmed that the light emitting elements of Examples 1-1 to 1-10 showed lower driving voltages, higher emission efficiency and long-life characteristics when compared to the light emitting elements of Comparative Examples 1-1 to 1-7.

4. Manufacture and Evaluation of Light Emitting Element 2

(1) Manufacture of Light Emitting Element 2

The light emitting elements of Example 2-1 to Example 2-6 were manufactured by the same method of the light emitting element 1 except for not using the phosphorescence sensitizer during the formation of the emission layer. The light emitting elements of Comparative Example 2-1 to Example 2-4 were manufactured by the same method of the light emitting element 1 except for not using the phosphorescence sensitizer during the formation of the emission layer. For forming the emission layers of the light emitting elements of Example 2-1 to Example 2-6 and Comparative Example 2-1 to Comparative Example 2-4, a host mixture and a dopant were provided in a weight ratio of about 99:1 and co-deposited to a thickness of about 200 Å.

(2) Evaluation of Light Emitting Element 2

In Table 2, the emission efficiency (cd/A), maximum external quantum efficiency (EQEₘₐₓ, %), and emission wavelength (nm) of the light emitting elements of Examples 2-1 to 2-6, and Comparative Examples 2-1 to 2-4 were measured, and the results are shown. The emission efficiency (cd/A), maximum external quantum efficiency (EQEₘₐₓ, %), and emission wavelength (nm) of the light emitting elements were measured at a luminance of about 1,000 cd/m² using Keithley MU 236 and a luminance meter PR650.

TABLE 2

| | | | | Maximum external | Emission |
|---|---|---|---|---|---|
| | Host | Dopant | Efficiency | quantum efficiency | wavelength |
| | (HT:ET = 5:5) | compound | (cd/A) | (%) | (nm) |
| Example 2-1 | HT60/EHT66 | Example | 8.5 | 8.2 | 458 |
| | | Compound 1 | | | |
| Example 2-2 | HT60/EHT66 | Example | 9.2 | 8.8 | 462 |
| | | Compound 20 | | | |
| Example 2-3 | HT60/EHT66 | Example | 9.3 | 8.9 | 461 |
| | | Compound 26 | | | |
| Example 2-4 | HT60/EHT66 | Example | 8.7 | 8.1 | 458 |
| | | Compound 48 | | | |
| Example 2-5 | HT60/EHT66 | Example | 8.9 | 7.9 | 460 |
| | | Compound 51 | | | |
| Example 2-6 | HT60/EHT66 | Example | 9.4 | 8.9 | 463 |
| | | Compound 68 | | | |
| Comparative | HT60/EHT66 | Comparative | 6.5 | 6.3 | 462 |
| Example 2-1 | | Compound C1 | | | |
| Comparative | HT60/EHT66 | Comparative | 6.8 | 6.7 | 459 |
| Example 2-2 | | Compound C2 | | | |
| Comparative | HT60/EHT66 | Comparative | 6.5 | 5.9 | 456 |
| Example 2-3 | | Compound C3 | | | |
| Comparative | HT60/EHT66 | Comparative | 6.8 | 7.0 | 458 |
| Example 2-4 | | Compound C4 | | | |

Referring to the results of Table 2, the light emitting elements of Examples 2-1 to 2-6 showed element properties of higher emission efficiency and improved maximum external quantum efficiency when compared to the light emitting elements of Comparative Examples 2-1 to 2-4.

The polycyclic compound of an embodiment includes a fused ring core that includes a boron atom and two nitrogen atoms, and bulky substituents connected to the two nitrogen atoms, and the stability of the compound as a whole may be improved, and increased emission efficiency properties may be shown due to delayed fluorescence. A light emitting element that includes a polycyclic compound according to an embodiment may show long-life characteristics, while maintaining excellent emission efficiency.

The light emitting element of an embodiment includes the polycyclic compound of an embodiment in an emission layer and may show high efficiency and long-life characteristics.

The polycyclic compound of an embodiment includes a fused ring core including a boron atom and two nitrogen atoms as ring-forming atoms, and substituents connected to the two nitrogen atoms and having large steric hindrance, and may contribute to the increase of the lifetime and emission efficiency of a light emitting element.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer comprises a first compound represented by Formula 1: 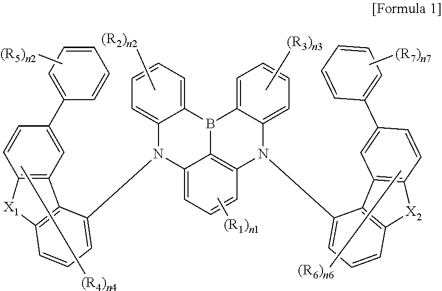
wherein in Formula 1,
X₁ and X₂ are each independently O, S, N(R₈), or C(R₉)(R₁₀),
R₁ to R₇ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms,
R₈ to R₁₀ are each independently a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms, or R₉ and R₁₀ are combined with each other to form a ring,
n1 is an integer from 0 to 3,
n2 and n3 are each independently an integer from 0 to 4,
n4 and n6 are each independently an integer from 0 to 6, and
n5 and n7 are each independently an integer from 0 to 5.

2. The light emitting element of claim 1, wherein the first compound is represented by one of Formula 2-1 to Formula 2-5: 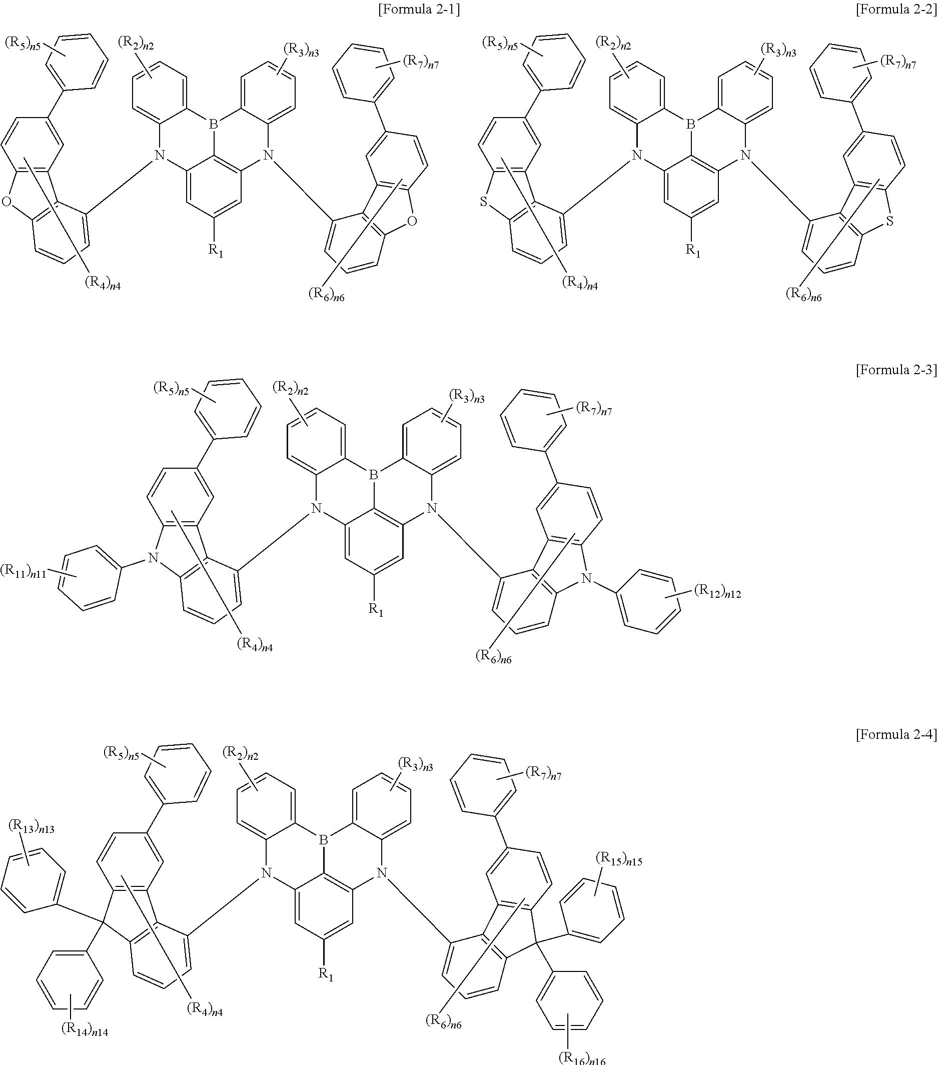 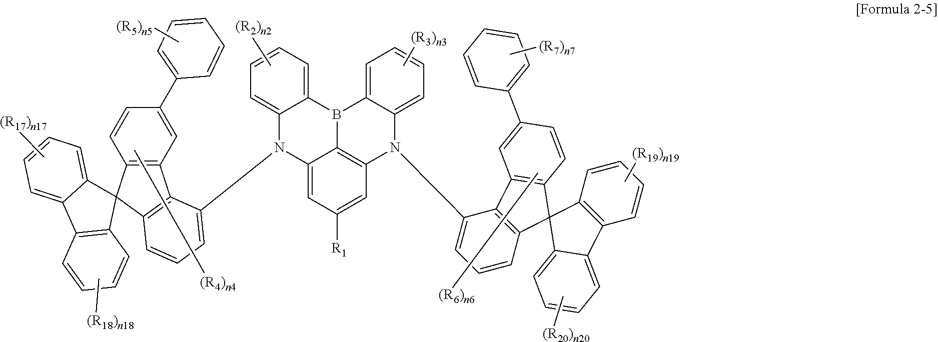
wherein in Formula 2-3 to Formula 2-5,
R₁₁ to R₂₀ are each independently a hydrogen atom, a deuterium atom, a substituted or unsubstituted alkyl group of 1 to 20 carbon atoms, or a substituted or unsubstituted aryl group of 3 to 20 ring-forming carbon atoms,
n11 to n16 are each independently an integer from 0 to 5, and
n17 to n20 are each independently an integer from 0 to 4, and
wherein in Formula 2-1 to Formula 2-5,
R₁ to R₇ and n2 to n7 are the same as defined in Formula 1.

3. The light emitting element of claim 1, wherein the first compound is represented by Formula 3: 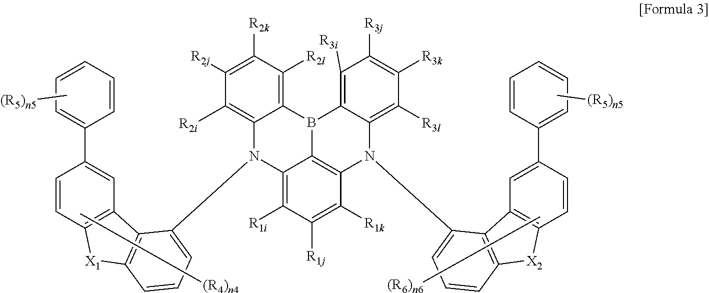
wherein in Formula 3,
at least one of R₁ᵢ, R₁ⱼ, and R₁ₖ is each independently a substituted or unsubstituted t-butyl group, a substituted or unsubstituted dibenzofuran group, a substituted or unsubstituted carbazole group, or a substituted or unsubstituted benzofurocarbazole group,
the remainder of R₁ᵢ, R₁ⱼ, and R₁ₖ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms,
at least one of R₂ᵢ, R₂ⱼ, R₂ₖ, R₂ₗ, R₃ᵢ, R₃ⱼ, R₃ₖ, and R₃ₗ is each independently a substituted or unsubstituted phenyl group or a substituted or unsubstituted carbazole group,
the remainder of R₂ᵢ, R₂ⱼ, R₂ₖ, R₂ₗ, R₃ᵢ, R₃ⱼ, R₃ₖ, and R₃ₗ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms, and
X₁, X₂, R₄ to R₇, and n4 to n7 are the same as defined in Formula 1.

4. The light emitting element of claim 1, wherein the first compound is represented by one of Formula 4-1 to Formula 4-3: 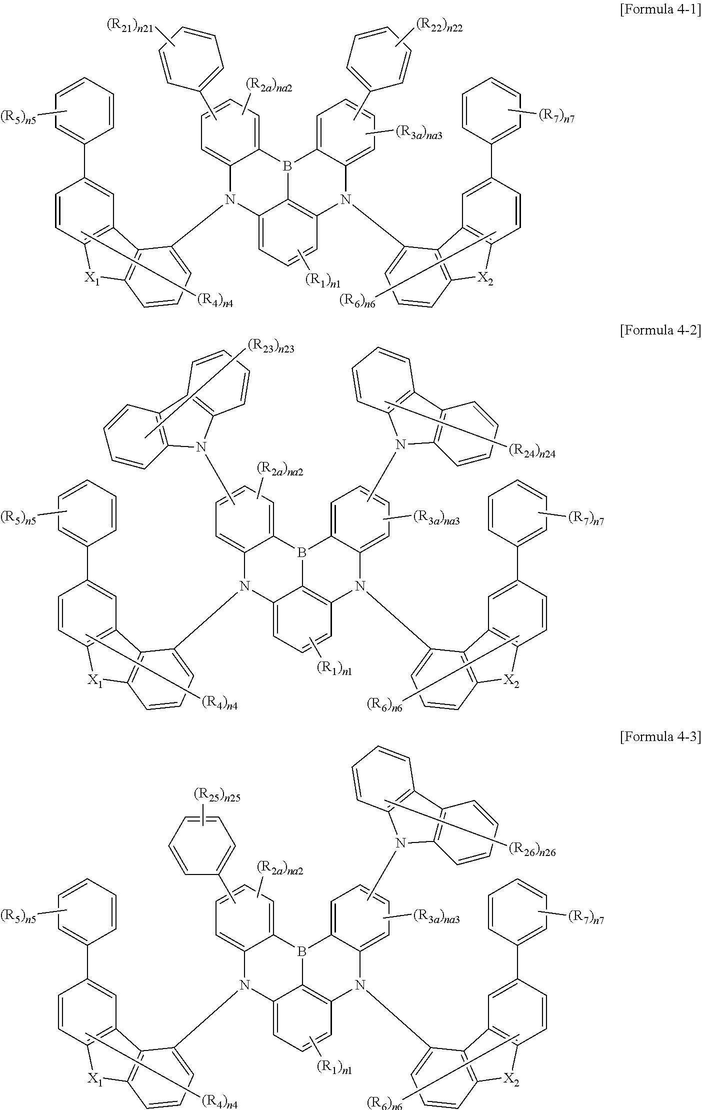
wherein in Formula 4-1 to Formula 4-3,
R₂₁ to R₂₆ are each independently a hydrogen atom, a deuterium atom, a cyano group, a substituted or unsubstituted alkyl group of 1 to 20 carbon atoms, or a substituted or unsubstituted aryl group of 3 to 20 ring-forming carbon atoms,
R₂ₐ and R₃ₐ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms,
n21, n22, and n25 are each independently an integer from 0 to 5,
n23, n24, and n26 are each independently an integer from 0 to 8,
na2 and na3 are each independently an integer from 0 to 3, and
X₁, X₂, R₁, R₄ to R₇, n1, and n4 to n7 are the same as defined in Formula 1.

5. The light emitting element of claim 4, wherein the first compound is represented by one of Formula 5-1 to Formula 5-4: 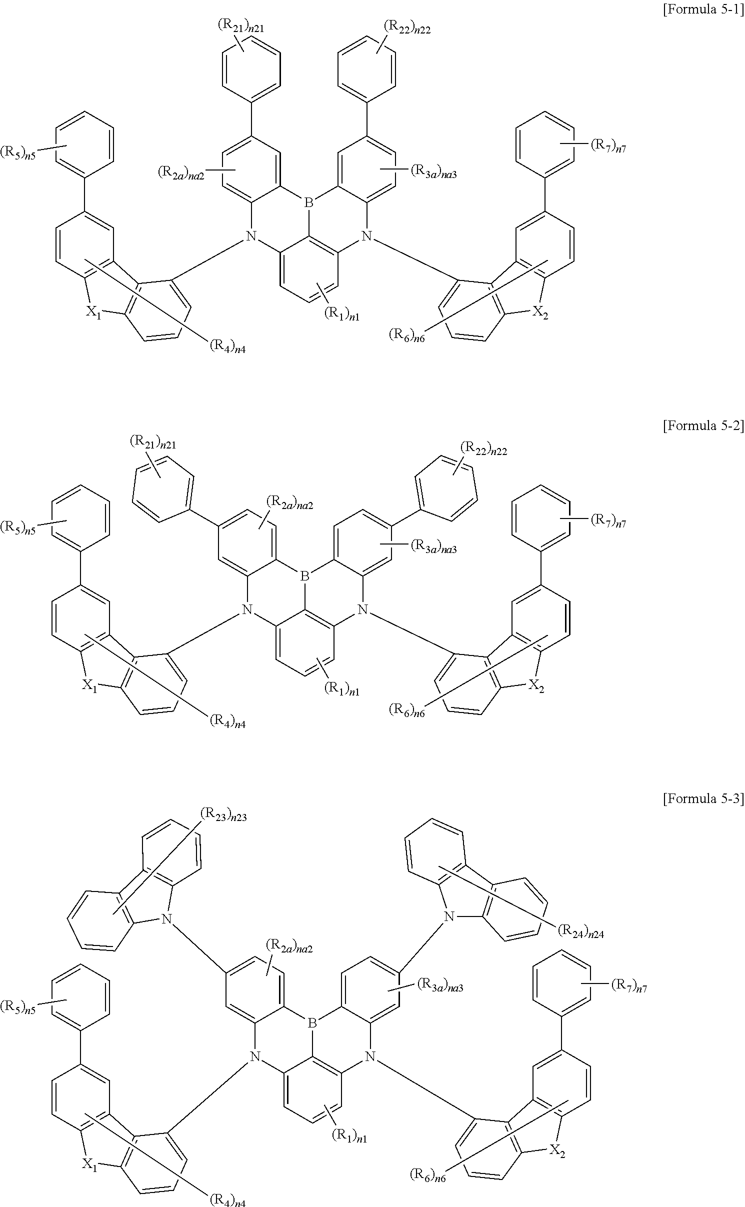 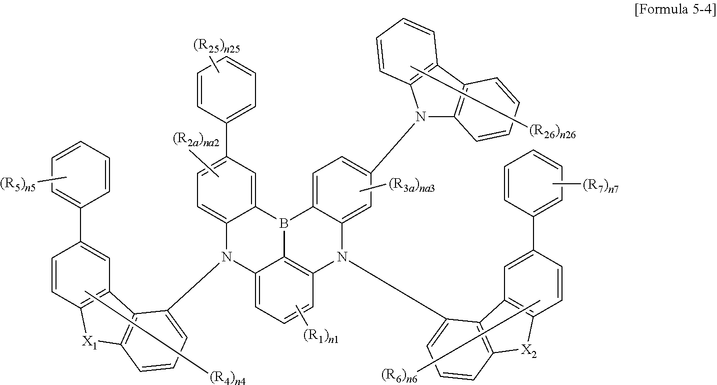
wherein in Formula 5-1 to Formula 5-4,
X₁, X₂, R₁, R₄ to R₇, n1, and n4 to n7 are the same as defined in Formula 1, and
R₂₁ to R₂₆, R₂ₐ, R₃ₐ, n21 to n26, na2, and na3 are the same as defined in Formula 4-1 to Formula 4-3.

6. The light emitting element of claim 1, wherein R₁ is a group represented by one of Formula RS-1 to Formula RS-5: 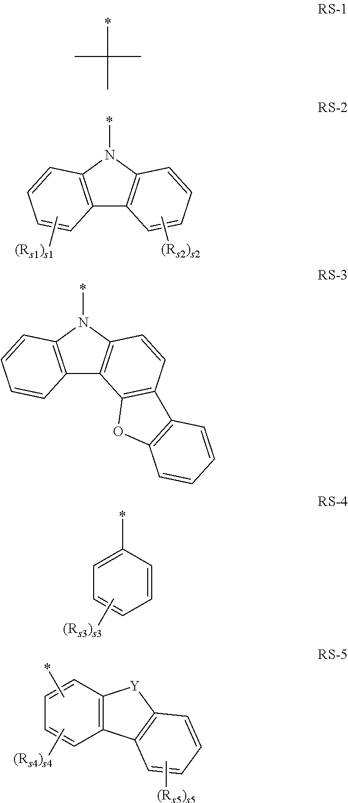
wherein in Formula RS-5,
Y is O or N(Rₛ₆), and
wherein in Formula RS-2, Formula RS-4, and Formula RS-5,
Rₛ₁ to Rₛ₆ are each independently a hydrogen atom, a deuterium atom, a cyano group, a substituted or unsubstituted alkyl group of 1 to 10 carbon atoms, or a substituted or unsubstituted aryl group of 6 to 10 ring-forming carbon atoms,
s1, s2, and s5 are each independently an integer from 0 to 4,
s3 is an integer from 0 to 5, and
s4 is an integer from 0 to 3.

7. The light emitting element of claim 1, wherein R₄ to R₇ are each independently a hydrogen atom, a deuterium atom, a substituted or unsubstituted t-butyl group, or a substituted or unsubstituted phenyl group.

8. The light emitting element of claim 1, wherein the emission layer further comprises at least one of a second compound represented by Formula HT and a third compound represented by Formula ET: 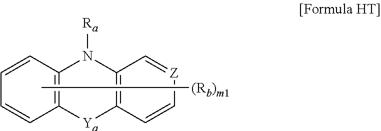
wherein in Formula HT,
Rₐ and R_{b} are each independently a hydrogen atom, a deuterium atom, a cyano group, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring,
m1 is an integer from 0 to 7,
Yₐ is a direct linkage, C(R_{y1})(R_{y2}), or Si(R_{y3})(R_{y4}),
Z is C(R_{z}) or N,
R_{y1} to R_{y4} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, and
R_{z} is a hydrogen atom or a deuterium atom, 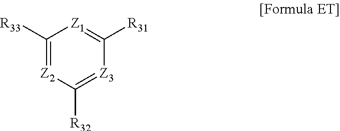
wherein in Formula ET,
Z₁ to Z₃ are each independently N or C(R₃₄),
at least one of Z₁ to Z₃ is each N, and
R₃₁ to R₃₄ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring.

9. The light emitting element of claim 8, wherein the emission layer further comprises a fourth compound represented by Formula PS: 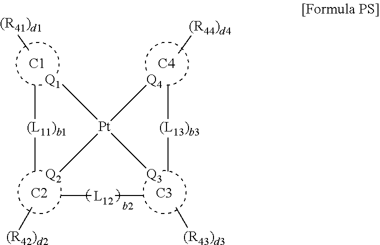
wherein in Formula,
Q₁ to Q₄ are each independently C or N,
C1 to C4 are each independently a substituted or unsubstituted hydrocarbon ring of 5 to 30 ring-forming carbon atoms or a substituted or unsubstituted heterocycle of 2 to 30 ring-forming carbon atoms,
L₁₁ to L₁₃ are each independently a direct linkage, 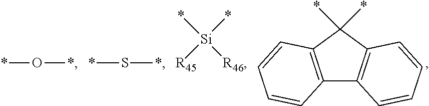
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₄₁ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, or combined with an adjacent group to form a ring, and
d1 to d4 are each independently an integer from 0 to 4.

10. The light emitting element of claim 8, wherein the emission layer comprises the first compound, the second compound, and the third compound.

11. The light emitting element of claim 9, wherein the emission layer comprises the first compound, the second compound, the third compound, and the fourth compound.

12. The light emitting element of claim 1, wherein the first compound comprises at least one compound selected from Compound Group 1: 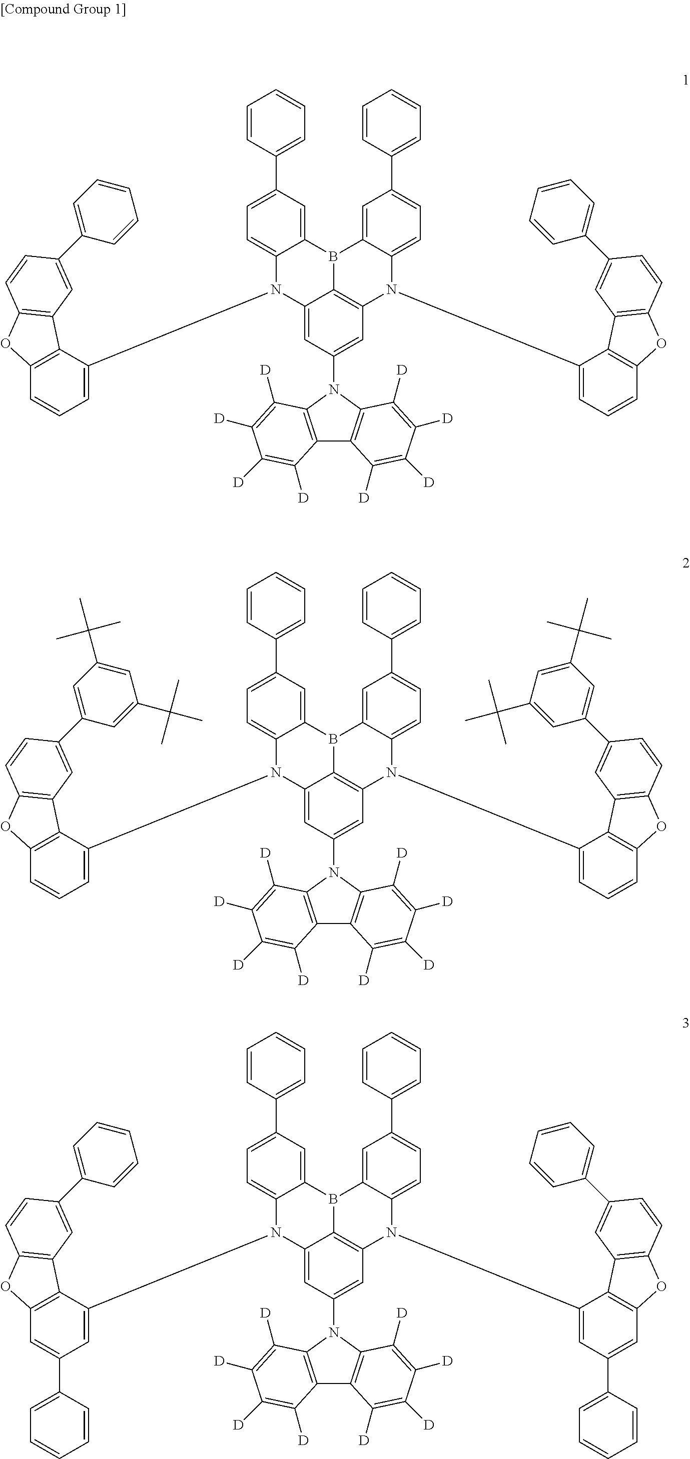 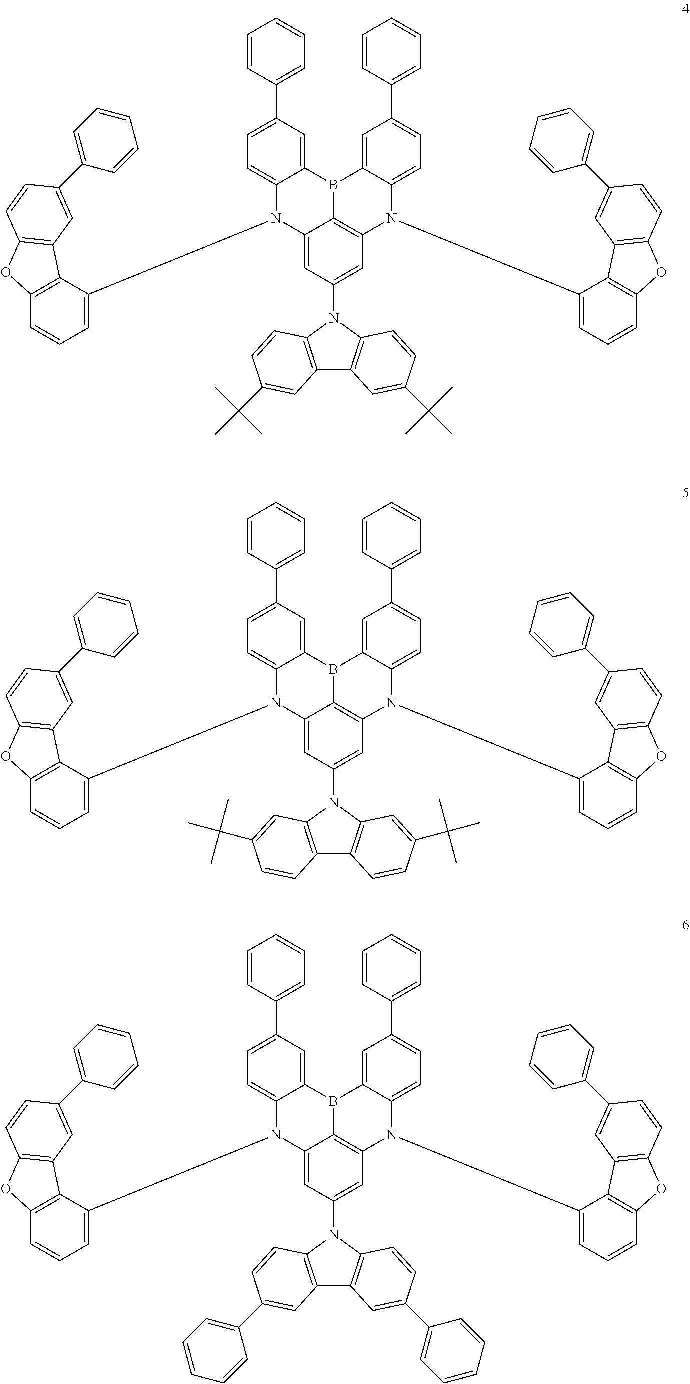 [SMILES: CC(C)(C)c1ccc2c(c1)c1cc(C(C)(C)C)ccc1n2-c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1ccc2c3ccc(C(C)(C)C)cc3n(-c3cc4c5c(c3)N(c3cccc6oc7ccc(-c8ccccc8)cc7c36)c3ccc(-c6ccccc6)cc3B5c3cc(-c5ccccc5)ccc3N4c3cccc4oc5ccc(-c6ccccc6)cc5c34)c2c1 ; c1ccc(-c2ccc3c(c2)B2c4cc(-c5ccccc5)ccc4N(c4cccc5oc6ccc(-c7ccccc7)cc6c45)c4cc(-n5c6ccc(-c7ccccc7)cc6c6cc(-c7ccccc7)ccc65)cc(c42)N3c2cccc3oc4ccc(-c5ccccc5)cc4c23)cc1] 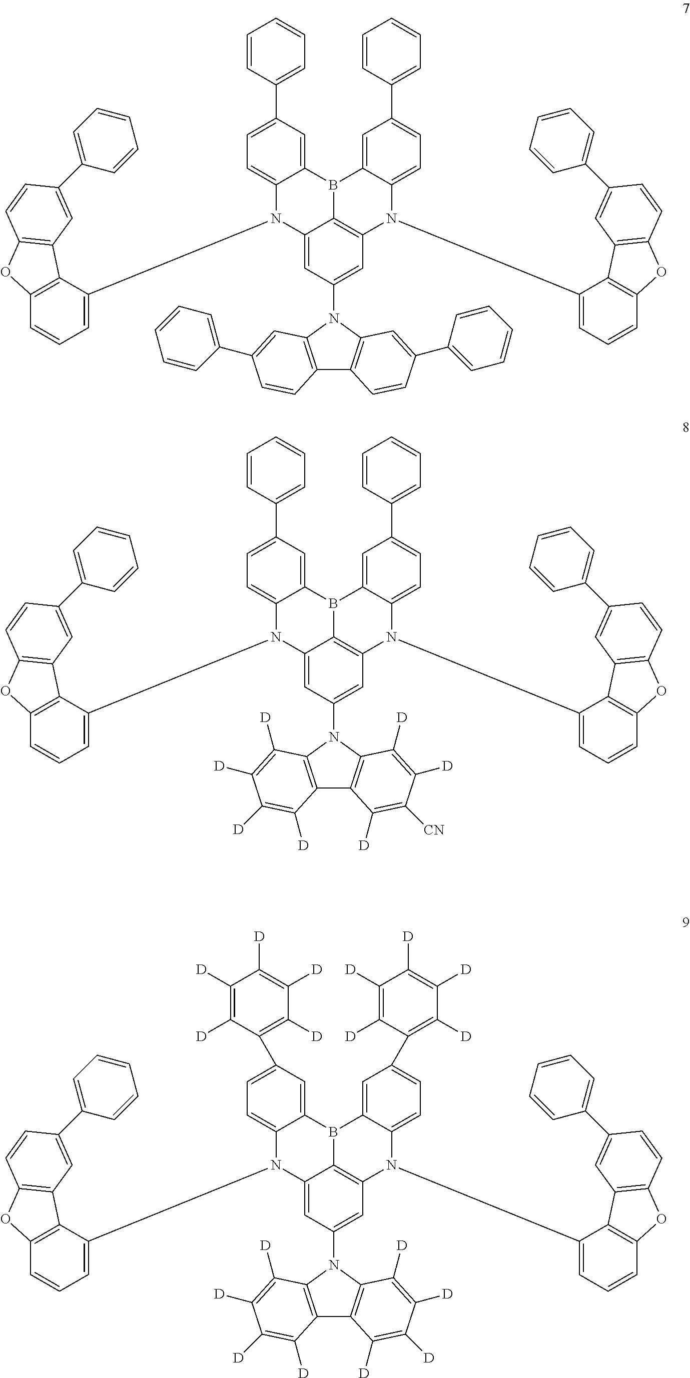 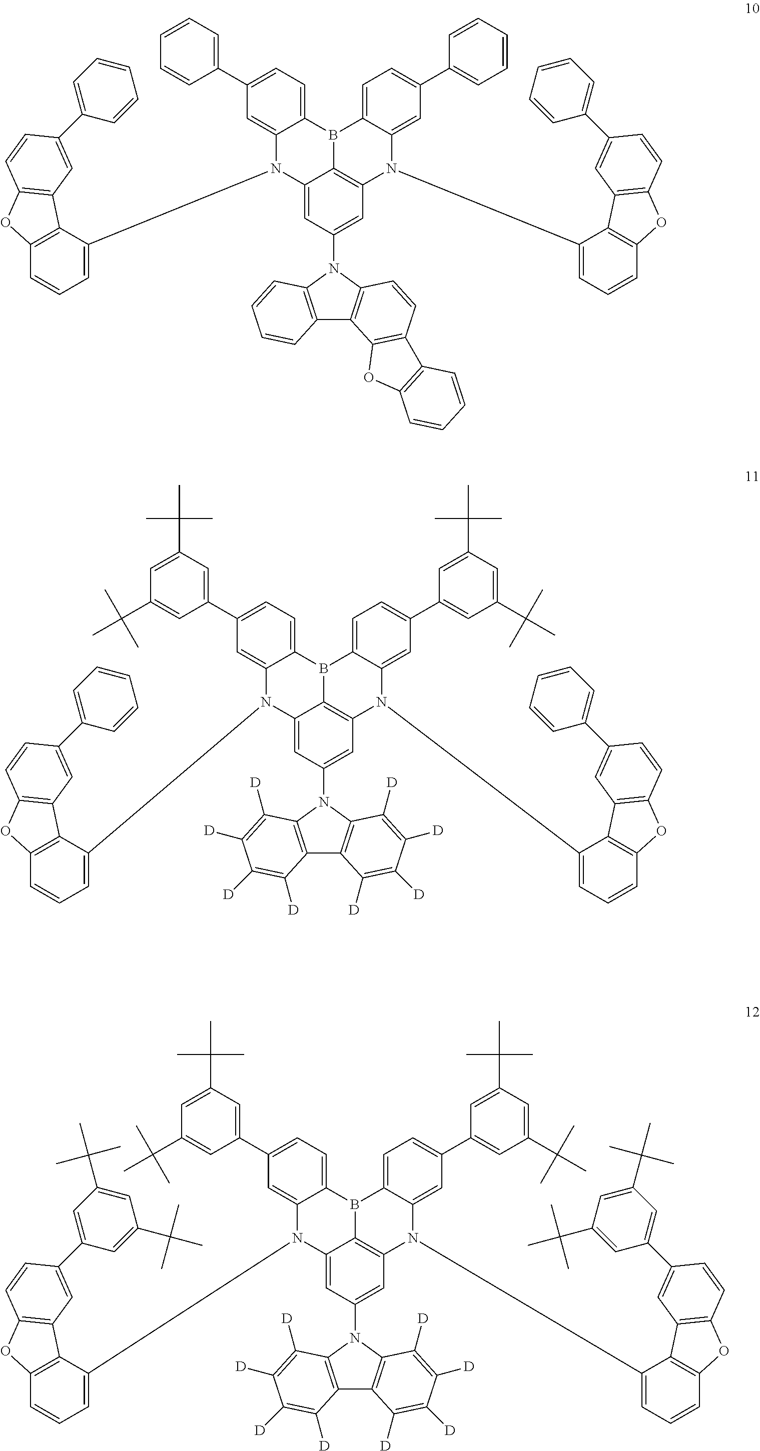 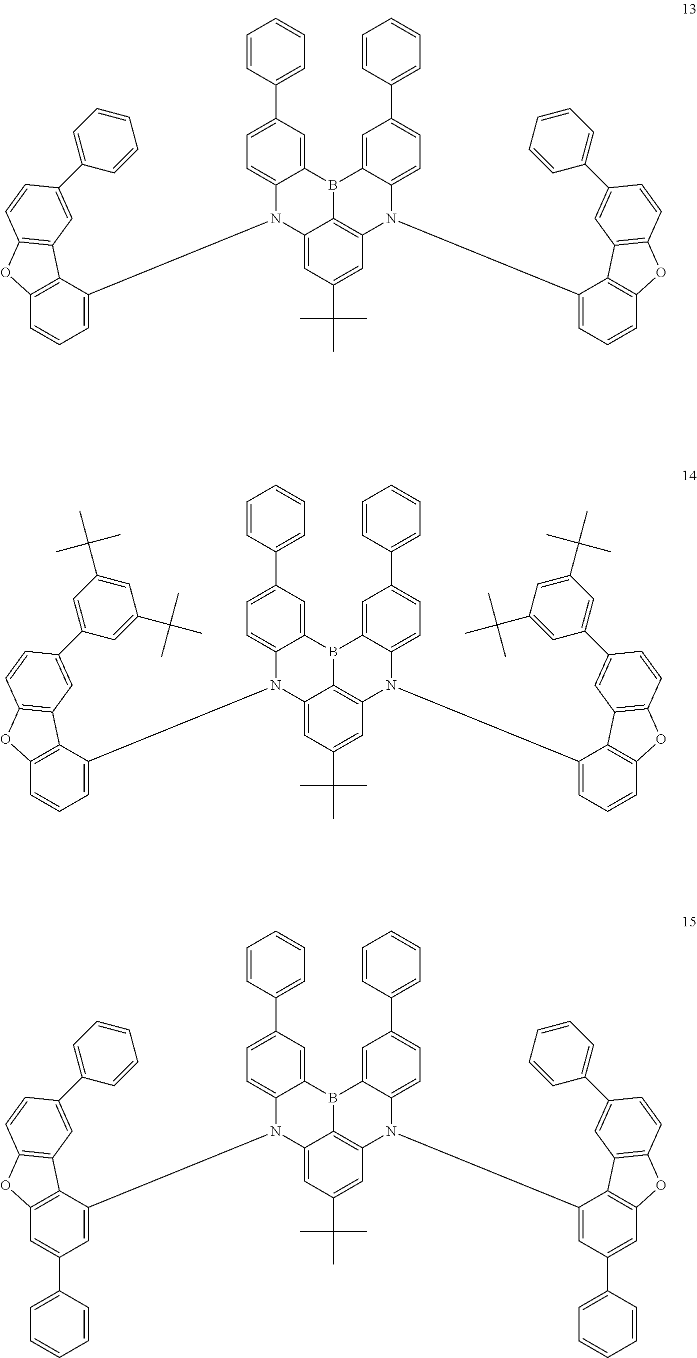 [SMILES: CC(C)(C)c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1cc(-c2ccc3oc4cccc(N5c6ccc(-c7ccccc7)cc6B6c7cc(-c8ccccc8)ccc7N(c7cccc8oc9ccc(-c%10cc(C(C)(C)C)cc(C(C)(C)C)c%10)cc9c78)c7cc(C(C)(C)C)cc5c76)c4c3c2)cc(C(C)(C)C)c1 ; CC(C)(C)c1cc2c3c(c1)N(c1cc(-c4ccccc4)cc4oc5ccc(-c6ccccc6)cc5c14)c1ccc(-c4ccccc4)cc1B3c1cc(-c3ccccc3)ccc1N2c1cc(-c2ccccc2)cc2oc3ccc(-c4ccccc4)cc3c12] 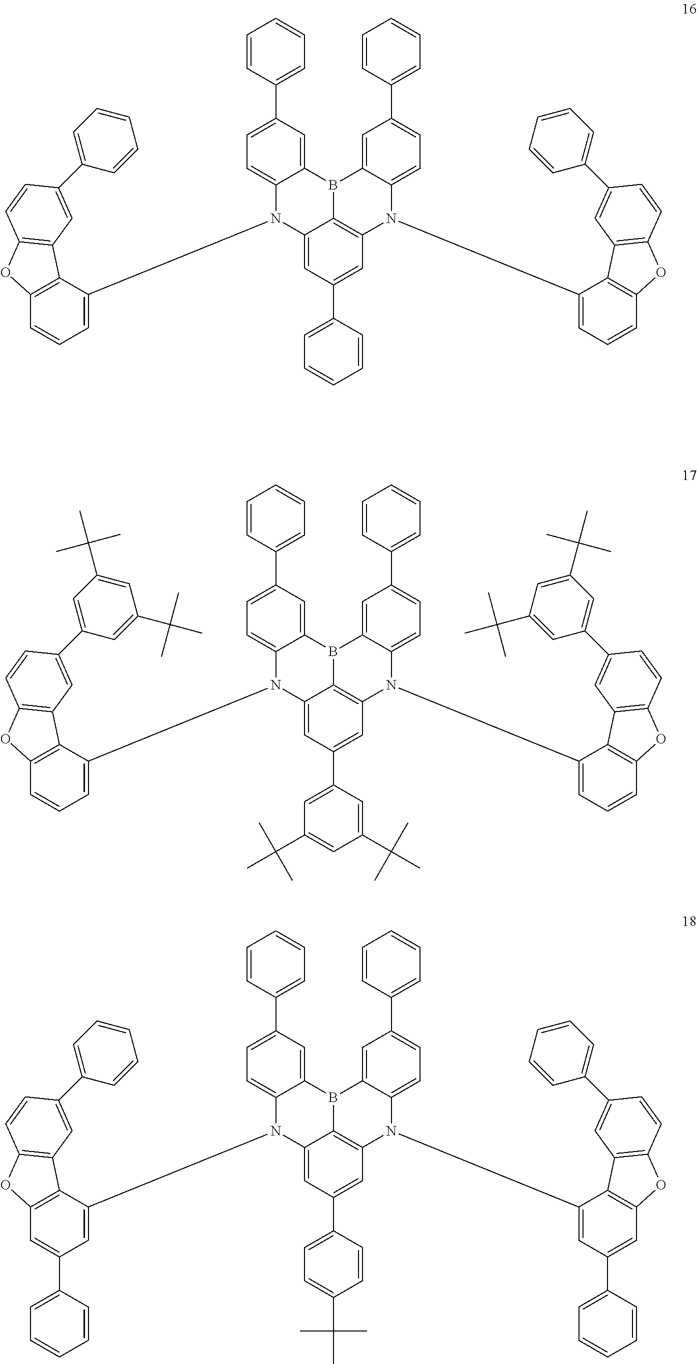 [SMILES: c1ccc(-c2ccc3c(c2)B2c4cc(-c5ccccc5)ccc4N(c4cccc5oc6ccc(-c7ccccc7)cc6c45)c4cc(-c5ccccc5)cc(c42)N3c2cccc3oc4ccc(-c5ccccc5)cc4c23)cc1 ; CC(C)(C)c1cc(-c2cc3c4c(c2)N(c2cccc5oc6ccc(-c7cc(C(C)(C)C)cc(C(C)(C)C)c7)cc6c25)c2ccc(-c5ccccc5)cc2B4c2cc(-c4ccccc4)ccc2N3c2cccc3oc4ccc(-c5cc(C(C)(C)C)cc(C(C)(C)C)c5)cc4c23)cc(C(C)(C)C)c1 ; CC(C)(C)c1ccc(-c2cc3c4c(c2)N(c2cc(-c5ccccc5)cc5oc6ccc(-c7ccccc7)cc6c25)c2ccc(-c5ccccc5)cc2B4c2cc(-c4ccccc4)ccc2N3c2cc(-c3ccccc3)cc3oc4ccc(-c5ccccc5)cc4c23)cc1] 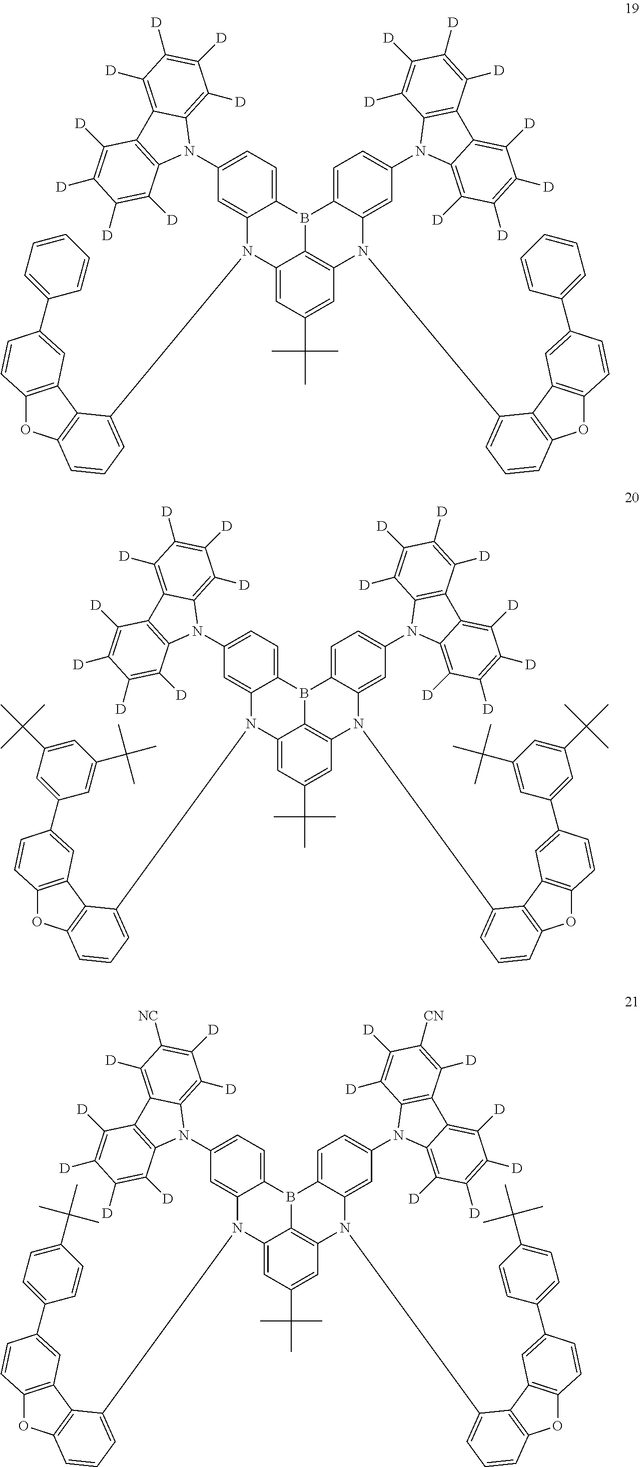 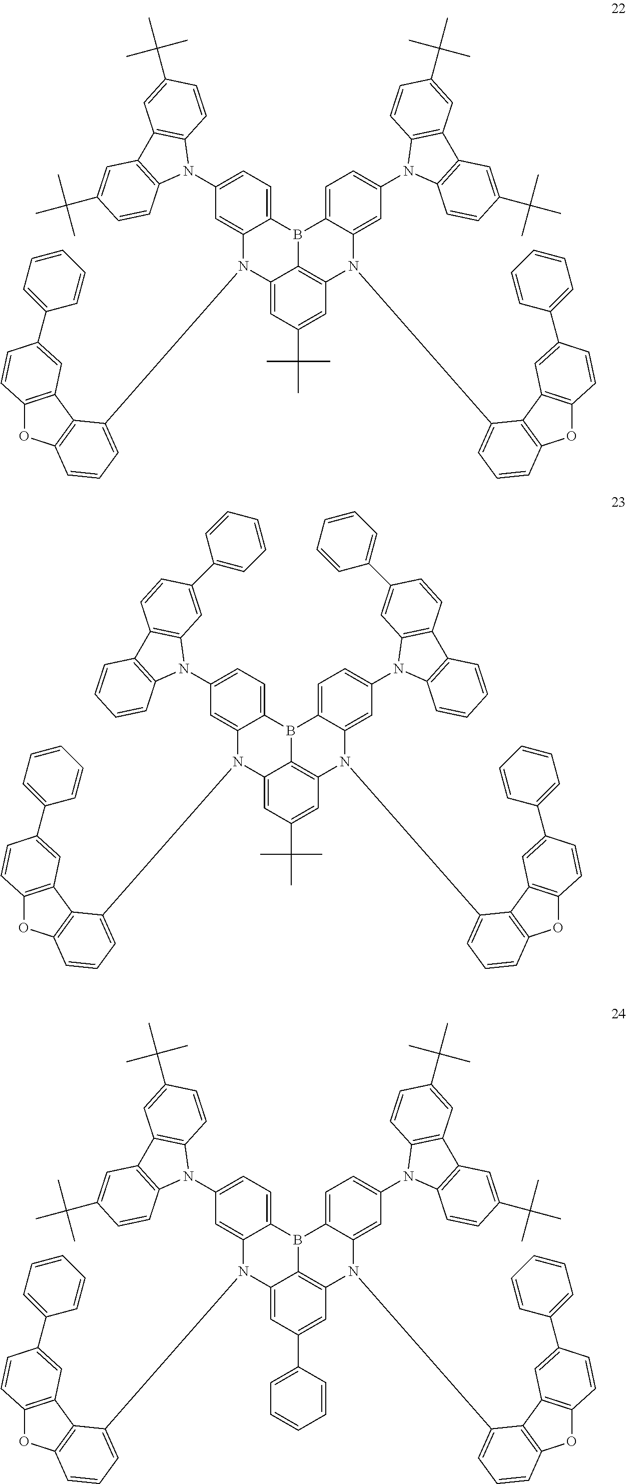 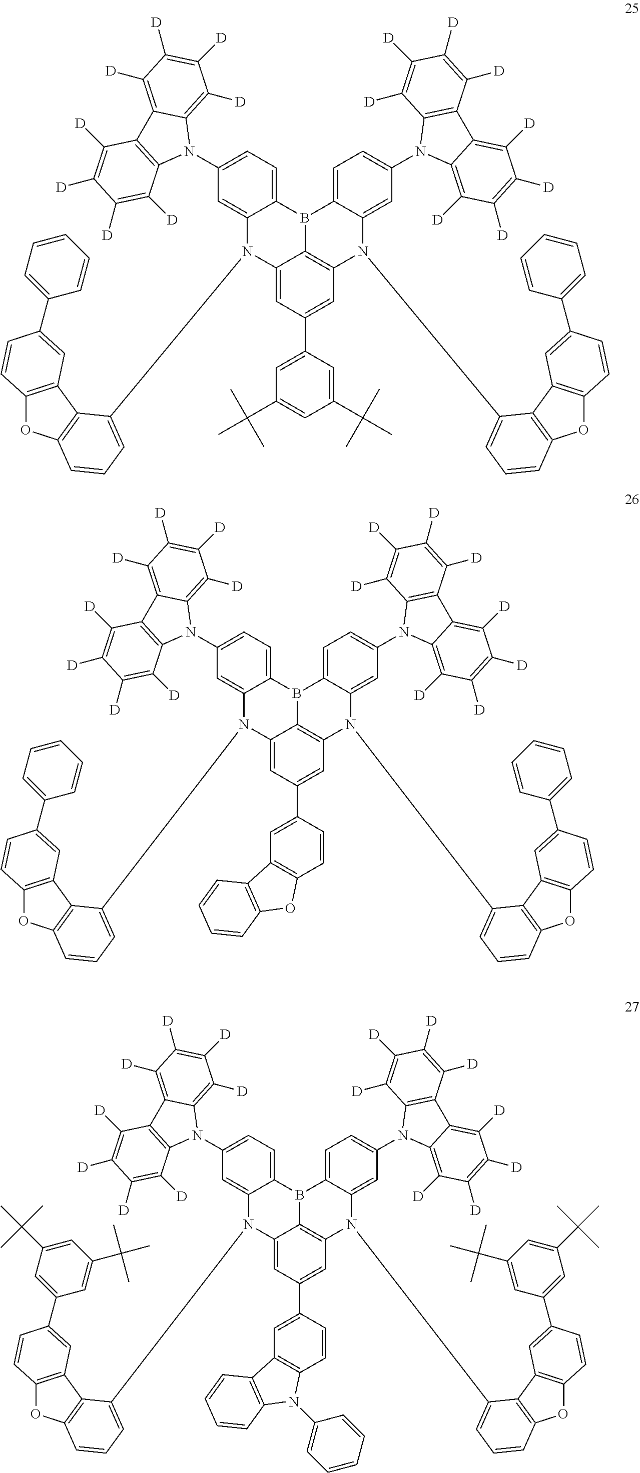 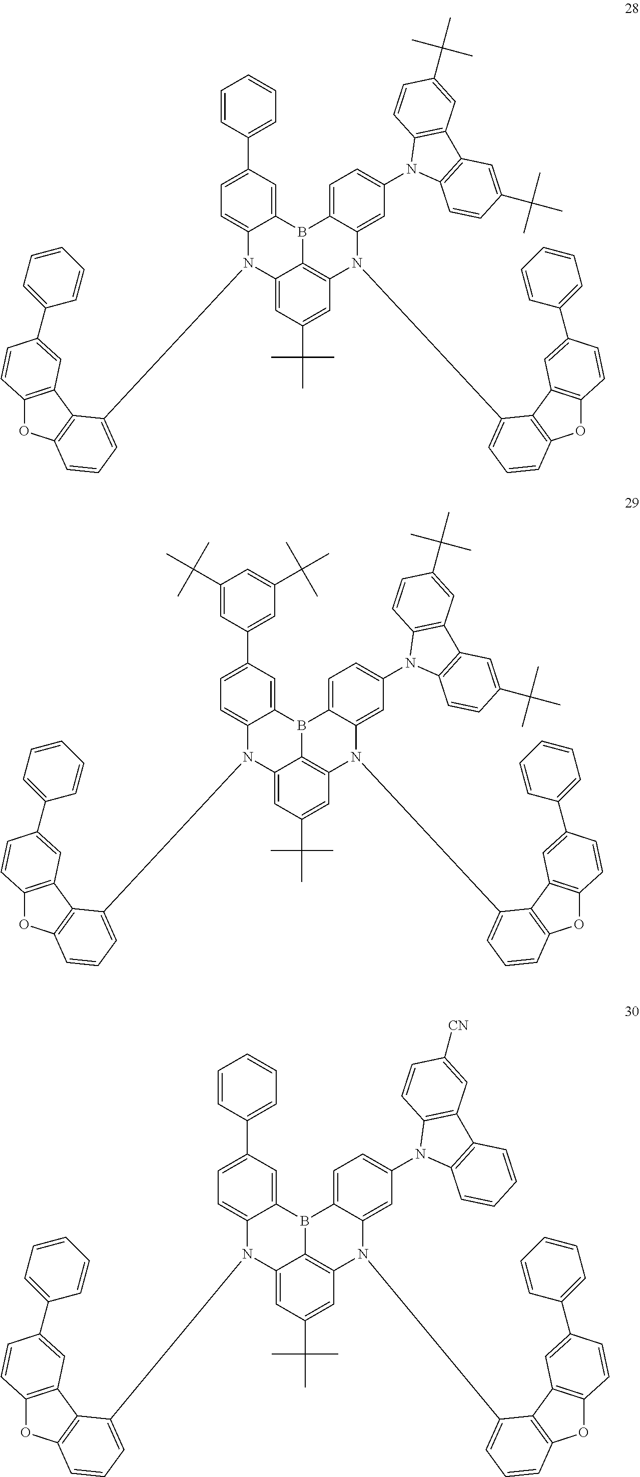 [SMILES: CC(C)(C)c1cc2c3c(c1)N(c1cccc4oc5ccc(-c6ccccc6)cc5c14)c1cc(-n4c5ccc(C(C)(C)C)cc5c5cc(C(C)(C)C)ccc54)ccc1B3c1cc(-c3ccccc3)ccc1N2c1cccc2oc3ccc(-c4ccccc4)cc3c12 ; CC(C)(C)c1cc(-c2ccc3c(c2)B2c4ccc(-n5c6ccc(C(C)(C)C)cc6c6cc(C(C)(C)C)ccc65)cc4N(c4cccc5oc6ccc(-c7ccccc7)cc6c45)c4cc(C(C)(C)C)cc(c42)N3c2cccc3oc4ccc(-c5ccccc5)cc4c23)cc(C(C)(C)C)c1 ; CC(C)(C)c1cc2c3c(c1)N(c1cccc4oc5ccc(-c6ccccc6)cc5c14)c1cc(-n4c5ccccc5c5cc(C#N)ccc54)ccc1B3c1cc(-c3ccccc3)ccc1N2c1cccc2oc3ccc(-c4ccccc4)cc3c12] 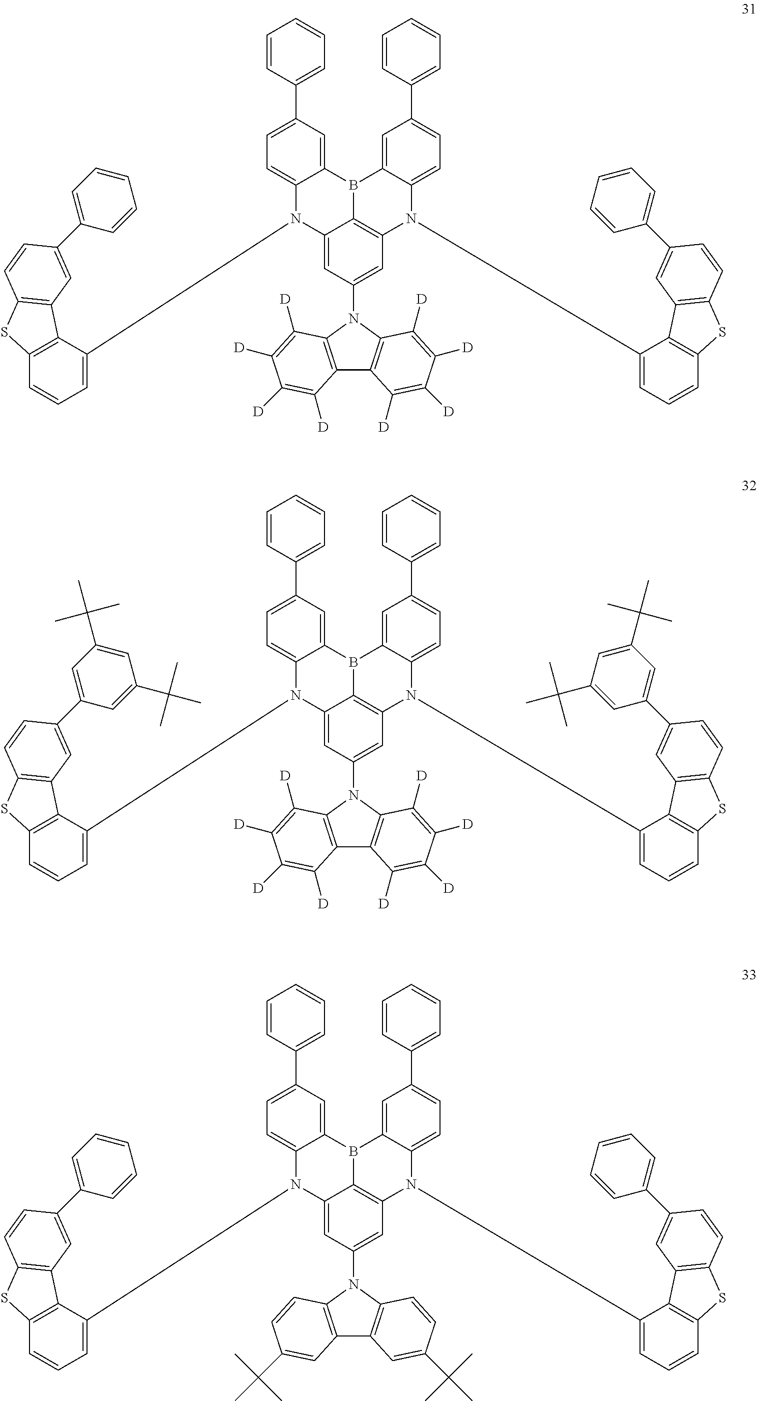 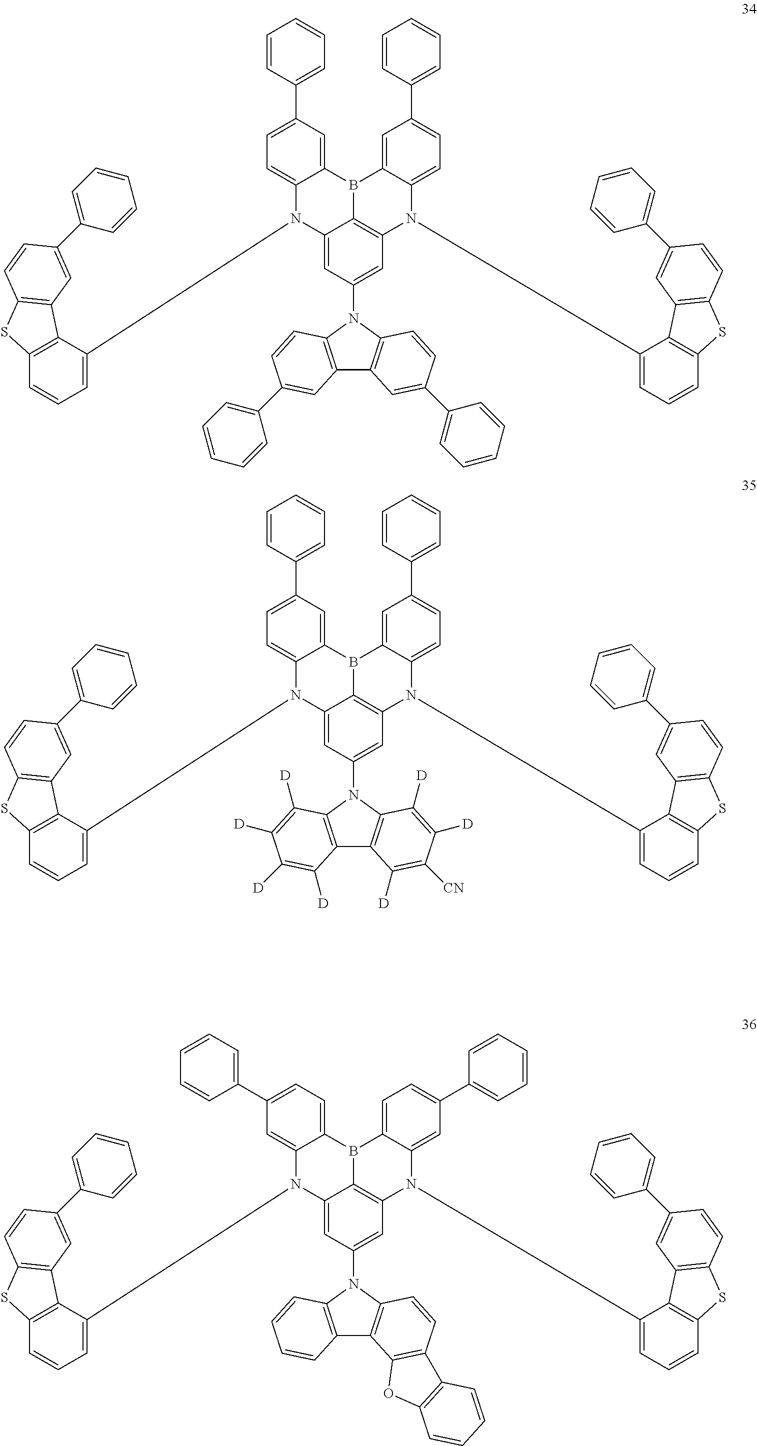 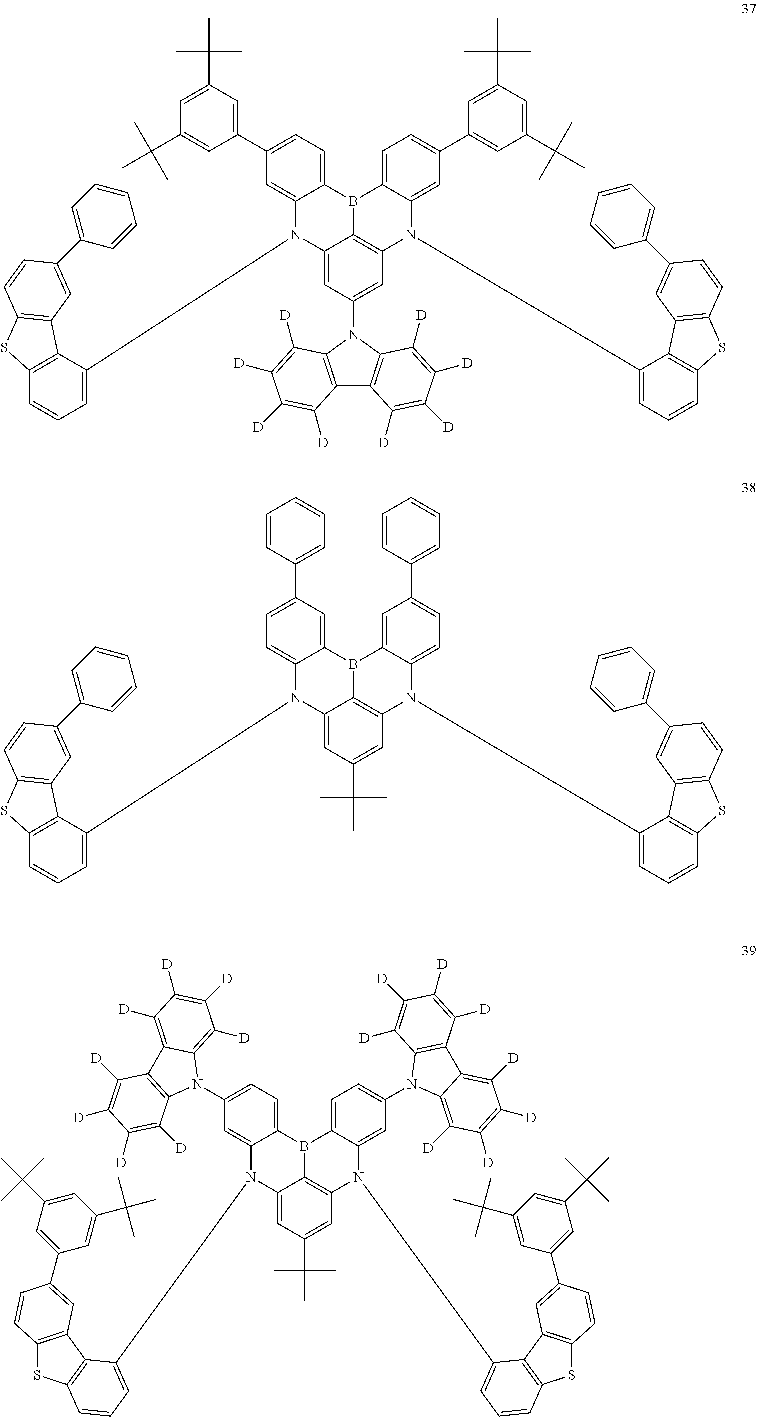 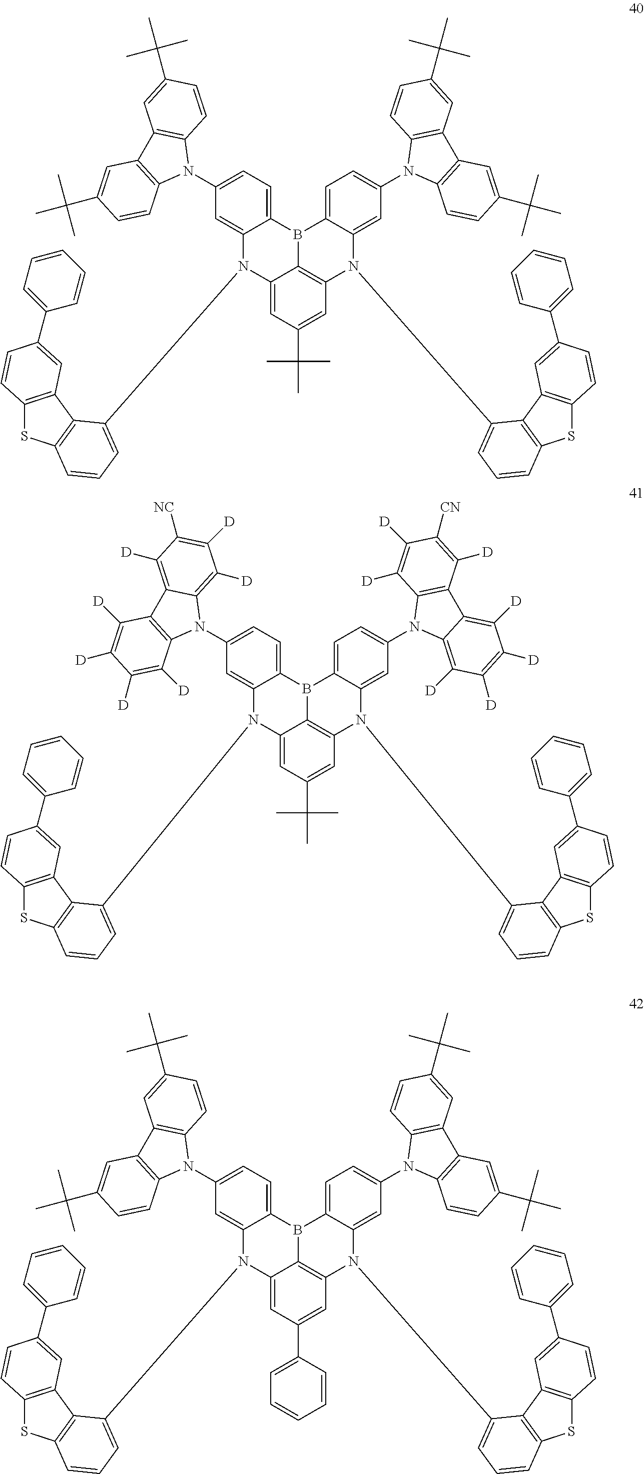 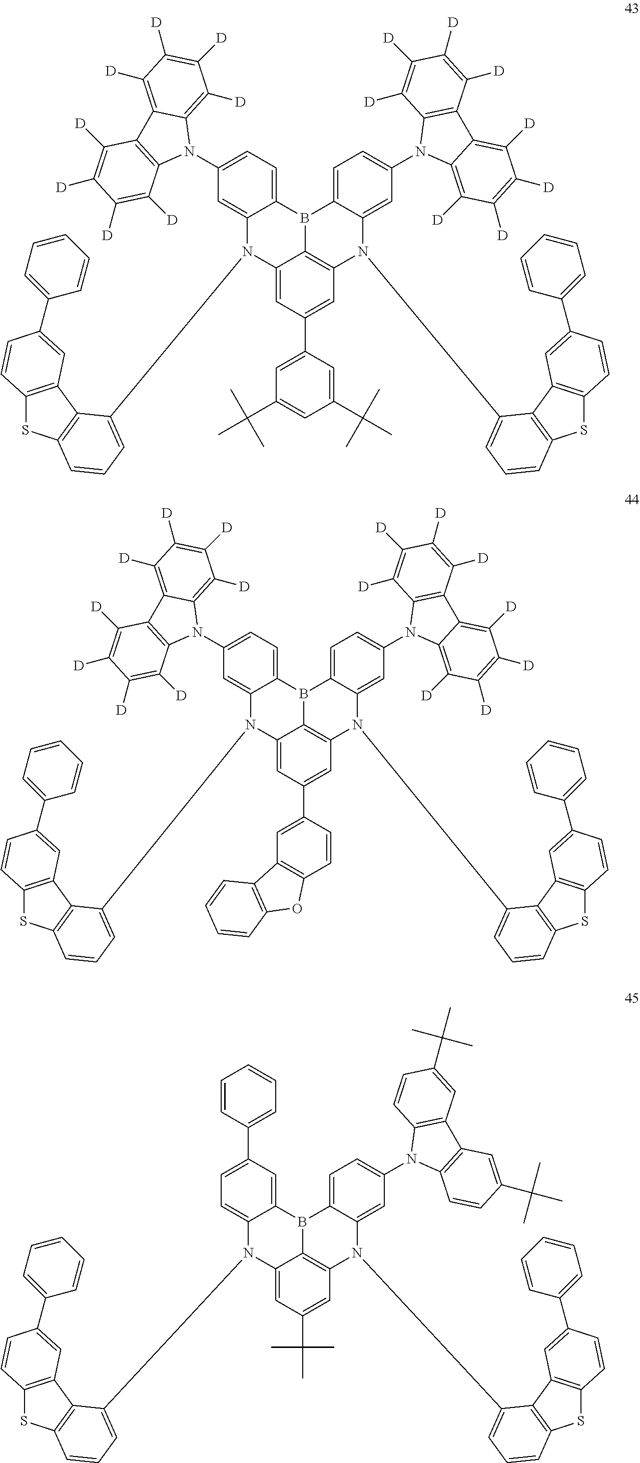 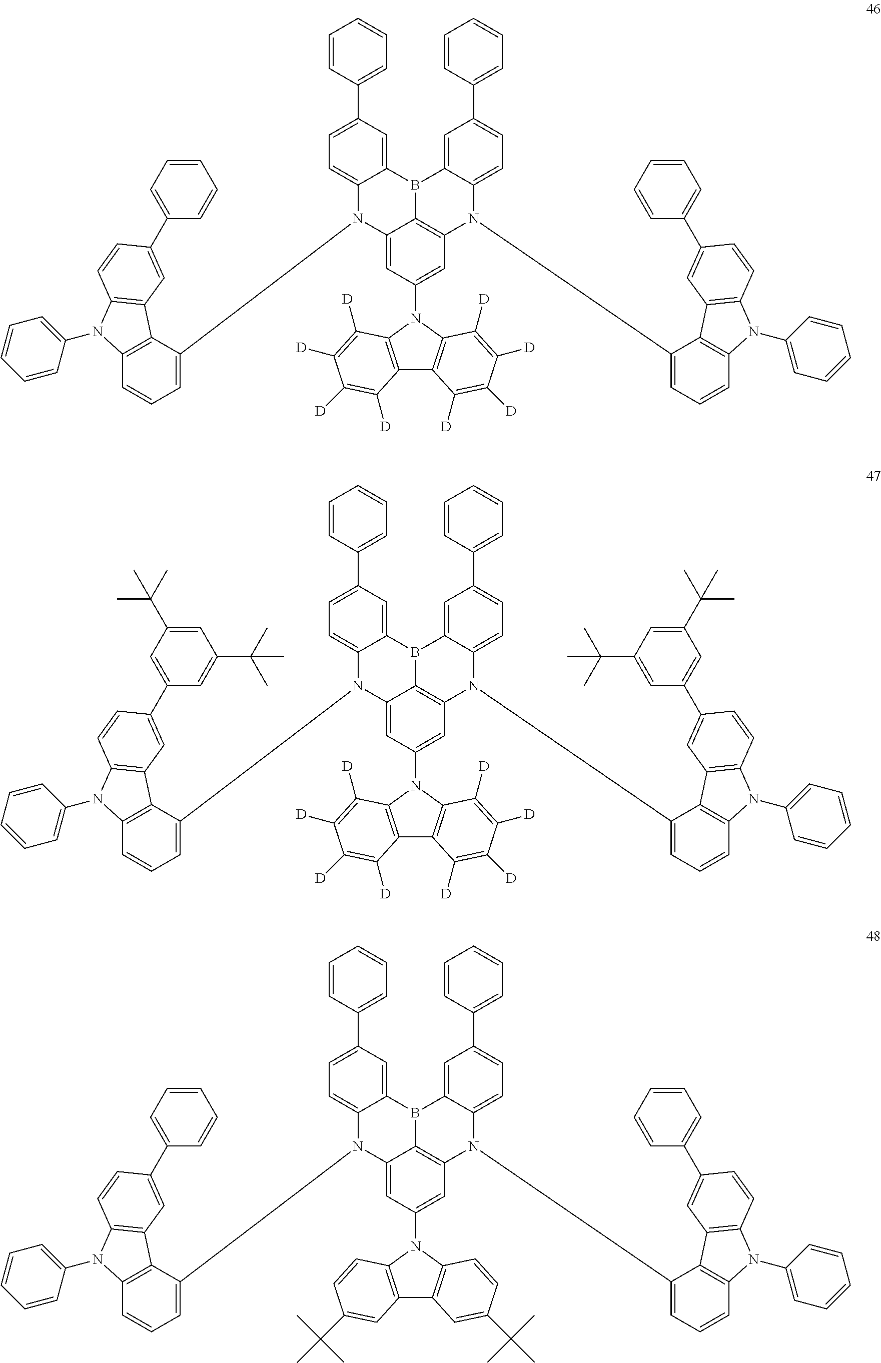 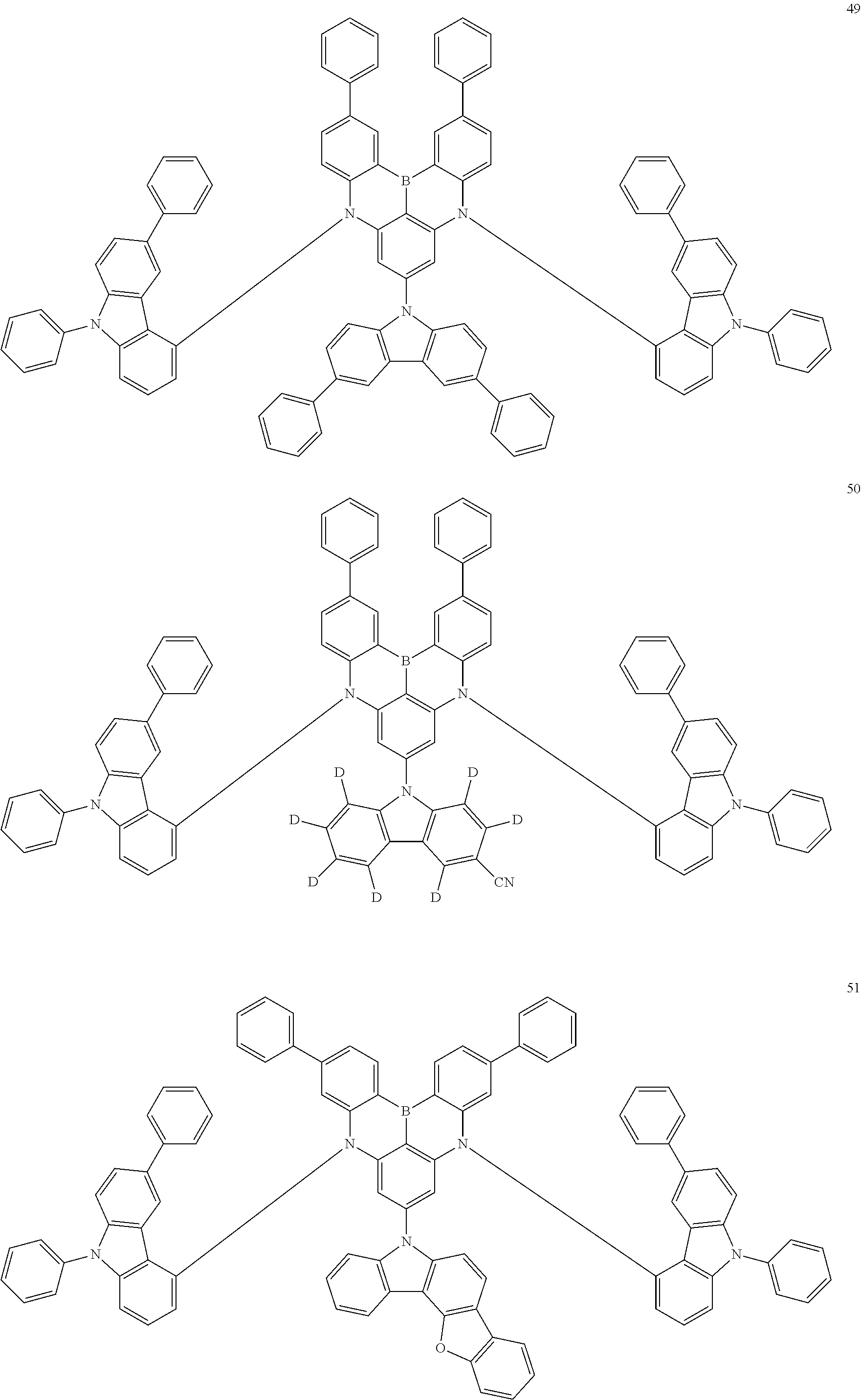 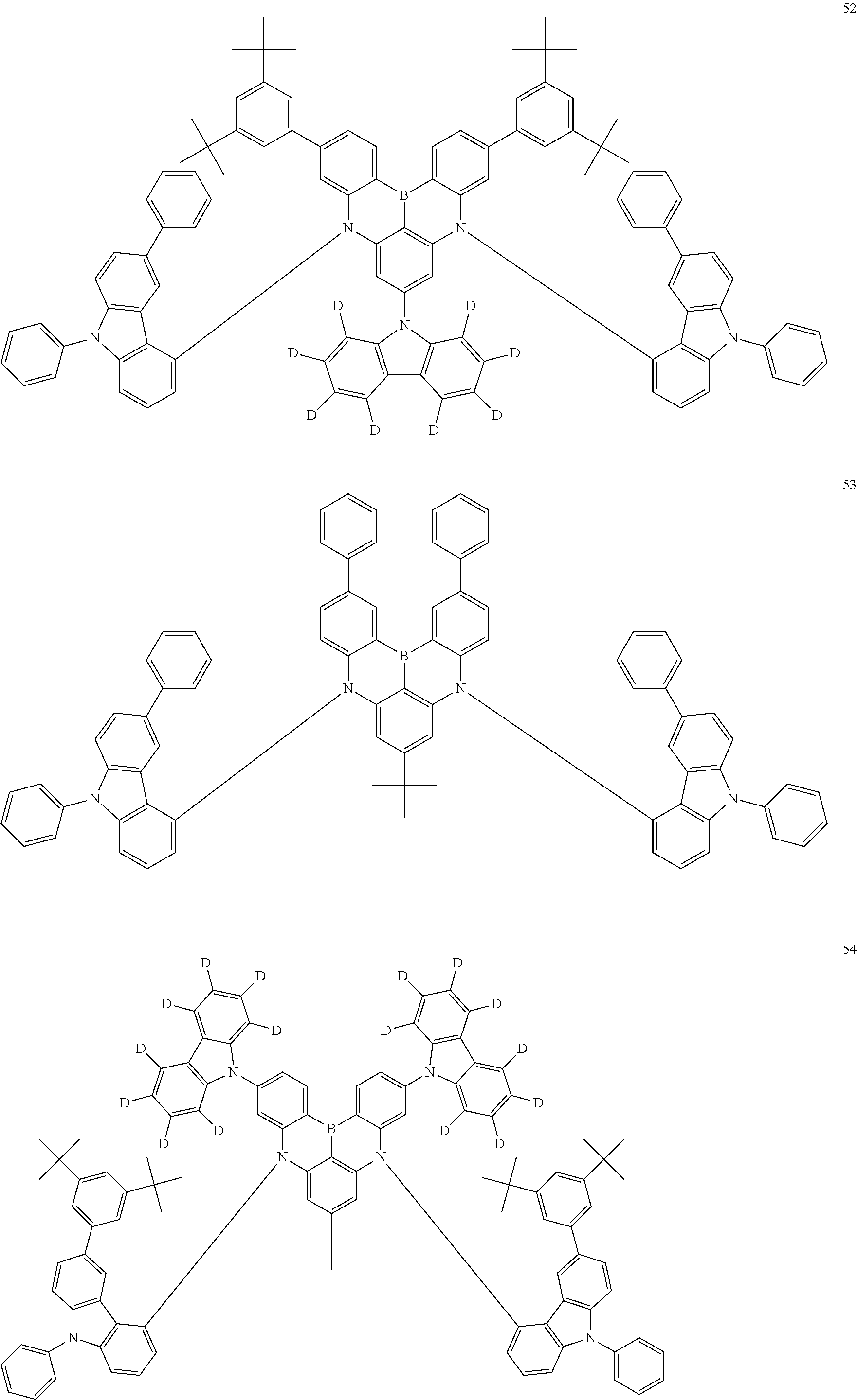 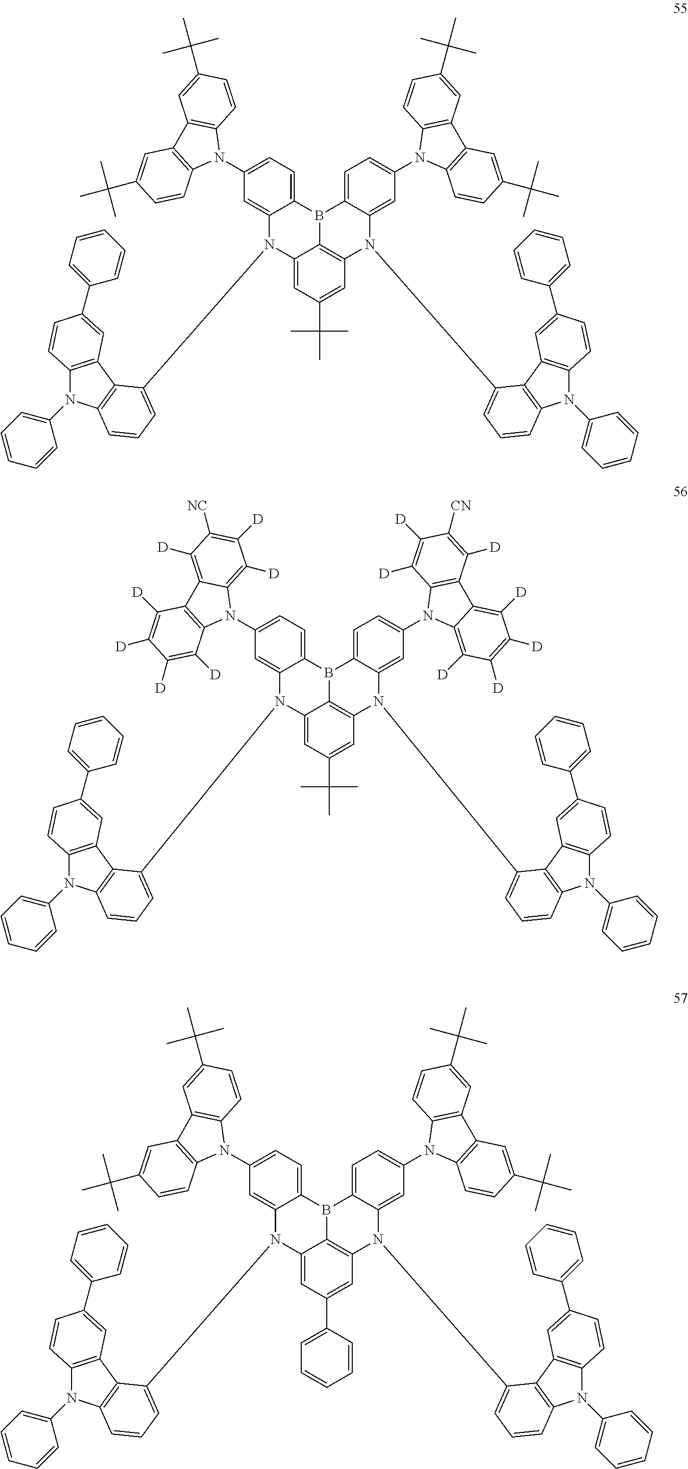 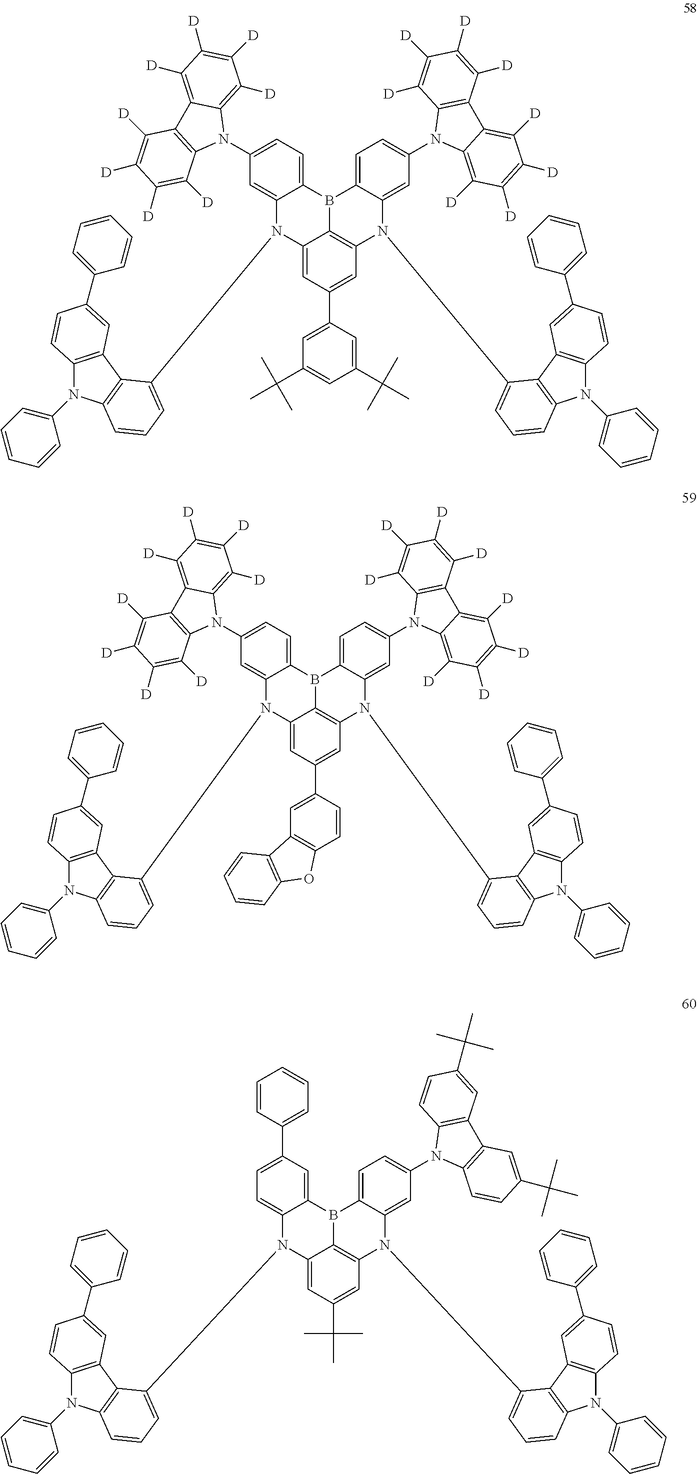 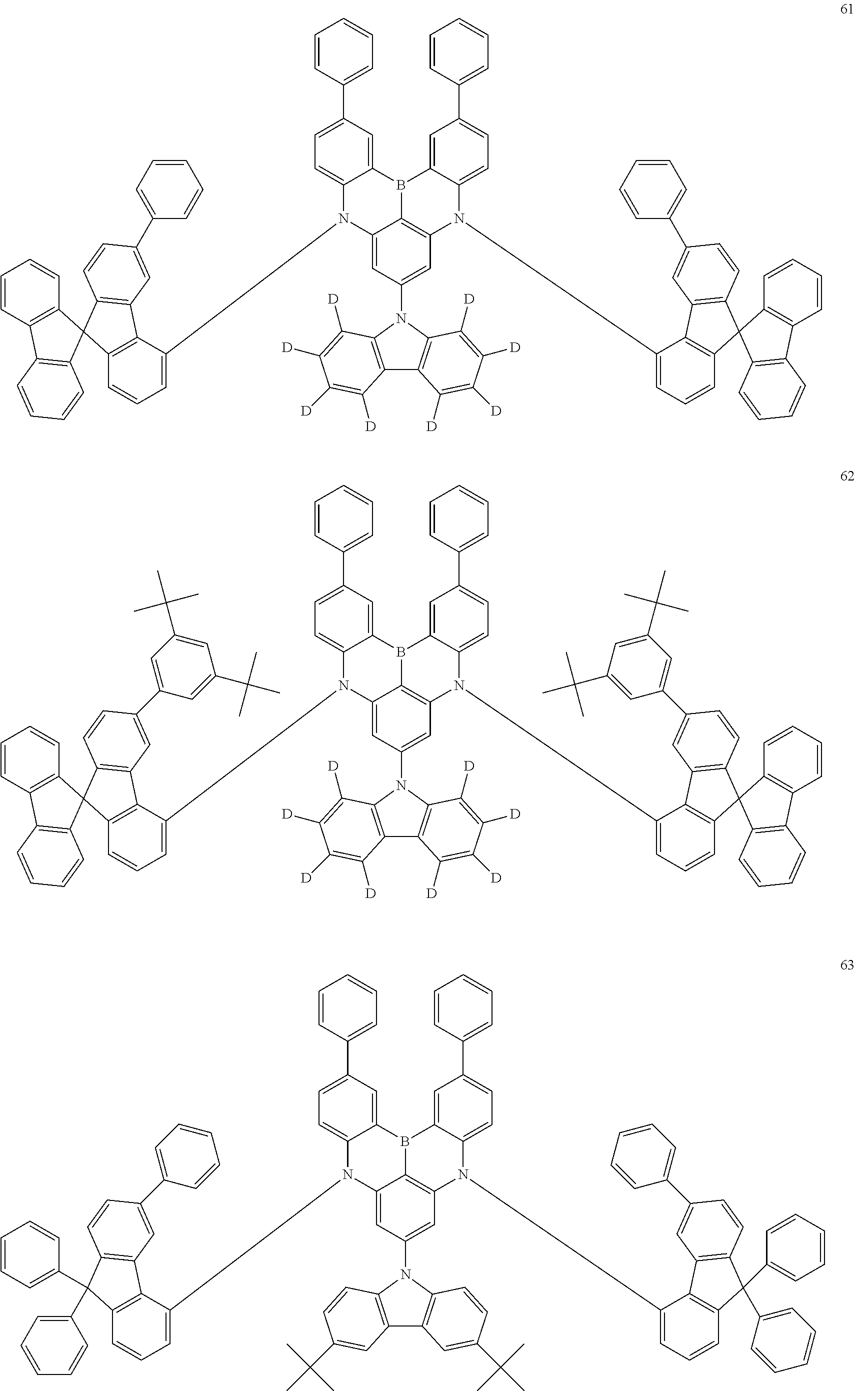 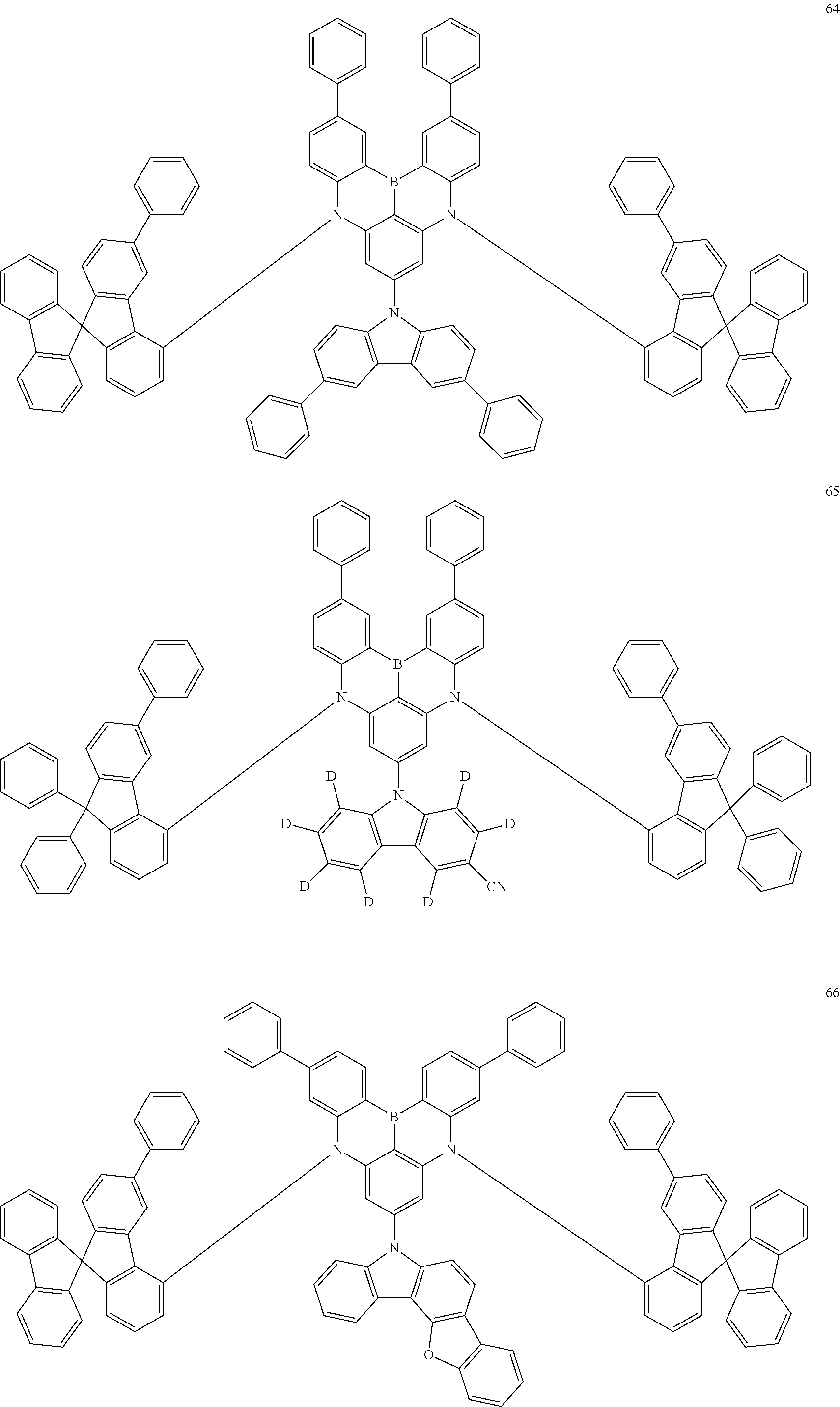 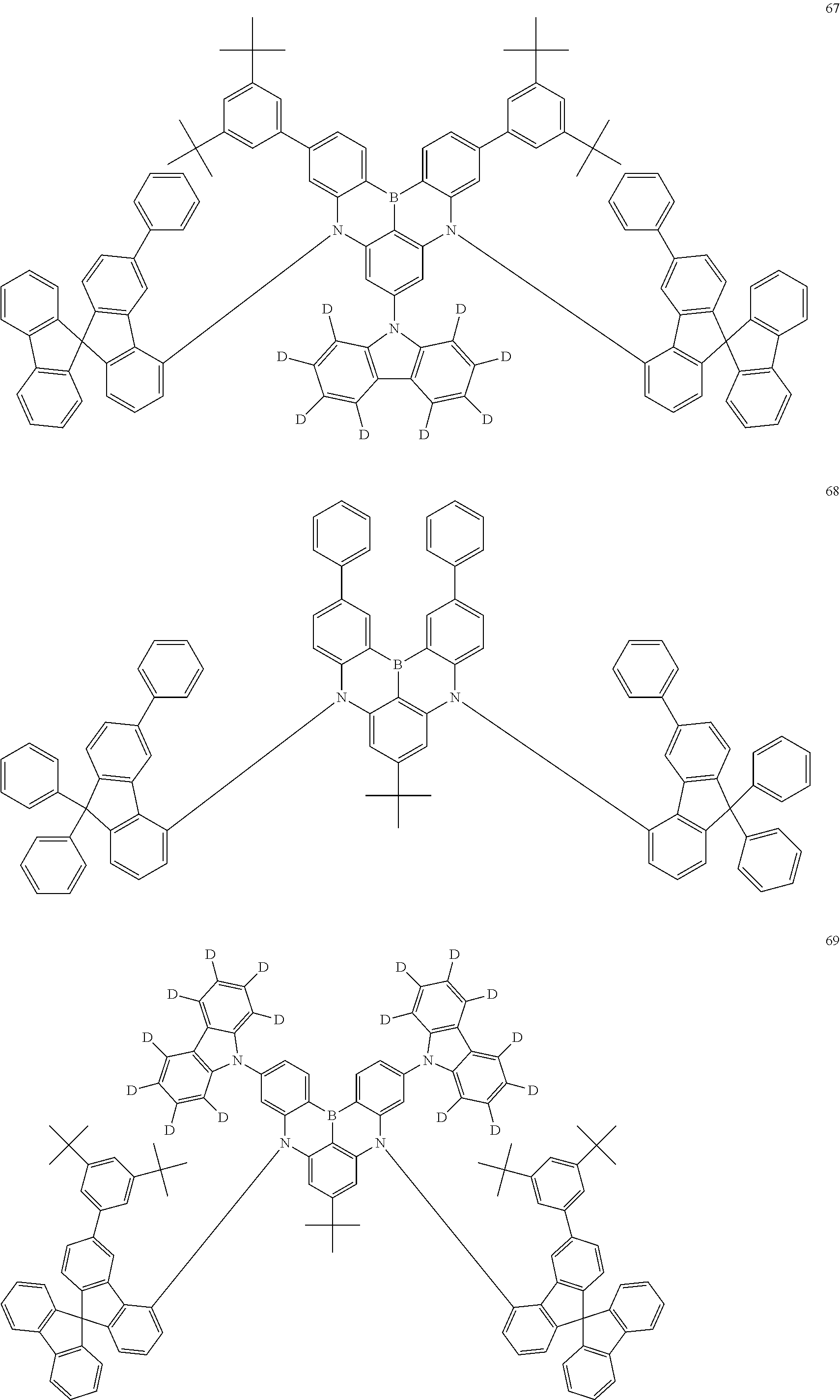 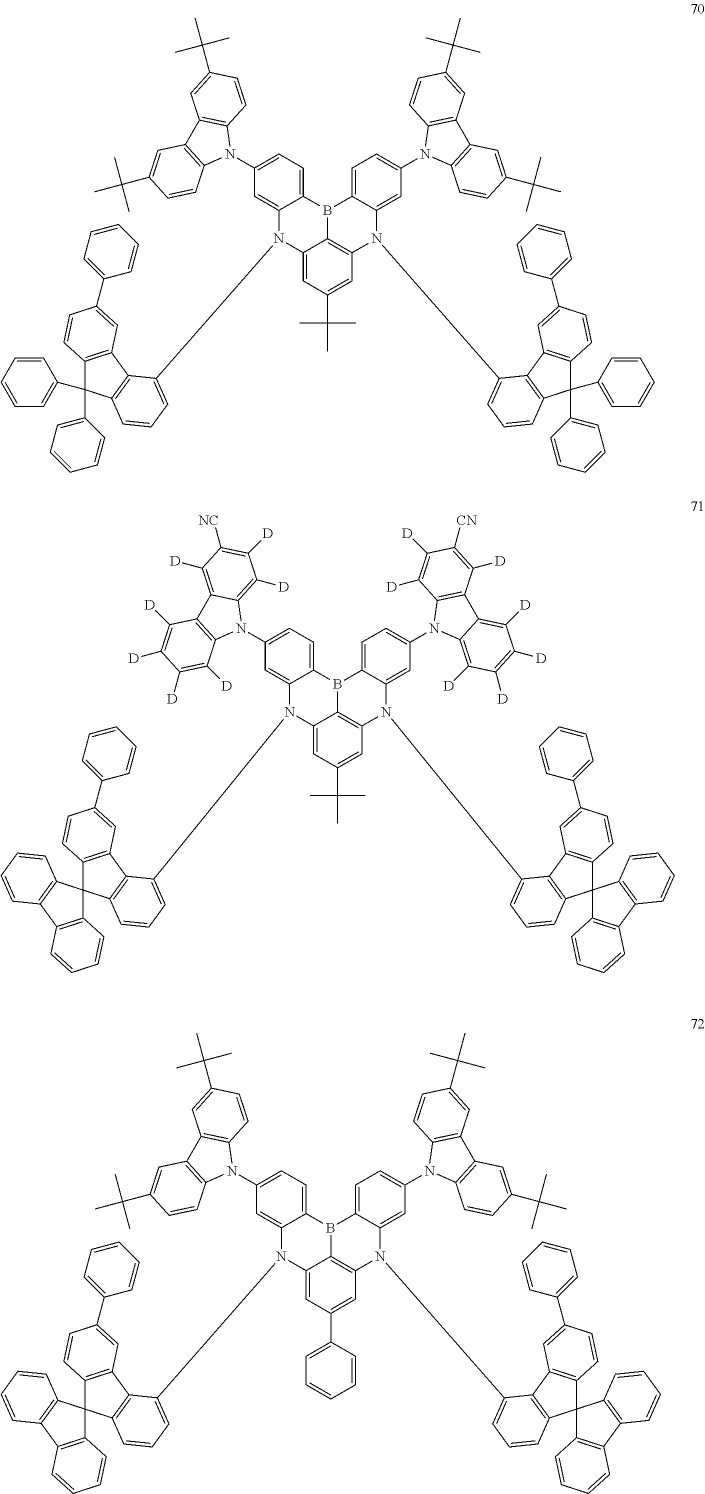 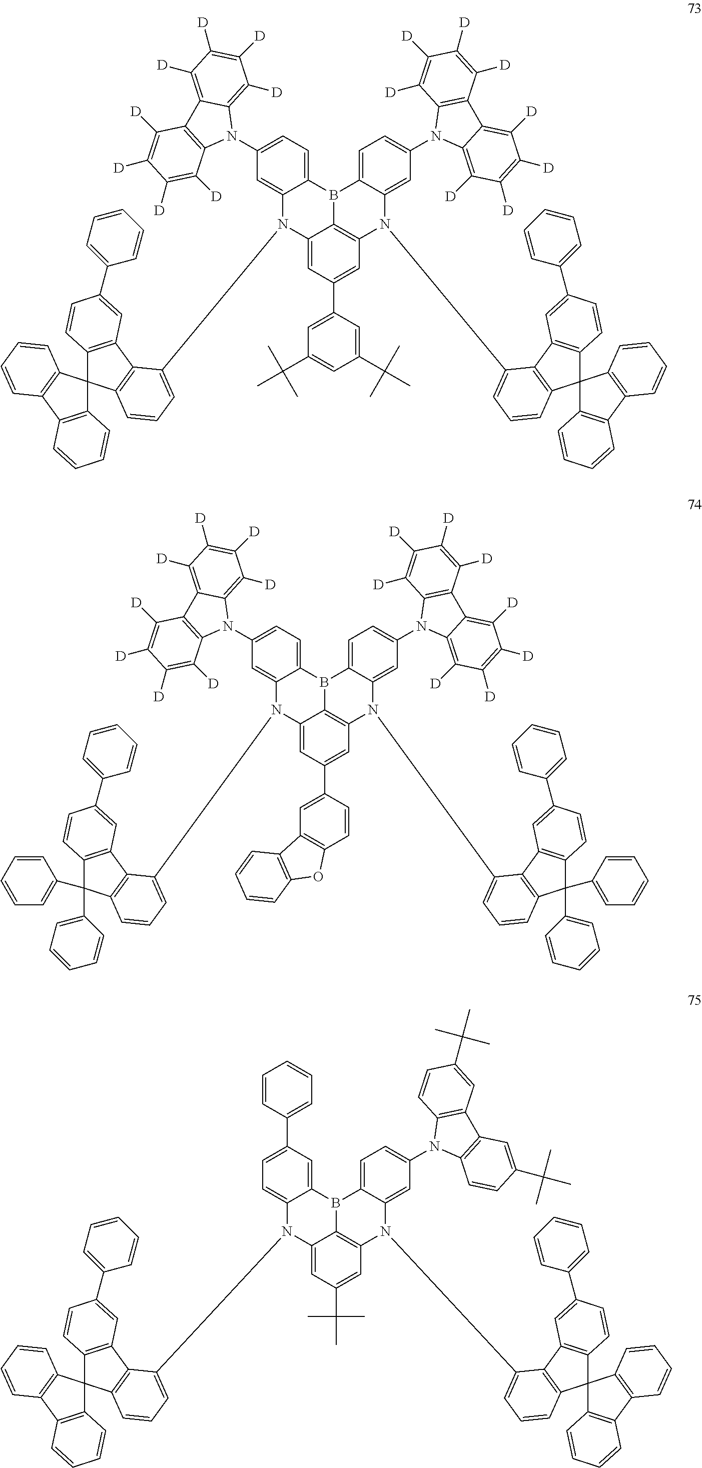
wherein in Compound Group 1,
D represents a deuterium atom.

13. A polycyclic compound represented by Formula 1: 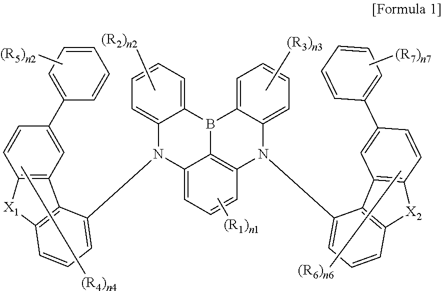
wherein in Formula 1,
X₁ and X₂ are each independently O, S, N(R₈), or C(R₉)(R₁₀),
R₁ to R₇ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms,
R₈ to R₁₀ are each independently a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms, or R₉ and R₁₀ are combined with each other to form a ring,
n1 is an integer from 0 to 3,
n2 and n3 are each independently an integer from 0 to 4,
n4 and n6 are each independently an integer from 0 to 6, and
n5 and n7 are each independently an integer from 0 to 5.

14. The polycyclic compound of claim 13, wherein Formula 1 is represented by one of Formula 2-1 to Formula 2-5: 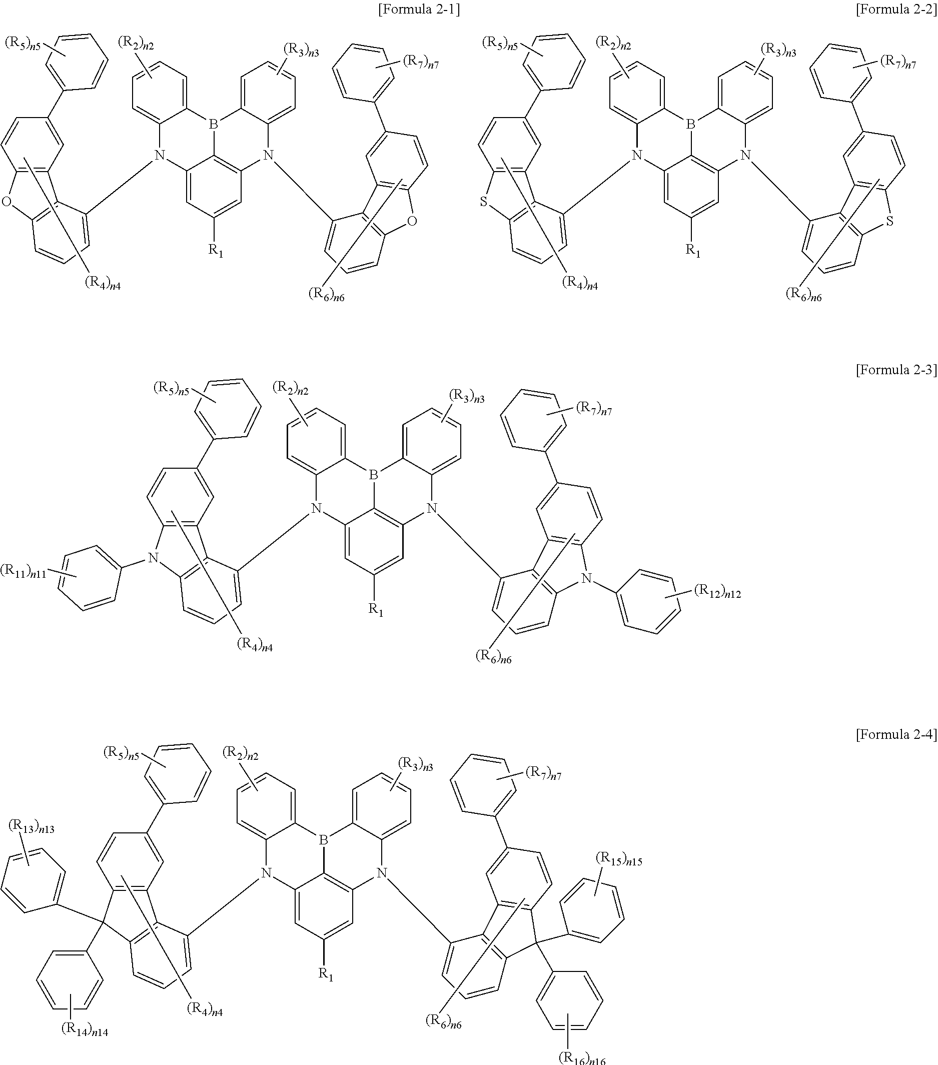 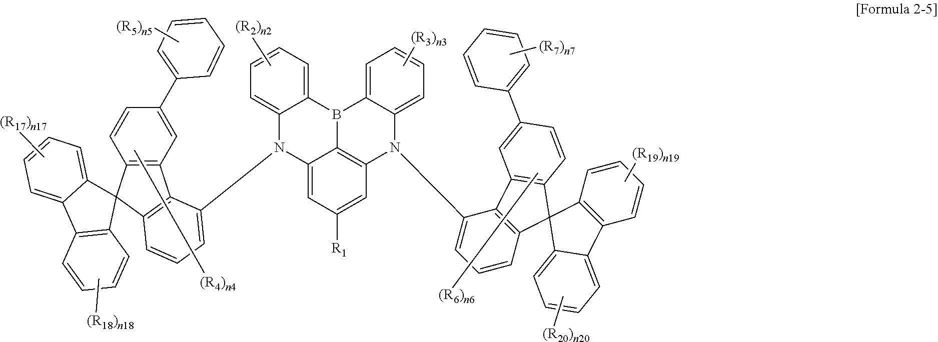
wherein in Formula 2-3 to Formula 2-5,
R₁₁ to R₂₀ are each independently a hydrogen atom, a deuterium atom, a substituted or unsubstituted alkyl group of 1 to 20 carbon atoms, or a substituted or unsubstituted aryl group of 3 to 20 ring-forming carbon atoms,
n11 to n16 are each independently an integer from 0 to 5, and
n17 to n20 are each independently an integer from 0 to 4, and
wherein in Formula 2-1 to Formula 2-5,
R₁ to R₇ and n2 to n7 are the same as defined in Formula 1.

15. The polycyclic compound of claim 13, wherein Formula 1 is represented by Formula 3: 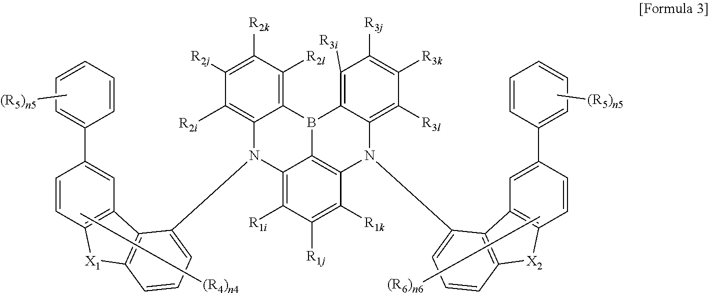
wherein in Formula 3,
at least one of R₁ᵢ, R₁ⱼ, and R₁ₖ is each independently a substituted or unsubstituted t-butyl group, a substituted or unsubstituted dibenzofuran group, a substituted or unsubstituted carbazole group, or a substituted or unsubstituted benzofurocarbazole group,
the remainder of R₁ᵢ, R₁ⱼ, and R₁ₖ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms,
at least one of R₂ᵢ, R₂ⱼ, R₂ₖ, R₂ₗ, R₃ᵢ, R₃ⱼ, R₃ₖ, and R₃ₗ is a substituted or unsubstituted phenyl group or a substituted or unsubstituted carbazole group,
the remainder of R₂ᵢ, R₂ⱼ, R₂ₖ, R₂ₗ, R₃ᵢ, R₃ⱼ, R₃ₖ, and R₃ₗ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms, and
X₁, X₂, R₄ to R₇, and n4 to n7 are the same as defined in Formula 1.

16. The polycyclic compound of claim 13, wherein Formula 1 is represented by one of Formula 4-1 to Formula 4-3: 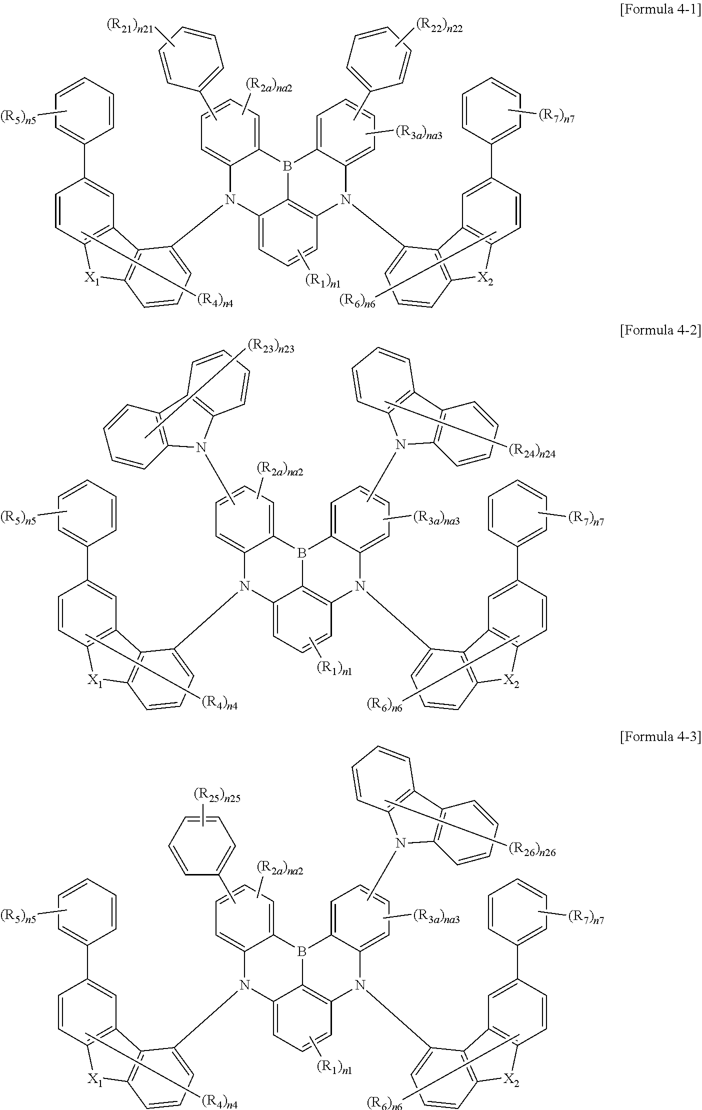
wherein in Formula 4-1 to Formula 4-3,
R₂₁ to R₂₆ are each independently a hydrogen atom, a deuterium atom, a cyano group, a substituted or unsubstituted alkyl group of 1 to 20 carbon atoms, or a substituted or unsubstituted aryl group of 3 to 20 ring-forming carbon atoms,
R₂ₐ and R₃ₐ are each independently a hydrogen atom, a deuterium atom, a substituted or unsubstituted alkyl group of 1 to 30 carbon atoms, a substituted or unsubstituted aryl group of 3 to 30 ring-forming carbon atoms, or a substituted or unsubstituted heteroaryl group of 2 to 30 ring-forming carbon atoms,
n21, n22, and n25 are each independently an integer from 0 to 5,
n23, n24, and n26 are each independently an integer from 0 to 8,
na2 and na3 are each independently an integer from 0 to 3, and
X₁, X₂, R₁, R₄ to R₇, n1, and n4 to n7 are the same as defined in Formula 1.

17. The polycyclic compound of claim 16, wherein Formula 1 is represented by one of Formula 5-1 to Formula 5-4: 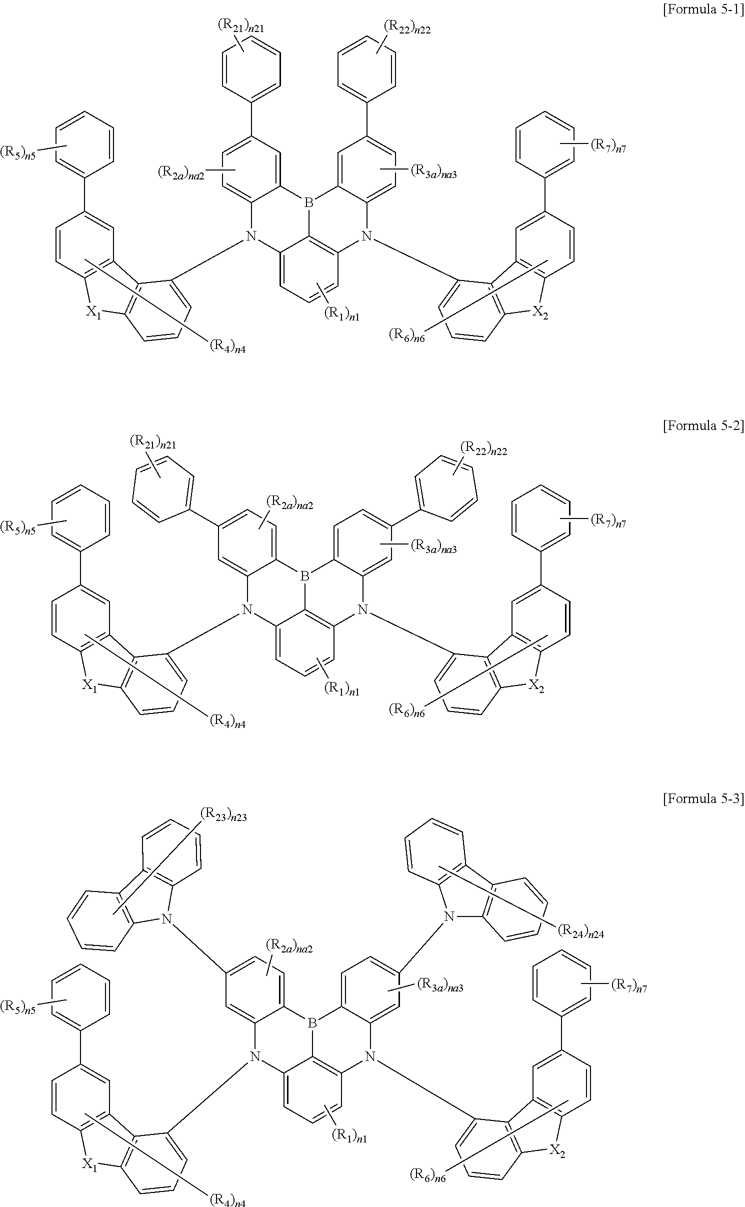 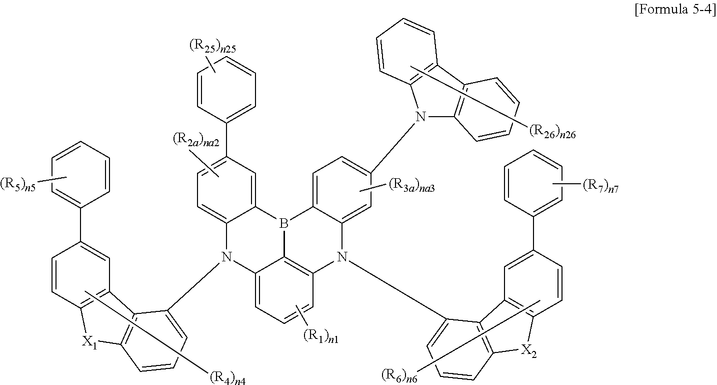
wherein in Formula 5-1 to Formula 5-4,
X₁, X₂, R₁, R₄ to R₇, n1, and n4 to n7 are the same as defined in Formula 1, and
R₂₁ to R₂₆, R₂ₐ, R₃ₐ, n21 to n26, na2, and na3 are the same as defined in Formula 4-1 to Formula 4-3.

18. The polycyclic compound of claim 13, wherein R₁ is a group represented by one of Formula RS-1 to Formula RS-5: 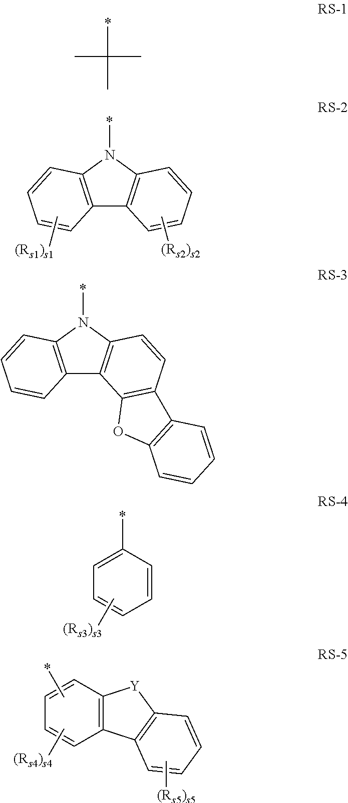
wherein in Formula RS-5,
Y is O or N(Rₛ₆), and
wherein in Formula RS-2, Formula RS-4, and Formula RS-5,
Rₛ₁ to Rₛ₆ are each independently a hydrogen atom, a deuterium atom, a cyano group, a substituted or unsubstituted alkyl group of 1 to 10 carbon atoms, or a substituted or unsubstituted aryl group of 6 to 10 ring-forming carbon atoms,
s1, s2, and s5 are each independently an integer from 0 to 4,
s3 is an integer from 0 to 5, and
s4 is an integer from 0 to 3.

19. The polycyclic compound of claim 13, wherein R₄ to R₇ are each independently a hydrogen atom, a deuterium atom, a substituted or unsubstituted t-butyl group, or a substituted or unsubstituted phenyl group.

20. The polycyclic compound of claim 13, wherein the polycyclic compound represented Formula 1 is selected from Compound Group 1: 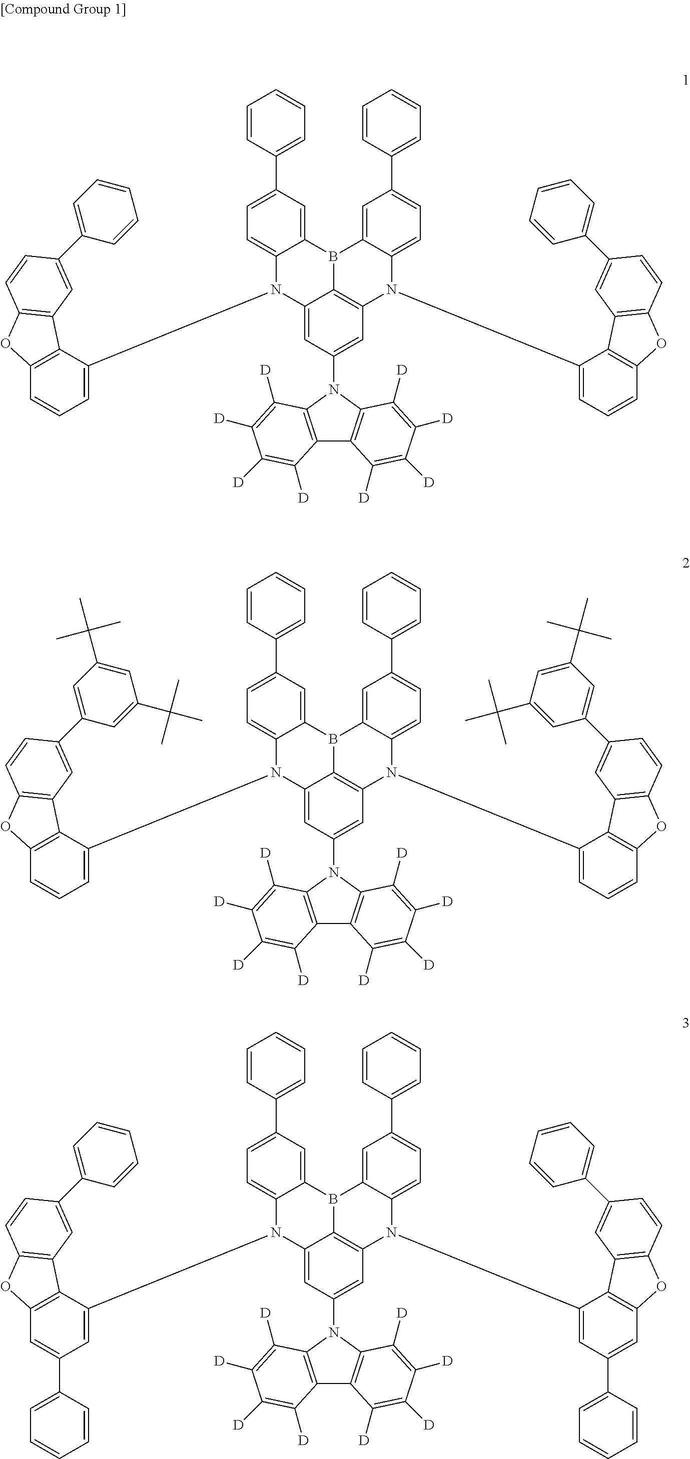 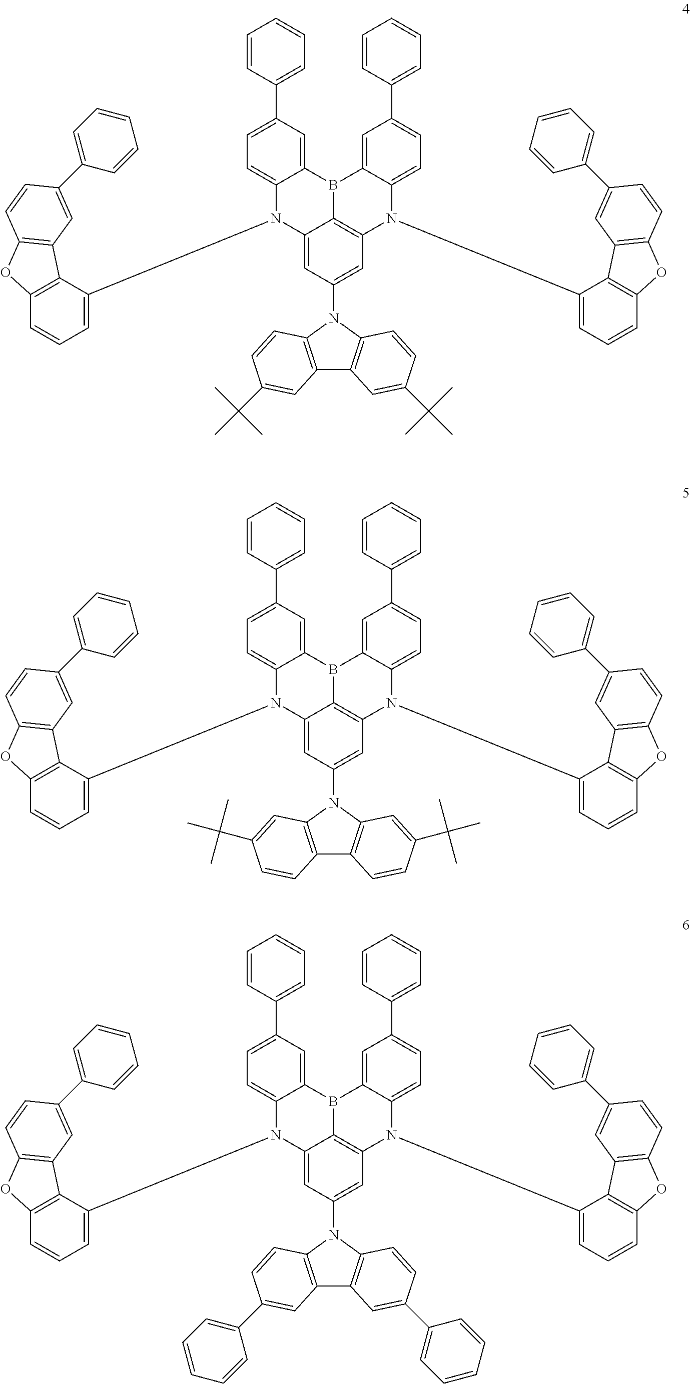 [SMILES: CC(C)(C)c1ccc2c(c1)c1cc(C(C)(C)C)ccc1n2-c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1ccc2c3ccc(C(C)(C)C)cc3n(-c3cc4c5c(c3)N(c3cccc6oc7ccc(-c8ccccc8)cc7c36)c3ccc(-c6ccccc6)cc3B5c3cc(-c5ccccc5)ccc3N4c3cccc4oc5ccc(-c6ccccc6)cc5c34)c2c1 ; c1ccc(-c2ccc3c(c2)B2c4cc(-c5ccccc5)ccc4N(c4cccc5oc6ccc(-c7ccccc7)cc6c45)c4cc(-n5c6ccc(-c7ccccc7)cc6c6cc(-c7ccccc7)ccc65)cc(c42)N3c2cccc3oc4ccc(-c5ccccc5)cc4c23)cc1] 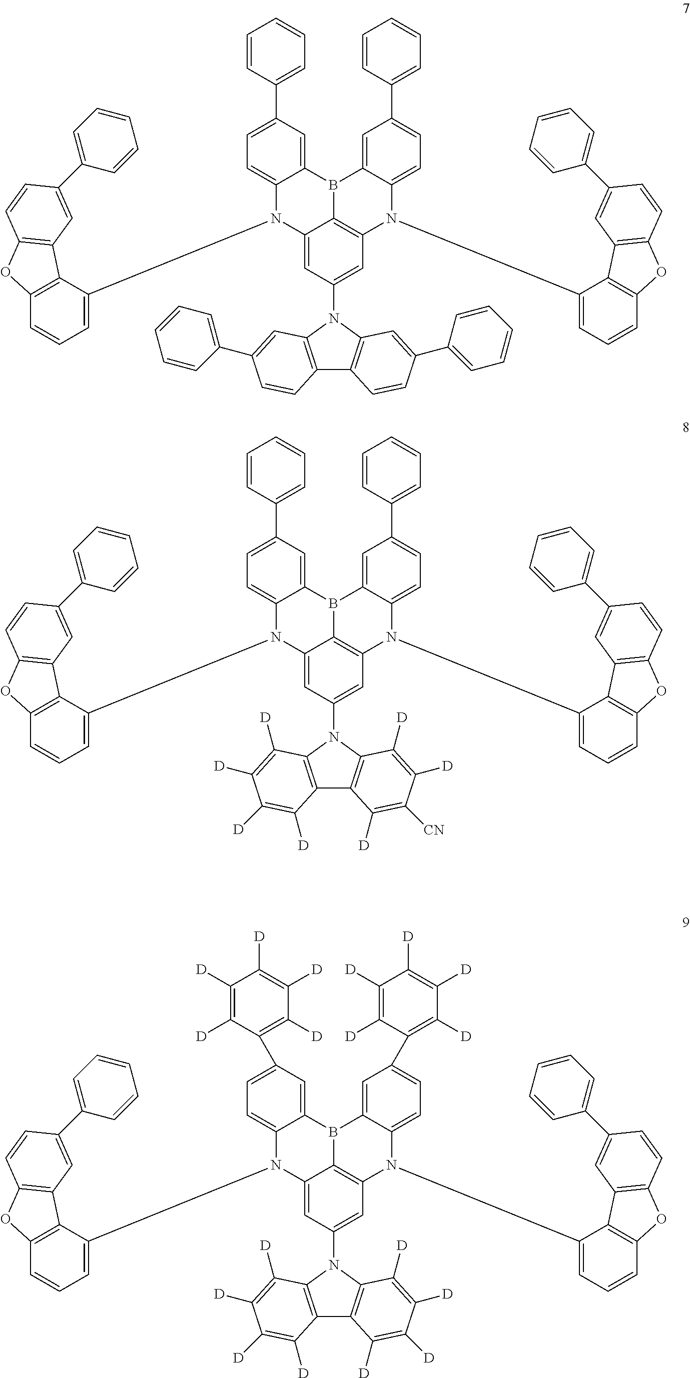 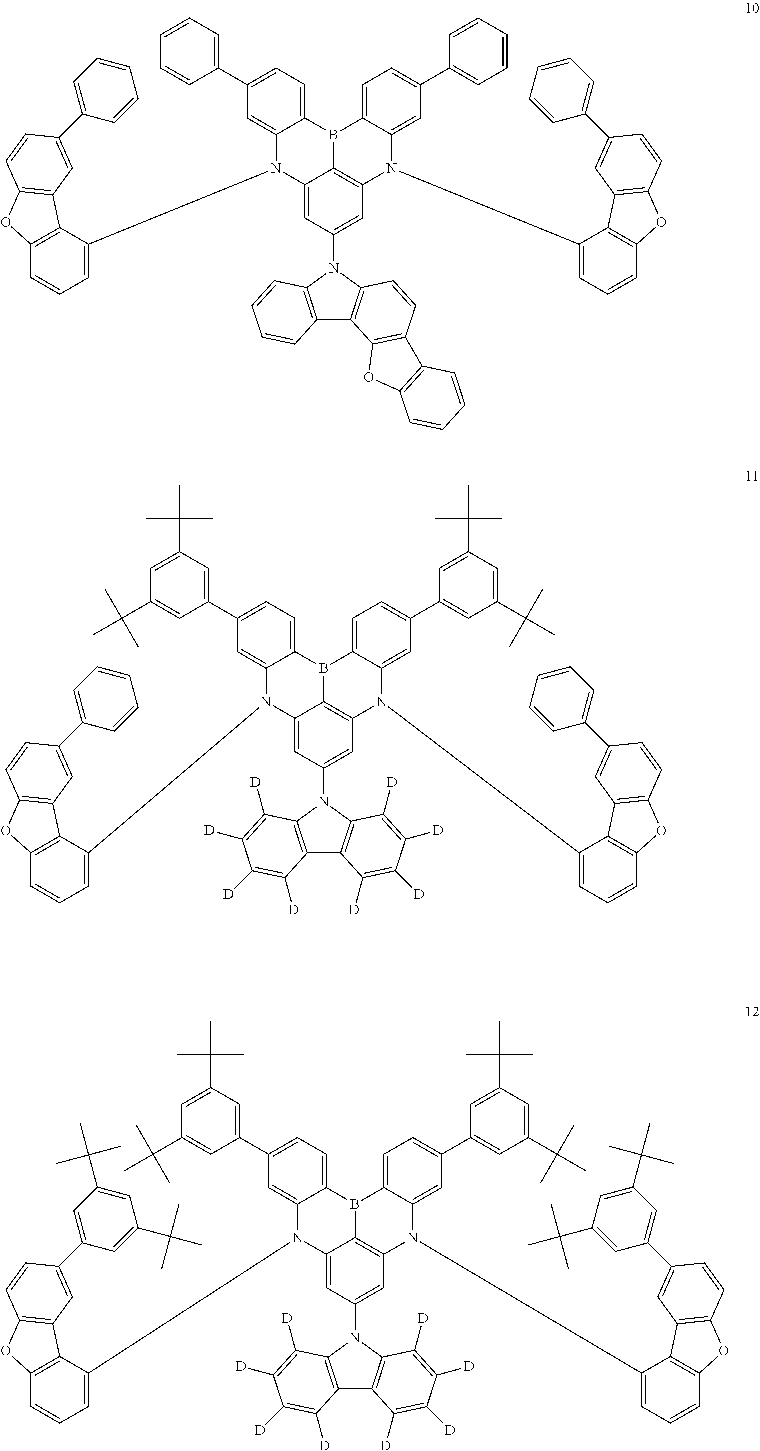 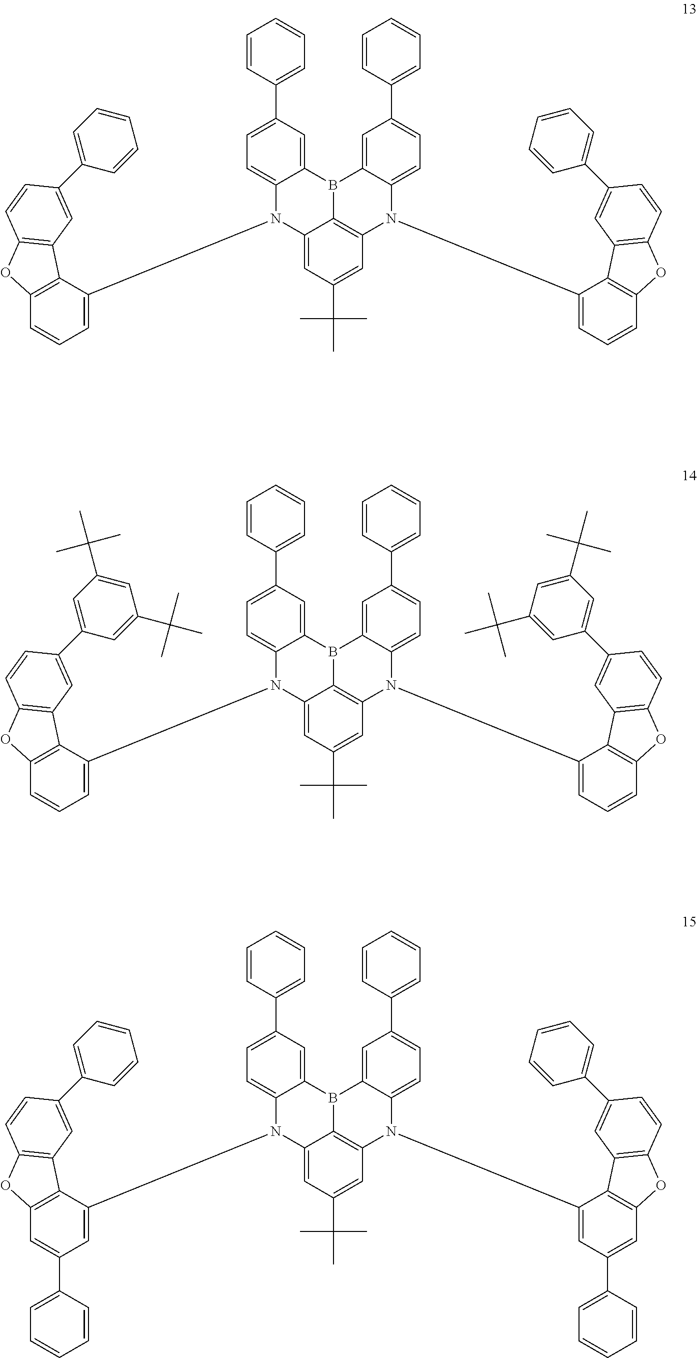 [SMILES: CC(C)(C)c1cc2c3c(c1)N(c1cccc4oc5ccc(-c6ccccc6)cc5c14)c1ccc(-c4ccccc4)cc1B3c1cc(-c3ccccc3)ccc1N2c1cccc2oc3ccc(-c4ccccc4)cc3c12 ; CC(C)(C)c1cc(-c2ccc3oc4cccc(N5c6ccc(-c7ccccc7)cc6B6c7cc(-c8ccccc8)ccc7N(c7cccc8oc9ccc(-c%10cc(C(C)(C)C)cc(C(C)(C)C)c%10)cc9c78)c7cc(C(C)(C)C)cc5c76)c4c3c2)cc(C(C)(C)C)c1 ; CC(C)(C)c1cc2c3c(c1)N(c1cc(-c4ccccc4)cc4oc5ccc(-c6ccccc6)cc5c14)c1ccc(-c4ccccc4)cc1B3c1cc(-c3ccccc3)ccc1N2c1cc(-c2ccccc2)cc2oc3ccc(-c4ccccc4)cc3c12] 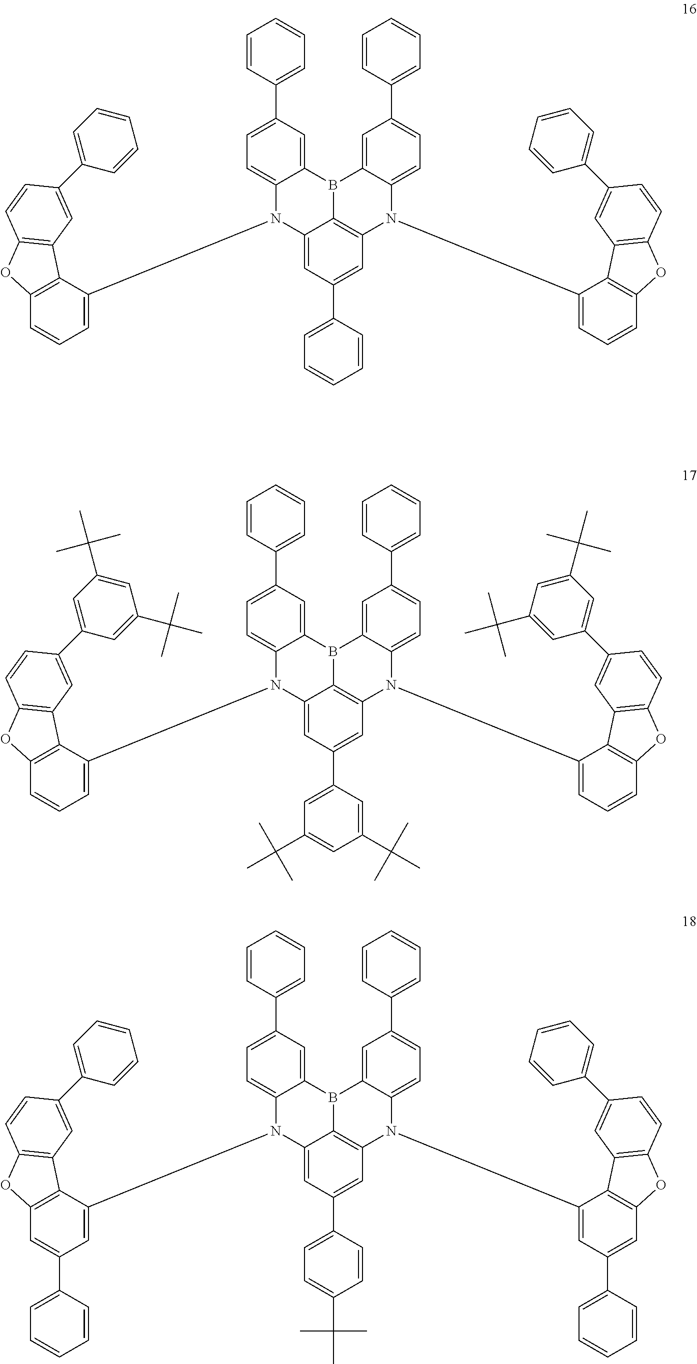 [SMILES: c1ccc(-c2ccc3c(c2)B2c4cc(-c5ccccc5)ccc4N(c4cccc5oc6ccc(-c7ccccc7)cc6c45)c4cc(-c5ccccc5)cc(c42)N3c2cccc3oc4ccc(-c5ccccc5)cc4c23)cc1 ; CC(C)(C)c1cc(-c2cc3c4c(c2)N(c2cccc5oc6ccc(-c7cc(C(C)(C)C)cc(C(C)(C)C)c7)cc6c25)c2ccc(-c5ccccc5)cc2B4c2cc(-c4ccccc4)ccc2N3c2cccc3oc4ccc(-c5cc(C(C)(C)C)cc(C(C)(C)C)c5)cc4c23)cc(C(C)(C)C)c1 ; CC(C)(C)c1ccc(-c2cc3c4c(c2)N(c2cc(-c5ccccc5)cc5oc6ccc(-c7ccccc7)cc6c25)c2ccc(-c5ccccc5)cc2B4c2cc(-c4ccccc4)ccc2N3c2cc(-c3ccccc3)cc3oc4ccc(-c5ccccc5)cc4c23)cc1] 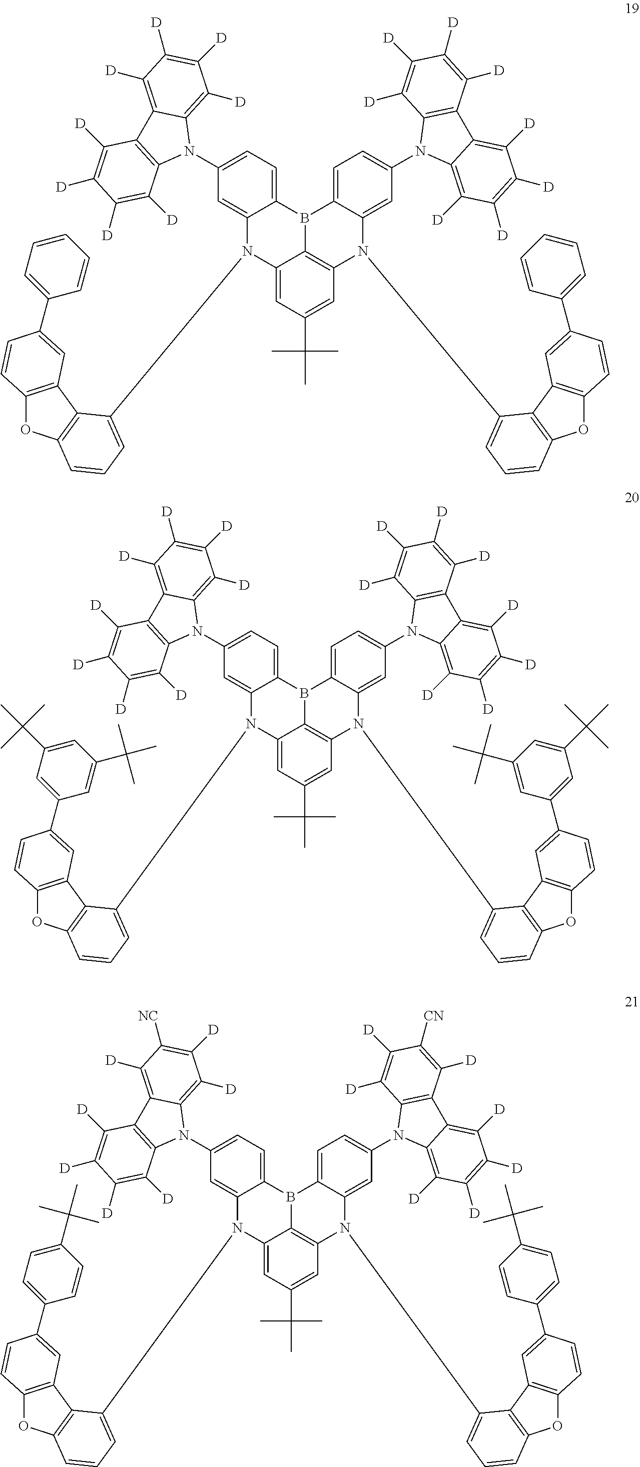 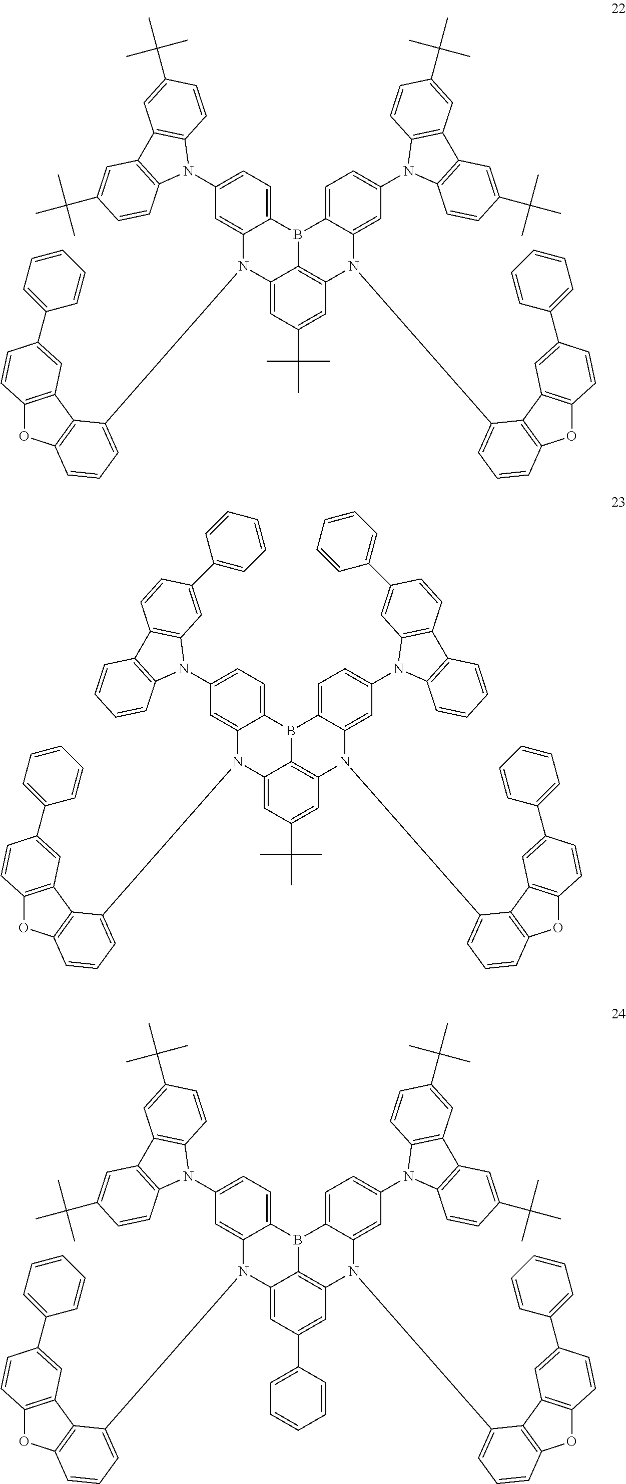 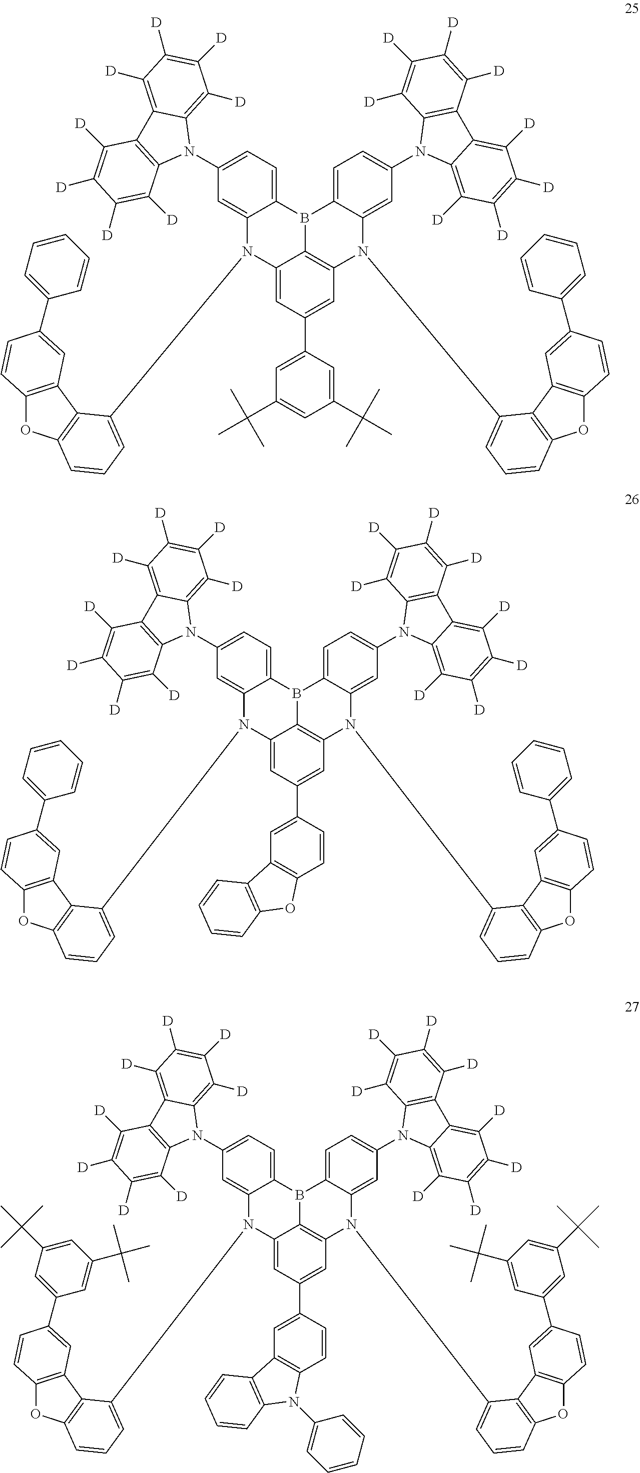 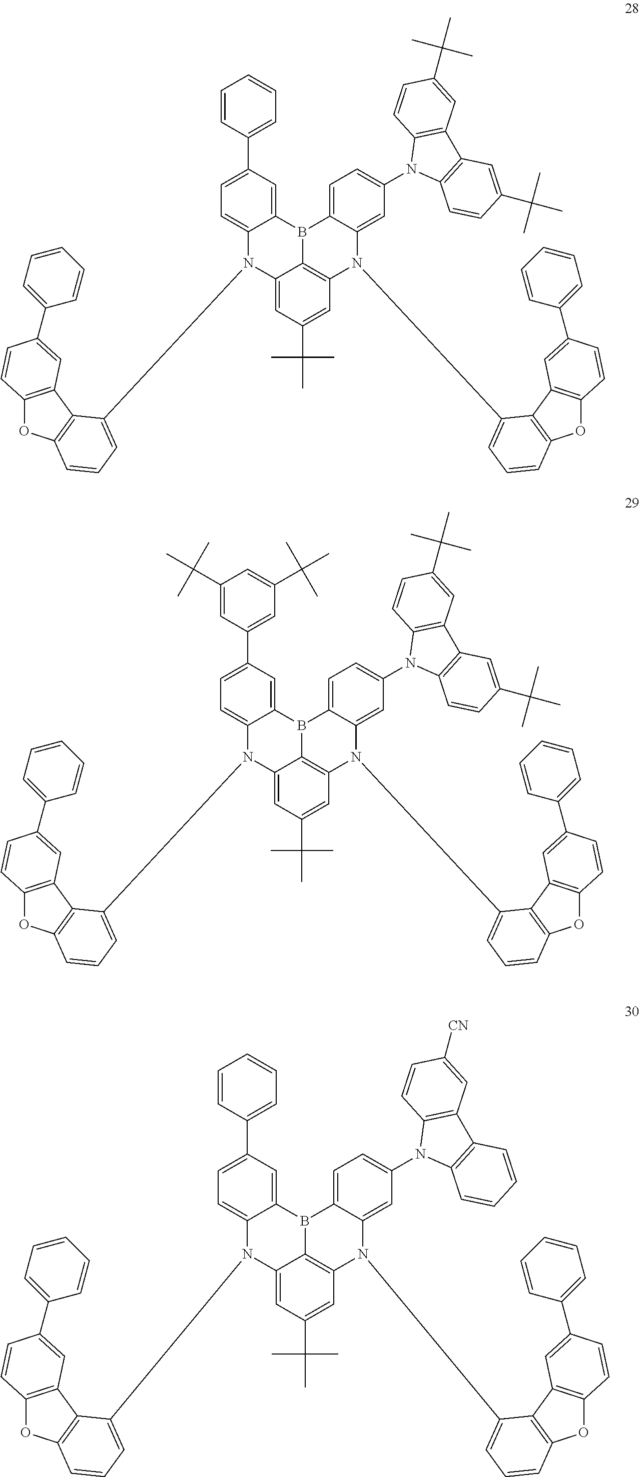 [SMILES: CC(C)(C)c1cc2c3c(c1)N(c1cccc4oc5ccc(-c6ccccc6)cc5c14)c1cc(-n4c5ccc(C(C)(C)C)cc5c5cc(C(C)(C)C)ccc54)ccc1B3c1cc(-c3ccccc3)ccc1N2c1cccc2oc3ccc(-c4ccccc4)cc3c12 ; CC(C)(C)c1cc(-c2ccc3c(c2)B2c4ccc(-n5c6ccc(C(C)(C)C)cc6c6cc(C(C)(C)C)ccc65)cc4N(c4cccc5oc6ccc(-c7ccccc7)cc6c45)c4cc(C(C)(C)C)cc(c42)N3c2cccc3oc4ccc(-c5ccccc5)cc4c23)cc(C(C)(C)C)c1 ; CC(C)(C)c1cc2c3c(c1)N(c1cccc4oc5ccc(-c6ccccc6)cc5c14)c1cc(-n4c5ccccc5c5cc(C#N)ccc54)ccc1B3c1cc(-c3ccccc3)ccc1N2c1cccc2oc3ccc(-c4ccccc4)cc3c12] 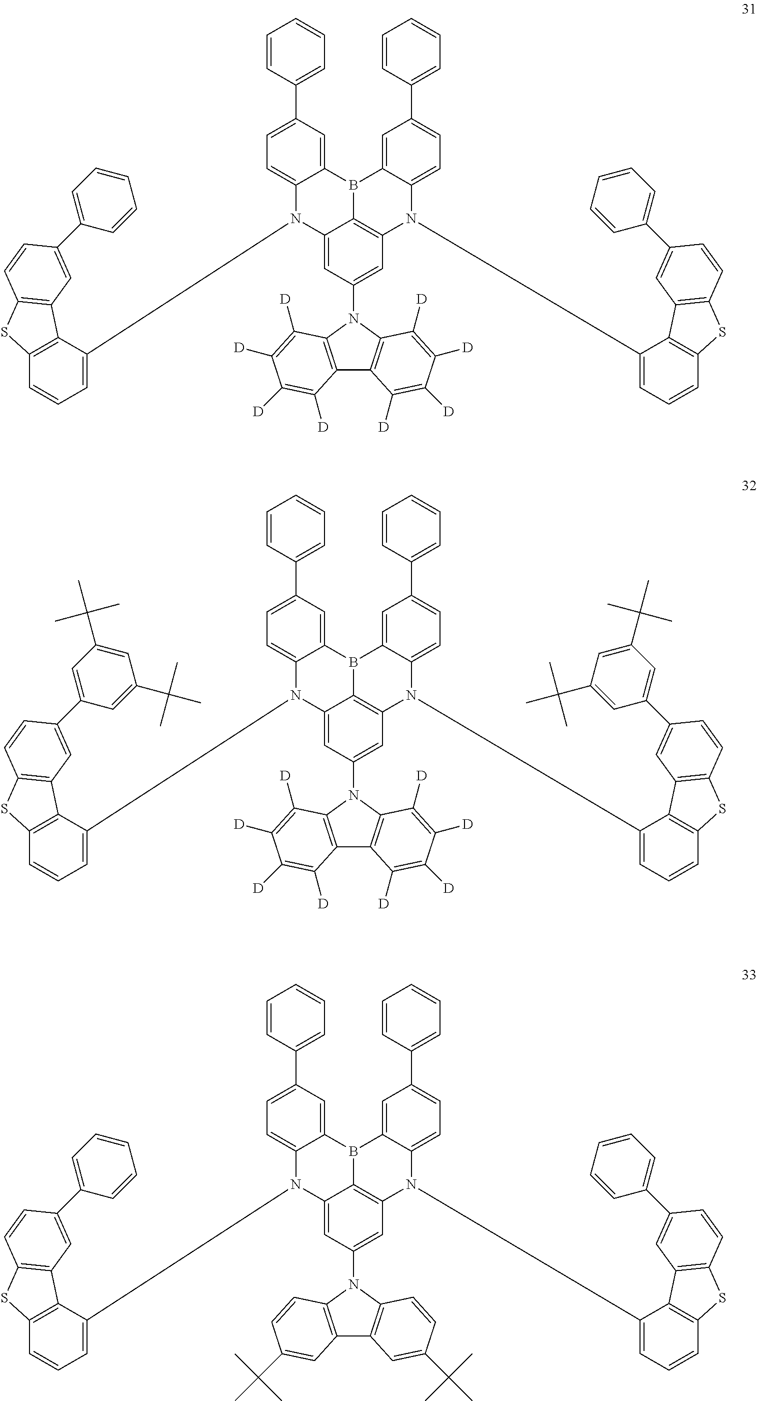 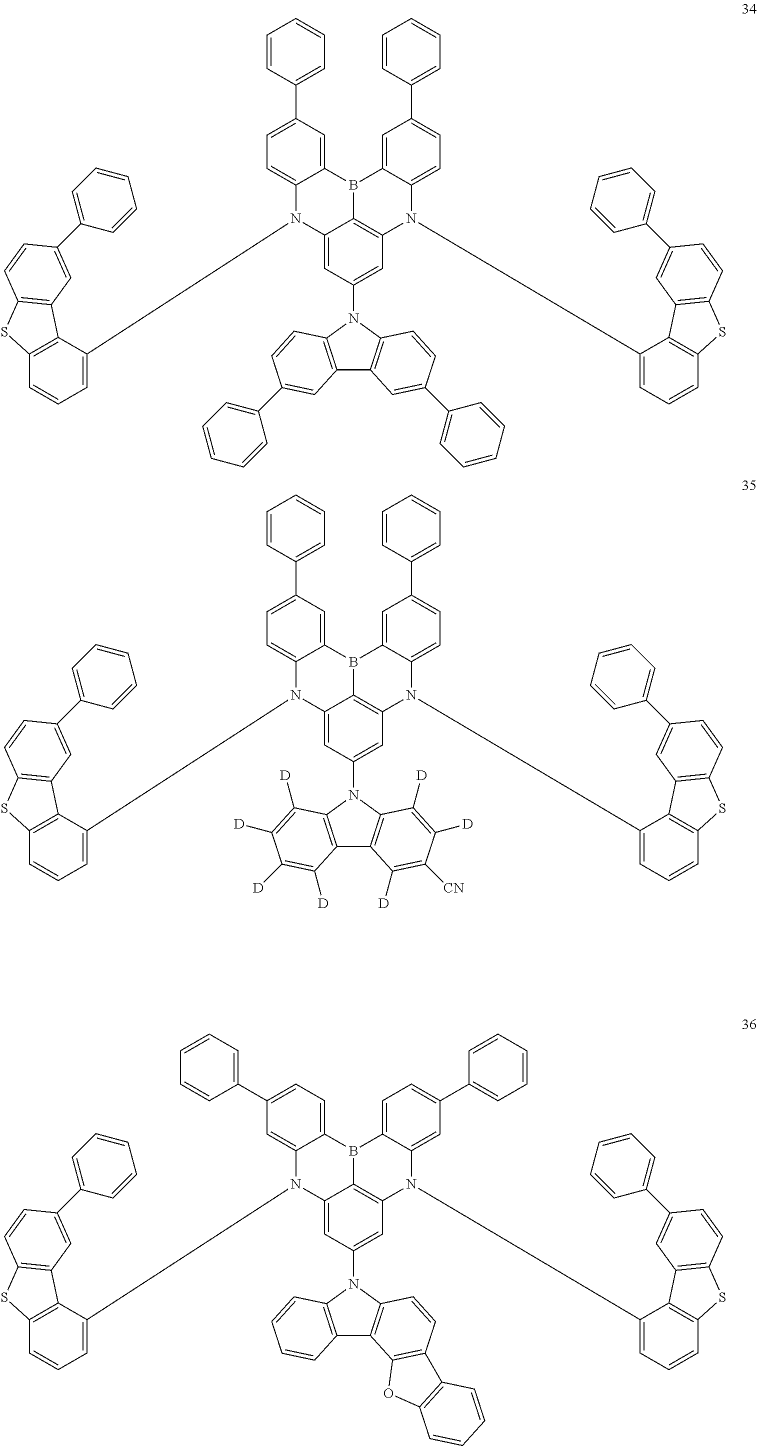 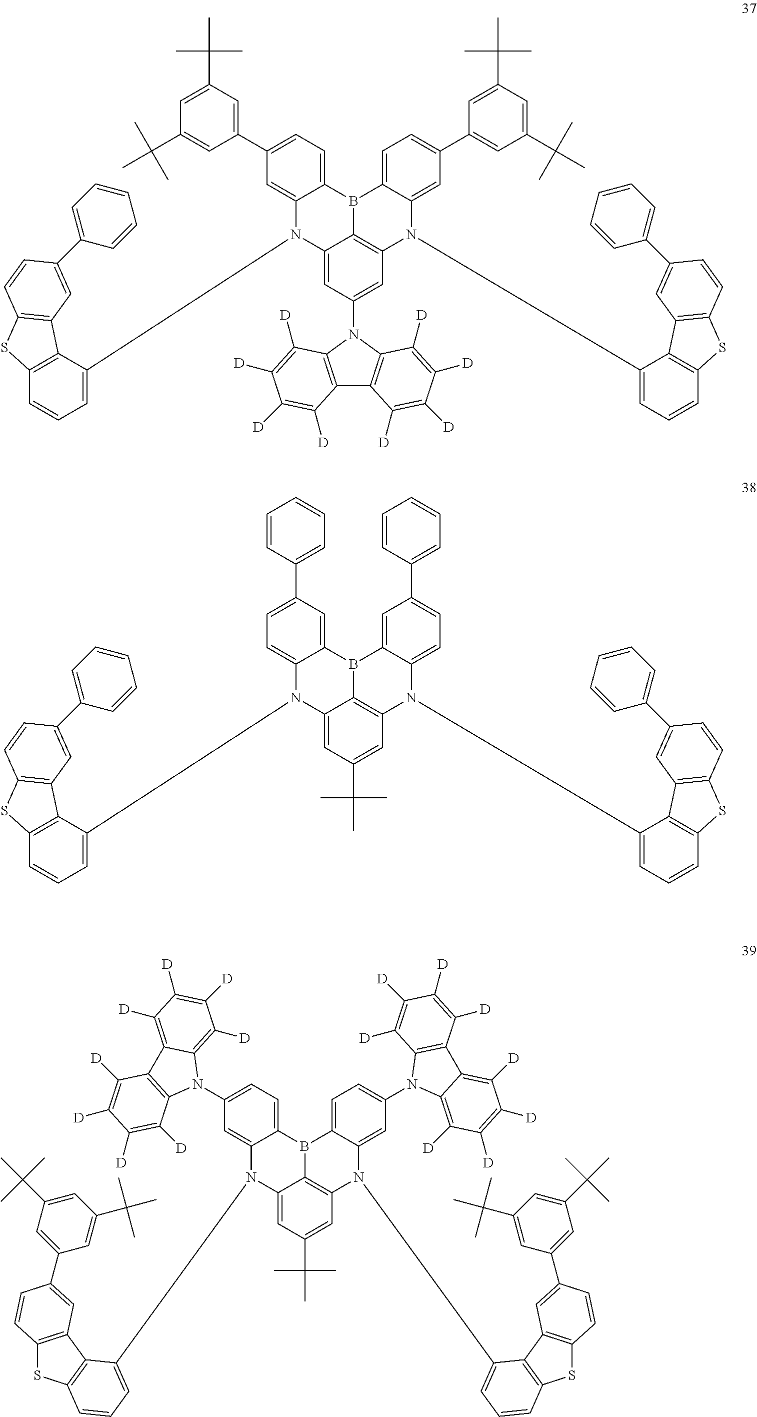 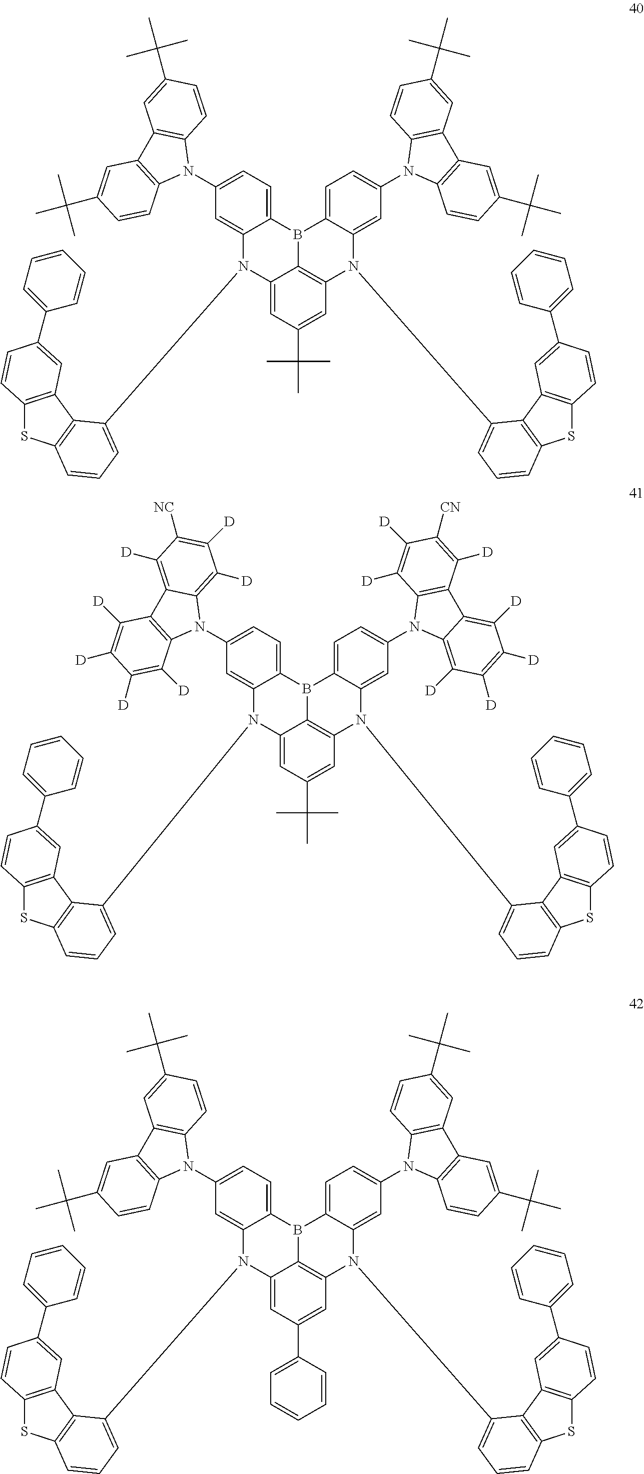 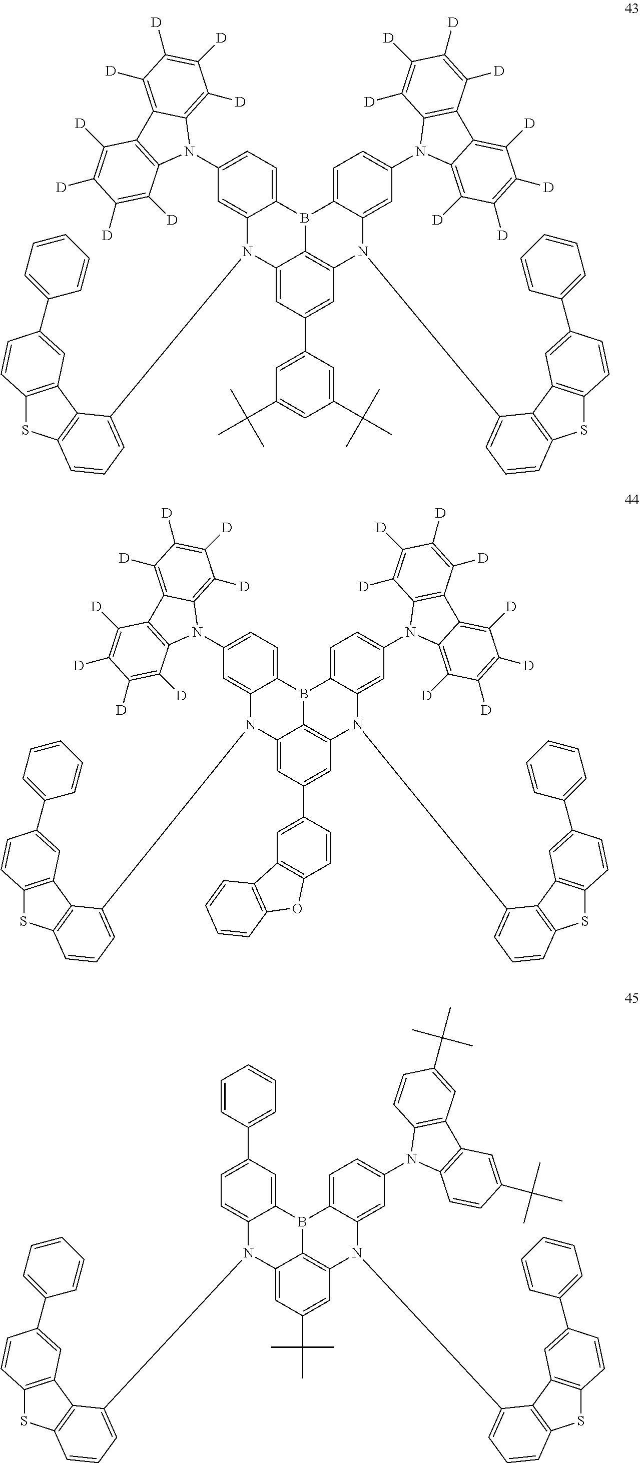 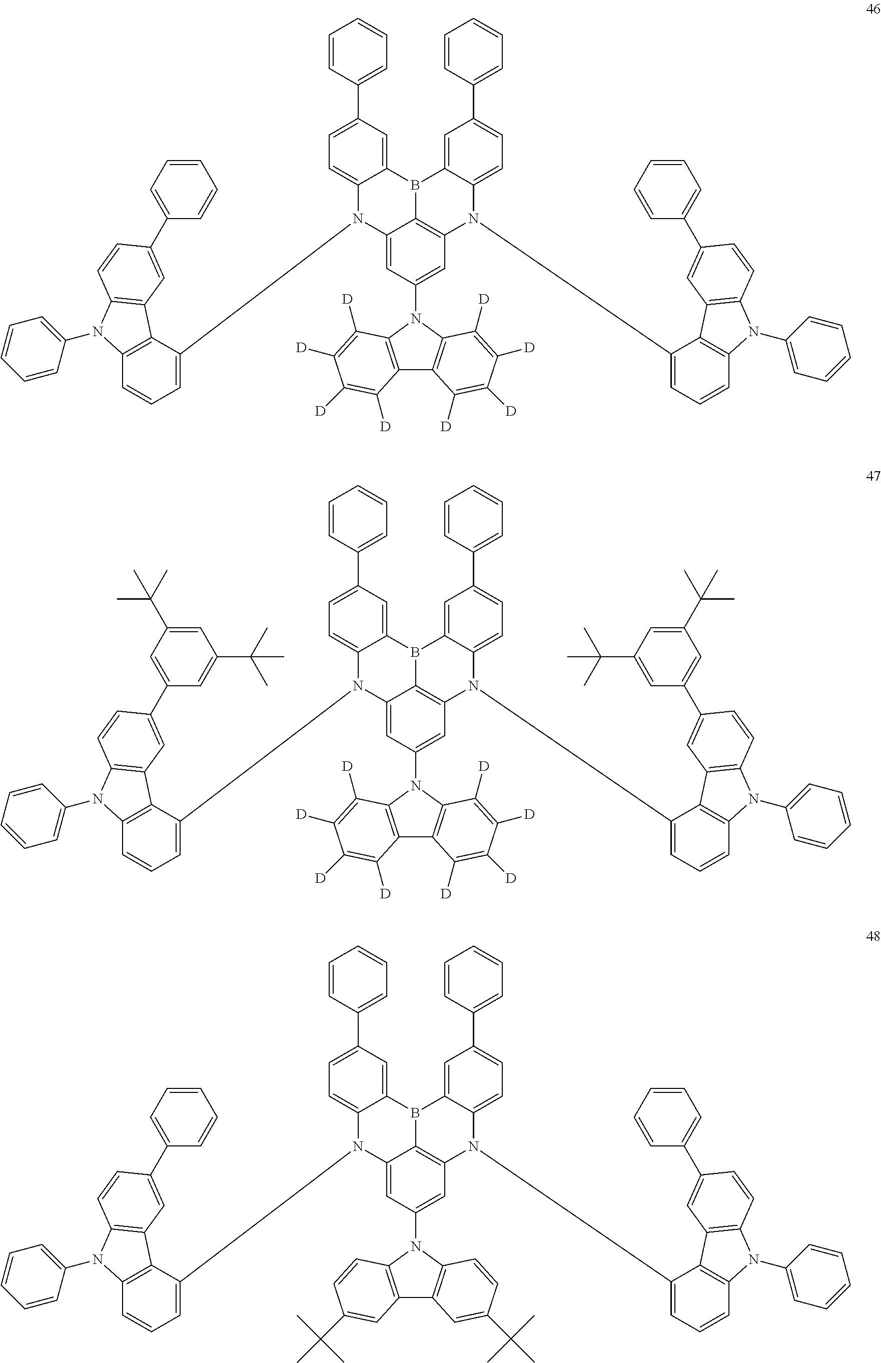 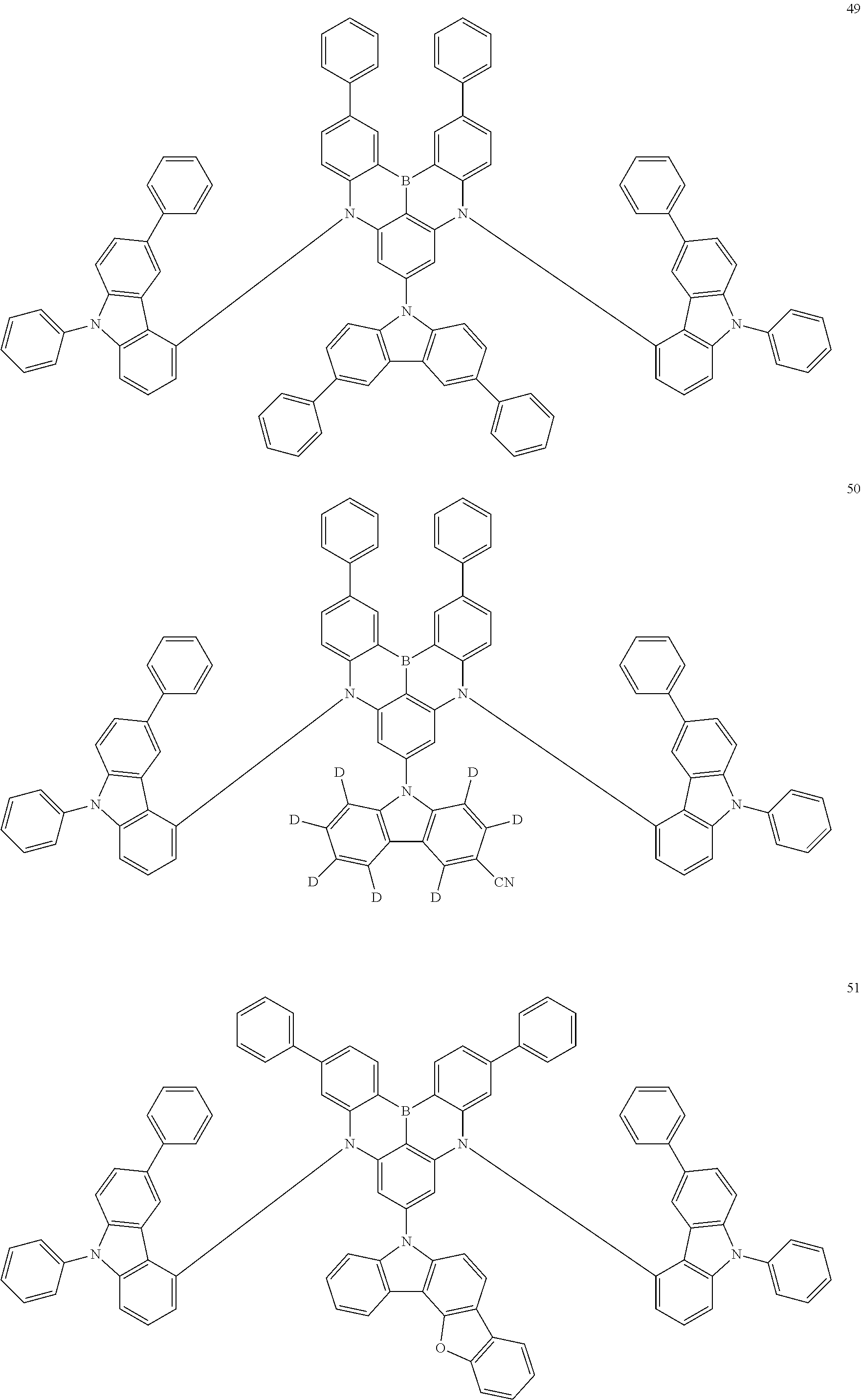 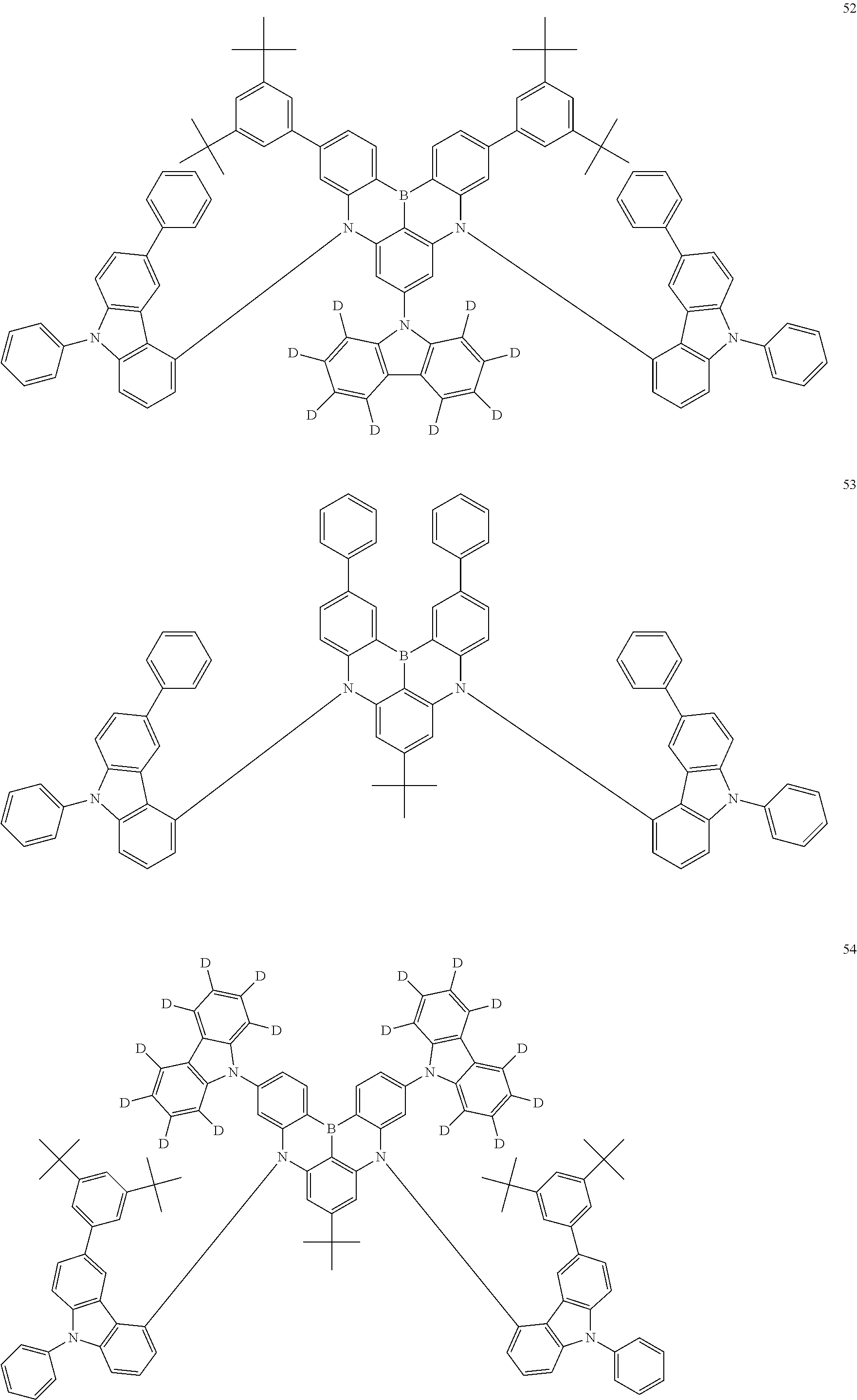 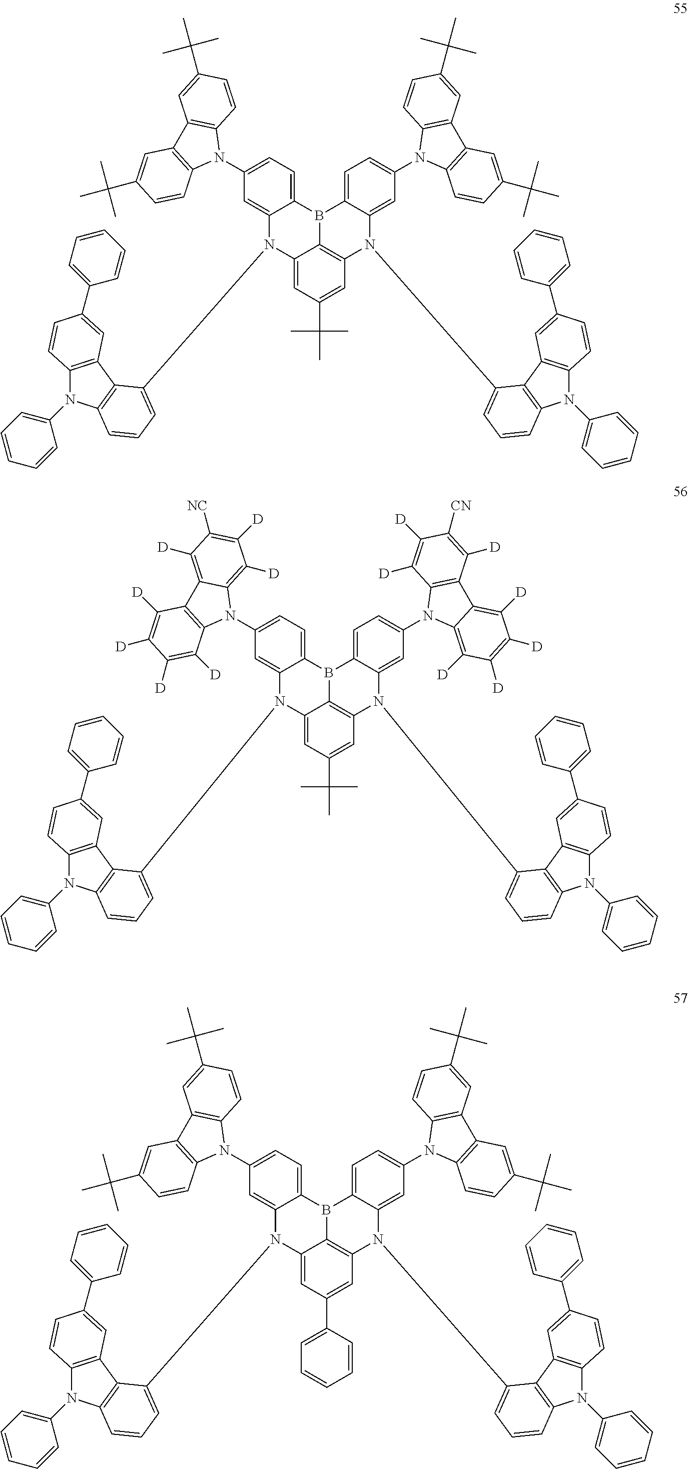 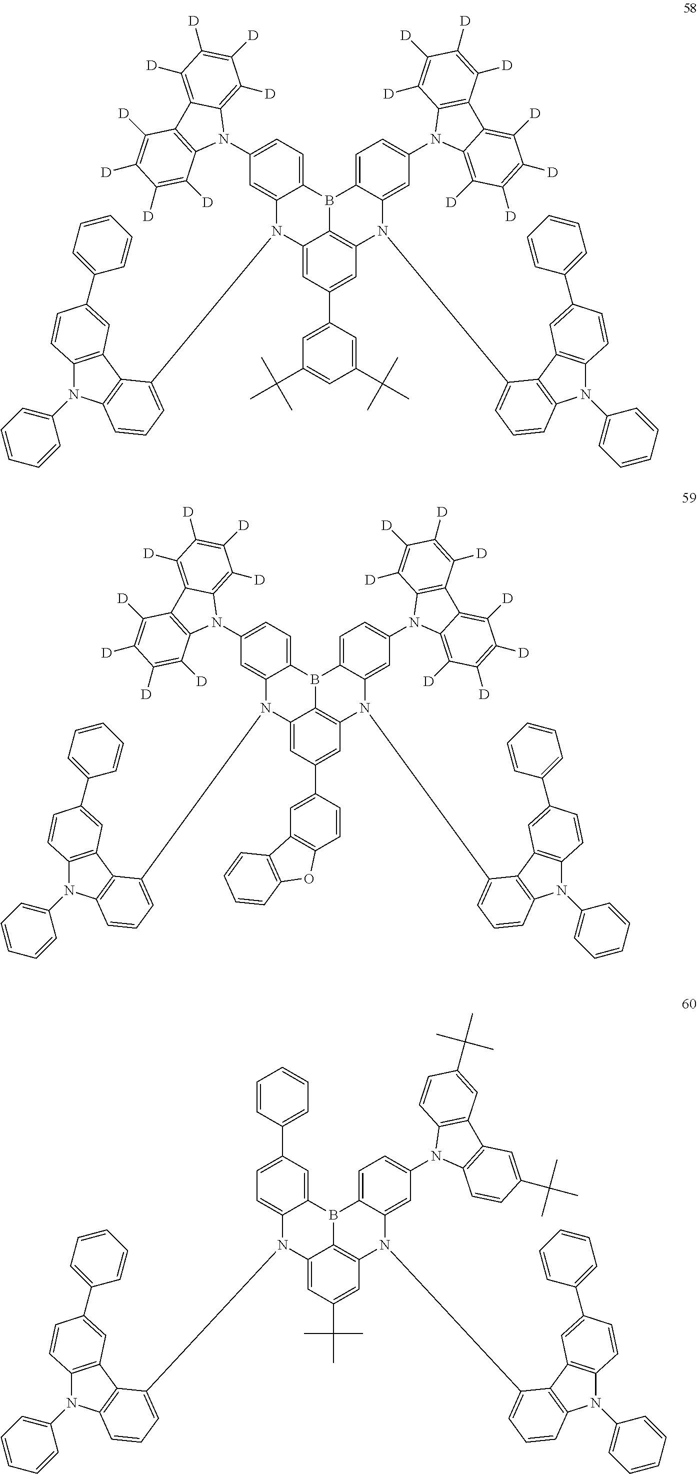 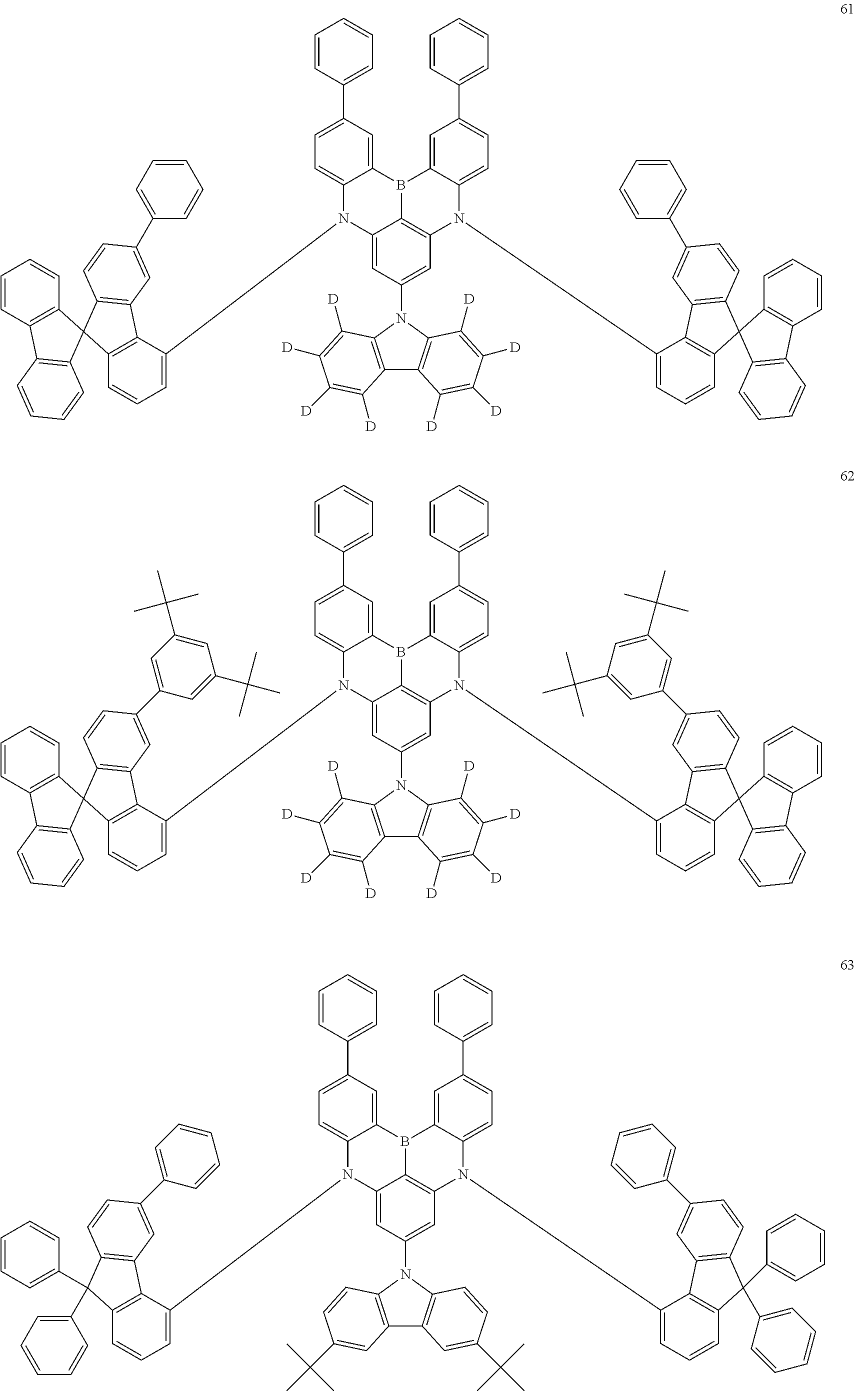 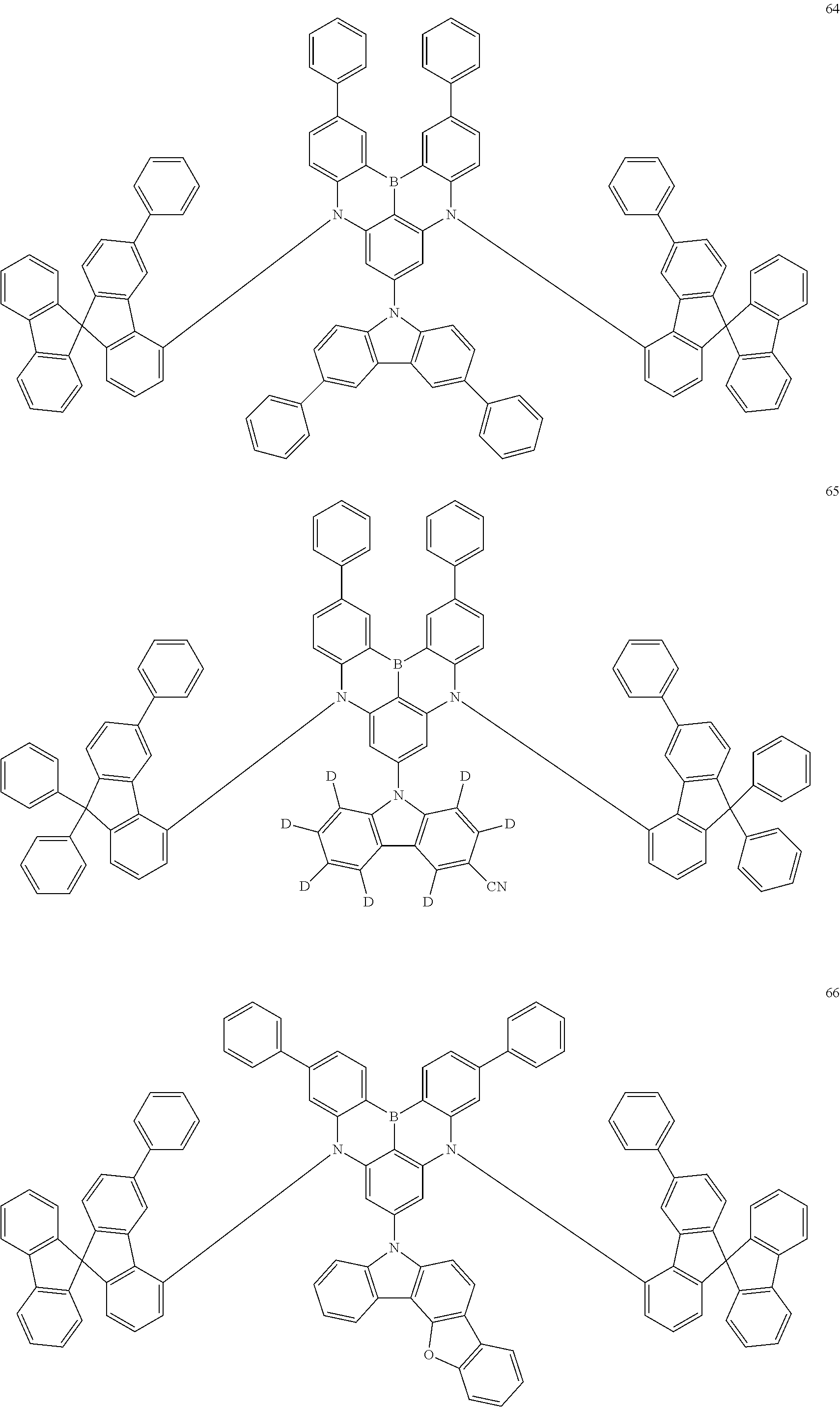 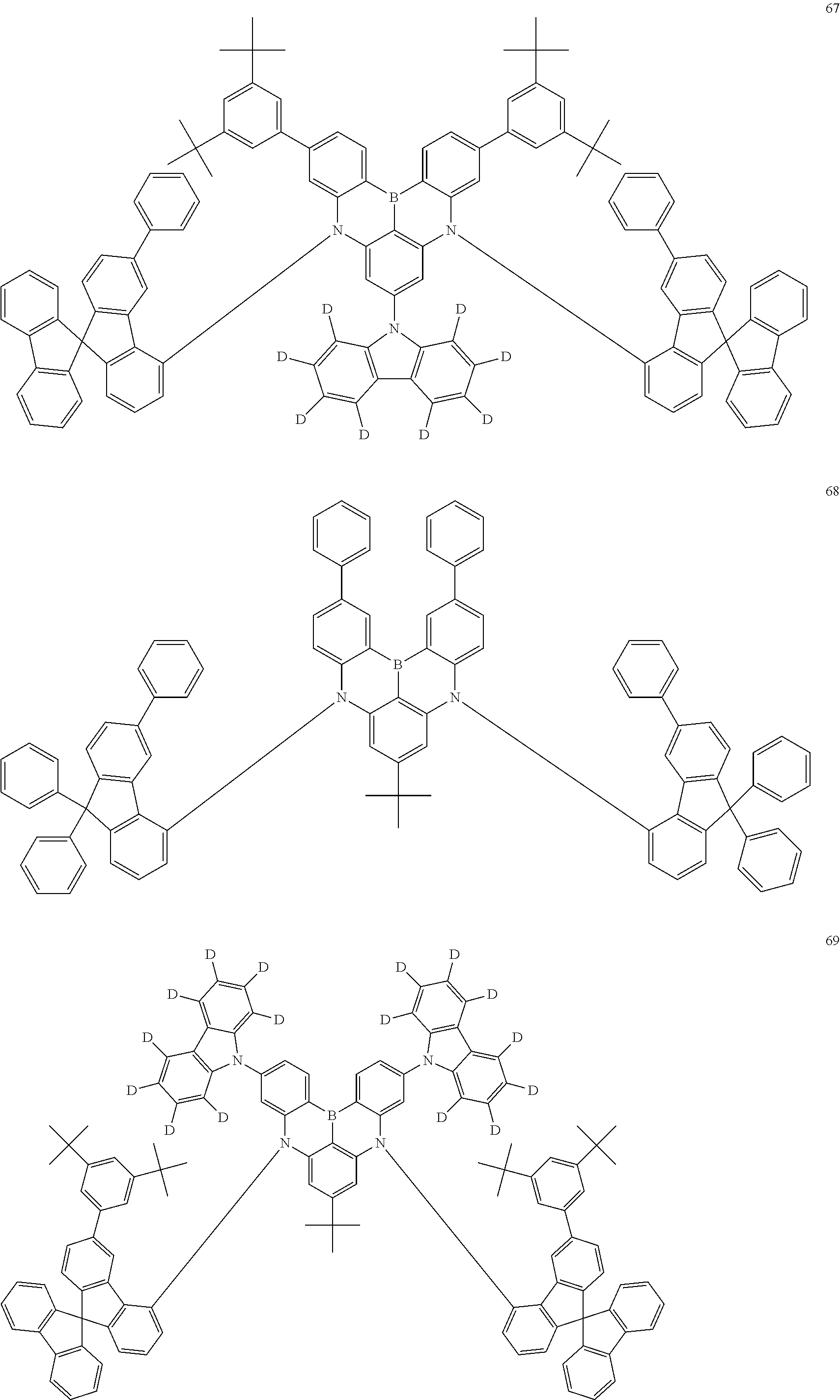 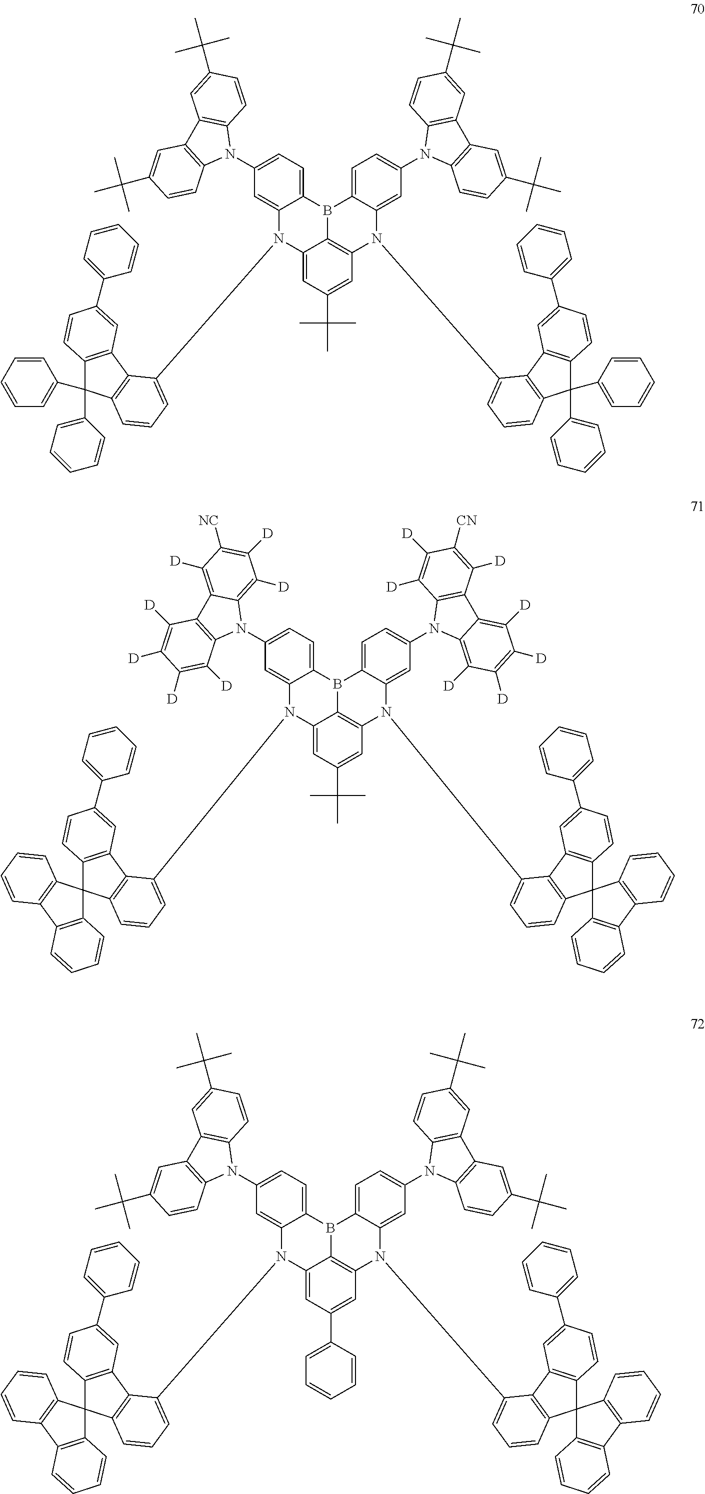 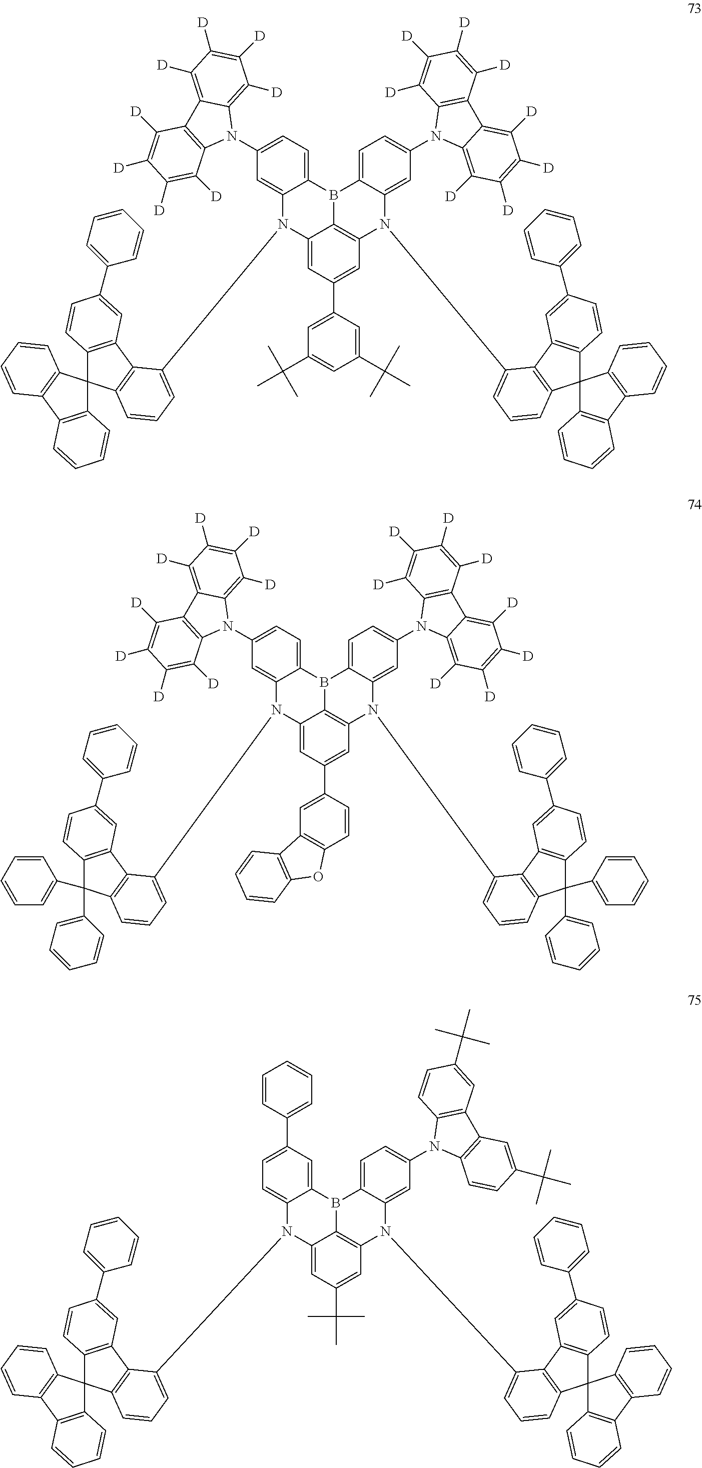
wherein in Compound Group 1,
D represents a deuterium atom.
